(19) United States
(12) Patent Application Publication
(10) Pub. No.: US 2025/0386702 A1
(43) Pub. Date: Dec. 18, 2025

(54) LIGHT-EMITTING DEVICE AND DISPLAY DEVICE

(71) Applicant: SEMICONDUCTOR ENERGY LABORATORY CO., LTD., Atsugi-shi (JP)

(72) Inventors: Satoshi SEO, Sagamihara (JP); Nobuharu OHSAWA, Zama (JP); Hiromi SEO, Sagamihara (JP); Hiromitsu KIDO, Atsugi (JP); Yuki HAYASHI, Atsugi (JP)

(21) Appl. No.: 19/232,097

(22) Filed: Jun. 9, 2025

(30) Foreign Application Priority Data
Jun. 13, 2024 (JP) 2024-096254

(51) Int. Cl. H10K 59/38; H10K 50/16; H10K 85/30; H10K 85/40; H10K 85/60

(52) U.S. Cl. CPC H10K 59/38; H10K 50/167; H10K 85/342; H10K 85/346; H10K 85/40; H10K 85/622; H10K 85/626; H10K 85/633; H10K 85/636; H10K 85/654; H10K 85/656; H10K 85/6572; H10K 85/6574; H10K 85/6576; H10K 85/658

(57) ABSTRACT

A light-emitting device having favorable characteristics is provided. In the light-emitting device, an intermediate layer is positioned between first and second electrodes. A first light-emitting layer is positioned between the first electrode and the intermediate layer. A second light-emitting layer is positioned between the intermediate layer and the second electrode. The first light-emitting layer includes a first emission center substance and a first organic compound. The first organic compound includes deuterium. The second light-emitting layer includes a second emission center substance. The first emission center substance is a phosphorescent substance having an emission peak in a wavelength range of 440 nm to 500 nm. The difference between the maximum peak wavelengths of the PL spectra of the first and second emission center substances is 30 nm or less. The first and second light-emitting layers each emit light with a color gamut different from a color gamut of light emitted by a light-emitting layer included in at least one of adjacent light-emitting devices.

### BACKGROUND OF THE INVENTION

### 1. Field of the Invention

One embodiment of the present invention relates to a light-emitting device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting apparatus, a lighting device, a power storage device, a memory device, an imaging device, an electronic appliance, a driving method thereof, and a manufacturing method thereof.

### 2. Description of the Related Art

Recently, display devices have been expected to be applied to a variety of uses. Usage examples of large-sized display devices include a television device for home use (also referred to as TV or television receiver), digital signage, and a public information display (PID). In addition, a smartphone and a tablet terminal each including a touch panel, for example, are being developed as portable information terminals.

Higher-resolution display devices have been required. For example, devices for virtual reality (VR), augmented reality (AR), substitutional reality (SR), or mixed reality (MR) are given as devices requiring high-resolution display devices and have been actively developed.

Light-emitting apparatuses that include light-emitting devices (also referred to as light-emitting elements) have been developed as display devices, for example. Light-emitting devices utilizing electroluminescence (hereinafter referred to as EL; such devices are also referred to as EL devices or EL elements) have features such as ease of reduction in thickness and weight, high-speed response to input signals, and driving with a constant voltage DC power source, and have been widely used in display devices.

Tandem light-emitting devices have attracted particular attention because of their high current efficiency, and Patent Documents 1 and 2 disclose tandem light-emitting devices fabricated by a side-by-side patterning method.

### REFERENCES

[Patent Document 1] Japanese Published Patent Application No. 2005-317548
[Patent Document 2] Japanese Published Patent Application No. 2023-161850

### SUMMARY OF THE INVENTION

An object of one embodiment of the present invention is to provide a light-emitting device having favorable characteristics. Another object of one embodiment of the present invention is to provide a light-emitting device having high emission efficiency. Another object of one embodiment of the present invention is to provide a light-emitting device having high reliability. Another object of one embodiment of the present invention is to provide a light-emitting device having a low driving voltage. Another object of one embodiment of the present invention is to provide a light-emitting device having high reliability and a low driving voltage.

Another object of one embodiment of the present invention is to provide a light-emitting device which enables a display device to have favorable characteristics. Another object of one embodiment of the present invention is to provide a light-emitting device which enables a display device to have high emission efficiency. Another object of one embodiment of the present invention is to provide a light-emitting device which enables a display device to have high reliability. Another object of one embodiment of the present invention is to provide a light-emitting device which enables a display device to have a low driving voltage. Another object of one embodiment of the present invention is to provide a light-emitting device which enables a display device to have high reliability and a low driving voltage.

Another object of one embodiment of the present invention is to provide any of an organic semiconductor device, a light-emitting device, a light-receiving device, a display device, an electronic appliance, and a lighting device each having low power consumption. Another object of one embodiment of the present invention is to provide an electronic appliance having high reliability or a lighting device having high reliability. Another object of one embodiment of the present invention is to provide any of a novel organic semiconductor device, a novel light-emitting device, a novel light-receiving device, a novel display device, a novel electronic appliance, and a novel lighting device.

Note that the description of these objects does not preclude the existence of other objects. One embodiment of the present invention does not need to achieve all of these objects. Other objects will be apparent from and can be derived from the description of the specification, the drawings, the claims, and the like.

One embodiment of the present invention is a light-emitting device including a first electrode, a second electrode, an intermediate layer, a first light-emitting layer, and a second light-emitting layer. The intermediate layer is positioned between the first electrode and the second electrode. The first light-emitting layer is positioned between the first electrode and the intermediate layer. The second light-emitting layer is positioned between the intermediate layer and the second electrode. The first light-emitting layer includes a first emission center substance and a first organic compound. The first organic compound includes deuterium. The second light-emitting layer includes a second emission center substance. The first emission center substance is a phosphorescent substance having an emission peak at a wavelength longer than or equal to 440 nm and shorter than or equal to 500 nm. A difference between a maximum peak wavelength of a PL spectrum of the first emission center substance and a maximum peak wavelength of a PL spectrum of the second emission center substance is less than or equal to 30 nm. The first light-emitting layer and the second light-emitting layer each emit light with a color gamut different from a color gamut of light emitted by a light-emitting layer included in at least one of a plurality of adjacent light-emitting devices.

One embodiment of the present invention is a light-emitting device including a first electrode, a second electrode, an intermediate layer, a first light-emitting layer, and a second light-emitting layer. The intermediate layer is positioned between the first electrode and the second electrode. The first light-emitting layer is positioned between the first electrode and the intermediate layer. The second light-emitting layer is positioned between the intermediate layer and the second electrode. The first light-emitting layer includes a first emission center substance, a first organic compound, and a second organic compound. At least one of the first organic compound and the second organic compound includes deuterium. The second light-emitting layer includes a second emission center substance. The first emission center substance is a phosphorescent substance having an emission peak at a wavelength longer than or equal to 440 nm and shorter than or equal to 500 nm. A difference between a maximum peak wavelength of a PL spectrum of the first emission center substance and a maximum peak wavelength of a PL spectrum of the second emission center substance is less than or equal to 30 nm. The first light-emitting layer and the second light-emitting layer each emit light with a color gamut different from a color gamut of light emitted by a light-emitting layer included in at least one of a plurality of adjacent light-emitting devices.

In the above light-emitting device of one embodiment of the present invention, the first organic compound includes a π-electron deficient heteroaromatic ring, and the second organic compound includes at least one of a π-electron rich heteroaromatic ring and an aromatic amine skeleton.

In the above light-emitting device of one embodiment of the present invention, the second light-emitting layer includes the second emission center substance, a third organic compound, and a fourth organic compound. The third organic compound includes a π-electron deficient heteroaromatic ring. The fourth organic compound includes at least one of a π-electron rich heteroaromatic ring and an aromatic amine skeleton. At least one of the third organic compound and the fourth organic compound includes deuterium. A combination of the first organic compound and the second organic compound forms a first exciplex. A combination of the third organic compound and the fourth organic compound forms a second exciplex. An emission edge on a shorter wavelength side of a PL spectrum of the first exciplex is positioned at a shorter wavelength than an absorption edge on a longer wavelength side of an absorption spectrum of the first emission center substance. An emission edge on a shorter wavelength side of a PL spectrum of the second exciplex is positioned at a shorter wavelength than an absorption edge on a longer wavelength side of an absorption spectrum of the second emission center substance.

In the above light-emitting device of one embodiment of the present invention, a difference between a lowest triplet excitation energy level of the first organic compound and a lowest triplet excitation energy level of the second organic compound is less than or equal to 0.20 eV. A difference between a lowest triplet excitation energy level of the third organic compound and a lowest triplet excitation energy level of the fourth organic compound is less than or equal to 0.20 eV.

In the above light-emitting device of one embodiment of the present invention, a phosphorescence lifetime or a delayed fluorescence lifetime at 77 K of the first organic compound is 1.20 times or more a phosphorescence lifetime or a delayed fluorescence lifetime at 77 K of a fifth organic compound that is a non-deuterated substance of the first organic compound. A phosphorescence lifetime or a delayed fluorescence lifetime at 77 K of the second organic compound is 1.05 times or more a phosphorescence lifetime or a delayed fluorescence lifetime at 77 K of a sixth organic compound that is a non-deuterated substance of the second organic compound.

In the above light-emitting device of one embodiment of the present invention, a product of X and Y is greater than or equal to 1.26 in the case where a phosphorescence lifetime or a delayed fluorescence lifetime at 77 K of the first organic compound is X times a phosphorescence lifetime or a delayed fluorescence lifetime at 77 K of a fifth organic compound that is a non-deuterated substance of the first organic compound and a phosphorescence lifetime or a delayed fluorescence lifetime at 77 K of the second organic compound is Y times a phosphorescence lifetime or a delayed fluorescence lifetime at 77 K of a sixth organic compound that is a non-deuterated substance of the second organic compound.

In the above light-emitting device of one embodiment of the present invention, the first emission center substance is the same substance as the second emission center substance.

In the above light-emitting device of one embodiment of the present invention, the first emission center substance is a platinum complex.

The above light-emitting device of one embodiment of the present invention includes a first hole-transport layer between the first electrode and the first light-emitting layer and a second hole-transport layer between the intermediate layer and the second light-emitting layer. The first hole-transport layer or the second hole-transport layer has a stacked-layer structure including at least a first layer including a seventh organic compound and a second layer including an eighth organic compound. The second layer is in contact with the first light-emitting layer or the second light-emitting layer. The seventh organic compound includes an amine skeleton and a polycyclic hydrocarbon. The eighth organic compound includes a π-electron rich polycyclic heteroaromatic ring.

The above light-emitting device of one embodiment of the present invention includes a first electron-transport layer between the second light-emitting layer and the second electrode. The first electron-transport layer includes a layer including a ninth organic compound including a triazine skeleton. The intermediate layer includes a first mixed layer of lithium or a lithium compound and a tenth organic compound including a phenanthroline skeleton.

In the above light-emitting device of one embodiment of the present invention, the first electron-transport layer includes a second mixed layer of lithium or a lithium compound and an eleventh organic compound including a triazine skeleton. The second mixed layer is positioned between the second electrode and the layer including the ninth organic compound.

One embodiment of the present invention is a display device including a light-emitting device A and a light-emitting device B whose emission color is different from an emission color of the light-emitting device A. The light-emitting device A includes a first electrode A, a second electrode A, an intermediate layer A, a first light-emitting layer A, and a second light-emitting layer A. The intermediate layer A is positioned between the first electrode A and the second electrode A. The first light-emitting layer A is positioned between the first electrode A and the intermediate layer A. The second light-emitting layer A is positioned between the intermediate layer A and the second electrode A. The first light-emitting layer A includes a first emission center substance A, a first organic compound A, and a second organic compound A. At least one of the first organic compound A and the second organic compound A includes deuterium. The second light-emitting layer A includes a second emission center substance A. The first emission center substance A and the second emission center substance A are phosphorescent substances each having an emission peak at a wavelength longer than or equal to 440 nm and shorter than or equal to 500 nm. A difference between a maximum peak wavelength of a PL spectrum of the first emission center substance A and a maximum peak wavelength of a PL spectrum of the second emission center substance A is less than or equal to 30 nm. The light-emitting device B includes a first electrode B, a second electrode B, an intermediate layer B, a first light-emitting layer B, and a second light-emitting layer B. The intermediate layer B is positioned between the first electrode B and the second electrode B. The first light-emitting layer B is positioned between the first electrode B and the intermediate layer B. The second light-emitting layer B is positioned between the intermediate layer B and the second electrode B. The first light-emitting layer B includes a first emission center substance B. The second light-emitting layer B includes a second emission center substance B. A difference between a maximum peak wavelength of a PL spectrum of the first emission center substance B and a maximum peak wavelength of a PL spectrum of the second emission center substance B is less than or equal to 30 nm. Each of the first light-emitting layer A and the second light-emitting layer A emits light with a color gamut different from a color gamut of light emitted by each of the first light-emitting layer B and the second light-emitting layer B.

In the above display device of one embodiment of the present invention, the first light-emitting layer B includes a first organic compound B, and the first organic compound B includes deuterium.

One embodiment of the present invention is a display device including a light-emitting device A, a light-emitting device B whose emission color is different from an emission color of the light-emitting device A, and a light-emitting device C whose emission color is different from the emission color of the light-emitting device A and the emission color of the light-emitting device B. The light-emitting device A includes a first electrode A, a second electrode A, an intermediate layer A, a first light-emitting layer A, and a second light-emitting layer A. The intermediate layer A is positioned between the first electrode A and the second electrode A. The first light-emitting layer A is positioned between the first electrode A and the intermediate layer A. The second light-emitting layer A is positioned between the intermediate layer A and the second electrode A. The first light-emitting layer A includes a first emission center substance A, a first organic compound A, and a second organic compound A. At least one of the first organic compound A and the second organic compound A includes deuterium. The second light-emitting layer A includes a second emission center substance A. The first emission center substance A and the second emission center substance A are phosphorescent substances. A difference between a maximum peak wavelength of a PL spectrum of the first emission center substance A and a maximum peak wavelength of a PL spectrum of the second emission center substance A is less than or equal to 30 nm. The light-emitting device B includes a first electrode B, a second electrode B, an intermediate layer B, a first light-emitting layer B, and a second light-emitting layer B. The intermediate layer B is positioned between the first electrode B and the second electrode B. The first light-emitting layer B is positioned between the first electrode B and the intermediate layer B. The second light-emitting layer B is positioned between the intermediate layer B and the second electrode B. The first light-emitting layer B includes a first emission center substance B. The second light-emitting layer B includes a second emission center substance B. The first emission center substance B and the second emission center substance B are phosphorescent substances. A difference between a maximum peak wavelength of a PL spectrum of the first emission center substance B and a maximum peak wavelength of a PL spectrum of the second emission center substance B is less than or equal to 30 nm. The light-emitting device C includes a first electrode C, a second electrode C, an intermediate layer C, a first light-emitting layer C, and a second light-emitting layer C. The intermediate layer C is positioned between the first electrode C and the second electrode C. The first light-emitting layer C is positioned between the first electrode C and the intermediate layer C. The second light-emitting layer C is positioned between the intermediate layer C and the second electrode C. The first light-emitting layer C includes a first emission center substance C. The second light-emitting layer C includes a second emission center substance C. The first emission center substance C and the second emission center substance C are phosphorescent substances. A difference between a maximum peak wavelength of a PL spectrum of the first emission center substance C and a maximum peak wavelength of a PL spectrum of the second emission center substance C is less than or equal to 30 nm. Each of the first light-emitting layer A and the second light-emitting layer A emits light with a color gamut different from a color gamut of light emitted by each of the first light-emitting layer B, the second light-emitting layer B, the first light-emitting layer C, and the second light-emitting layer C.

In the above display device of one embodiment of the present invention, the first light-emitting layer B includes a first organic compound B. The first organic compound B includes deuterium. The first light-emitting layer C includes a first organic compound C. The first organic compound C includes deuterium.

Another embodiment of the present invention is a light-emitting apparatus that includes any of the above light-emitting devices and a transistor or a substrate.

Another embodiment of the present invention is an electronic appliance including the above light-emitting apparatus, and a sensing portion, an input portion, or a communication portion.

Note that the light-emitting apparatus in this specification includes, in its category, an image display device that uses a light-emitting device. The light-emitting apparatus may also include a module in which a light-emitting device over a substrate is provided with a connector such as an anisotropic conductive film or a tape carrier package (TCP), a module in which a printed wiring board is further provided at the end of the TCP, and a module in which an integrated circuit (IC) is directly mounted on a light-emitting device by a chip on glass (COG) method. Furthermore, a lighting device or the like may include the light-emitting apparatus.

One embodiment of the present invention can provide a light-emitting device having favorable characteristics. Another embodiment of the present invention can provide a light-emitting device having high emission efficiency. Another embodiment of the present invention can provide a light-emitting device having high reliability. Another embodiment of the present invention can provide a light-emitting device having a low driving voltage. Another embodiment of the present invention can provide a light-emitting device having high reliability and a low driving voltage.

Another embodiment of the present invention can provide a light-emitting device which enables a display device to have favorable characteristics. Another embodiment of the present invention can provide a light-emitting device which enables a display device to have high emission efficiency. Another embodiment of the present invention can provide a light-emitting device which enables a display device to have high reliability. Another embodiment of the present invention can provide a light-emitting device which enables a display device to have a low driving voltage. Another embodiment of the present invention can provide a light-emitting device which enables a display device to have high reliability and a low driving voltage.

Another embodiment of the present invention can provide any of an organic semiconductor device, a light-emitting device, a light-receiving device, a display device, an electronic appliance, and a lighting device each having low power consumption. Another embodiment of the present invention can provide an electronic appliance having high reliability or a lighting device having high reliability. Another embodiment of the present invention can provide any of a novel organic semiconductor device, a novel light-emitting device, a novel light-receiving device, a novel display device, a novel electronic appliance, and a novel lighting device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIGS. 1A and 1B each illustrate a light-emitting device.

FIG. 2 illustrates a light-emitting device.

FIGS. 3A and 3B each illustrate a light-emitting device.

FIG. 4 illustrates a light-emitting device.

FIGS. 5A and 5B illustrate a display device of one embodiment of the present invention.

FIGS. 6A and 6B are a top view and a cross-sectional view of a light-emitting apparatus.

FIGS. 7A to 7E are cross-sectional views illustrating an example of a method for manufacturing a display device.

FIGS. 8A and 8B are cross-sectional views illustrating an example of a method for manufacturing a display device.

FIGS. 9A to 9D are cross-sectional views illustrating an example of a method for manufacturing a display device.

FIGS. 10A to 10C are cross-sectional views illustrating an example of a method for manufacturing a display device.

FIGS. 11A to 11C are cross-sectional views illustrating an example of a method for manufacturing a display device.

FIGS. 12A to 12C are cross-sectional views illustrating an example of a method for manufacturing a display device.

FIGS. 13A to 13G are top views each illustrating a structure example of a pixel.

FIGS. 14A to 14I are top views each illustrating a structure example of a pixel.

FIGS. 15A and 15B are perspective views illustrating a structure example of a display module.

FIGS. 16A and 16B are cross-sectional views illustrating structure examples of a display device.

FIG. 17 is a perspective view illustrating a structure example of a display device.

FIG. 18 is a cross-sectional view illustrating a structure example of a display device.

FIG. 19 is a cross-sectional view illustrating a structure example of a display device.

FIG. 20A is a cross-sectional view illustrating a structure example of a display device, and FIGS. 20B and 20C are top views illustrating the structure example of the display device.

FIG. 21 is a cross-sectional view illustrating a structure example of a display device.

FIG. 22A is a cross-sectional view illustrating a structure example of a display device, and FIGS. 22B and 22C are top views illustrating the structure example of the display device.

FIGS. 23A to 23D illustrate examples of electronic appliances.

FIGS. 24A to 24F illustrate examples of electronic appliances.

FIGS. 25A to 25G illustrate examples of electronic appliances.

FIG. 26 illustrates a structure of samples.

FIG. 27 illustrates a structure of samples.

FIGS. 28A and 28B show PL spectra of organic compounds used for samples.

FIGS. 29A and 29B show PL spectra of organic compounds used for samples.

FIG. 30 shows a PL spectrum of an organic compound used for a sample.

FIG. 31 shows a PL spectrum of an organic compound used for a sample.

FIGS. 32A and 32B show PL spectra of organic compounds used for samples.

FIGS. 33A and 33B show PL spectra of organic compounds used for samples.

FIG. 34 shows a PL spectrum of a mixed film used for a sample.

FIG. 35 shows a PL spectrum of a mixed film used for a sample.

FIG. 36 shows a PL spectrum of a mixed film used for a sample.

FIG. 37 shows a PL spectrum of a mixed film used for a sample.

FIG. 38 shows a PL spectrum of a mixed film used for a sample.

FIG. 39 shows an absorption spectrum and a PL spectrum of an organic compound used for a sample.

FIG. 40 shows an absorption spectrum and a PL spectrum of an organic compound used for a sample.

FIG. 41 shows an absorption spectrum and a PL spectrum of an organic compound used for a sample.

FIG. 42 shows a PL spectrum of an organic compound used for a sample.

FIG. 43 shows a PL spectrum of an organic compound used for a sample.

FIG. 44 shows a PL spectrum of an organic compound used for a sample.

FIG. 45 illustrates measurement of a phosphorescence lifetime of an organic compound used for a sample.

FIG. 46 illustrates measurement of a phosphorescence lifetime of an organic compound used for a sample.

FIG. 47 illustrates measurement of a phosphorescence lifetime of an organic compound used for a sample.

FIG. 48 illustrates measurement of a phosphorescence lifetime of an organic compound used for a sample.

FIG. 49 shows luminance-current density characteristics of samples.

FIG. 50 shows luminance-voltage characteristics of the samples.

FIG. 51 shows current efficiency-luminance characteristics of the samples.

FIG. 52 shows current density-voltage characteristics of the samples.

FIG. 53 shows electroluminescence spectra of the samples.

FIG. 54 shows blue index-current density characteristics of the samples.

FIG. 55 shows luminance-current density characteristics of samples.

FIG. 56 shows luminance-voltage characteristics of the samples.

FIG. 57 shows current efficiency-luminance characteristics of the samples.

FIG. 58 shows current density-voltage characteristics of the samples.

FIG. 59 shows electroluminescence spectra of the samples.

FIG. 60 shows blue index-current density characteristics of the samples.

FIG. 61 shows luminance-current density characteristics of samples.

FIG. 62 shows luminance-voltage characteristics of the samples.

FIG. 63 shows current efficiency-luminance characteristics of the samples.

FIG. 64 shows current density-voltage characteristics of the samples.

FIG. 65 shows electroluminescence spectra of the samples.

FIG. 66 shows blue index-current density characteristics of the samples.

FIG. 67 shows luminance-current density characteristics of samples.

FIG. 68 shows luminance-voltage characteristics of the samples.

FIG. 69 shows current efficiency-luminance characteristics of the samples.

FIG. 70 shows current density-voltage characteristics of the samples.

FIG. 71 shows electroluminescence spectra of the samples.

FIG. 72 shows luminance-current density characteristics of samples.

FIG. 73 shows luminance-voltage characteristics of the samples.

FIG. 74 shows current efficiency-luminance characteristics of the samples.

FIG. 75 shows current density-voltage characteristics of the samples.

FIG. 76 shows electroluminescence spectra of the samples.

FIG. 77 shows reliability characteristics of light-emitting devices.

FIG. 78 shows a PL spectrum of a mixed film used for a sample.

FIG. 79 shows a PL spectrum of a mixed film used for a sample.

FIG. 80 illustrates measurement of a phosphorescence lifetime of an organic compound used for a sample.

FIG. 81 illustrates measurement of a phosphorescence lifetime of an organic compound used for a sample.

FIG. 82 illustrates measurement of a phosphorescence lifetime of an organic compound used for a sample.

FIG. 83 illustrates measurement of a phosphorescence lifetime of an organic compound used for a sample.

FIG. 84 shows luminance-current density characteristics of samples.

FIG. 85 shows luminance-voltage characteristics of the samples.

FIG. 86 shows current efficiency-luminance characteristics of the samples.

FIG. 87 shows current density-voltage characteristics of the samples.

FIG. 88 shows electroluminescence spectra of the samples.

FIG. 89 shows luminance-current density characteristics of samples.

FIG. 90 shows luminance-voltage characteristics of the samples.

FIG. 91 shows current efficiency-luminance characteristics of the samples.

FIG. 92 shows current density-voltage characteristics of the samples.

FIG. 93 shows electroluminescence spectra of the samples.

FIG. 94 shows luminance-current density characteristics of samples.

FIG. 95 shows luminance-voltage characteristics of the samples.

FIG. 96 shows current efficiency-luminance characteristics of the samples.

FIG. 97 shows current density-voltage characteristics of the samples.

FIG. 98 shows electroluminescence spectra of the samples.

FIG. 99 shows luminance-current density characteristics of samples.

FIG. 100 shows luminance-voltage characteristics of the samples.

FIG. 101 shows current efficiency-luminance characteristics of the samples.

FIG. 102 shows current density-voltage characteristics of the samples.

FIG. 103 shows electroluminescence spectra of the samples.

FIG. 104 shows luminance-current density characteristics of samples.

FIG. 105 shows luminance-voltage characteristics of the samples.

FIG. 106 shows current efficiency-luminance characteristics of the samples.

FIG. 107 shows current density-voltage characteristics of the samples.

FIG. 108 shows electroluminescence spectra of the samples.

FIG. 109 shows blue index-current density characteristics of the samples.

FIG. 110 shows luminance-current density characteristics of samples.

FIG. 111 shows luminance-voltage characteristics of the samples.

FIG. 112 shows current efficiency-luminance characteristics of the samples.

FIG. 113 shows current density-voltage characteristics of the samples.

FIG. 114 shows electroluminescence spectra of the samples.

FIG. 115 shows blue index-current density characteristics of the samples.

FIG. 116 shows reliability characteristics of light-emitting devices.

FIG. 117 shows reliability characteristics of light-emitting devices.

FIG. 118 shows reliability characteristics of light-emitting devices.

FIG. 119 shows a PL spectrum of a mixed film used for a sample.

FIG. 120 shows luminance-current density characteristics of samples.

FIG. 121 shows luminance-voltage characteristics of the samples.

FIG. 122 shows current efficiency-luminance characteristics of the samples.

FIG. 123 shows current density-voltage characteristics of the samples.

FIG. 124 shows electroluminescence spectra of the samples.

FIG. 125 shows luminance-current density characteristics of samples.

FIG. 126 shows luminance-voltage characteristics of the samples.

FIG. 127 shows current efficiency-luminance characteristics of the samples.

FIG. 128 shows current density-voltage characteristics of the samples.

FIG. 129 shows electroluminescence spectra of the samples.

FIG. 130 shows an absorption spectrum and a PL spectrum of an organic compound used for a sample.

FIG. 131 shows an absorption spectrum and a PL spectrum of an organic compound used for a sample.

FIG. 132 shows luminance-current density characteristics of a sample.

FIG. 133 shows luminance-voltage characteristics of the sample.

FIG. 134 shows current efficiency-luminance characteristics of the sample.

FIG. 135 shows current density-voltage characteristics of the sample.

FIG. 136 shows an electroluminescence spectrum of the sample.

FIG. 137 shows blue index-current density characteristics of the sample.

FIG. 138 shows luminance-current density characteristics of a sample.

FIG. 139 shows luminance-voltage characteristics of the sample.

FIG. 140 shows current efficiency-luminance characteristics of the sample.

FIG. 141 shows current density-voltage characteristics of the sample.

FIG. 142 shows an electroluminescence spectrum of the sample.

FIG. 143 shows luminance-current density characteristics of a sample.

FIG. 144 shows luminance-voltage characteristics of the sample.

FIG. 145 shows current efficiency-luminance characteristics of the sample.

FIG. 146 shows current density-voltage characteristics of the sample.

FIG. 147 shows an electroluminescence spectrum of the sample.

FIG. 148 shows luminance-current density characteristics of a sample.

FIG. 149 shows luminance-voltage characteristics of the sample.

FIG. 150 shows current efficiency-luminance characteristics of the sample.

FIG. 151 shows current density-voltage characteristics of the sample.

FIG. 152 shows an electroluminescence spectrum of the sample.

FIG. 153 shows blue index-current density characteristics of the sample.

FIG. 154 shows luminance-current density characteristics of a sample.

FIG. 155 shows luminance-voltage characteristics of the sample.

FIG. 156 shows current efficiency-luminance characteristics of the sample.

FIG. 157 shows current density-voltage characteristics of the sample.

FIG. 158 shows an electroluminescence spectrum of the sample.

FIG. 159 shows luminance-current density characteristics of a sample.

FIG. 160 shows luminance-voltage characteristics of the sample.

FIG. 161 shows current efficiency-luminance characteristics of the sample.

FIG. 162 shows current density-voltage characteristics of the sample.

FIG. 163 shows an electroluminescence spectrum of the sample.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases. The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification, the term “deuterated organic compound” refers to an organic compound in which, with a focus on hydrogen (including deuterium) present at a certain position(s), the proportion of the hydrogen (including the deuterium) being deuterium is higher than the natural abundance ratio of deuterium. This proportion is preferably adequately higher than the natural abundance ratio. Here, “adequately” means that 7.5% or more of hydrogen has been replaced with deuterium, for example. Note that deuteration of an organic compound can be verified by NMR, mass spectrometry, or the like.

In this specification and the like, a device formed using a metal mask or a fine metal mask (FMM, a high-resolution metal mask) is sometimes referred to as a device having a metal mask (MM) structure. In this specification and the like, a device formed without using a metal mask or an FMM is sometimes referred to as a device having a metal maskless (MML) structure.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other. One layer may have two or three functions of the carrier-injection layer, the carrier-transport layer, and the carrier-blocking layer in some cases. Furthermore, an injection layer, a transport layer, or a blocking layer may be referred to simply as a layer. Similarly, the other layers such as a light-emitting layer and an intermediate layer may each be referred to simply as a layer.

In this specification and the like, a light-emitting device (also referred to as a light-emitting element) includes an EL layer between a pair of electrodes. The EL layer includes at least a light-emitting layer. In this specification and the like, a light-receiving device (also referred to as a light-receiving element) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a tapered shape indicates a shape such that at least part of a side surface of a structure is inclined relative to a substrate surface. For example, a tapered shape preferably includes a region where the angle formed between the inclined side surface and the substrate surface (such an angle is also referred to as a taper angle) is less than 90°. Note that the side surface of the component and the substrate surface are not necessarily completely flat and may be substantially flat with a slight curvature or with slight unevenness.

Note that the light-emitting apparatus in this specification includes, in its category, an image display device that uses an organic EL device. The light-emitting apparatus may also include a module in which an organic EL device is provided with a connector such as an anisotropic conductive film or a tape carrier package (TCP), a module in which a printed wiring board is further provided at the end of the TCP, and a module in which an integrated circuit (IC) is directly mounted on an organic EL device by a chip on glass (COG) method. Furthermore, a lighting device or the like may include the light-emitting apparatus.

### Embodiment 1

A tandem light-emitting device has a structure in which a plurality of light-emitting units are stacked between a pair of electrodes with an intermediate layer (a charge-generation layer) between the plurality of light-emitting units. The plurality of light-emitting units include their respective light-emitting layers, and each of the light-emitting layers can emit light with a flow of current therethrough. The tandem light-emitting device having such a structure has a much higher current efficiency than a non-tandem light-emitting device, and can thus be suitably used for a display device that is required to perform high-luminance display or that needs to have high reliability.

Since the tandem light-emitting device includes a plurality of light-emitting layers and can thus easily provide white light emission, many full-color display devices including the tandem light-emitting device employ a “white+color filter” method. A color conversion method is also in practical use in which light-emitting layers that emit blue light are stacked and a color conversion layer typified by quantum dots is used.

Meanwhile, some full-color display devices employing a side-by-side patterning method and the tandem light-emitting device have also been put into practical use. A light-emitting device fabricated by the side-by-side patterning method has little or no energy loss due to a color filter or a color conversion layer and can thus have a higher emission efficiency than light-emitting devices fabricated by the above-described two methods.

The light-emitting layer included in the tandem light-emitting device is preferably separated from a light-emitting layer included in at least one adjacent light-emitting device. Alternatively, the light-emitting layer included in the tandem light-emitting device is preferably different from a light-emitting layer included in at least one adjacent light-emitting device. Alternatively, the emission color of the tandem light-emitting device is preferably different from the emission color of at least one adjacent light-emitting device. Alternatively, the emission center substance included in the light-emitting layer of the tandem light-emitting device preferably has a structure different from that of an emission center substance included in a light-emitting layer of at least one adjacent light-emitting device.

The light-emitting device of one embodiment of the present invention that has the above structure can have high current efficiency, low energy loss, and favorable characteristics. A display device of one embodiment of the present invention that includes such a light-emitting device can achieve low power consumption, high reliability, high-luminance display, and high visibility.

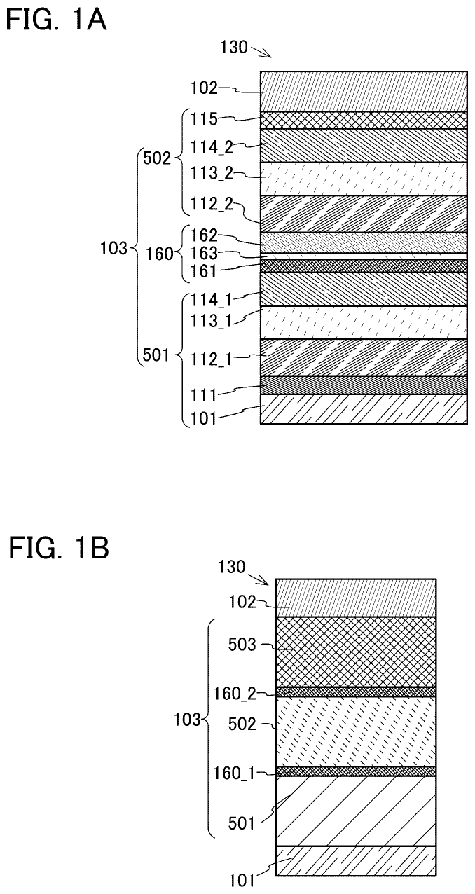

Next, light-emitting devices of one embodiment of the present invention will be described in detail with reference to the drawings. FIG. 1A illustrates a light-emitting device 130 of one embodiment of the present invention. The light-emitting device of one embodiment of the present invention is a tandem light-emitting device including an organic compound layer 103 (also referred to as an EL layer) between a first electrode 101 including an anode and a second electrode 102 including a cathode. The organic compound layer 103 includes a first light-emitting unit 501 including a first light-emitting layer 113_1, a second light-emitting unit 502 including a second light-emitting layer 113_2, and an intermediate layer 160.

Although light-emitting devices each including one intermediate layer 160 and two light-emitting units are described as examples in this embodiment, a light-emitting device including n intermediate layer(s) (n is an integer greater than or equal to 1) and n+1 light-emitting units may be employed. For example, the light-emitting device 130 illustrated in FIG. 1B is an example of a tandem light-emitting device with n=2 that includes the first light-emitting unit 501, a first intermediate layer 160_1, the second light-emitting unit 502, a second intermediate layer 160_2, and a third light-emitting unit 503.

The light-emitting layers in the light-emitting units preferably emit light with the same color gamut.

In one embodiment of the present invention, a material that emits phosphorescent light (hereinafter also referred to as a phosphorescent substance) is used as an emission center substance in the first light-emitting layer 113_1 or the second light-emitting layer 113_2. Preferably, a phosphorescent substance is particularly used for a light-emitting device that exhibits blue light emission.

It is known that in current-excitation type organic EL devices, the theoretical limit of the internal quantum efficiency of a light-emitting device using a fluorescent substance, which can utilize only a singlet excited state for light emission, is 25% since the generation probability ratio of a singlet excited state to a triplet excited state is 1:3. By contrast, a phosphorescent substance can convert a singlet excited state into a triplet excited state through intersystem crossing and thus enables a light-emitting device with an internal quantum efficiency of 100% theoretically, which allows the light-emitting device to have higher emission efficiency than that including a fluorescent substance.

In the case where the above-described organic compound that emits blue phosphorescent light is used for the light-emitting layer, the light-emitting layer preferably includes at least one of a compound having a heteroaromatic ring, a compound having a carbazole skeleton, and a compound having an aromatic amine skeleton as a host material. It is particularly preferable that the host material include deuterium. Specifically, the host material has a structure in which part or the whole of protium has been replaced with deuterium. As compared with an organic compound including only protium, an organic compound including deuterium shows little material deterioration when used in a light-emitting device and can improve the reliability of the light-emitting device.

A compound having a heteroaromatic ring functions as an electron-transport host, and a compound having a carbazole skeleton or a compound having an aromatic amine skeleton functions as a hole-transport host. The electron-transport host and the hole-transport host are preferably used in combination to easily form an exciplex. In this manner, it is preferable to use a plurality of host materials, and it is particularly preferable to use a host material including deuterium as at least one of the plurality of host materials.

In addition, when a phosphorescent substance and an exciplex are included in the light-emitting layer, exciplex-triplet energy transfer (ExTET), which is energy transfer from the exciplex to a light-emitting substance, can be performed efficiently, increasing emission efficiency. This structure also enables the light-emitting device to have high efficiency, low-voltage driving, and a long lifetime at the same time.

At least one of light-emitting layers included in a tandem light-emitting device of one embodiment of the present invention includes the emission center substance, a first host material, and a second host material. The emission center substance is preferably a phosphorescent substance. The first and second host materials are organic compounds and form an exciplex in combination. The tandem light-emitting device of one embodiment of the present invention has a structure in which energy is transferred from the exciplex formed by the first and second host materials to the emission center substance to make the emission center substance emit light. Thus, the transfer efficiency of excitation energy to the emission center substance is improved, so that the light-emitting device can have high efficiency and high reliability. In addition, the driving voltage can be reduced.

The HOMO level of a hole-transport material is preferably higher than or equal to that of an electron-transport material so that the exciplex can be efficiently formed by the materials in combination. In addition, the LUMO level of the hole-transport material is preferably higher than or equal to that of the electron-transport material. In addition, the difference between the HOMO levels of the hole-transport material and the electron-transport material is preferably greater than or equal to 0.2 eV. In addition, the difference between the LUMO levels of the hole-transport material and the electron-transport material is preferably greater than or equal to 0.2 eV. Such a structure is suitable because it facilitates hole injection into the hole-transport material and electron injection into the electron-transport material. The LUMO levels and the HOMO levels of the materials can be derived from the electrochemical characteristics (reduction potentials and oxidation potentials) of the materials that are measured by cyclic voltammetry (CV) or derived by photoelectron spectroscopy, optical absorption spectroscopy, inverse photoelectron spectroscopy, or the like. For comparison between the values of different compounds, it is preferable to use values estimated by the same measurement method.

Preferably, the HOMO level of the phosphorescent substance is lower than that of the hole-transport material and the LUMO level of the phosphorescent substance is higher than that of the electron-transport material. In other words, the energy difference between the LUMO and HOMO levels of the phosphorescent substance is preferably greater than the energy difference between the LUMO level of the electron-transport material and the HOMO level of the hole-transport material. That can inhibit the phosphorescent substance from forming an exciplex with the hole-transport material or the electron-transport material, leading to efficient light emission of the light-emitting device.

Note that the phosphorescent substance has a function of converting triplet excitation energy into light emission. In addition, energy is lower and thus more stable in a triplet excited state than in a singlet excited state. Thus, the phosphorescent substance is capable of emitting light with energy less than the energy difference between the LUMO and HOMO levels. Even when the energy difference between the LUMO and HOMO levels of the phosphorescent substance is greater than the energy difference between the LUMO level of the electron-transport material and the HOMO level of the hole-transport material, the exciplex can transfer excitation energy to the phosphorescent substance as long as the emission energy of the phosphorescent substance or the transition energy calculated from its absorption spectrum is equal to or less than the energy difference between the LUMO level of the electron-transport material and the HOMO level of the hole-transport material, or is equal to or less than the emission energy of the exciplex formed by the electron-transport material and the hole-transport material, whereby light emission can be efficiently obtained from the phosphorescent substance.

In order to emit light with high emission energy (a short wavelength), the phosphorescent substance preferably has a high level of the lowest triplet excitation energy (T₁ level). Hence, a ligand coordinated to a heavy metal atom in the phosphorescent substance also preferably has a high T₁ level, and the ligand preferably has a low electron-accepting property and a high LUMO level. These enable the phosphorescent substance to have a molecular structure that has high LUMO and HOMO levels and easily accepts holes. In the case where the phosphorescent substance has a molecular structure that easily accepts holes, the HOMO level of the phosphorescent substance is sometimes higher than that of the hole-transport material. However, even in such a case, when the energy difference between the LUMO and HOMO levels of the phosphorescent substance is greater than the energy difference between the LUMO level of the electron-transport material and the HOMO level of the hole-transport material, the exciplex can transfer excitation energy to the phosphorescent substance as long as the emission energy of the phosphorescent substance or the transition energy calculated from its absorption spectrum is equal to or less than the energy difference between the LUMO level of the electron-transport material and the HOMO level of the hole-transport material, or is equal to or less than the emission energy of the exciplex formed by the electron-transport material and the hole-transport material, whereby light emission can be efficiently obtained from the phosphorescent substance.

The formation of an exciplex can be confirmed by a phenomenon in which the PL spectrum of the mixed film in which the hole-transport material and the electron-transport material are mixed is shifted to a longer wavelength than the PL spectrum of each of the materials (or has another peak on the longer wavelength side) observed by comparison of the PL spectra of the hole-transport material, the electron-transport material, and the mixed film of these materials, for example. Alternatively, the formation of an exciplex can be confirmed by a difference in transient response, such as a phenomenon in which the transient photoluminescence (transient PL) lifetime of the mixed film has longer lifetime components or has a larger proportion of delayed components than that of each of the materials, observed by comparison of transient PL of the hole-transport material, the electron-transport material, and the mixed film of these materials. The transient PL can be rephrased as transient electroluminescence (transient EL). That is, the formation of an exciplex can also be confirmed by a difference in transient response observed by comparison of the transient EL of the hole-transport material, the electron-transport material, and the mixed film of these materials.

In the case where an exciplex is formed by the first and second host materials, for example, an emission edge on a shorter wavelength side of a photoluminescence (PL) spectrum of the exciplex is preferably positioned at a shorter wavelength than an absorption edge on a longer wavelength side of an absorption spectrum of the emission center substance. When the PL spectrum of the exciplex and the absorption edge of the emission center substance have such a positional relation, energy can be efficiently transferred.

Alternatively, the peak wavelength of the PL spectrum of the exciplex formed by the first and second host materials is preferably shorter than the peak wavelength of the PL spectrum of the emission center substance. The difference between the peak wavelength of the PL spectrum of the exciplex and the peak wavelength of the PL spectrum of the emission center substance is further preferably less than or equal to 30 nm. When the peak wavelengths of the PL spectra of the exciplex and the emission center substance have such a relation, energy can be efficiently transferred.

Alternatively, the difference between the peak wavelength of the PL spectrum of the exciplex formed by the first and second host materials and the wavelength of the absorption edge on a longer wavelength side of the absorption spectrum of the emission center substance is preferably less than or equal to 30 nm. When the peak wavelength of the PL spectrum of the exciplex and the wavelength of the absorption edge on a longer wavelength side of the absorption spectrum of the emission center substance have such a relation, energy can be efficiently transferred.

Alternatively, the emission edge on the shorter wavelength side of the PL spectrum of the exciplex formed by the first and second host materials is preferably positioned at a shorter wavelength than the emission edge on the shorter wavelength side of the PL spectrum of the emission center substance. The difference between the emission edge on the shorter wavelength side of the PL spectrum of the exciplex and the emission edge on the shorter wavelength side of the PL spectrum of the emission center substance is further preferably less than or equal to 0.3 eV. When the emission edge on the shorter wavelength side of the PL spectrum of the exciplex and the emission edge on the shorter wavelength side of the PL spectrum of the emission center substance have such a relation, energy can be efficiently transferred.

The emission edge on the shorter wavelength side of the PL spectrum can be determined as the intersection between a tangent and the horizontal axis or the baseline. The tangent is drawn at a point at which the slope on a shorter wavelength side of the shortest-wavelength peak (or the shortest-wavelength shoulder peak) of the PL spectrum has the maximum absolute value. The absorption edge on the longer wavelength side of the absorption spectrum can be determined as the intersection between a tangent and the horizontal axis or the baseline. The tangent is drawn at a point at which the slope on a longer wavelength side of the longest-wavelength peak (or the longest-wavelength shoulder peak) of the absorption spectrum has the maximum absolute value.

The PL spectrum of the exciplex is preferably measured using a film formed by co-evaporation of the first and second host materials. The mixing ratio of the first host material to the second host material is in the range from 1:19 to 19:1, preferably in the range from 1:9 to 9:1, further preferably in the range from 3:7 to 7:3 in any of a weight ratio, a volume ratio, or a molar ratio. As the PL spectrum of a mixed film of the first and second host materials, a spectrum of a mixed film in which the first and second host materials are mixed at a ratio of 1:1 may be measured. Meanwhile, the PL spectrum or the absorption spectrum of the emission center substance may be measured using a sample in the form of a thin film or a solution; however, the sample is preferably in the form of a solution for examination of the state of an isolated molecule. As a solvent of the solution, a solvent with relatively low polarity, such as toluene or chloroform, is preferable.

In the case where the phosphorescent substance is used for the light-emitting layer, the T₁ levels of the first and second host materials are preferably higher than the T₁ level of the phosphorescent substance. The singlet excitation energy and the triplet excitation energy of the first host material or the second host material can be transferred from the S₁ level and the T₁ level of the first host material or the second host material to the T₁ level of the phosphorescent substance. As a result, the phosphorescent substance is brought into a triplet excited state to emit phosphorescent light.

As an indicator of a T₁ level, a phosphorescence component in a PL spectrum (phosphorescence spectrum) observed at a low temperature (at any temperature in the range from 4 K to 80 K, for example) is used. Specifically, for example, a sample formed as a 50-nm-thick thin film over a quartz substrate is prepared, its PL spectrum (phosphorescence spectrum) is measured at a measurement temperature of 10 K, and the energy of an emission edge on a shorter wavelength side of the spectrum can be regarded as the T₁ level. The emission edge can be determined as the intersection between a tangent and the horizontal axis (representing wavelength) or the baseline. The tangent is drawn at a point at which the slope on a shorter wavelength side of the shortest-wavelength peak (or the shortest-wavelength shoulder peak) of the PL spectrum (phosphorescence spectrum) has the maximum absolute value.

A PL spectrum observed at a low temperature (e.g., in the range from 4 K to 80 K) or at room temperature (e.g., in the range from 275 K to 305 K) is measured, and the energy of an emission edge on a shorter wavelength side of the spectrum can be regarded as the T₁ level of the phosphorescent substance.

In the light-emitting device of one embodiment of the present invention, when one or both of the first and second host materials include deuterium, the energy transfer efficiency can be improved. This is derived from the phosphorescence lifetime or delayed fluorescence lifetime of a deuterated organic compound which is longer than that of a non-deuterated organic compound. In other words, this is because a deuterated organic compound in the lowest triplet excited state (T₁ state) has less intramolecular vibration than a non-deuterated organic compound in the T₁ state and accordingly has less non-radiative transition from the T₁ state to a more stable state.

The energy transfer efficiency ϕ_{ET} from an energy donor (an exciplex in one embodiment of the present invention) to an energy acceptor (a substance that can convert triplet excitation energy into light emission in one embodiment of the present invention) is expressed by Formula (1) below. According to this formula, it can be found that the energy transfer efficiency ϕ_{ET} can be increased by increasing the rate constant k_{h*→g} of energy transfer so that another competing rate constant kᵣ+Kₙᵣ (=1/τ) becomes relatively small.

In Formula (1), kᵣ represents the rate constant of a light emission process (fluorescence in the case where energy transfer from a singlet excited state is discussed, and phosphorescence or delayed fluorescence in the case where energy transfer from a triplet excited state is discussed) of the energy donor, kₙᵣ represents the rate constant of a non-light-emission process (thermal deactivation and intersystem crossing) of the energy donor, and τ represents a measured lifetime of an excited state of the energy donor. In addition, k_{h*→g} represents the rate constant of energy transfer (Förster mechanism or Dexter mechanism).

$$\begin{matrix}[ Formula 1 ] & \\ {∅}_{E T} = \frac{{k}_{{h}^{*} \to g}}{{k}_{r} + {k}_{n r} + {k}_{{h}^{*} \to g}} = \frac{{k}_{{h}^{*} \to g}}{( \frac{1}{τ} ) + {k}_{{h}^{*} \to g}} & ( 1 )\end{matrix}$$

A deuterated organic compound and a non-deuterated organic compound have substantially the same atomic arrangement in a molecule and substantially the same spectrum shape, for example, and thus have substantially the same rate constant k_{h*→g} of energy transfer (see Formula (2) or (3) below). Thus, in comparison between the deuterated organic compound and the non-deuterated organic compound, the rate constant k_{h*→g} of energy transfer can be found to be greatly affected by the emission lifetime (phosphorescence lifetime or delayed fluorescence lifetime) τ. That is, the energy transfer efficiency improves as the emission lifetime (phosphorescence lifetime or delayed fluorescence lifetime) becomes longer.

$$\begin{matrix}[ Formula 2 ] & \\ {k}_{{h}^{*} \to g} = \frac{9000 {K}^{2} ∅ ln 10}{1 \; 287 {π}^{5} {n}^{4} N τ {R}^{6}} \int \frac{{f}_{h}^{′} ( v ) {ε}_{g} ( v )}{{v}^{4}} dv & ( 2 )\end{matrix}$$

$$\begin{matrix}[ Formula 3 ] & \\ {k}_{{h}^{*} \to g} = ( \frac{2 π}{h} ) {K}^{2} exp ( - \frac{2 R}{L} ) \int {f}_{h}^{′} ( v ) {ε}_{g}^{′} ( v ) dv & ( 3 )\end{matrix}$$

Formula (2) is a formula of the rate constant k_{h*→g} of the Förster mechanism, and Formula (3) is a formula of the rate constant k_{h*→g} of the Dexter mechanism.

In Formula (2), v represents a frequency, f′ₕ(v) represents a normalized emission spectrum of the host material (a fluorescence spectrum in the case where energy transfer from a singlet excited state is discussed, and a phosphorescence spectrum in the case where energy transfer from a triplet excited state is discussed), ε_{g}(v) represents a molar absorption coefficient of the guest material, N represents Avogadro's number, n represents a refractive index of a medium, R represents an intermolecular distance between the host material and the guest material, τ represents a measured lifetime of an excited state (fluorescence lifetime or phosphorescence lifetime), ϕ represents an emission quantum yield (a fluorescence quantum yield in the case where energy transfer from a singlet excited state is discussed, and a phosphorescence quantum yield in the case where energy transfer from a triplet excited state is discussed), and K² represents a coefficient (0 to 4) of orientation of a transition dipole moment between the host material and the guest material. Note that K² is ⅔ in random orientation.

In Formula (3), h represents a Planck constant, K represents a constant having an energy dimension, v represents a frequency, f′ₕ(v) represents a normalized emission spectrum of the host material (a fluorescence spectrum in the case where energy transfer from a singlet excited state is discussed, and a phosphorescence spectrum in the case where energy transfer from a triplet excited state is discussed), ε′_{g}(v) represents a normalized absorption spectrum of the guest material, L represents an effective molecular radius, and R represents an intermolecular distance between the host material and the guest material.

As described above, in energy transfer from the first and second host materials, the efficiency of energy transfer from the triplet excited state is important and thus the lifetime of the triplet excited state is important. That is, the phosphorescence lifetime or delayed fluorescence lifetime is increased when one or both of the first host material and the second host material are deuterated; hence, the efficiency of energy transfer is improved, and deterioration of the deuterated organic compound(s) can be inhibited. Accordingly, a light-emitting device including a deuterated organic compound as an energy donor has less deterioration of the organic compound than a light-emitting device not including a deuterated organic compound as an energy donor, and thus can have high reliability.

The phosphorescence lifetime and the delayed fluorescence lifetime are calculated by measuring the transient PL by time-resolved measurement, in which the intensity of light attenuating after the excitation light is blocked by a shutter is measured at certain intervals. In this measurement, a graph is sometimes not linear because fluorescence components can be mixed at the initial stage of attenuation. In such a case, a starting point is set in a portion where the graph is linear, and the time taken for the intensity at the starting point to attenuate to 1/e is regarded as the phosphorescence lifetime or the delayed fluorescence lifetime.

Note that an exciplex formed by the first and second host materials preferably serves as an energy donor in the light-emitting device of one embodiment of the present invention, and as described above, the triplet excitation energy can be transferred from the exciplex in the triplet excited state to the light-emitting substance through the first and second host materials in the triplet excited states; thus, the phosphorescence lifetimes or delayed fluorescence lifetimes of the first and second host materials forming the exciplex are important. It has been found that in the light-emitting device of one embodiment of the present invention utilizing the exciplex as the energy donor, one of the first and second host materials, preferably both of them, include deuterium to have the phosphorescence lifetimes or the delayed fluorescence lifetimes longer than a certain length, and thus the reliability of the light-emitting device improves significantly.

That is, the phosphorescence lifetime or delayed fluorescence lifetime of the organic compound as the first host material is preferably 1.20 times or more that of the first host material that is not deuterated. The phosphorescence lifetime or delayed fluorescence lifetime of the organic compound as the second host material is preferably 1.05 times or more that of the second host material that is not deuterated. In the case where the phosphorescence lifetime or delayed fluorescence lifetime of the first host material is X times that of the first host material that is not deuterated and the phosphorescence lifetime or delayed fluorescence lifetime of the second host material is Y times that of the second host material that is not deuterated, the product of X and Y is preferably greater than or equal to 1.26. Here, it is preferable that light emitted from the substance that can convert triplet excitation energy into light emission (the light-emitting substance included in the light-emitting layer) be in the blue region, that is, the peak wavelength be typically greater than or equal to 440 nm and less than or equal to 500 nm.

In the case where light emitted from the substance that can convert triplet excitation energy into light emission (the light-emitting substance included in the light-emitting layer) be in the green region, that is, the peak wavelength is typically greater than 500 nm and less than or equal to 600 nm, the phosphorescence lifetime or delayed fluorescence lifetime of the organic compound as the first host material is preferably 1.50 times or more that of the first host material that is not deuterated. The phosphorescence lifetime or delayed fluorescence lifetime of the organic compound as the second host material is preferably 3.00 times or more that of the second host material that is not deuterated. In the case where the phosphorescence lifetime or delayed fluorescence lifetime of the first host material is X times that of the first host material that is not deuterated and the phosphorescence lifetime or delayed fluorescence lifetime of the second host material is Y times that of the second host material that is not deuterated, the product of X and Y is preferably greater than or equal to 4.50.

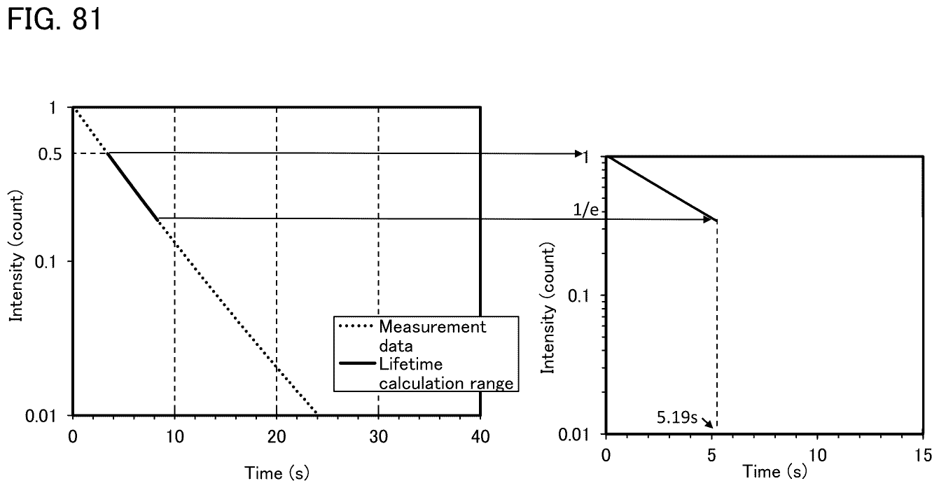

From the measurement data shown in the left graph in FIG. 81, the starting point is set as t=0 within the range where the graph is linear (here, the time at which the light amount becomes 50% of that at the start of the measurement is set as t=0) (the right graph in FIG. 81). The time taken for the light amount to attenuate to 1/e of that at t=0 is regarded as the phosphorescence lifetime or the delayed fluorescence lifetime. In the right graph of FIG. 81, the time at which the intensity reaches 50% of that at the start of the measurement in the measured data is set as time 0 s, the light amount at 0 s is regarded as 1, and the time taken for the light amount to become 1/e is the phosphorescence lifetime or the delayed fluorescence lifetime. Although the point where the intensity becomes 50% of that at the start of the measurement is easily used as the starting point, a point with another intensity may be used as the starting point.

The phosphorescence lifetime can be measured at liquid nitrogen temperature (77 K) with a fluorescence spectrophotometer such as FP-8600 produced by JASCO Corporation, in which a liquid nitrogen cooling unit is set. A solution of a material is prepared in a glove box in the following manner: a sample is dissolved in 2-MeTHF that has been deoxidized, and then stirring is performed with a stirrer at room temperature for approximately 30 minutes (heating is also performed in the case where the material has low solubility) so that the concentration of the solution is adjusted to approximately 1.2 E⁻⁴ M.

The time-resolved measurement can be performed in the following manner: a sample cell is irradiated with excitation light for approximately 30 seconds and the emission intensity attenuating after the excitation light is blocked by a shutter is measured at 10 ms intervals. The peak wavelength of the phosphorescence spectrum is preferably used to measure the phosphorescence lifetime. In the case where the phosphorescence spectrum has a plurality of peaks, a wavelength with the highest peak intensity is preferably selected. Depending on the wavelength, the measurement cannot be performed accurately because of a mixed fluorescence spectrum in some cases. In such a case, in comparison between a PL spectrum measured at low temperature (e.g., 77 K) (an emission spectrum including phosphorescence components) and a PL spectrum measured at normal temperature (an emission spectrum including only fluorescence components and not including phosphorescence components), it is preferable to select a phosphorescence wavelength of the emission spectrum not overlapping with the fluorescence spectrum as much as possible. Alternatively, a wavelength of a peak on the longest wavelength side in the phosphorescence spectrum can be selected. In the case of a frozen solution, light emission from a state other than the lowest triplet excited state may also be observed. In this case, a wavelength of a peak on the longest wavelength side is selected.

Note that the excitation wavelength is appropriately selected within a wavelength range where a solvent has no influence. As long as the material can be excited sufficiently, measurement is preferably performed at a wavelength of 330 nm because there is no influence by a solvent. The band widths of the excitation light and the measured light are each approximately 10 nm. Ideally, light emission attenuates single-exponentially; thus, a starting point is set in a portion where a graph is linear, and the time taken for the intensity at the starting point to attenuate to 1/e can be defined as the phosphorescence lifetime or the delayed fluorescence lifetime.

The fluorescence lifetime can be distinguished from the phosphorescence lifetime and the delayed fluorescence lifetime by the length of the lifetime in the time-resolved measurement. An emission lifetime on the order of nanoseconds is the fluorescence lifetime, and an emission lifetime on the order of microseconds to milliseconds or more is the phosphorescence lifetime or the delayed fluorescence lifetime.

The reliability of the light-emitting device of one embodiment of the present invention is improved in accordance with an increase in the phosphorescence lifetime, i.e., the lifetime of triplet excitons, of the first and second host materials. The increase in the lifetime of triplet excitons is caused by inhibited non-radiative deactivation of the triplet excitation energy, which is due to inhibited vibration owing to deuteration. At this time, the difference in the lowest triplet excitation energy level (T₁ level) between the first and second host materials is preferably small, in which case the excitation energy is less likely to be localized in one of the organic compounds and thus significant deterioration of one of the organic compounds can be prevented, leading to high reliability of the light-emitting device. Specifically, the difference in the T₁ level between the first and second host materials is preferably less than or equal to 0.20 eV, further preferably less than or equal to 0.15 eV, still further preferably less than or equal to 0.10 eV.

For calculation of the lowest triplet excitation energy level (T₁ level), a PL spectrum (phosphorescence spectrum) is measured at a measurement temperature of 10 K using a 50-nm-thick thin film of a sample formed over a quartz substrate. The measurement is preferably performed with a PL microscope (LabRAM HR-PL, produced by HORIBA, Ltd.) and a He—Cd laser (325 nm) as excitation light. Note that the emission edge can be determined as the intersection of a tangent and the horizontal axis (representing wavelength) or the baseline. The tangent is drawn at a point at which the slope on a shorter wavelength side of the shortest-wavelength peak (or the shortest-wavelength shoulder peak) of the PL spectrum (phosphorescence spectrum) has the maximum absolute value.

In one embodiment of the present invention, the sublimation temperatures of the first and second host materials are preferably close to each other. For example, the difference between the 5% weight loss temperature of the first host material measured by thermogravimetry and the 5% weight loss temperature of the second host material measured by thermogravimetry is preferably less than or equal to 60° C., further preferably less than or equal to 45° C., still further preferably less than or equal to 20° C., yet further preferably less than or equal to 10° C. This enables evaporation using a mixed material of the first and second host materials, thereby reducing the number of evaporation sources and providing a light-emitting device with favorable characteristics at low cost.

The 5% weight loss temperature can be obtained from the relation between weight and temperature (thermogravimetric measurement) by performing thermogravimetry-differential thermal analysis (TG-DTA). In the case where the pressure for the evaporation is determined in advance, it is preferable to use a value measured under the pressure.

Note that the light-emitting device can have more favorable characteristics owing to a preferred combination of the increasing rate of the phosphorescence lifetime or the delayed fluorescence lifetime due to deuteration, the product of the increasing rates, the difference in T₁ level, and the difference in sublimation temperature of the first and second host materials.

In addition, the photoluminescence (PL) spectrum of the exciplex formed by the first and second host materials and that of the light-emitting substance (the substance that can convert triplet energy into light emission) preferably have an overlap. This is because the driving voltage of the light-emitting device can be lowered when the excitation energy of the energy donor is close to the excitation energy of the light-emitting substance. Thus, the difference between the maximum peak wavelengths is preferably less than or equal to 30 nm. Alternatively, the difference in the wavelength of the emission edge on a shorter wavelength side of the PL spectrum between the exciplex and the light-emitting substance is preferably less than or equal to 30 nm, in which case the driving voltage of the light-emitting device can be decreased.

The PL spectrum of the exciplex is preferably measured using a film formed by co-evaporation of the first and second host materials. Note that the PL spectrum of the light-emitting substance (the substance that can convert triplet energy into light emission) may be measured using a sample in the form of a thin film or a solution; however, a sample in the form of a solution is preferably used for examination of the state of an isolated molecule. There is no particular limitation on a solvent of the solution as long as the same solvent is used for a comparison between the PL spectra. A solvent with relatively low polarity, such as toluene or chloroform, is preferred.

In the case where the substance that can convert triplet excitation energy into light emission (the light-emitting substance included in the light-emitting layer) emits light in the blue region, that is, in the case where the peak wavelength is typically greater than or equal to 440 nm and less than or equal to 500 nm, the first host material is preferably an organic compound having an azine skeleton, and the second host material is preferably an organic compound having a carbazole skeleton.

Examples of azine skeletons that can be used for the host material include a pyridine ring, a pyrimidine ring, and a triazine ring. These can improve the electron-transport property. A compound in which a carbazole skeleton is directly bonded to an azine skeleton or bonded to an azine skeleton through an arylene group is preferably used, and the number of carbazole skeletons is preferably more than one. It is preferable that the plurality of carbazole skeletons not be bonded to each other. Such a structure having carbazole skeletons enables adjustment of the electron-transport property. Furthermore, the compound having a heteroaromatic ring may include one or more kinds of elements such as silicon, boron, oxygen, and sulfur.

A compound having a carbazole skeleton preferably has a plurality of carbazole skeletons. It is preferable to employ at least one of a structure in which the 3-position of one carbazole skeleton is bonded to the 9-position of another carbazole skeleton, a structure in which the 2-position of one carbazole skeleton is bonded to the 9-position of another carbazole skeleton, a structure in which the 4-position of one carbazole skeleton is bonded to the 9-position of another carbazole skeleton, a structure in which the 1-position of one carbazole skeleton is bonded to the 9-position of another carbazole skeleton, and a structure in which the 3-position of one carbazole skeleton is bonded to the 3-position of another carbazole skeleton. Since the 3-position and the 9-position of the carbazole skeleton have excellent reactivity, a compound having a bonding position at the 3-position or the 9-position of the carbazole skeleton facilitates an increase in yield or purity in the manufacturing process of the compound. A compound having a bonding position at the 1-position of the carbazole skeleton is likely to have a low evaporation temperature and can be easily deposited by evaporation as a film. The T₁ level can be adjusted with the bonding position of the carbazole skeleton; thus, molecular design is preferably performed in accordance with the required properties of the organic compound. It is further preferable to employ a plurality of the above structures. Furthermore, the compound having a carbazole skeleton may include one or more kinds of elements such as silicon, boron, oxygen, and sulfur.

In the case where two compounds are used in combination as the host materials, each of the compound having a heteroaromatic ring and the compound having a carbazole skeleton preferably has a plurality of carbazole skeletons. In that case, the compound having a carbazole skeleton preferably has at least the same number of carbazole skeletons as the compound having a heteroaromatic ring. Including carbazole skeletons with such a number enables adjustment of the electron-transport property and the hole-transport property of the host materials.

In the case where an element such as silicon, boron, oxygen, or sulfur is included in each of the compound having a heteroaromatic ring and the compound having a carbazole skeleton, the two compounds preferably include the same element to improve characteristics of the light-emitting device including the phosphorescent substance.

Examples of the organic compounds that can be used as the host materials include organic compounds obtained by deuterating 9,9′-{6-[3-(triphenylsilyl)phenyl]-1,3,5-triazine-2,4-diyl}bis(9H-carbazole) (abbreviation: SiTrzCz2) represented by Structural Formula (450), 2-phenyl-4,6-bis[3-(triphenylsilyl)phenyl]-1,3,5-triazine (abbreviation: mSiTrz) represented by Structural Formula (451), 9-{4-phenyl-6-[3-(triphenylsilyl)phenyl]-1,3,5-triazin-2-yl}-9H-carbazole (abbreviation: SiCzTrz) represented by Structural Formula (452), 9-{4,6-bis[3-(triphenylsilyl)phenyl]-1,3,5-triazin-2-yl}-9H-carbazole (abbreviation: DSiCzTrz) represented by Structural Formula (453), 9-(biphenyl-4-yl)-3-(4-{[4′-(4,6-diphenyl-1,3,5-triazin-2-yl)biphenyl-4-yl]diphenylsilyl}phenyl)-9H-carbazole (abbreviation: CzSiTzn) represented by Structural Formula (454), 3-{6-[3-(4,6-diphenyl-1,3,5-triazin-2-yl)phenyl]dibenzothiophen-4-yl}-9-phenyl-9H-carbazole (abbreviation: mPCDBtPTzn) represented by Structural Formula (455), 9-[3-(triphenylsilyl)phenyl]-3,9′-bi-9H-carbazole (abbreviation: PSiCzCz) represented by Structural Formula (456), [4-(2,12-di-tert-butyl-5,9-dioxa-13b-boranaphtho[3,2,1-de]anthracen-7-yl)phenyl]triphenylsilane represented by Structural Formula (457), and organic compounds represented by Structural Formulae (458), (459), and (460).

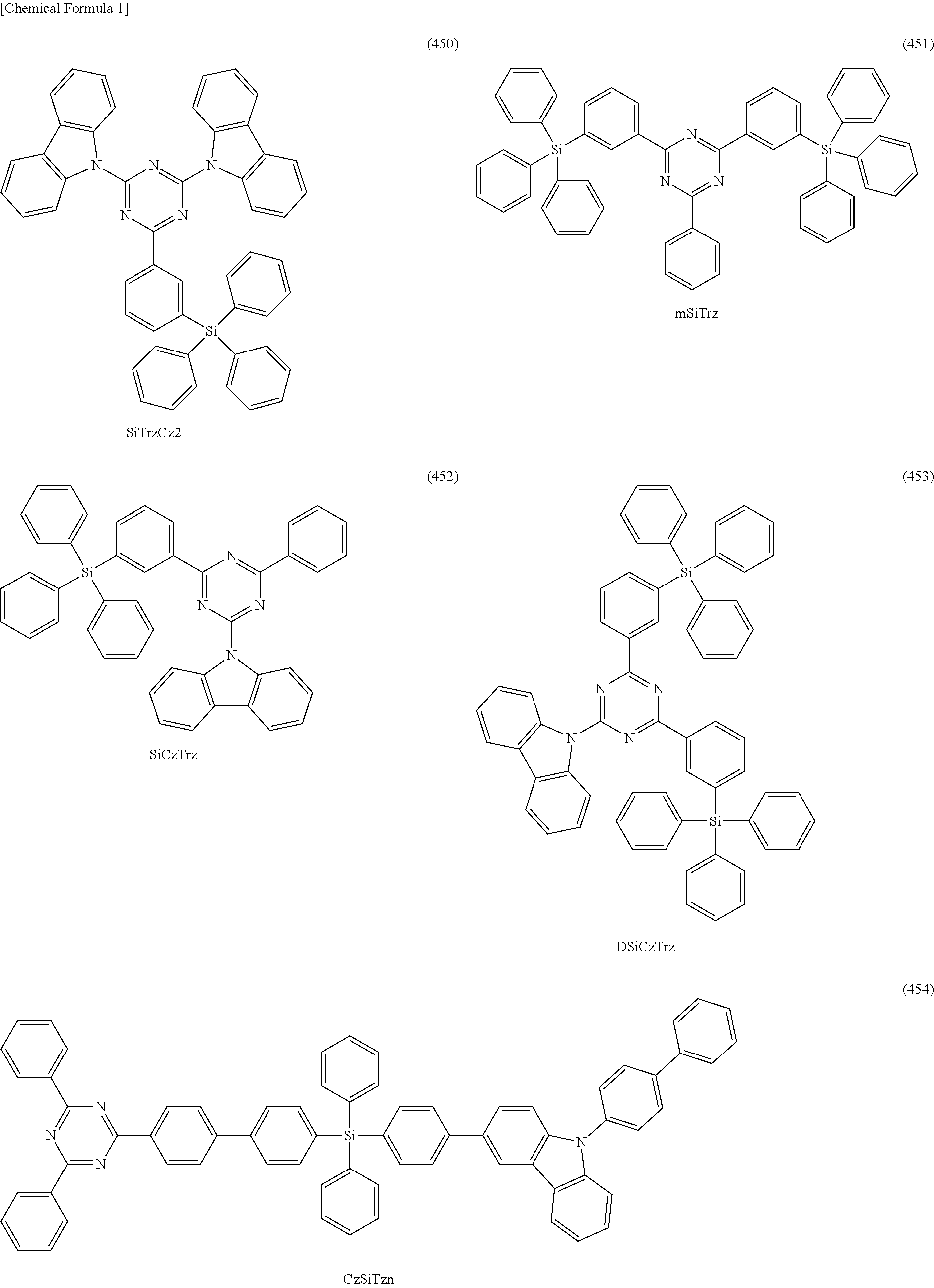

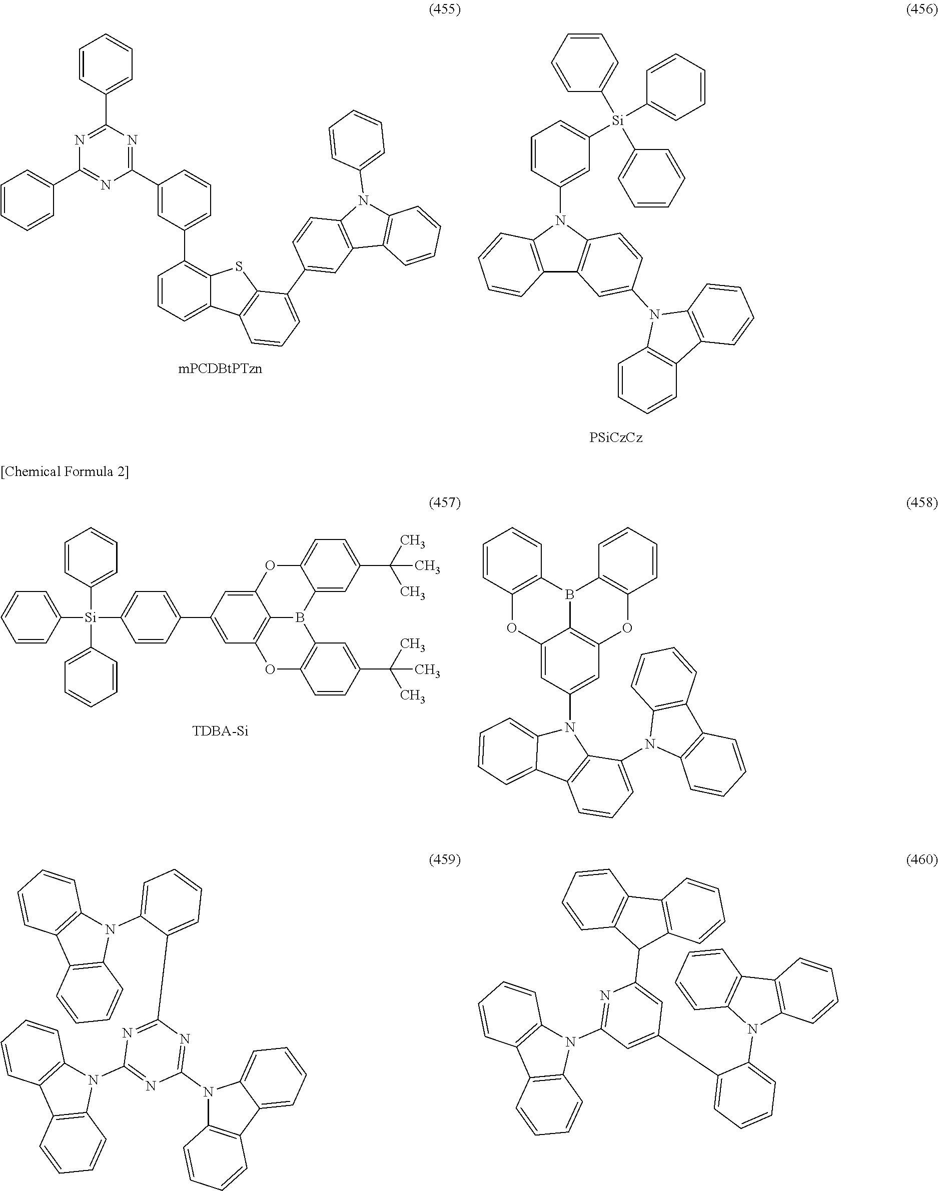

In the case where the host material includes deuterium, the whole molecule may be deuterated, or part of the molecule may be deuterated. In the case where a compound is partly deuterated, a group where the lowest triplet excitation energy level is localized is preferably deuterated. A compound that is partly deuterated can be manufactured at a lower cost than a compound whose whole molecule is deuterated. There are cases where only a heteroaromatic ring is deuterated, only a carbazole skeleton is deuterated, and only a hydrocarbon group is deuterated. In a compound having a heteroaromatic ring and a hydrocarbon group, part of the heteroaromatic ring and part of the hydrocarbon group may be deuterated. The group where the lowest triplet excitation energy level is localized can be deuterated.

Specific examples of deuterated organic compounds that can be used as the host material include organic compounds represented by Structural Formulae (461) to (483) below, such as 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d₁₆) (abbreviation: SiTrzCz2-d₁₆) represented by Structural Formula (461) and 9-[3-(triphenylsilyl)phenyl]-3,9′-(bi-9H-carbazole-d₁₅) (abbreviation: PSiCzCz-d₁₅) represented by Structural Formula (475).

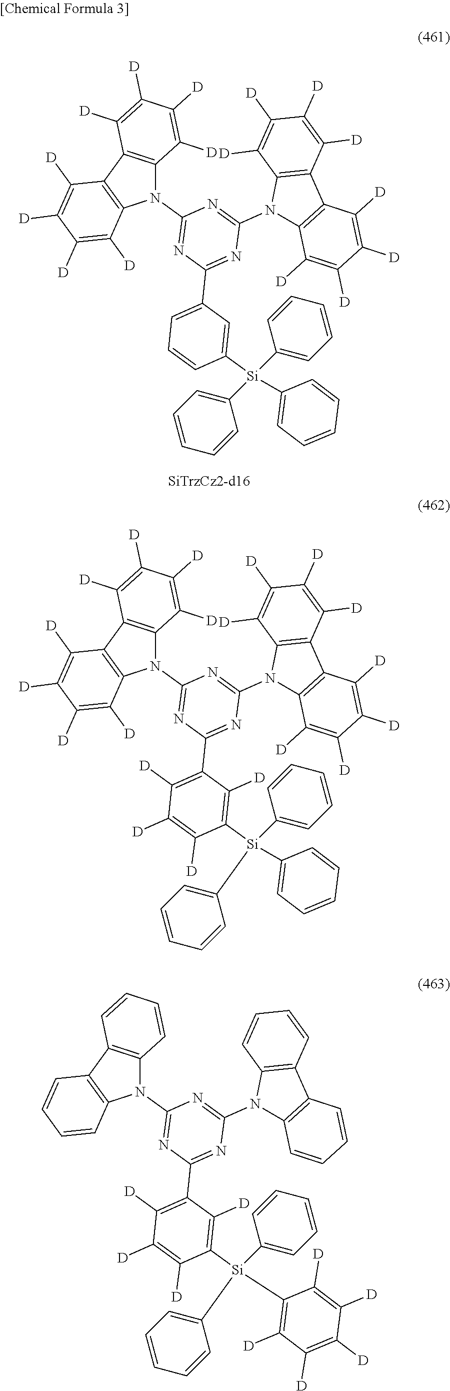

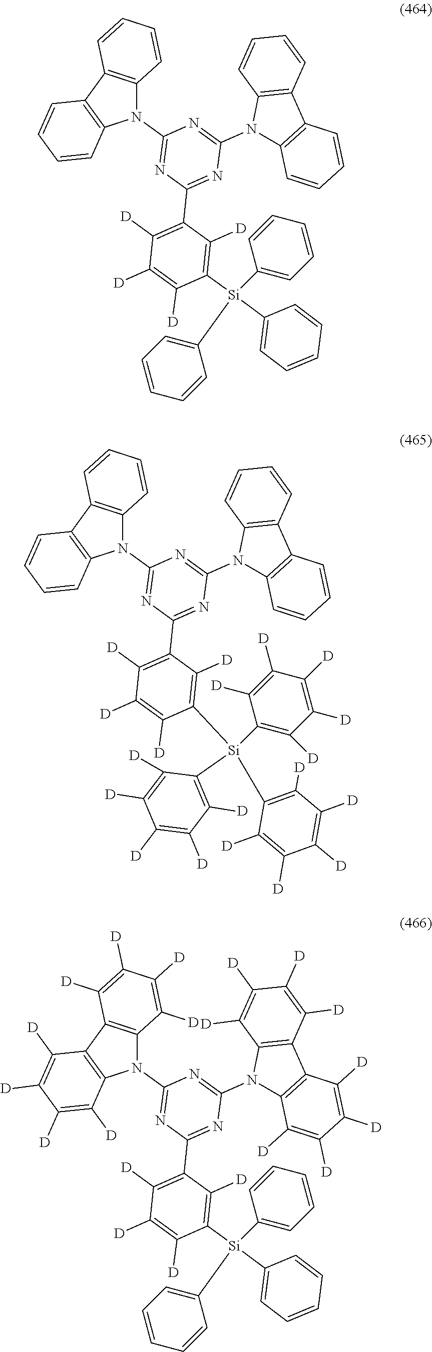

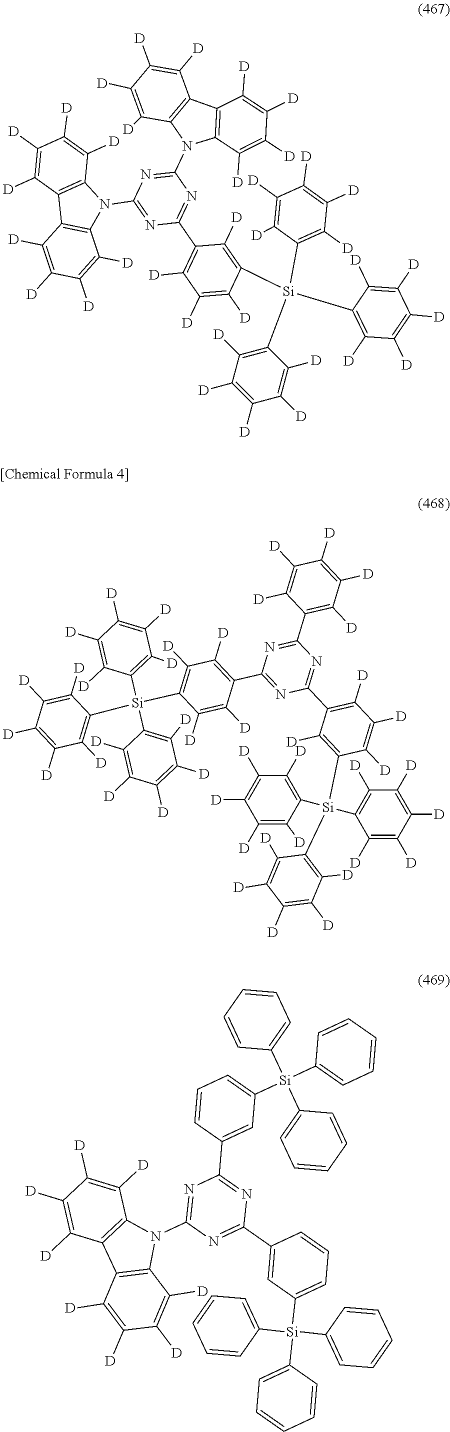

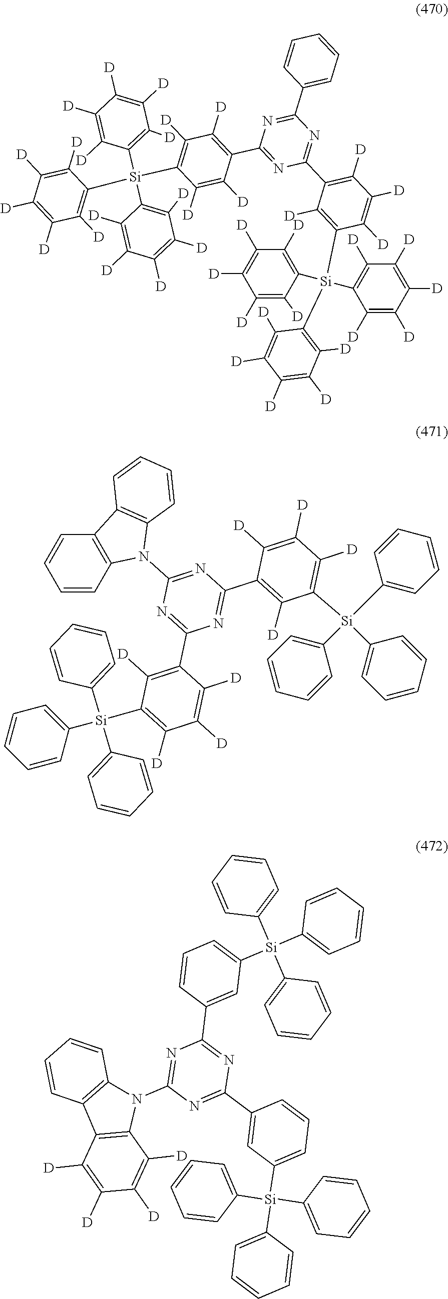

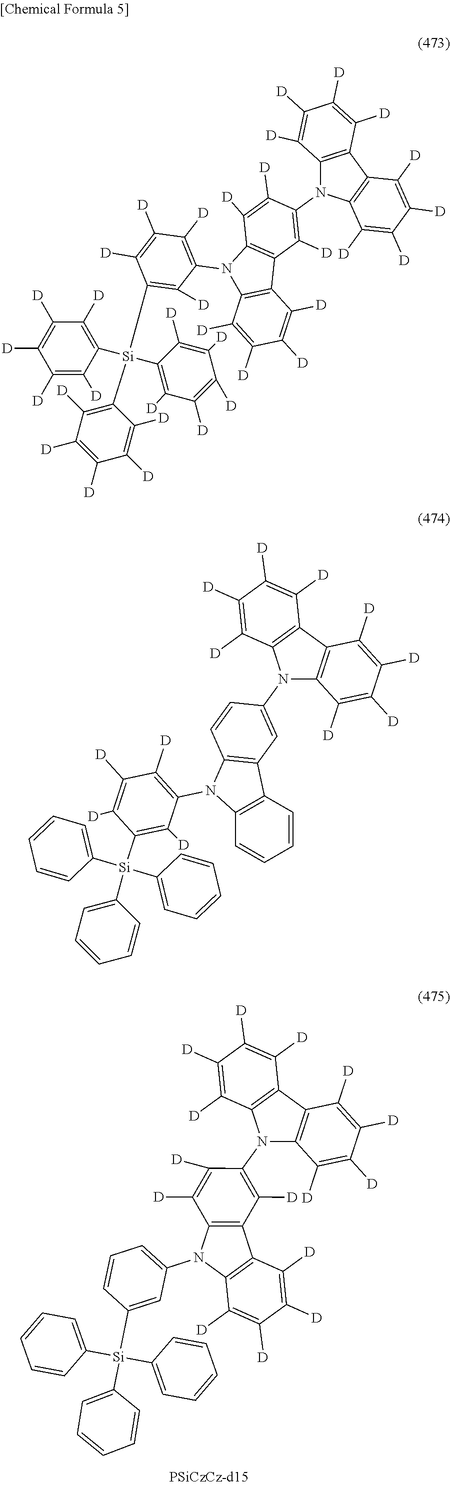

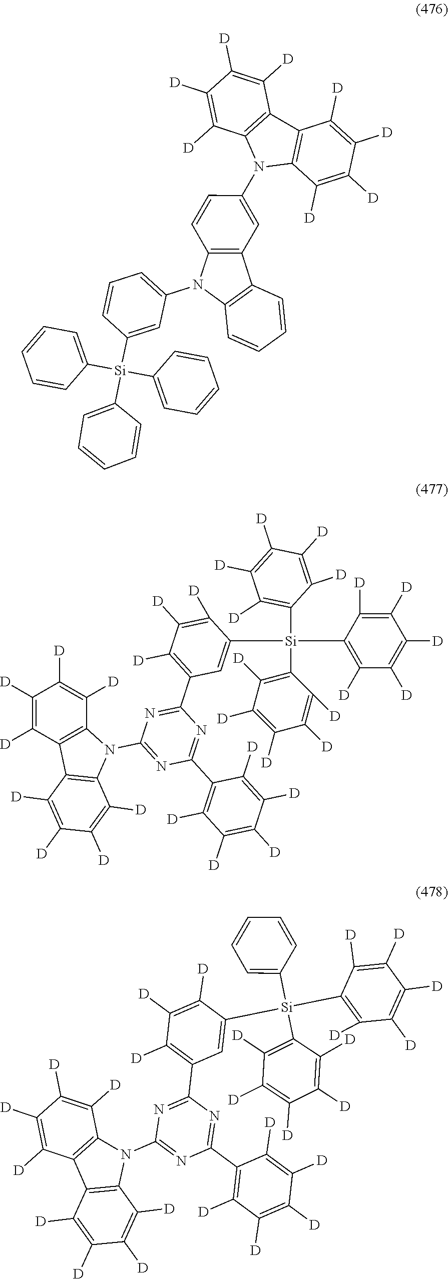

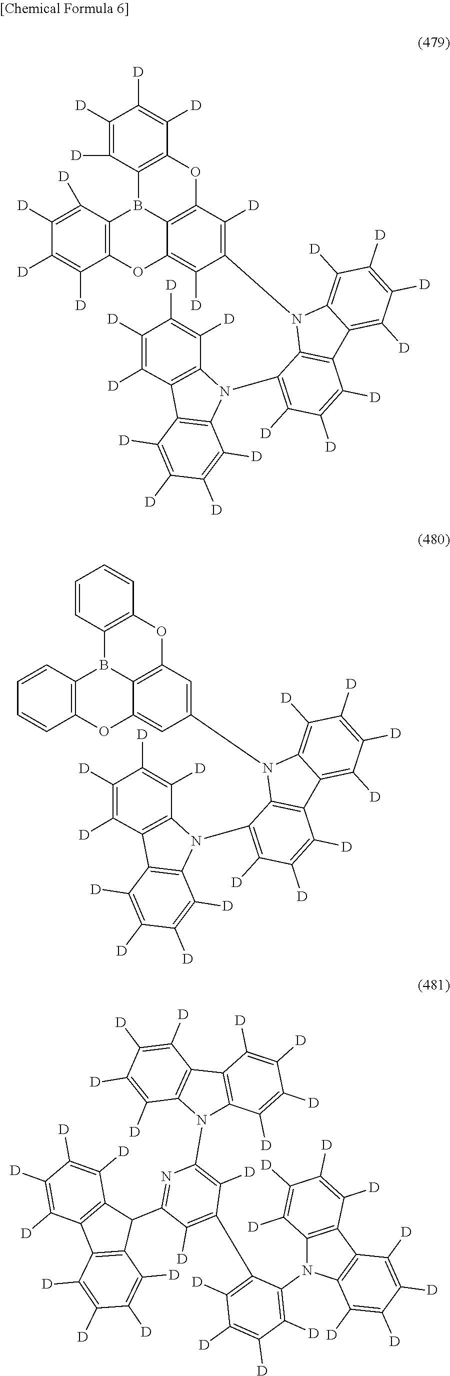

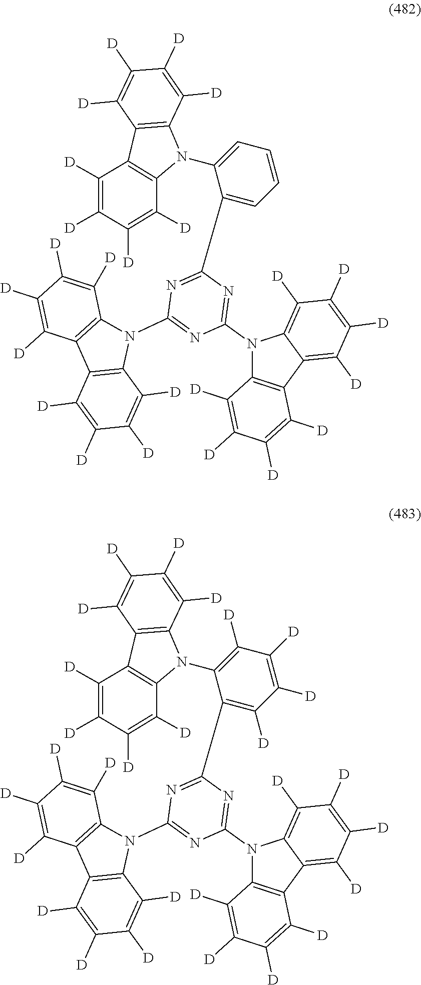 [SMILES: [2H]c1c([2H])c([2H])c2c(c1[2H])c1c([2H])c([2H])c([2H])c([2H])c1n2-c1nc(-c2ccccc2-n2c3c([2H])c([2H])c([2H])c([2H])c3c3c([2H])c([2H])c([2H])c([2H])c32)nc(-n2c3c([2H])c([2H])c([2H])c([2H])c3c3c([2H])c([2H])c([2H])c([2H])c32)n1 ; [2H]c1c([2H])c([2H])c(-n2c3c([2H])c([2H])c([2H])c([2H])c3c3c([2H])c([2H])c([2H])c([2H])c32)c(-c2nc(-n3c4c([2H])c([2H])c([2H])c([2H])c4c4c([2H])c([2H])c([2H])c([2H])c43)nc(-n3c4c([2H])c([2H])c([2H])c([2H])c4c4c([2H])c([2H])c([2H])c([2H])c43)n2)c1[2H]]

In the case where the substance that can convert triplet excitation energy into light emission (the light-emitting substance included in the light-emitting layer) emits light in the green region (typically having a peak wavelength of greater than 500 nm and less than or equal to 600 nm) or in the red region (typically having a peak wavelength of greater than 600 nm and less than or equal to 700 nm), the first host material is preferably an organic compound having a diazine skeleton or a triazine skeleton, and the second host material is preferably an organic compound having a carbazole skeleton.

Specific examples include 3-[9-(4,6-diphenyl-1,3,5-triazin-2-yl)-2-dibenzofuranyl]-9-phenyl-9H-carbazole (abbreviation: PCDBfTzn) represented by Structural Formula (600), bBCzDBfTzn represented by Structural Formula (601), 11-[4-(biphenyl-4-yl)-6-phenyl-1,3,5-triazin-2-yl]-11,12-dihydro-12-(biphenyl-3-yl)indolo[2,3-a]cabazole (abbreviation: BP-mBPIcz(II)Tzn) represented by Structural Formula (602), 2-(6-benzo[b]naphtho[1,2-d]furan-3-yl-1-naphthalenyl)-4,6-diphenyl-1,3,5-triazine (abbreviation: Bnf(3)NTzn) represented by Structural Formula (603), 9-[4-phenyl-6-(9-phenyl-3-dibenzofuranyl)-1,3,5-triazin-2-yl]-9H-carbazole (abbreviation: PDBf-CzTzn) represented by Structural Formula (604), 2-[3′-(triphenylen-2-yl)biphenyl-3-yl]-4,6-diphenyl-1,3,5-triazine (abbreviation: mTpBPTzn) represented by Structural Formula (605), 2-(biphenyl-4-yl)-4-phenyl-6-[3-(triphenylen-2-yl)phenyl]-1,3,5-triazine (abbreviation: BP-mTpPTzn) represented by Structural Formula (606), an organic compound represented by Structural Formula (607), 9-(biphenyl-3-yl)-9′-(biphenyl-4-yl)-9H,9′H-3,3′-bicarbazole (abbreviation: mBPCCBP) represented by Structural Formula (608), 9,9′-bis(biphenyl-4-yl)-3,3′-bi-9H-carbazole (abbreviation: BisBPCz) represented by Structural Formula (609), N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (610), and 9-(biphenyl-4-yl)-9′-phenyl-3,3′-bi-9H-carbazole (abbreviation: PCCzBP) represented by Structural Formula (611).

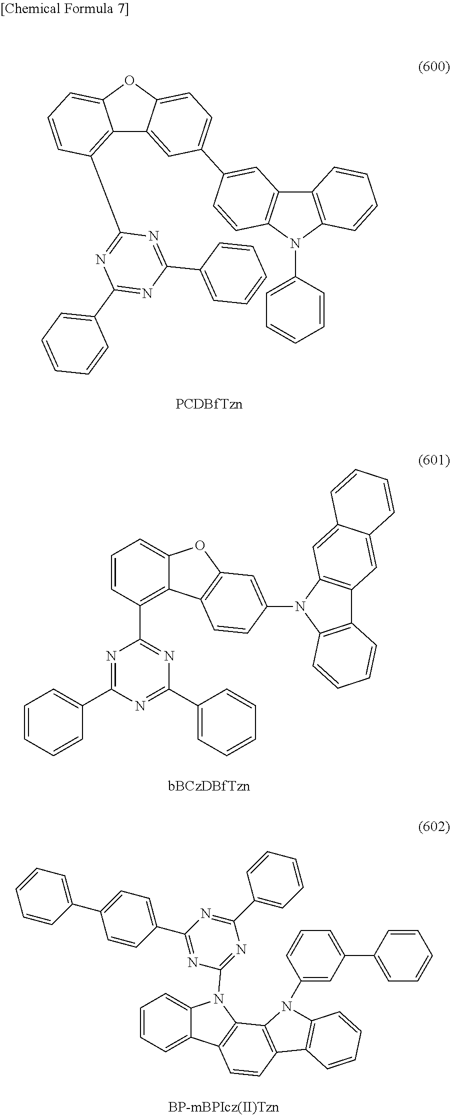 [SMILES: c1ccc(-c2nc(-c3ccccc3)nc(-c3cccc4oc5ccc(-c6ccc7c(c6)c6ccccc6n7-c6ccccc6)cc5c34)n2)cc1 ; c1ccc(-c2nc(-c3ccccc3)nc(-c3cccc4oc5cc(-n6c7ccccc7c7cc8ccccc8cc76)ccc5c34)n2)cc1 ; c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1]

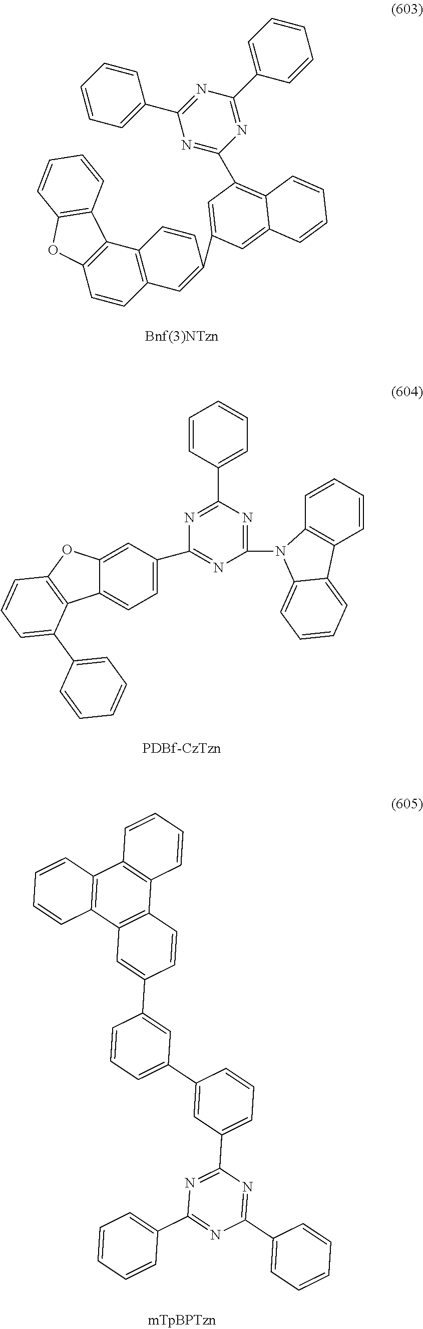 [SMILES: c1ccc(-c2nc(-c3ccccc3)nc(-c3cc(-c4ccc5c(ccc6oc7ccccc7c65)c4)cc4ccccc34)n2)cc1 ; c1ccc(-c2nc(-c3ccc4c(c3)oc3cccc(-c5ccccc5)c34)nc(-n3c4ccccc4c4ccccc43)n2)cc1 ; c1ccc(-c2nc(-c3ccccc3)nc(-c3cccc(-c4cccc(-c5ccc6c7ccccc7c7ccccc7c6c5)c4)c3)n2)cc1]

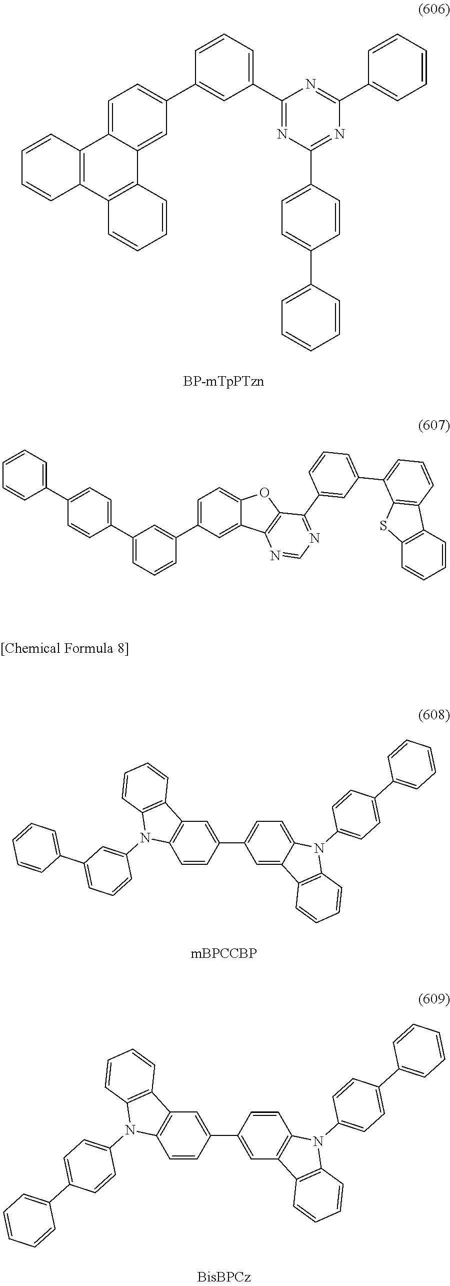 [SMILES: c1ccc(-c2ccc(-c3nc(-c4ccccc4)nc(-c4cccc(-c5ccc6c7ccccc7c7ccccc7c6c5)c4)n3)cc2)cc1 ; c1ccc(-c2ccc(-c3cccc(-c4ccc5oc6c(-c7cccc(-c8cccc9c8sc8ccccc89)c7)ncnc6c5c4)c3)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

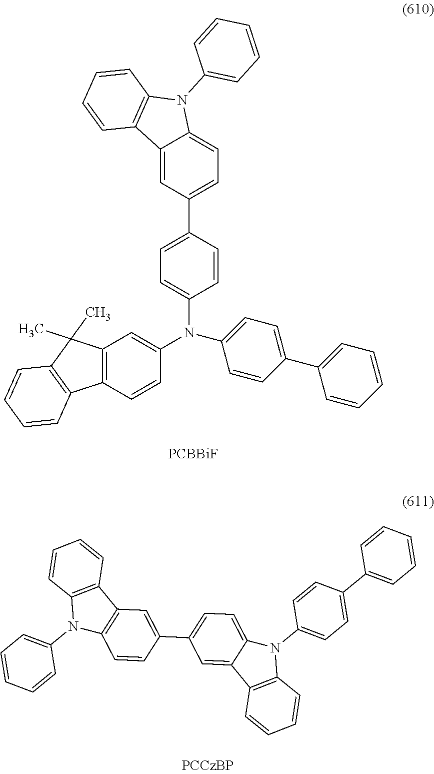

Other examples of deuterated organic compounds that can be used as the host material include organic compounds represented by Structural Formulae (612) to (631), such as PCzC represented by Structural Formula (618), PCBA1BPIV represented by Structural Formula (619), 1Adm-mCP represented by Structural Formula (629), mCz2C-PCz represented by Structural Formula (630), and mFadPCz represented by Structural Formula (631).

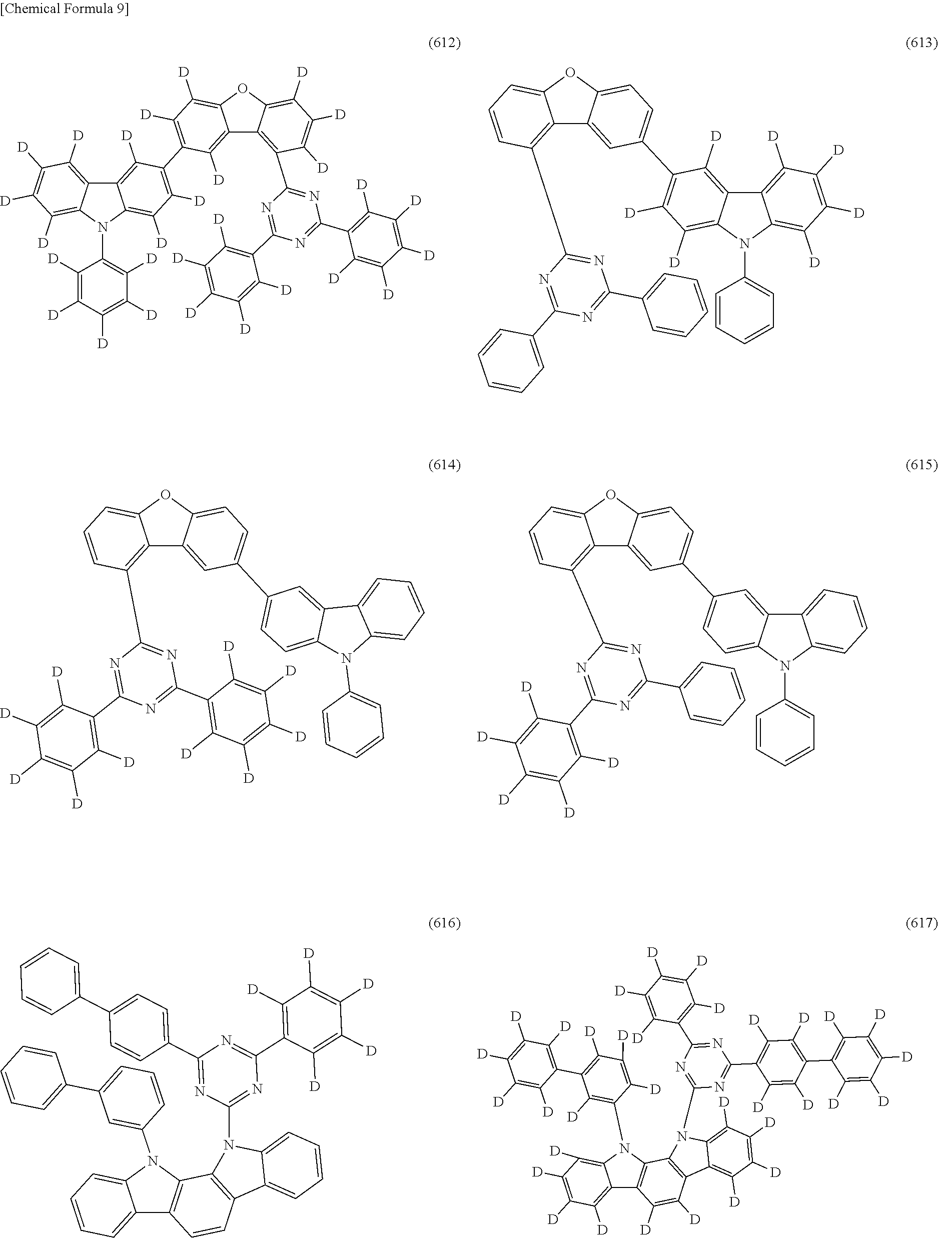

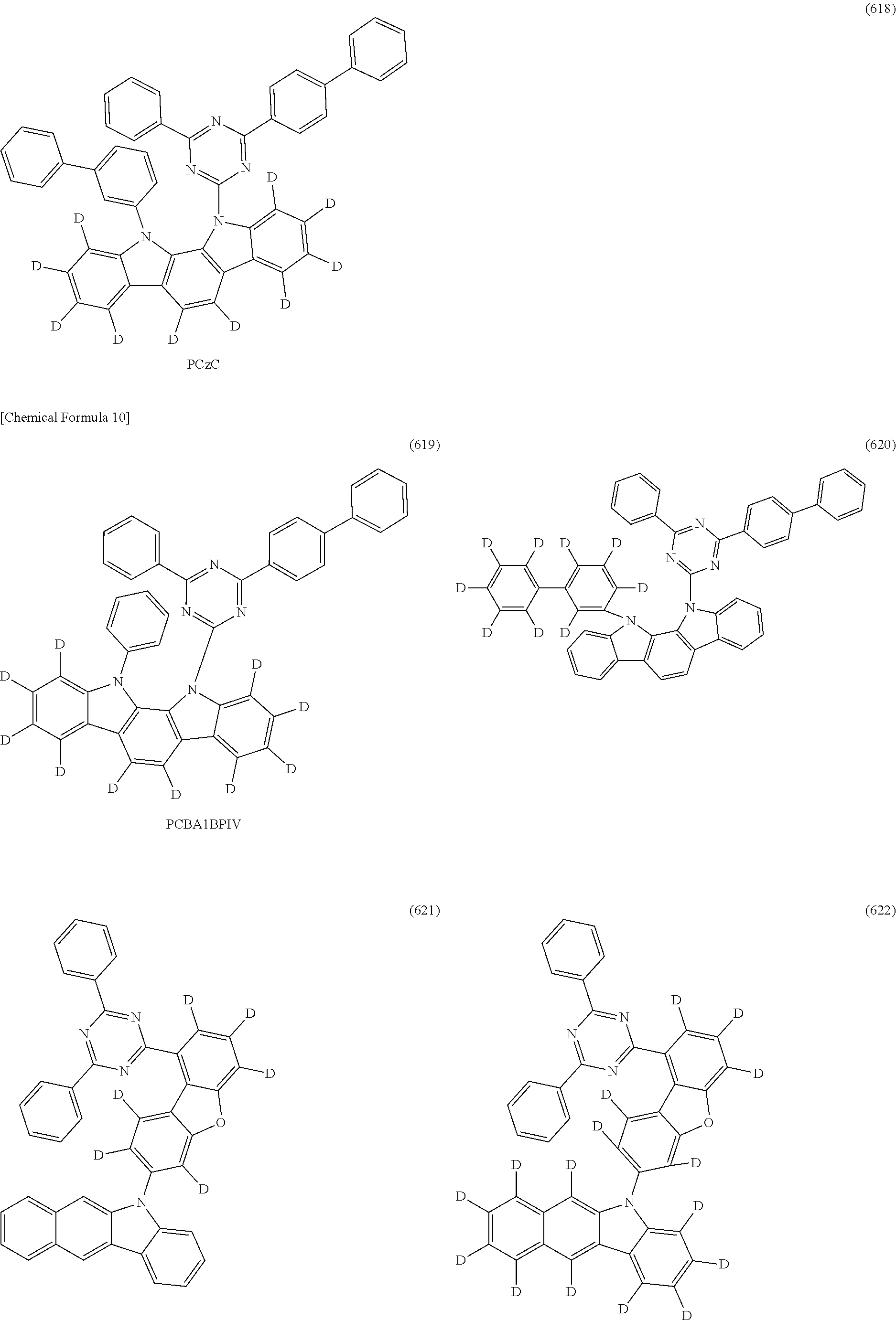

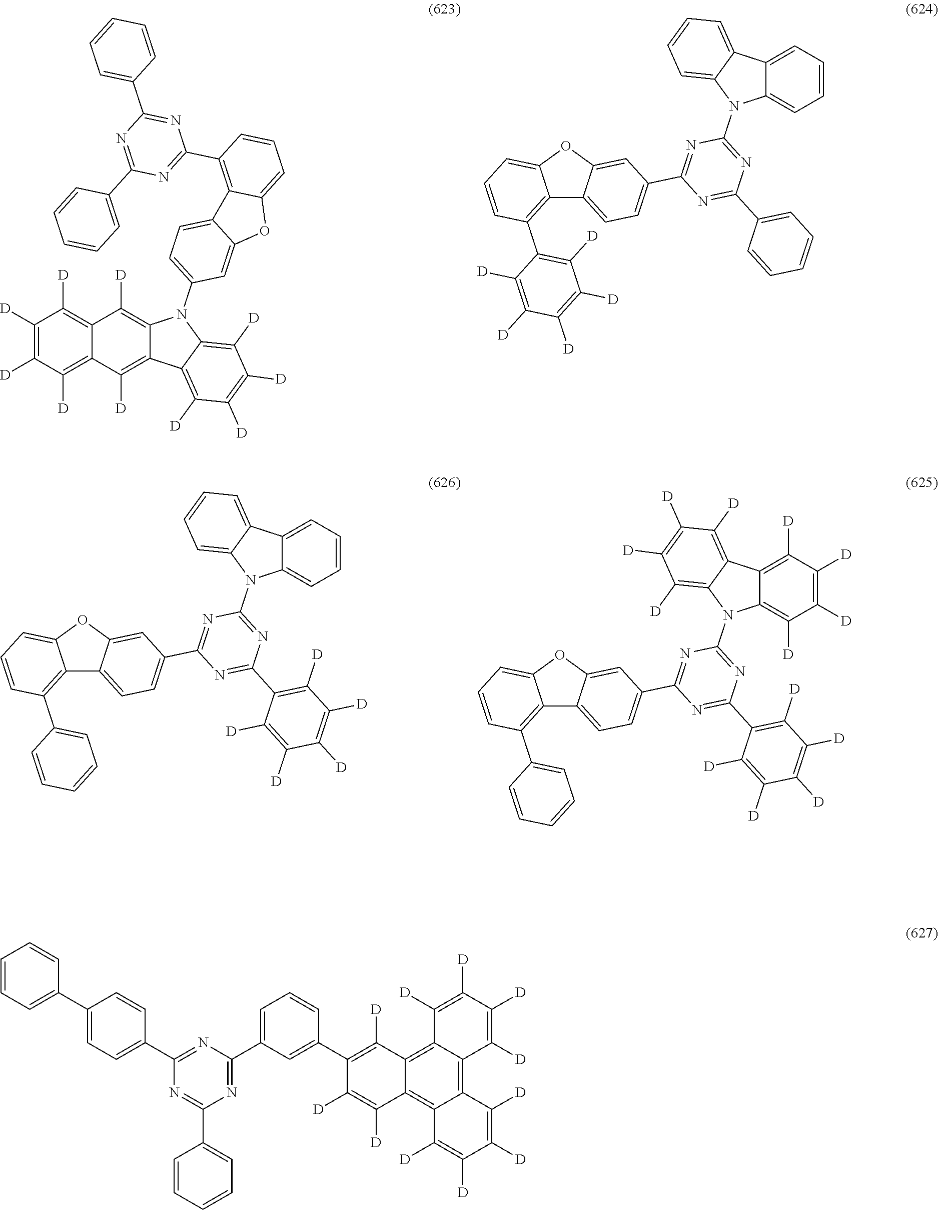

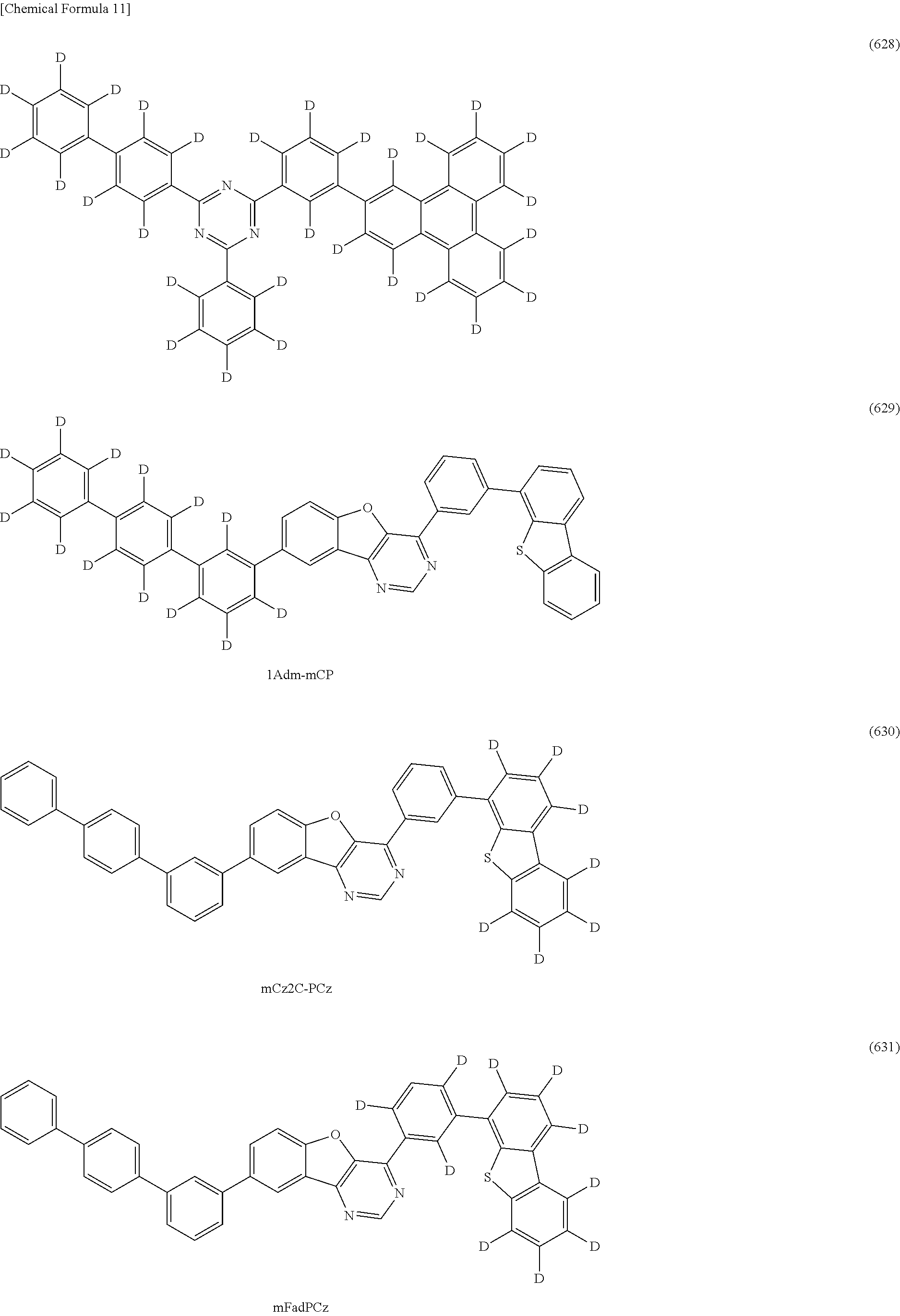

In the case where a plurality of host materials are used, any combination of organic compounds represented by Structural Formulae (632) to (640) below can be used, for example.

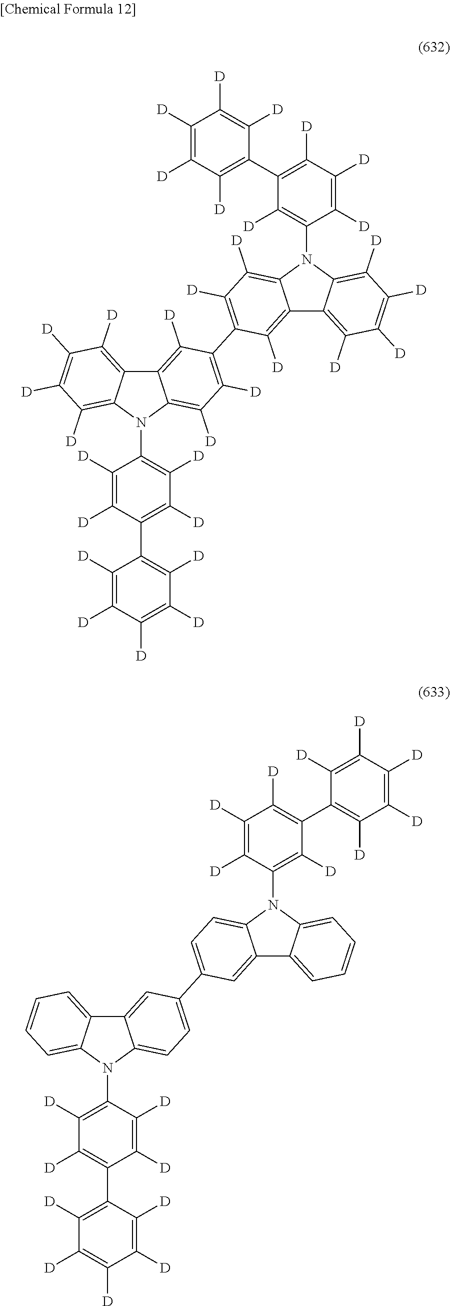 [SMILES: [2H]c1c([2H])c([2H])c(-c2c([2H])c([2H])c(-n3c4c([2H])c([2H])c([2H])c([2H])c4c4c([2H])c(-c5c([2H])c([2H])c6c(c5[2H])c5c([2H])c([2H])c([2H])c([2H])c5n6-c5c([2H])c([2H])c([2H])c(-c6c([2H])c([2H])c([2H])c([2H])c6[2H])c5[2H])c([2H])c([2H])c43)c([2H])c2[2H])c([2H])c1[2H] ; [2H]c1c([2H])c([2H])c(-c2c([2H])c([2H])c(-n3c4ccccc4c4cc(-c5ccc6c(c5)c5ccccc5n6-c5c([2H])c([2H])c([2H])c(-c6c([2H])c([2H])c([2H])c([2H])c6[2H])c5[2H])ccc43)c([2H])c2[2H])c([2H])c1[2H]]

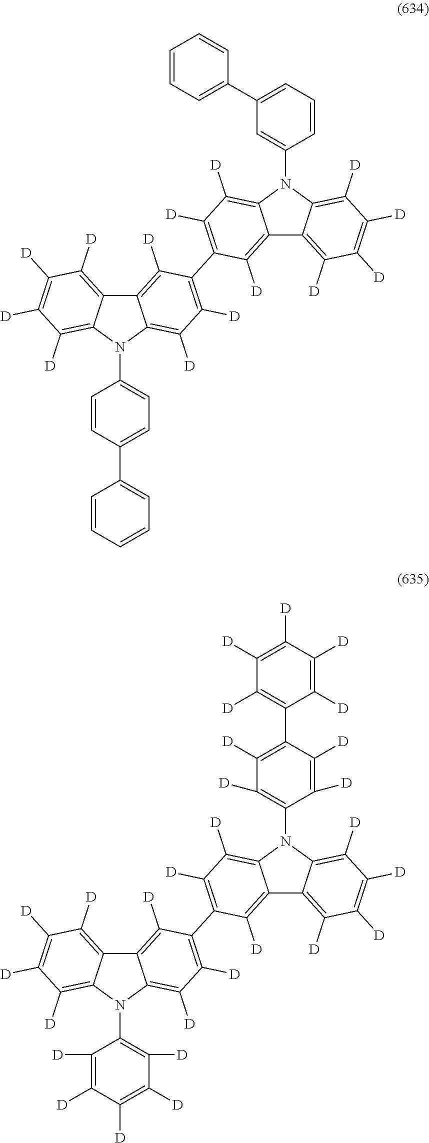 [SMILES: [2H]c1c([2H])c([2H])c2c(c1[2H])c1c([2H])c(-c3c([2H])c([2H])c4c(c3[2H])c3c([2H])c([2H])c([2H])c([2H])c3n4-c3cccc(-c4ccccc4)c3)c([2H])c([2H])c1n2-c1ccc(-c2ccccc2)cc1 ; [2H]c1c([2H])c([2H])c(-c2c([2H])c([2H])c(-n3c4c([2H])c([2H])c([2H])c([2H])c4c4c([2H])c(-c5c([2H])c([2H])c6c(c5[2H])c5c([2H])c([2H])c([2H])c([2H])c5n6-c5c([2H])c([2H])c([2H])c([2H])c5[2H])c([2H])c([2H])c43)c([2H])c2[2H])c([2H])c1[2H]]

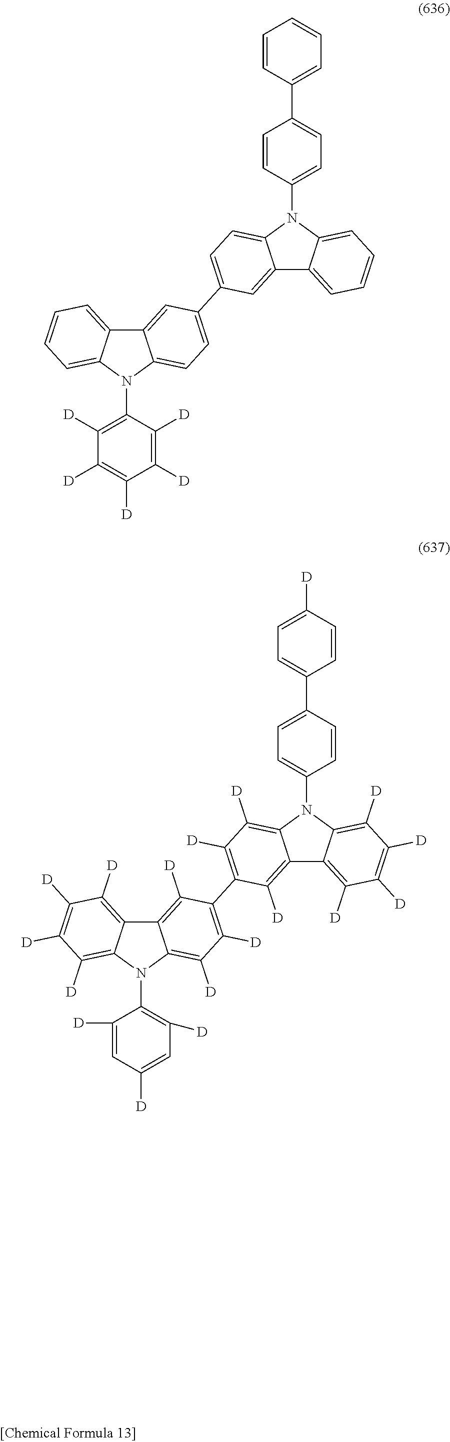 [SMILES: [2H]c1c([2H])c([2H])c(-n2c3ccccc3c3cc(-c4ccc5c(c4)c4ccccc4n5-c4ccc(-c5ccccc5)cc4)ccc32)c([2H])c1[2H] ; [2H]c1ccc(-c2ccc(-n3c4c([2H])c([2H])c([2H])c([2H])c4c4c([2H])c(-c5c([2H])c([2H])c6c(c5[2H])c5c([2H])c([2H])c([2H])c([2H])c5n6-c5c([2H])cc([2H])cc5[2H])c([2H])c([2H])c43)cc2)cc1]

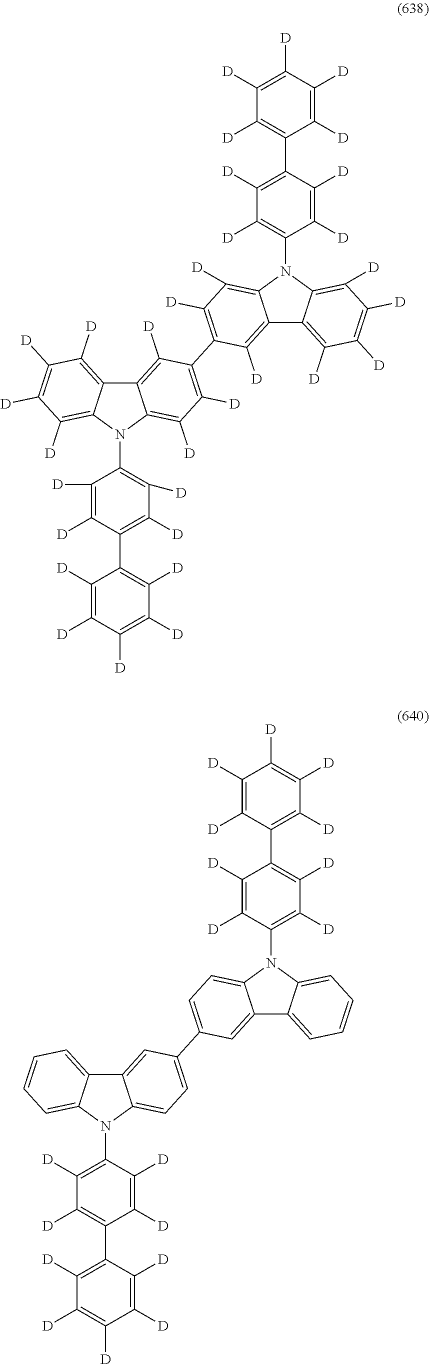 [SMILES: [2H]c1c([2H])c([2H])c(-c2c([2H])c([2H])c(-n3c4c([2H])c([2H])c([2H])c([2H])c4c4c([2H])c(-c5c([2H])c([2H])c6c(c5[2H])c5c([2H])c([2H])c([2H])c([2H])c5n6-c5c([2H])c([2H])c(-c6c([2H])c([2H])c([2H])c([2H])c6[2H])c([2H])c5[2H])c([2H])c([2H])c43)c([2H])c2[2H])c([2H])c1[2H] ; [2H]c1c([2H])c([2H])c(-c2c([2H])c([2H])c(-n3c4ccccc4c4cc(-c5ccc6c(c5)c5ccccc5n6-c5c([2H])c([2H])c(-c6c([2H])c([2H])c([2H])c([2H])c6[2H])c([2H])c5[2H])ccc43)c([2H])c2[2H])c([2H])c1[2H]]

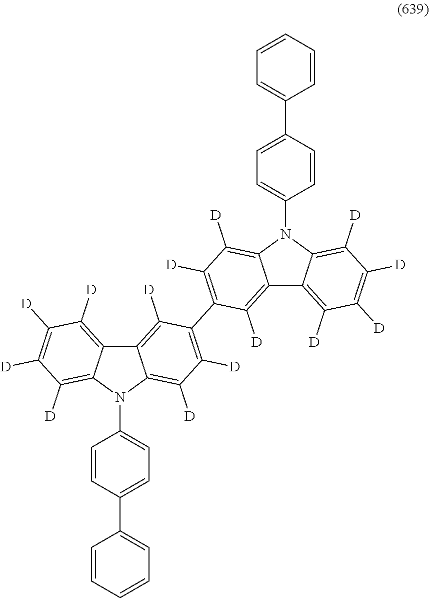 [SMILES: [2H]c1c([2H])c([2H])c2c(c1[2H])c1c([2H])c(-c3c([2H])c([2H])c4c(c3[2H])c3c([2H])c([2H])c([2H])c([2H])c3n4-c3ccc(-c4ccccc4)cc3)c([2H])c([2H])c1n2-c1ccc(-c2ccccc2)cc1]

Examples of the first host material include 8-(1,1′:4′,1″-terphenyl-3-yl-2,4,5,6,2′,3′,5′,6′,2″,3″,4″,5″,6″-d₁₃)-4-[3-(dibenzothiophen-4-yl-1,2,3,6,7,8,9-d₇)phenyl-2,4,6-d₃]-[1]benzofuro[3,2-d]pyrimidine (abbreviation: 8mpTP-4mDBtPBfpm-d₂₃), 8-(1,1′:4′,1″-terphenyl-3-yl-2,4,5,6,2′,3′,5′,6′,2″,3″,4″,5″,6″-d₁₃)-4-[3-(dibenzothiophen-4-yl)phenyl]-[1]benzofuro[3,2-d]pyrimidine (abbreviation: 8mpTP-4mDBtPBfpm-d₁₃), and 11-[4-(biphenyl-4-yl-2,2′,3,3′,4′,5,5′,6,6′-d₉)-6-(phenyl-2,3,4,5,6-d₅)-1,3,5-triazin-2-yl]-11,12-dihydro-12-(biphenyl-3-yl)indolo[2,3-a]carbazole-1,2,3,4,5,6,7,8,9,10-d₁₀.

Examples of the second host material include 9-(2-naphthyl-1,3,4,5,6,7,8-d₇)-9′-(phenyl-2,3,4,5,6-d₅)-3,3′-bi-9H-carbazole-1,1′,2,2′,4,4′,5,5′,6,6′,7,7′,8,8′-d₁₄ (abbreviation: βNCCP-d₂₆) and 9-phenyl-9′-(phenyl-2,3,4,5,6-d₅)-3,3′-bis(9H-carbazole) (abbreviation: PCCP-d₅).

With the use of the above host materials in combination with a phosphorescent substance, a highly efficient light-emitting device can be provided.

As a phosphorescent substance that emits blue light, for example, an organometallic complex can be used. An organometallic complex includes a central metal, which can be a heavy metal such as platinum (Pt), palladium (Pd), iridium (Ir), ruthenium (Ru), rhenium (Re), gold (Au), or osmium (Os). A heterocycle is preferably coordinated to the central metal and can be a six-membered ring such as a pyridine ring, a pyrazine ring, a triazine ring, or a pyrimidine ring or a five-membered ring such as a pyrazole ring, an indole ring, or a triazole ring. A structure in which both a five-membered ring and a six-membered ring are coordinated to the central metal can also be used. Moreover, the organometallic complex preferably includes a nitrogen-containing heterocyclic carbene coordinated to the central metal. The heterocycle preferably has an alkyl group as a substituent. For example, in the case where a pyridine ring is used as the heterocycle, the 4-position of the pyridine ring is preferably bonded to an alkyl group, further preferably bonded to an alkyl group including deuterium. Alternatively, the 3- and 5-positions of the pyridine ring are each preferably bonded to an alkyl group, further preferably bonded to an alkyl group including deuterium. Moreover, the 4-position of the pyridine ring is preferably bonded to a phenyl group, and the phenyl group further preferably has an alkyl group.

Since the dissociation energy of a carbon-deuterium bond is higher than the dissociation energy of a carbon-protium bond, an organometallic complex including a pyridine ring can have a stable molecular structure when an alkyl group including deuterium is bonded to each of the carbon atoms at the 3- and 5-positions of the pyridine ring, which have a high spin density in a triplet excited state. That can also inhibit bond dissociation in an excited state, increasing the stability of the organometallic complex. In addition, bonding an alkyl group including deuterium to each of the carbon atoms at the 3- and 5-positions of the pyridine ring, where the distribution of the LUMO is concentrated, can increase the stability of the organometallic complex in a state where the LUMO has received electrons, i.e., a reduction state.

Moreover, the bonding of an alkyl group including deuterium in the organometallic complex including a pyridine ring produces an effect of steric hindrance on a phenyl group bonded to the 4-position of the pyridine ring. This can inhibit rotation of the phenyl group, thereby improving the thermophysical property, e.g., the sublimation property of the organometallic complex. The vibration of the organometallic complex can also be inhibited, so that thermal deactivation from the excited state can be inhibited.

Furthermore, the LUMO distribution can be expanded by bonding the phenyl group to a carbon atom at the 4-position adjacent to the carbon atoms at the 3- and 5-positions of the pyridine ring, where the LUMO distribution is concentrated. Moreover, the LUMO can be stabilized and the stability of the organometallic complex in a reduction state can be improved.

Moreover, in the organometallic complex including a pyridine ring, bonding the phenyl group to the carbon atom at the 4-position of the pyridine ring can enhance the planarity of the organometallic complex. Accordingly, in the case where the organometallic complex is used as the emission center substance in a light-emitting layer of a light-emitting device, a higher molecular orientation is induced and the orientation is easily parallel to the substrate plane. Furthermore, since the light emission from the organometallic complex occurs perpendicular to the transition dipole moment involved in the light emission, when the transition dipole moment of the organometallic complex is parallel to the substrate plane, more emission will be directed perpendicular to the substrate plane, thereby improving the light extraction efficiency of the light-emitting device. Thus, the organometallic complex preferably has an orientation where the transition dipole moment involved in the light emission of the organometallic complex is parallel to the substrate plane.

Moreover, when the phenyl group bonded to the 4-position of the pyridine ring is bonded to an alkyl group, intermolecular interaction can be inhibited. For example, the interaction between the emission center substance and a host material (one or more of host materials in the case where a plurality of host materials are present) can be prevented when an organometallic complex of one embodiment of the present invention is used as the emission center substance in a light-emitting layer of a light-emitting device, whereby the emission efficiency of the light-emitting device can be improved.

Thus, the above-described organometallic complex can be suitably used for a light-emitting layer of a light-emitting device of one embodiment of the present invention, for example.

Specific examples of organic compounds that emit blue phosphorescent light having emission peaks in the wavelength range of 440 nm to 500 nm inclusive include the following: (2-{3-[3-(3,5-di-tert-butylphenyl)benzimidazol-1-yl-2-ylidene-κC²]phenoxy-κC²}-9-[5-(methyl-d₃)-4-phenyl-2-pyridinyl-κN]carbazole-2,1-diyl-κC)platinum(II) (abbreviation: Pt(mmtBubOcz5m4ppy-d₃)) represented by Structural Formula (400); (2-{3-[3-(3,5-di-tert-butylphenyl)benzimidazol-1-yl-2-ylidene-κC²]phenoxy-κC²}-9-(4-tert-butyl-2-pyridinyl-κN)-6-(5-cyano-2-methylphenyl) carbazole-2,1-diyl-κC)platinum(II) (abbreviation: Pt(mmtBubOm5CPcztBupy)) represented by Structural Formula (401); {[9-(4-tert-butyl-2-pyridinyl-κN)-[3,9′-bi-9H-carbazole]-2,1-diyl-κC]oxy-9-(4-tert-butyl-2-pyridinyl-κN) carbazole-2,1-diyl-κC}platinum(II) (abbreviation: Pt(cztBucpyOtBucpy)) represented by Structural Formula (402); {[9-(4-tert-butyl-2-pyridinyl-κN) carbazole-2,1-diyl-κC]oxy-9-(4-tert-butyl-2-pyridinyl-κN) carbazole-2,1-diyl-κC}platinum(II) (abbreviation: Pt(tBucpy2O)) represented by Structural Formula (403); {[9-(2-pyridinyl-κN) carbazole-2,1-diyl-κC]oxy-9-(2-pyridinyl-κN) carbazole-2,1-diyl-κC}platinum(II) (abbreviation: PtNON) represented by Structural Formula (404); (2-{4-methyl-3-[3-(3,5-di-tert-butylphenyl)benzimidazol-1-yl-2-ylidene-κC²]phenoxy-κC²}-9-[3,5-di(methyl-d₃)-4-phenyl-2-pyridinyl-κN]carbazole-2,1-diyl-κC)platinum(II) (abbreviation: Pt(Me-mmtBubOcz35dm4ppy-d₆)) represented by Structural Formula (405); {[3-(3,5-di-tert-butylphenyl)-9-(4-tert-butyl-2-pyridinyl-κN) carbazole-2,1-diyl-κC]oxy-9-(4-tert-butyl-2-pyridinyl-κN) carbazole-2,1-diyl-κC}platinum(II) (abbreviation: Pt(mmtBuptBucpyOtBucpy)) represented by Structural Formula (406); (2-{3-[3-(3,5-di-tert-butylphenyl)benzimidazol-1-yl-2-ylidene-κC²]phenoxy-κC²}-9-[3,5-di(methyl-d₃)-4-phenyl-2-pyridinyl-κN]carbazole-2,1-diyl-κC)platinum(II) (abbreviation: Pt(mmtBubOcz35dm4ppy-d₆)) represented by Structural Formula (407); (2-{5-tert-butyl-3-[3-(3,5-di-tert-butylphenyl)benzimidazol-1-yl-2-ylidene-κC²]phenoxy-κC²}-9-[3,5-di(methyl-d₃)-4-phenyl-2-pyridinyl-κN]carbazole-2,1-diyl-κC)platinum(II) (abbreviation: Pt(tBu-mmtBubOcz35dm4ppy-d₆)) represented by Structural Formula (408); {2-(3-{3-[2,6-di(phenyl-d₅)phenyl]benzimidazol-1-yl-2-ylidene-κC²}phenoxy-κC²)-9-[3,5-di(methyl-d₃)-4-phenyl-2-pyridinyl-κN]carbazole-2,1-diyl-κC¹}platinum(II) (abbreviation: Pt(mTPbOcz35dm4ppy-d₁₆)) represented by Structural Formula (409); and (2-{3-[3-(3,5-di-tert-butylphenyl)benzimidazol-1-yl-2-ylidene-κC²]phenoxy-κC²}-9-[4-tert-butylphenyl-3,5-di(methyl-d₃)-2-pyridinyl-κN]carbazole-2,1-diyl-κC)platinum(II) (abbreviation: Pt(mmtBubOcz35dm4tBuppy-d₆)) represented by Structural Formula (410). Other examples include PtON1 represented by Structural Formula (411), PtON7 represented by Structural Formula (412), PtON1-Me represented by Structural Formula (413), PtON1-tBu represented by Structural Formula (414), PtON1-NMe2 represented by Structural Formula (415), PtON6-tBu represented by Structural Formula (416), PtON7-dtb represented by Structural Formula (417), PtN1N represented by Structural Formula (418), PtN1pyCl represented by Structural Formula (419), PtON7-tBu represented by Structural Formula (420), Pt(ppzOczpy) represented by Structural Formula (421), Pt(ppzOczpy-m) represented by Structural Formula (422), Pt(ppzOczpy-2m) represented by Structural Formula (423), PdN1N represented by Structural Formula (424), PdN1N-dm represented by Structural Formula (425), and PdN6N represented by Structural Formula (426).

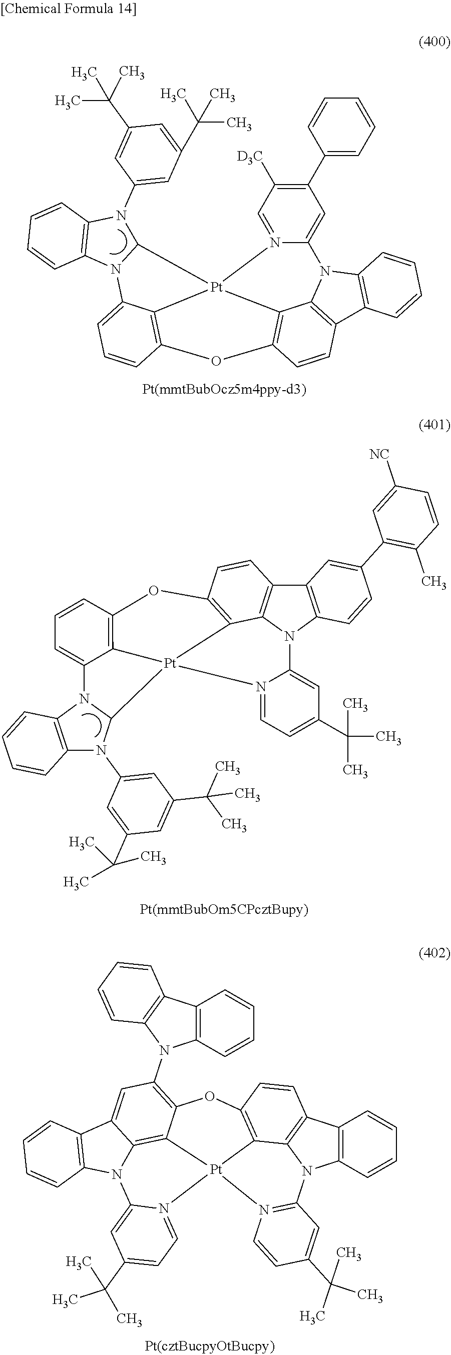

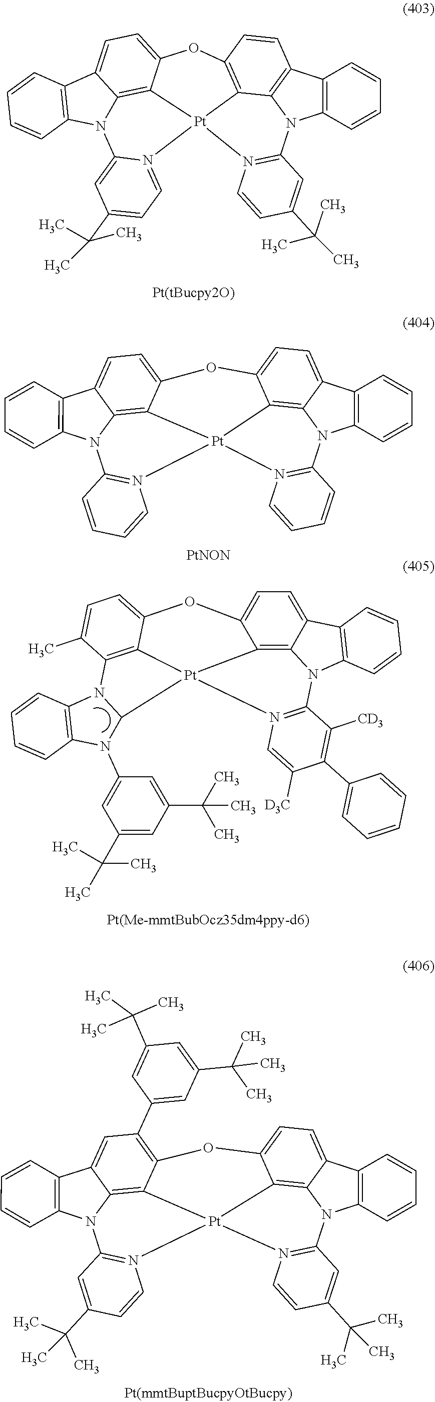

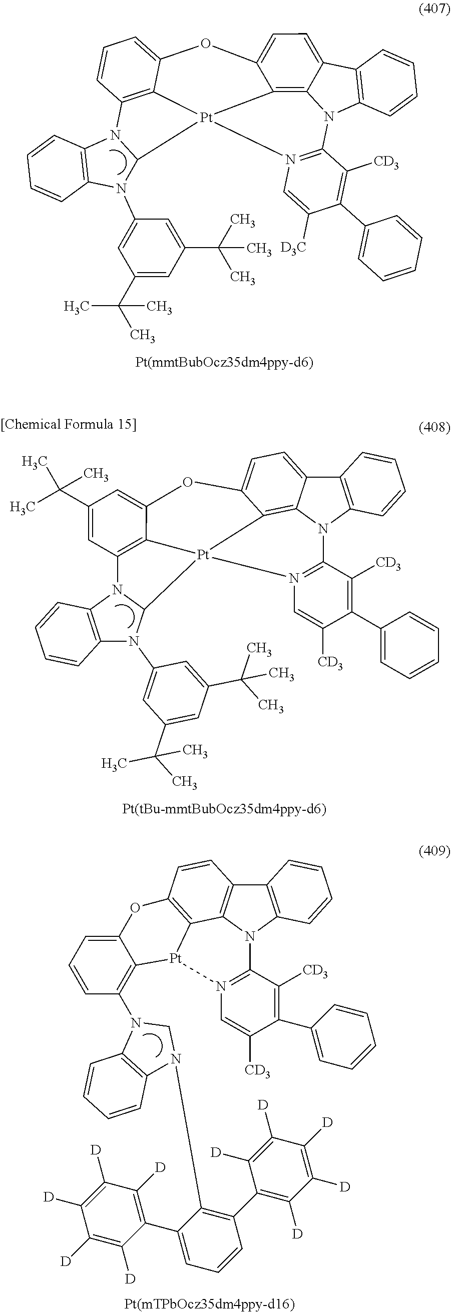

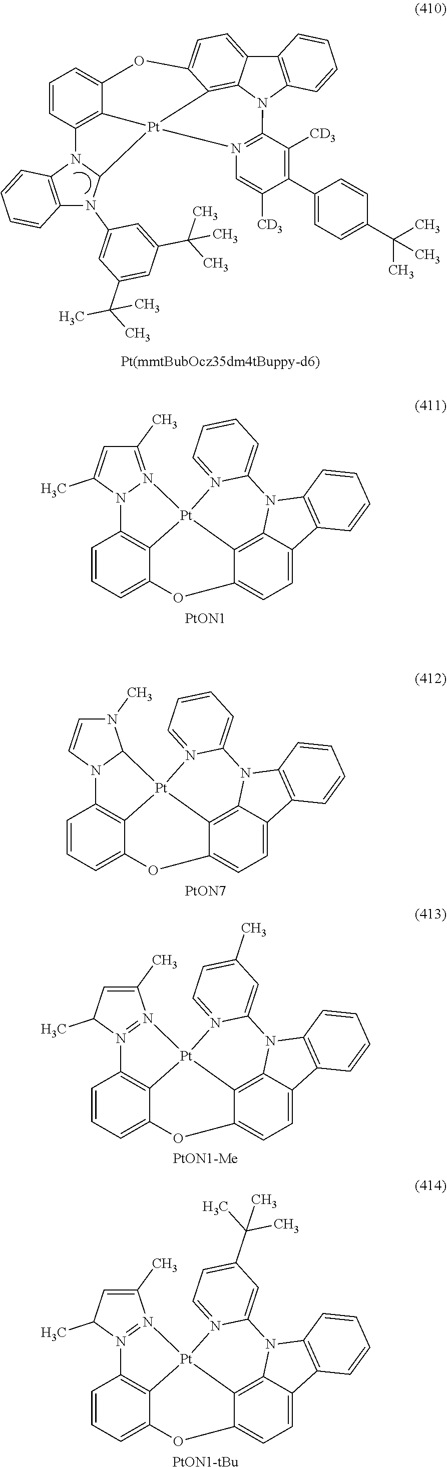

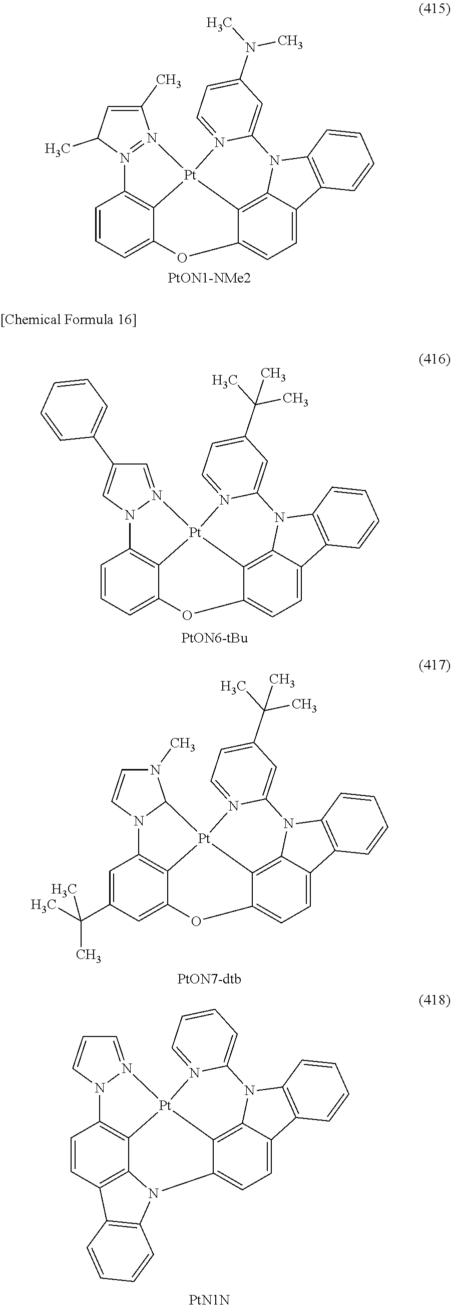

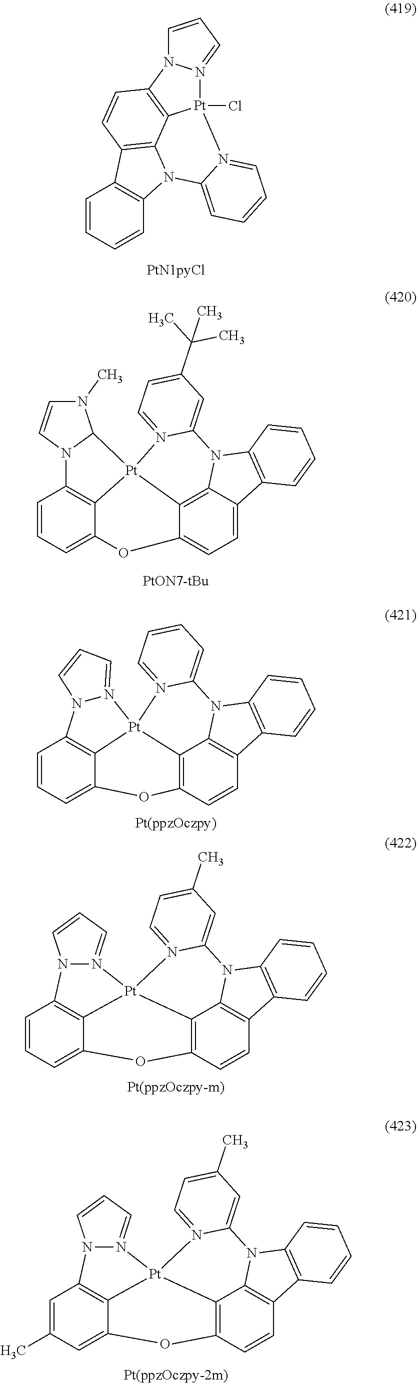

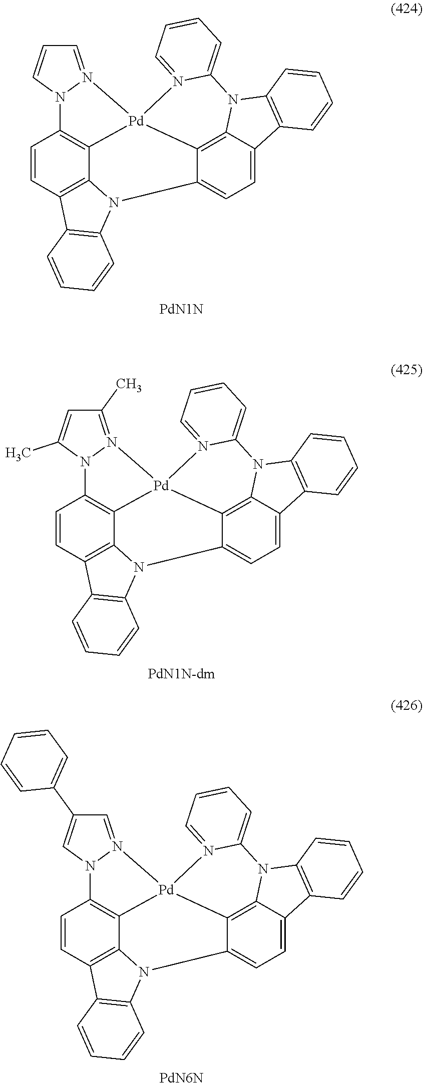

The other examples include organometallic iridium complexes having a 4H-triazole skeleton, such as tris {2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), and tris(5-methyl-3,4-diphenyl-4H-1,2,4-triazolato)iridium(III) (abbreviation: [Ir(Mptz)₃]); organometallic iridium complexes having a 1H-triazole skeleton, such as tris[3-methyl-1-(2-methylphenyl)-5-phenyl-1H-1,2,4-triazolato]iridium(III) (abbreviation: [Ir(Mptz1-mp) 3]) and tris(1-methyl-5-phenyl-3-propyl-1H-1,2,4-triazolato)iridium(III) (abbreviation: [Ir(Prptz1-Me) 3]); organometallic iridium complexes having an imidazole skeleton, such as fac-tris[1-(2,6-diisopropylphenyl)-2-phenyl-1H-imidazole]iridium(III) (abbreviation: [Ir(iPrpim) 3]), tris[3-(2,6-dimethylphenyl)-7-methylimidazo[1,2-f]phenanthridinato]iridium(III) (abbreviation: [Ir(dmpimpt-Me) 3]), and tris(2-{1-[2,6-bis(1-methylethyl)phenyl]-1H-imidazol-2-yl-κN³}-4-cyanophenyl-κC)iridium(III) (abbreviation: CNImIr); organometallic complexes having a benzimizazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); organometallic iridium complexes in which a phenylpyridine derivative having an electron-withdrawing group is a ligand, such as bis[2-(4′,6′-difluorophenyl)pyridinato-N, (2′]iridium(III) tetrakis(1-pyrazolyl) borate (abbreviation: FIr6), bis[2-(4′,6′-difluorophenyl)pyridinato-N,C^{2′}]iridium(III) picolinate (abbreviation: FIrpic), bis {2-[3′,5′-bis(trifluoromethyl)phenyl]pyridinato-N, (2}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac); and platinum complexes such as (2-{3-[3-(3,5-di-tert-butylphenyl)benzimidazol-1-yl-2-ylidene-κC²]phenoxy-κC²}-9-(4-tert-butyl-2-pyridinyl-κN) carbazole-2,1-diyl-κ(11)platinum(II) (abbreviation: PtON-TBBI).

With the use of any of the above phosphorescent substances, a light-emitting device with high emission efficiency can be provided.

The first light-emitting unit 501 and the second light-emitting unit 502 may each include another functional layer in addition to the above-described light-emitting layer. In the structure illustrated in FIG. 1A, the first light-emitting unit 501 includes a first hole-transport layer 112_1, a hole-injection layer 111, and a first electron-transport layer 114_1 in addition to the first light-emitting layer 113_1, and the second light-emitting unit 502 includes a second hole-transport layer 112_2, a second electron-transport layer 114_2, and an electron-injection layer 115 in addition to the second light-emitting layer 113_2. However, the structure of the organic compound layer 103 in one embodiment of the present invention is not limited thereto and any of the layers may be omitted or other layers may be added.

Although being a single layer in FIG. 1A, each of the first electron-transport layer 114_1 and the second electron-transport layer 114_2 may be a single layer or have a stacked-layer structure. The first electron-transport layer 114_1 and the second electron-transport layer 114_2 do not necessarily have same structure.

For example, the structure in which the first electron-transport layer 114_1 is a single layer and the second electron-transport layer 114_2 has a stacked-layer structure may be employed. Specifically, the structure may be employed in which the electron-transport layer (e.g., the second electron-transport layer 114_2 in FIG. 1A) included in the light-emitting unit on the cathode side has a stacked-layer structure, and the electron-transport layer (e.g., the first electron-transport layer 114_1 in FIG. 1A) included in another light-emitting unit has a single-layer structure.

In one embodiment of the present invention, at least one electron-transport layer included in the light-emitting unit on the cathode side preferably includes an organic compound having a triazine skeleton. Alternatively, layers including organic compounds having different triazine skeletons may be stacked. Among the stacked layers, in particular, a layer on the cathode side preferably includes an organic compound having a triazine skeleton and an alkali metal such as Li. Such a structure can improve the electron-injection property.

The electron-transport layer included in the light-emitting unit closer to the anode than the light-emitting unit on the cathode side is (hereinafter also referred to as a light-emitting unit on the anode side) may include an organic compound that is the same as or different from the organic compound included in the electron-transport layer in the light-emitting unit on the cathode side. For example, an organic compound having a triazine skeleton, which is different from the organic compound having a triazine skeleton in the electron-transport layer included in the light-emitting unit on the cathode side, may be used.

Moreover, the electron-transport layer included in the light-emitting unit on the anode side preferably includes an organic compound having a triazine skeleton in order to reduce power consumption. In particular, the electron-transport layer included in the light-emitting unit on the anode side preferably includes the same organic compound as that in the electron-transport layer included in the light-emitting unit on the cathode side in order to inhibit a manufacturing apparatus from becoming complex and offer a cost advantage in raw material procurement.

When the electron-transport layer included in the light-emitting unit on the anode side includes an organic compound having no triazine skeleton, the carrier-transport property can be easily controlled to provide a light-emitting device with better characteristics. The organic compound having no triazine skeleton is preferably an organic compound that has a heteroaromatic ring having a pyridine skeleton or an organic compound that has a heteroaromatic ring having a diazine (pyrimidine or pyrazine) skeleton. Thus, the electron-transport layer included in the light-emitting unit on the anode side preferably includes an organic compound having a triazine skeleton, a pyrimidine skeleton, an imidazole skeleton, or an anthracene skeleton.

The electron-transport layer included in the light-emitting unit on the anode side may have a stacked-layer structure or a single-layer structure. When the electron-transport layer has a stacked-layer structure, the light-emitting device can have high current efficiency, low power consumption, and favorable characteristics. When the electron-transport layer has a single-layer structure, the number of film formation chambers can be reduced, which is advantageous in terms of manufacturing cost.

The above-described organic compound having a triazine skeleton that can be used in the electron-transport layer included in the light-emitting unit on each of the anode side and the cathode side preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has a property of transporting more electrons than holes.

The organic compound having a triazine skeleton preferably has the triazine skeleton and an aromatic ring. The aromatic ring is preferably a monocyclic aromatic ring, a polycyclic aromatic ring, an aromatic ring having an alkyl group as a substituent, an aromatic ring having a fluoro group as a substituent, an aromatic ring having a cyano group as a substituent, or the like. The triazine skeleton may have a substituent other than the above-described aromatic ring, and the aromatic ring may have a substituent other than the above-described fluoro group, cyano group, or alkyl group. Note that the triazine skeleton is also referred to as a triazine ring, and other skeletons can also be rephrased as rings.

Examples of the monocyclic aromatic ring include aromatic hydrocarbon rings such as a benzene ring and heteroaromatic rings such as a pyrrole ring, a pyridine ring, a pyrimidine ring, and a triazine ring. Having the aromatic ring as a substituent has the effect of improving heat resistance, specifically, a glass transition temperature (7 g), and the effect of improving an electron-transport property, for example.

Examples of the polycyclic aromatic ring include aromatic hydrocarbon rings such as a naphthalene ring, a phenanthrene ring, a chrysene ring, a triphenylene ring, a fluorene ring, and a spirobifluorene ring and heteroaromatic rings such as a carbazole ring, a dibenzofuran ring, a dibenzothiophene ring, a xanthene ring, an indolocarbazole ring, and an indenocarbazole ring. A compound having the polycyclic aromatic ring as a substituent can improve heat resistance more than a compound having a benzene ring and is thus preferable. A compound having as a substituent a ring in which an aromatic ring (e.g., a benzene ring, a naphthalene ring, or a pyridine ring) is further fused to any of the above polycyclic aromatic rings can further improve heat resistance. Examples of the ring in which an aromatic ring is further fused to the polycyclic aromatic ring include a benzofluorene ring, a benzonaphthofuran ring, a benzoxanthene ring, and a benzonaphthothiophene ring. Providing a layer including a compound having high heat resistance in the vicinity of the cathode can inhibit heat damage to the device when high-temperature treatment in a patterning step or the like is performed after the layer or the cathode is formed.

Examples of the alkyl group include a methyl group, an ethyl group, a propyl group, a tertiary butyl group, a cyclohexyl group, and an adamantyl group. A layer including a compound having the alkyl group as a substituent can have a low refractive index. This can inhibit total reflection at the interface between the layer and another layer and improve the light extraction efficiency of the light-emitting device including the layer. When such a compound having an alkyl group is used also for the hole-transport layer, the refractive index of the hole-transport layer can be lowered. In particular, when a compound having a triazine skeleton and an alkyl group is used for the electron-transport layer and a compound having an aromatic amine skeleton and an alkyl group is used for the hole-transport layer, the effect of improving the light extraction efficiency can be synergistically enhanced. A compound having an alkyl group having a plurality of carbon atoms, preferably three or more carbon atoms, further preferably four or more carbon atoms, still further preferably five or more carbon atoms, can enhance the effect of lowering the refractive index. A layer including a compound having a fluoro group as a substituent is also preferable because it can lower the refractive index. In particular, a compound having a plurality of fluoro groups can enhance the effect of lowering the refractive index. It is also effective to use a compound having a fluoro group for both the electron-transport layer and the hole-transport layer.

A compound having a cyano group as a substituent is preferable because it can improve the electron-transport property.

A combination of some of polycyclic aromatic rings, alkyl groups, fluoro groups, and cyano groups is also suitable for substituents of the compound. Having a polycyclic aromatic ring and a cyano group as substituents, for example, can improve both the heat resistance and the electron-transport property. In addition, having a polycyclic aromatic ring and an alkyl group can improve both the heat resistance and the light extraction efficiency. In this manner, substituents can be combined in accordance with the required function.

A compound having a plurality of polycyclic aromatic rings as substituents can further improve the heat resistance. In that case, the compound preferably has the aromatic hydrocarbon ring and the heteroaromatic ring.

Specific examples of the organic compound having a triazine skeleton include organic compounds that have a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: 2-{3-[3-(benzo[b]naphtho[1,2-d]furan-6-yl)phenyl]phenyl}-4,6-diphenyl-1,3,5-mBnfBPTzn), triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthryl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-[4-(2-naphthyl)phenyl]-4-phenyl-6-spiro[9H-fluoren-9,9′-[9H]xanthen]-4-yl-1,3,5-triazine abbreviation: βNP-SFx(4) Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl)indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 3-pheny-9-[4-phenyl-6-(9-phenyl-3-dibenzofuranyl)-1,3,5-triazin-2-yl]-9H-carbazole (abbreviation: PDBf-PCzTzn), 9-[4-(4,6-diphenyl-1,3,5-triazin-2-yl)-2-dibenzothienyl]-2-phenyl-9H-carbazole (abbreviation: PCzDBtTzn), 2,4-diphenyl-6-[3′-(spiro[7H-benzo[c]fluorene-7,9′-[9H]xanthen]-2′-yl)biphenyl-3-yl]-1,3,5-triazine (abbreviation: mSbfxBPTzn), 3′-[4-phenyl-6-(spiro[9H-fluorene-9,9′-[9H]xanthen]-2′-yl)-1,3,5-triazin-2-yl]biphenyl-4-carbonitrile (abbreviation: mpCNBP-SFxTzn), and 2,2′-(1,2-naphthalenediyldi-4,1-phenylene)bis[4,6-diphenyl-1,3,5-triazine](abbreviation: TznP2N). In particular, TznP2N represented by Structural Formula (500), mSbfxBPTzn represented by Structural Formula (501), mpCNBP-SFxTzn represented by Structural Formula (502), CNBPNPTzn represented by Structural Formula (503), BNP-SFx (4) Tzn represented by Structural Formula (504), mmtBuBP-mDMePyPTzn represented by Structural Formula (505), and mBnfBPTzn represented by Structural Formula (506) are preferable and shown below.

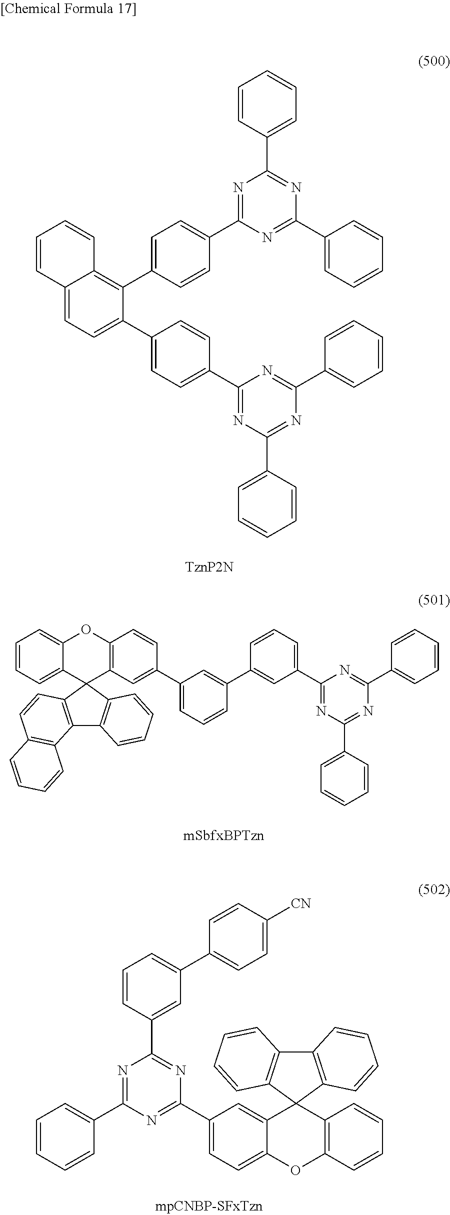 [SMILES: c1ccc(-c2nc(-c3ccccc3)nc(-c3ccc(-c4ccc5ccccc5c4-c4ccc(-c5nc(-c6ccccc6)nc(-c6ccccc6)n5)cc4)cc3)n2)cc1 ; c1ccc(-c2nc(-c3ccccc3)nc(-c3cccc(-c4cccc(-c5ccc6c(c5)C5(c7ccccc7O6)c6ccccc6-c6c5ccc5ccccc65)c4)c3)n2)cc1 ; N#Cc1ccc(-c2cccc(-c3nc(-c4ccccc4)nc(-c4ccc5c(c4)C4(c6ccccc6O5)c5ccccc5-c5ccccc54)n3)c2)cc1]

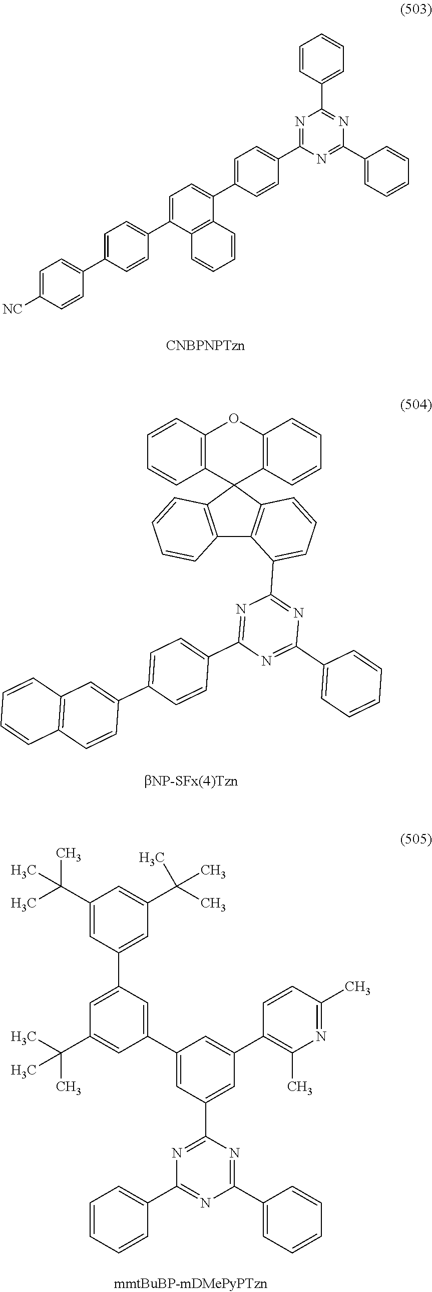 [SMILES: N#Cc1ccc(-c2ccc(-c3ccc(-c4ccc(-c5nc(-c6ccccc6)nc(-c6ccccc6)n5)cc4)c4ccccc34)cc2)cc1 ; c1ccc(-c2nc(-c3ccc(-c4ccc5ccccc5c4)cc3)nc(-c3cccc4c3-c3ccccc3C43c4ccccc4Oc4ccccc43)n2)cc1 ; Cc1ccc(-c2cc(-c3cc(-c4cc(C(C)(C)C)cc(C(C)(C)C)c4)cc(C(C)(C)C)c3)cc(-c3nc(-c4ccccc4)nc(-c4ccccc4)n3)c2)c(C)n1]

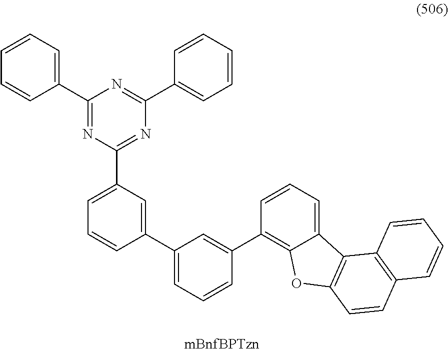 [SMILES: c1ccc(-c2nc(-c3ccccc3)nc(-c3cccc(-c4cccc(-c5cccc6c5oc5ccc7ccccc7c56)c4)c3)n2)cc1]

The material that can be used for the electron-transport layer included in the light-emitting unit on the anode side preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has a property of transporting more electrons than holes. The above substance is preferably an organic compound that has a π-electron deficient heteroaromatic ring. The organic compound that has a π-electron deficient heteroaromatic ring is preferably one or more of an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton, and is particularly preferably an organic compound that has a heteroaromatic ring having a triazine skeleton. Note that any of the above organic compounds deuterated as appropriate can also be used.

As the electron-transport organic compound that can be used in the electron-transport layer included in the light-emitting unit on the anode side, an electron-transport material described later can be used. In particular, the organic compound that has a heteroaromatic ring having a diazine skeleton, the organic compound that has a heteroaromatic ring having a pyridine skeleton, and the organic compound that has a heteroaromatic ring having a triazine skeleton are preferable because of having high reliability. In particular, the organic compound that has a heteroaromatic ring having a diazine (pyrimidine or pyrazine) skeleton and the organic compound that has a heteroaromatic ring having a triazine skeleton have a high electron-transport property, leading to a reduction in driving voltage.

In the tandem light-emitting device of one embodiment of the present invention, the intermediate layer 160 preferably includes an organic compound having a phenanthroline skeleton.

The above-described organic compound having a phenanthroline skeleton preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has a property of transporting more electrons than holes.

The organic compound having a phenanthroline skeleton preferably has the phenanthroline skeleton and an aromatic ring. The aromatic ring is preferably a monocyclic aromatic ring, a polycyclic aromatic ring, or the like.

Examples of the monocyclic aromatic ring include a benzene ring, a pyrrole ring, a pyridine ring, and a pyrimidine ring. Preferable examples of the polycyclic aromatic ring include heteroaromatic rings such as a phenanthroline ring and a pyrrole ring, as well as aromatic hydrocarbon rings such as a naphthalene ring, a phenanthrene ring, a chrysene ring, a triphenylene ring, and a fluorene ring. It is particularly preferable that the organic compound have a plurality of such polycyclic aromatic rings to improve its heat resistance or electron-transport property.

The organic compound having a phenanthroline skeleton can be, for example, an organic compound that has a heteroaromatic ring having a phenanthroline skeleton, such as bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthryl)-1-naphthyl]-1,10-phenanthroline (abbreviation: PnNPhen), or 2-[4-(2-triphenylenyl)phenyl]-1,10-phenanthroline (abbreviation: pTpPPhen), and is preferably PnNPhen represented by Structural Formula (200) below, mPPhen2P represented by Structural Formula (201) below, or the like.

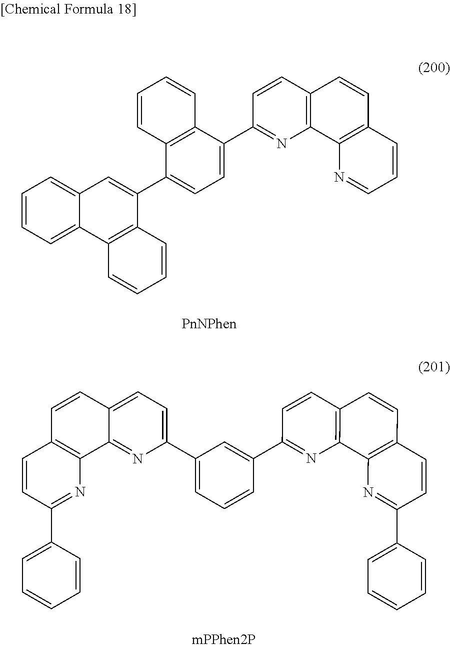 [SMILES: c1ccc2c(c1)cc(-c1ccc(-c3ccc4ccc5cccnc5c4n3)c3ccccc13)c1ccccc12 ; c1ccc(-c2ccc3ccc4ccc(-c5cccc(-c6ccc7ccc8ccc(-c9ccccc9)nc8c7n6)c5)nc4c3n2)cc1]

In the light-emitting device of one embodiment of the present invention, the intermediate layer can have any structure as long as it includes the organic compound having a phenanthroline skeleton and can inject electrons and holes respectively into the light-emitting unit on the anode side and the light-emitting unit on the cathode side, which are in contact with the intermediate layer, by voltage application between the first electrode and the second electrode. Note that the intermediate layer 160 preferably has a stacked-layer structure of a first layer 161 including an organic compound and a second layer 162 positioned closer to the cathode than the first layer is, as illustrated in FIG. 1A.

The first layer preferably includes a metal or a metal compound in addition to the organic compound. The metal or a metal of the metal compound is preferably an alkali metal (Group 1 element) such as Li, an alkaline earth metal (Group 2 element) such as Mg or Ca, a Group 3 element including Y and lanthanoids such as Eu and Yb, a Group 11 element such as Cu, Ag, or Au, a Group 12 element such as Zn, or an earth metal (Group 13 element) such as Al or In.

The first layer may have a stacked-layer structure of a layer including an organic compound and a layer that includes a metal or a metal compound and is positioned closer to the cathode than the layer including an organic compound is. Alternatively, the first layer may be a mixed layer of an organic compound and a metal or a metal compound. The first layer is preferably the mixed layer, in which case it requires a smaller number of film formation chambers and a lower manufacturing cost and contributes to an improvement in the stability of the light-emitting device.

In the case where the organic compound and the metal or the metal compound are mixed, the organic compound and the metal or the metal compound tend to show substantially the same distribution when the first layer is analyzed in the thickness direction. That is, when the organic compound is uniformly distributed, the metal or the metal compound is also substantially uniformly distributed. In the case of the stacked-layer structure of the layer including the organic compound and the layer including the metal or the metal compound, the metal or the metal compound is sometimes diffused from the layer including the metal or the metal compound and detected also in a region other than the layer but shows a distribution different from that of the organic compound; thus, the analysis results of diffusion and mixing can be distinguished from each other.

In the case where the metal or the metal compound is detected over a region having a thickness greater than or equal to 10 nm, preferably greater than or equal to 15 nm, further preferably greater than or equal to 20 nm when the first layer is analyzed in the thickness direction, the first layer can be regarded as including a mixed layer in which the organic compound and the metal or the metal compound are mixed.

The metal or a metal of the metal compound is preferably, among others, a substance exhibiting a donor property with respect to the organic compound having a phenanthroline skeleton. Examples of the substance exhibiting a donor property with respect to the organic compound having a phenanthroline skeleton include metals belonging to Groups 1 and 2; lithium or a lithium compound is particularly preferable. Specifically, Li, lithium fluoride (LiF), lithium oxide (Li₂O), 8-quinolinolato-lithium (abbreviation: Liq), or the like is preferable. In the case where the first layer includes the organic compound having a phenanthroline skeleton and the substance exhibiting a donor property with respect to the organic compound having a phenanthroline skeleton, electrons are generated by charge separation, and the electrons are injected into the light-emitting unit on the anode side through the organic compound having a phenanthroline skeleton when voltage is applied between the first and second electrodes. Thus, the light-emitting device of one embodiment of the present invention can have a low driving voltage.

The organic compound having a phenanthroline skeleton is preferably an organic compound having a phenanthroline skeleton having an electron-donating substituent, as well as the above-described organic compound. The phenanthroline skeleton is likely to interact with the metal or the like, and when the organic compound having such a phenanthroline skeleton further has an electron-donating group, the phenanthroline skeleton can have a higher electron density and become more likely to interact with the metal or the metal compound. In particular, the use of a metal belonging to Group 3, 11, 12, or 13 as the metal or a metal of the metal compound makes it possible to provide a tandem light-emitting device which is inhibited from having an increase in driving voltage and which has favorable characteristics.

Specific examples of the electron-donating group include an alkyl group, an alkoxy group, an aryloxy group, an alkylamino group, an arylamino group, and a heterocyclic amino group. Note that examples of the electron-donating group that is preferably introduced to the phenanthroline ring are not limited to the above examples. The electron-donating group may be any group that can increase the electron density of the phenanthroline ring by being introduced to the phenanthroline ring. The electron-donating group may be introduced to the phenanthroline ring via an arylene group such as a phenylene group, and the arylene group is preferably a p-phenylene group.

Specific examples of the organic compound having a phenanthroline skeleton having an electron-donating substituent are shown in Structural Formulae (203) to (213).

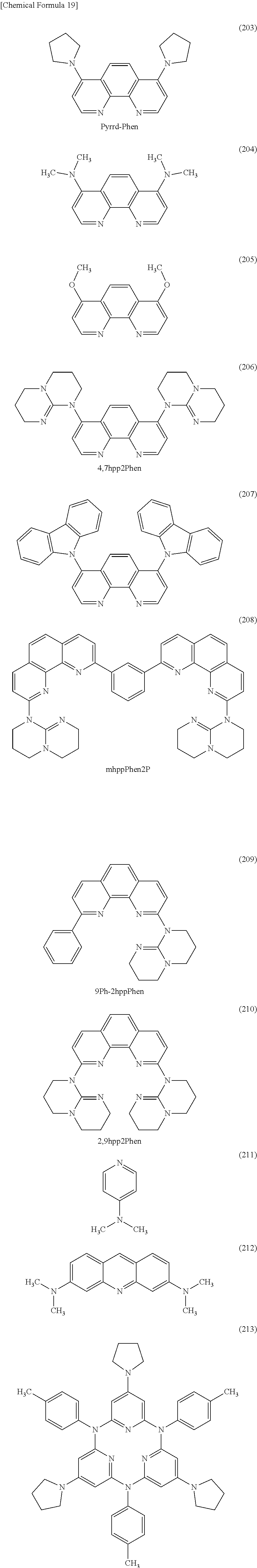

Note that the first layer preferably includes a Group 1 or Group 2 element, especially lithium or a lithium compound, and the organic compound having a phenanthroline skeleton having an electron-donating substituent, in which case the tandem light-emitting device can have a lower driving voltage and higher reliability. Moreover, the first layer preferably includes a Group 1 or Group 2 element, especially lithium or a lithium compound, and the organic compound having a phenanthroline skeleton having an electron-donating substituent, in which case it is possible to inhibit an increase in driving voltage due to processing of an organic compound layer of the light-emitting device by a photolithography method.

Among organic compounds having a phenanthroline skeleton, an organic compound having a 1,10-phenanthroline skeleton, the two nitrogen atoms of which can be coordinated to a metal, is particularly preferably used as the organic compound having a phenanthroline skeleton in the intermediate layer having the above-described structure to facilitate interaction with the metal or the metal compound.

In the case where an electron-donating group is introduced to a 1,10-phenanthroline skeleton, the electron-donating group is preferably substituted at the 4- and 7-positions of the 1,10-phenanthroline skeleton. Introducing electron-donating groups to the 4- and 7-positions of the 1,10-phenanthroline skeleton can increase the electron density of the nitrogen atoms at the 1- and 10-positions, thereby facilitating the interaction with the metal or the metal compound.

The first layer may further include a different organic compound other than the organic compound having a phenanthroline skeleton. The different organic compound preferably has an electron-transport property and particularly preferably includes two or more heteroaromatic rings bonded or fused to each other. The two or more heteroaromatic rings preferably have three or more heteroatoms in total. The first layer including such an organic compound can improve the heat resistance, the electron-transport property, and the like.

The second layer 162 preferably includes a hole-transport organic compound. The second layer 162 preferably further includes a substance exhibiting an acceptor property, and the substance exhibiting an acceptor property is preferably an organic compound exhibiting an acceptor property with respect to the hole-transport organic compound. The substance exhibiting an acceptor property is particularly preferably an organic compound having at least one of a halogen group and a cyano group, further preferably an organic compound having at least one of fluorine and a cyano group. Note that it is further preferable that the total number of halogen groups (fluorines) and cyano groups of the organic compound be four or more.

In the case where the second layer 162 includes the hole-transport organic compound and the substance exhibiting an acceptor property with respect to the hole-transport organic compound, holes are generated by charge separation, and the holes are injected into the light-emitting unit on the cathode side through the hole-transport organic compound when voltage is applied between the first and second electrodes. Thus, the light-emitting device of one embodiment of the present invention can have a low driving voltage.

The intermediate layer may include a third layer 163 between the first layer 161 and the second layer 162.

The third layer includes an electron-transport substance and has functions of smoothly transferring and receiving electrons between the first layer 161 and the second layer 162 to reduce the driving voltage, and reducing the interaction between the first layer 161 and the second layer 162 to improve the reliability, for example.

The thickness of the third layer 163 is preferably greater than or equal to 1 nm and less than or equal to 10 nm, further preferably greater than or equal to 2 nm and less than or equal to 5 nm, in which case an increase in driving voltage can be inhibited.

The light-emitting device of one embodiment of the present invention that has the above structure can have high current efficiency, low energy loss, and favorable characteristics. A display device of one embodiment of the present invention that includes such a light-emitting device can achieve low power consumption, high reliability, high-luminance display, and high visibility.

In the tandem light-emitting device of one embodiment of the present invention, each of the first hole-transport layer 112_1 and the second hole-transport layer 112_2 preferably includes an organic compound having an amine skeleton and a polycyclic hydrocarbon, further preferably an organic compound having an amine skeleton and a polycyclic aromatic hydrocarbon, still further preferably an organic compound having an amine skeleton and a fluorene skeleton. The organic compound having an amine skeleton and a fluorene skeleton has high reliability and a high hole-transport property. The use of the organic compound can reduce the power consumption of the tandem light-emitting device.

Each of the first hole-transport layer 112_1 and the second hole-transport layer 112_2 may have a stacked-layer structure. Specifically, the hole-transport layer in contact with the first light-emitting layer 113_1 or the second light-emitting layer 113_2 includes a material whose hole-transport property is excellent, electron-transport property is low, and lowest unoccupied molecular orbital (LUMO) level is high. In particular, it is preferable to use a material whose LUMO level is higher than the LUMO level of a material included in the light-emitting layer (at least the host material, preferably a host material having an electron-transport property, the material having the highest constituent ratio among the materials included in the light-emitting layer, or the material having the highest LUMO level among the materials included in the light-emitting layer), further preferably higher by 0.30 eV or more, still further preferably higher by 0.5 eV or more. An organic compound having a π-electron rich polycyclic heteroaromatic ring, particularly an organic compound having a carbazole skeleton or a bicarbazole skeleton, has high stability and high reliability and is suitable for the first hole-transport layer 112_1 and the second hole-transport layer 112_2.

When the first hole-transport layer 112_1 has a stacked-layer structure and the layer in contact with the first light-emitting layer 113_1 includes a material whose LUMO level is higher than that of the material included in the light-emitting layer, electrons can be prevented from passing the first light-emitting layer 113_1 to the first electrode 101 side. Similarly, when the second hole-transport layer 112_2 has a stacked-layer structure and the layer in contact with the second light-emitting layer 113_2 includes a material whose LUMO level is higher than that of the material included in the light-emitting layer, electrons can be prevented from passing the second light-emitting layer 113_2 to the intermediate layer 160, which enables manufacturing a display device with high efficiency and a long lifetime.

In the case where a phosphorescent substance that emits red or green light is used for the light-emitting layer, the T₁ level of the organic compound used for each of the first hole-transport layer 112_1 and the second hole-transport layer 112_2 is preferably higher than the T₁ level of the phosphorescent substance. This structure applies particularly to the layer in contact with the light-emitting layer among the layers in the above hole-transport layer, thereby preventing excitation energy of excitons, which are generated by recombination of carriers in the light-emitting layer, from diffusing into the layer in contact with the light-emitting layer; consequently, the light-emitting device can have high emission efficiency. Meanwhile, in the case where a phosphorescent substance that emits blue light is used for the light-emitting layer, an organic compound having a lower T₁ level than the phosphorescent substance is used for the layer in contact with the light-emitting layer, whereby the light-emitting device can be highly stable and highly reliable. When the T₁ level of the phosphorescent substance is lower than that of the organic compound used for one of the layers in contact with the light-emitting layer which are respectively on the anode side and the cathode side and is higher than that of the organic compound used for the other of the layers, the light-emitting device can have high emission efficiency, high stability, and high reliability. However, a significantly low T₁ level of the organic compound used for the layer in contact with the light-emitting layer is likely to decrease the emission efficiency. The energy difference between the T₁ levels of the phosphorescent substance and each of the organic compounds used for the layers in contact with the light-emitting layer is therefore greater than or equal to 0.1 eV, preferably greater than or equal to 0.2 eV, and less than or equal to 1.0 eV, preferably less than or equal to 0.5 eV, which avoids a reduction in emission efficiency and makes the light-emitting device highly stable and highly reliable.

As described above, the first hole-transport layer 112_1 and the second hole-transport layer 112_2 include different polycyclic aromatic rings and each have a stacked-layer structure in which organic compounds are combined so that first hole-transport layer 112_1 and the second hole-transport layer 112_2 have different properties; accordingly, the degree of freedom in design of the display device can be increased.

Specifically, as the organic compound that can be used for the first hole-transport layer 112_1 and the second hole-transport layer 112_2, an organic compound having one or both of an aromatic amine skeleton and a π-electron rich heteroaromatic ring is preferably used. Examples of aromatic rings included in the organic compound having an aromatic amine skeleton include a monocyclic aromatic ring and a polycyclic aromatic ring. These aromatic rings may have an alkyl group as a substituent.

Examples of the monocyclic aromatic ring include aromatic hydrocarbon rings such as a benzene ring and heteroaromatic rings such as a pyrrole ring and a furan ring. Having the aromatic ring as a substituent has the effect of improving heat resistance and increasing a glass transition temperature (T_{g}). Having the aromatic ring as a substituent also has the effect of adjusting the transport property of carriers such as holes or electrons, for example. Furthermore, having a plurality of such monocyclic aromatic rings can further improve T_{g}; a biphenyl structure or a terphenyl structure is preferably used, for example. A paraphenylene structure, a metaphenylene structure, or an orthophenylene structure may be used. When at least one of a metaphenylene structure and an orthophenylene structure is used, the solubility of a compound can be improved to facilitate manufacturing the compound and a reduction in refractive index can also be achieved. When a terphenyl structure or the like having three or more benzene rings is used, it is preferable to use an aromatic ring having at least two selected from a paraphenylene structure, a metaphenylene structure, and an orthophenylene structure, which enables adjustment of the solubility, the refractive index, and the carrier-transport property.

Note that a benzene ring used as a linking group is generally referred to as a phenylene group but sometimes referred to as a phenyl group to avoid complexity of description. Similarly, another aromatic ring used as a linking group is sometimes referred to as an aryl group instead of an arylene group, and another aromatic ring used as a linking group is sometimes referred to as a heteroaryl group instead of a heteroarylene group. Furthermore, a benzene ring is sometimes rephrased as a benzene structure or a benzene skeleton; the same applies to other substituents (e.g., aromatic rings).

Examples of the polycyclic aromatic ring include aromatic hydrocarbon rings such as a naphthalene ring, a phenanthrene ring, a chrysene ring, a triphenylene ring, a fluorene ring, and a spirobifluorene ring and heteroaromatic rings such as a carbazole ring, a dibenzofuran ring, a dibenzothiophene ring, and a xanthene ring. A compound having the polycyclic aromatic ring as a substituent can improve heat resistance more than a compound having the monocyclic aromatic ring and is thus preferable. A plurality of polycyclic aromatic rings are preferably included. The plurality of polycyclic aromatic rings included may be the same as or different from each other. In the case of the same rings, a structure including a plurality of aromatic hydrocarbon rings, a structure including a plurality of heteroaromatic rings, a structure including one or more aromatic hydrocarbon rings and one or more heteroaromatic rings, or the like can be given. In the case of the same aromatic rings, a reduction in raw material cost and simplification of the synthesis process can be expected. In the case of using different aromatic rings, the transport property of carriers such as holes or electrons can be adjusted or T_{g} can be adjusted depending on the kinds of the aromatic rings used. Examples of the case of using a plurality of polycyclic aromatic rings include a structure including a carbazole ring and a dibenzofuran ring, a structure including two, three, or four or more carbazole rings, and a structure including two, three, or four or more fluorene rings.

A compound having as a substituent a ring in which an aromatic ring (e.g., the above-described monocyclic aromatic ring) is further fused to any of the above polycyclic aromatic rings can further improve heat resistance. Examples of the ring in which an aromatic ring is further fused to the polycyclic aromatic ring include a benzofluorene ring, a benzonaphthofuran ring, a benzoxanthene ring, and a benzonaphthothiophene ring.

As the substituent, the monocyclic aromatic ring and the polycyclic aromatic ring can be used. For example, a structure in which a monocyclic aromatic ring is used as a linking group between nitrogen in an amine skeleton and the polycyclic aromatic ring can be given. Other examples include a structure in which a phenylene group is used between nitrogen and a fluorene ring, a structure in which a phenylene group is used between nitrogen and a carbazole ring, and a structure in which a phenylene group is used between nitrogen and a dibenzofluorene ring. A structure in which a plurality of polycyclic aromatic rings are bonded to one phenylene group used as a linking group is also effective. The plurality of polycyclic aromatic rings may be the same or different aromatic rings. For example, a compound in which both a carbazole ring and a dibenzofluorene ring are bonded to one phenylene group can have improved T_{g} as well as both functions of the carbazole ring and the dibenzofluorene ring.

Examples of the alkyl group include a methyl group, an ethyl group, a propyl group, a tertiary butyl group, a cyclohexyl group, and an adamantyl group. A layer including a compound having the alkyl group as a substituent can have a low refractive index. This can inhibit total reflection at the interface between the layer and another layer and improve the light extraction efficiency of the light-emitting device including the layer. When such a compound having an alkyl group is used also for the hole-transport layer, the refractive index of the hole-transport layer can be lowered. In particular, when a compound having an aromatic amine skeleton and an alkyl group is used for the hole-transport layer, the effect of improving the light extraction efficiency can be synergistically enhanced. A compound having an alkyl group having a plurality of carbon atoms, preferably three or more carbon atoms, further preferably four or more carbon atoms, still further preferably five or more carbon atoms, can enhance the effect of lowering the refractive index. Moreover, the case where a plurality of alkyl groups are bonded to one aromatic ring is preferable because the refractive index can be further reduced. In that case, the plurality of alkyl groups may be the same as or different from each other. For example, two or three tertiary butyl groups are preferably bonded to one benzene ring. In the case where a plurality of aromatic rings are included, bonding alkyl groups to two or more aromatic rings enables a reduction in refractive index. In addition, including alkyl groups in some of a plurality of aromatic rings enables adjustment of the refractive index. An example is a structure in which two out of three aromatic rings each include an alkyl group and the remaining one aromatic ring includes no alkyl group.

Structural Formulae (300) to (330) represent examples of the organic compound having an aromatic amine skeleton. Specifically, the following organic compounds are preferable: BBASF (4) represented by Structural Formula (300); oBBASF represented by Structural Formula (301); BBAFLP (4) represented by Structural Formula (302); oFBiSF (2) represented by Structural Formula (303); FBiSF (4) represented by Structural Formula (304); oFBiSF represented by Structural Formula (305); FBimFLP represented by Structural Formula (306); FBimMemFLP represented by Structural Formula (307); SF (4) FAF represented by Structural Formula (308); FrBBiFLP represented by Structural Formula (309); tBu-oFBiSF (2) represented by Structural Formula (310); FBiFLPB represented by Structural Formula (311); DBfBBFLP (2) represented by Structural Formula (312); FLP20BP represented by Structural Formula (313); PCAFLP (2)-02 represented by Structural Formula (314); tBu2FoFBi represented by Structural Formula (315); oFrTPPnox represented by Structural Formula (316); mPDBfBNBN represented by Structural Formula (317); BBAaBnf (7) represented by Structural Formula (318); DBfBB1TP represented by Structural Formula (319); BOx3Am represented by Structural Formula (320); BBA2BP represented by Structural Formula (321); PCBBi1BP represented by Structural Formula (322); YGBBi1BP-02 represented by Structural Formula (323); YGBBi1BP represented by Structural Formula (324); PCBBi1TP represented by Structural Formula (325); YGBBiPDBf represented by Structural Formula (326); BPPCA represented by Structural Formula (327); PCBBiF represented by Structural Formula (328); DBf-YGBBi1BP represented by Structural Formula (329); and YGTPDBfB represented by Structural Formula (330).

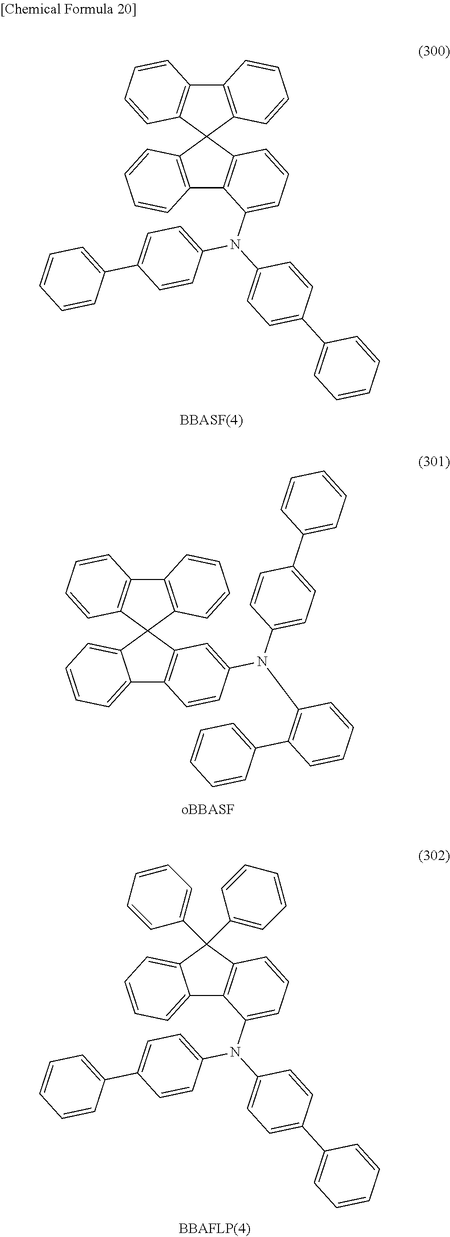 [SMILES: c1ccc(-c2ccc(N(c3ccc(-c4ccccc4)cc3)c3cccc4c3-c3ccccc3C43c4ccccc4-c4ccccc43)cc2)cc1 ; c1ccc(-c2ccc(N(c3ccc4c(c3)C3(c5ccccc5-c5ccccc53)c3ccccc3-4)c3ccccc3-c3ccccc3)cc2)cc1 ; c1ccc(-c2ccc(N(c3ccc(-c4ccccc4)cc3)c3cccc4c3-c3ccccc3C4(c3ccccc3)c3ccccc3)cc2)cc1]

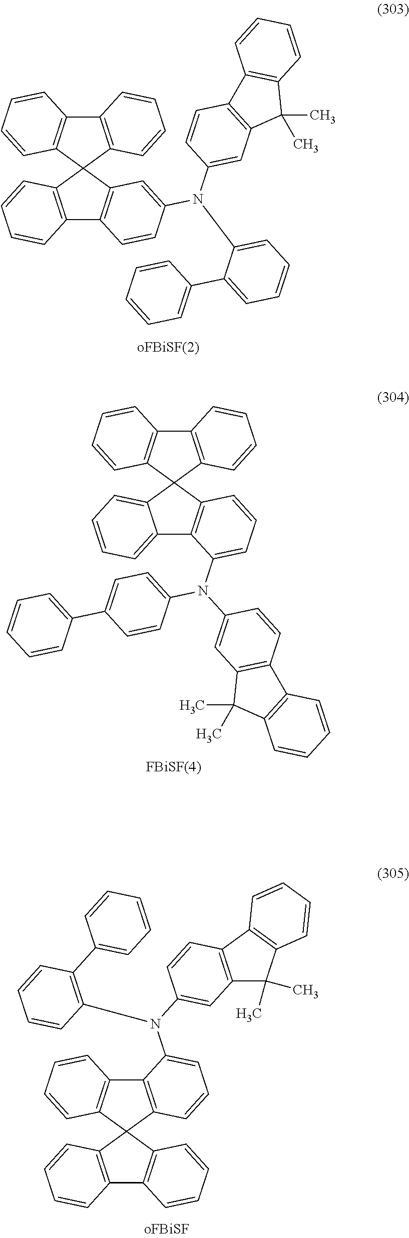 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc(-c4ccccc4)cc3)c3cccc4c3-c3ccccc3C43c4ccccc4-c4ccccc43)cc21 ; CC1(C)c2ccccc2-c2ccc(N(c3ccccc3-c3ccccc3)c3cccc4c3-c3ccccc3C43c4ccccc4-c4ccccc43)cc21]

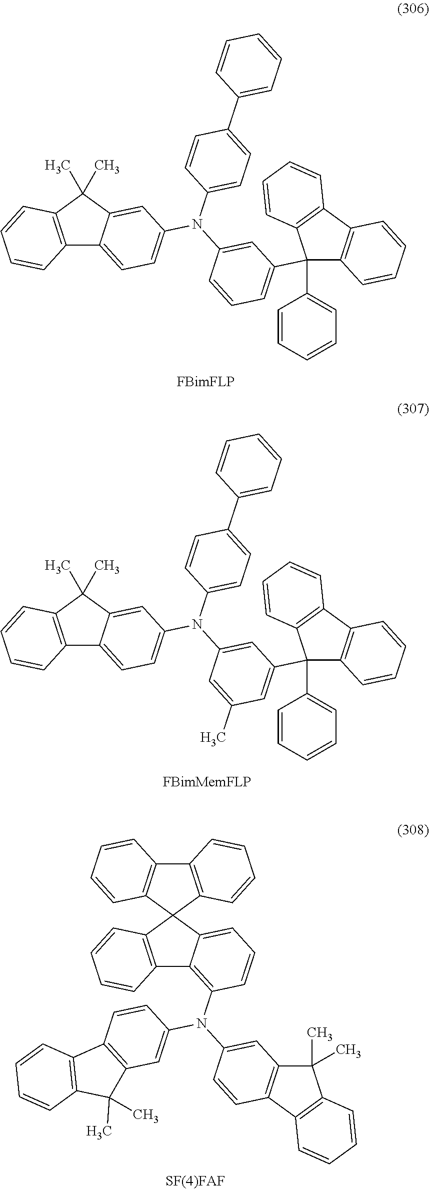 [SMILES: CC1(C)c2ccccc2-c2ccc(N(c3ccc(-c4ccccc4)cc3)c3cccc(C4(c5ccccc5)c5ccccc5-c5ccccc54)c3)cc21 ; Cc1cc(N(c2ccc(-c3ccccc3)cc2)c2ccc3c(c2)C(C)(C)c2ccccc2-3)cc(C2(c3ccccc3)c3ccccc3-c3ccccc32)c1 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21]

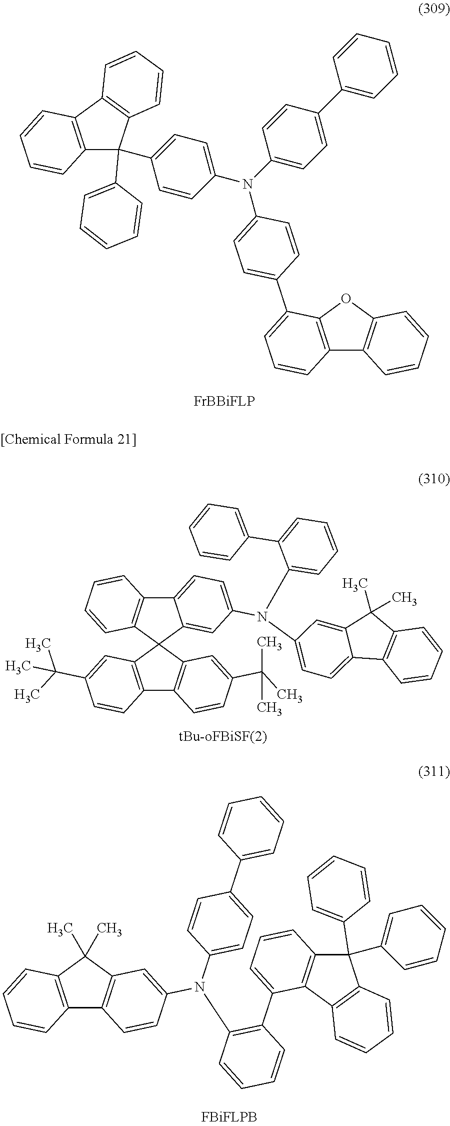 [SMILES: c1ccc(-c2ccc(N(c3ccc(-c4cccc5c4oc4ccccc45)cc3)c3ccc(C4(c5ccccc5)c5ccccc5-c5ccccc54)cc3)cc2)cc1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC1(C)c2ccccc2-c2ccc(N(c3ccc(-c4ccccc4)cc3)c3ccccc3-c3cccc4c3-c3ccccc3C4(c3ccccc3)c3ccccc3)cc21]

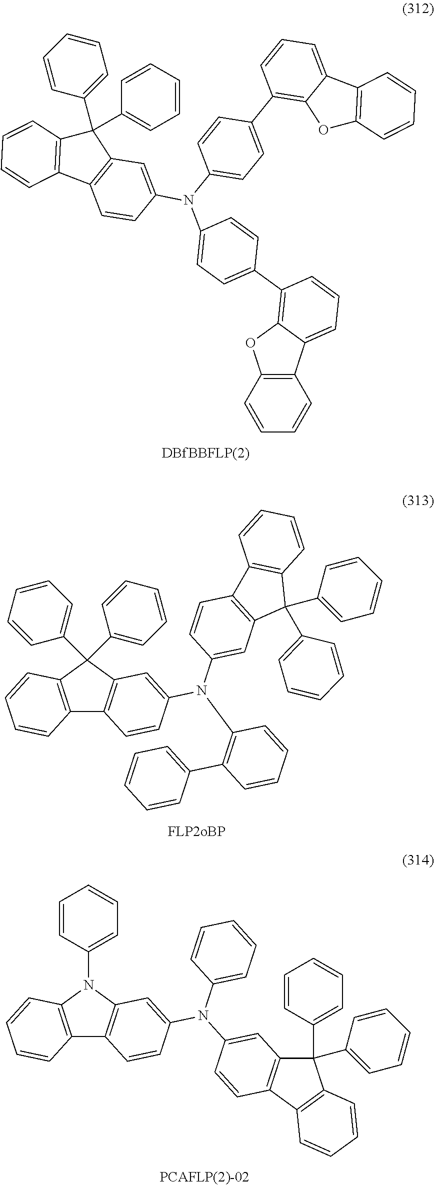 [SMILES: c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(N(c2ccc3c(c2)C(c2ccccc2)(c2ccccc2)c2ccccc2-3)c2ccc3c4ccccc4n(-c4ccccc4)c3c2)cc1]

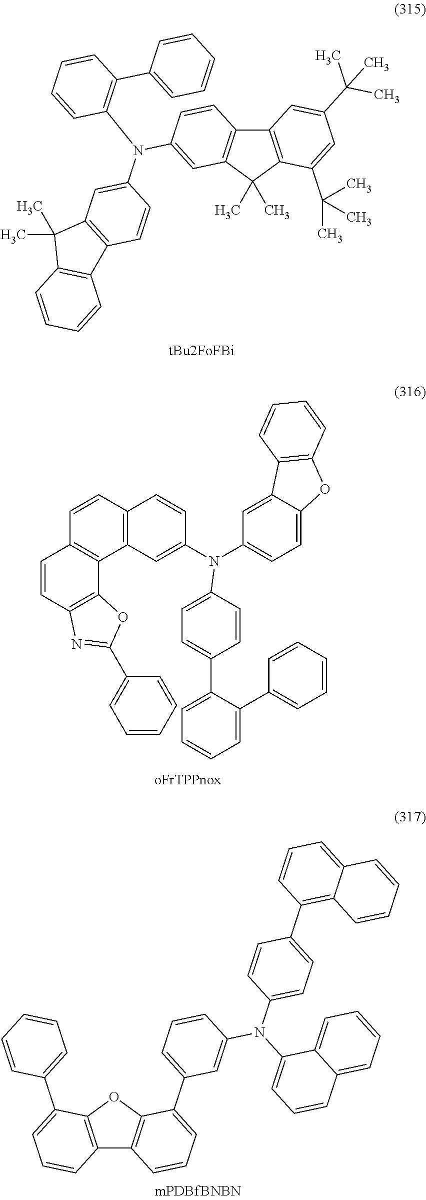 [SMILES: CC(C)(C)c1cc2c(c(C(C)(C)C)c1)C(C)(C)c1cc(N(c3ccc4c(c3)C(C)(C)c3ccccc3-4)c3ccccc3-c3ccccc3)ccc1-2 ; c1ccc(-c2nc3ccc4ccc5ccc(N(c6ccc(-c7ccccc7-c7ccccc7)cc6)c6ccc7oc8ccccc8c7c6)cc5c4c3o2)cc1 ; c1ccc(-c2cccc3c2oc2c(-c4cccc(N(c5ccc(-c6cccc7ccccc67)cc5)c5cccc6ccccc56)c4)cccc23)cc1]

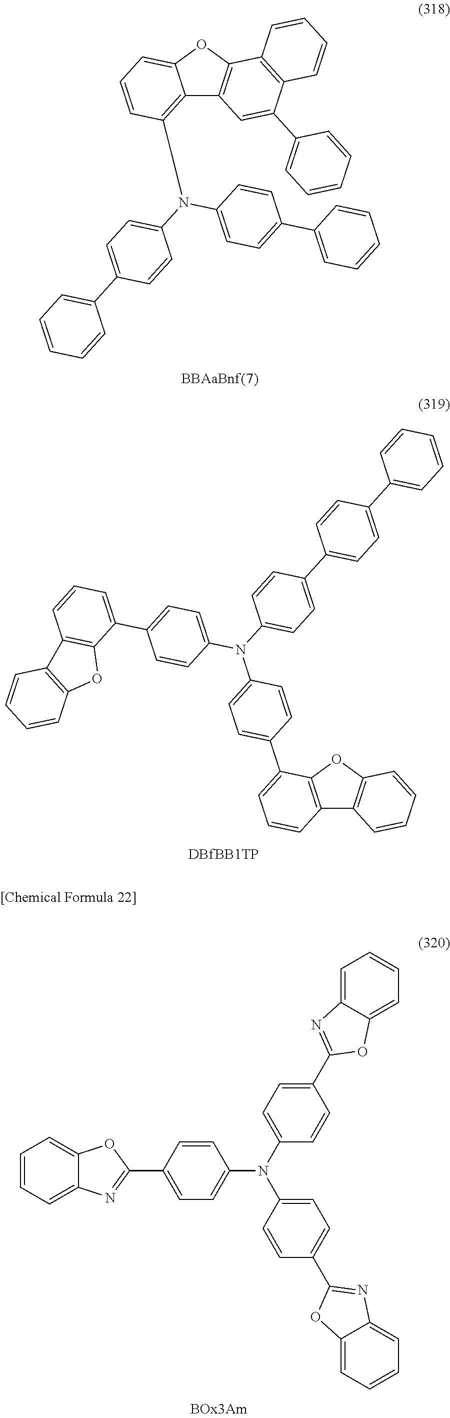 [SMILES: c1ccc(-c2ccc(N(c3ccc(-c4ccccc4)cc3)c3cccc4oc5c6ccccc6c(-c6ccccc6)cc5c34)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc2oc(-c3ccc(N(c4ccc(-c5nc6ccccc6o5)cc4)c4ccc(-c5nc6ccccc6o5)cc4)cc3)nc2c1]

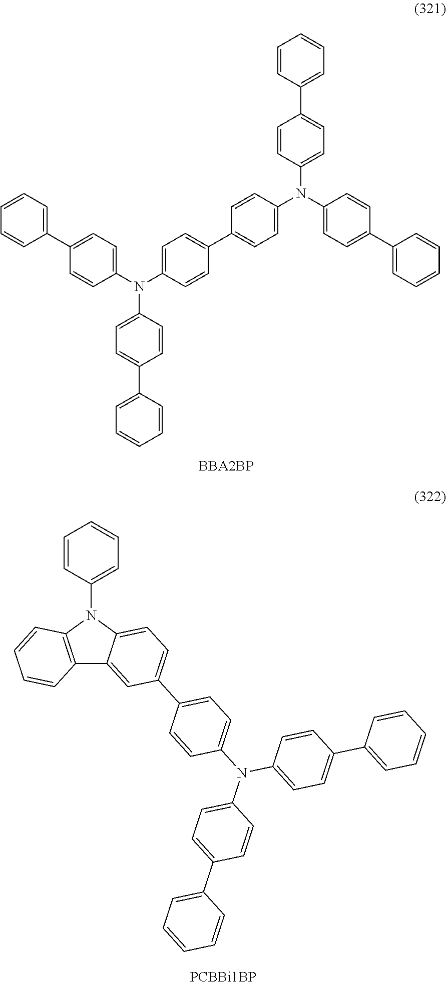

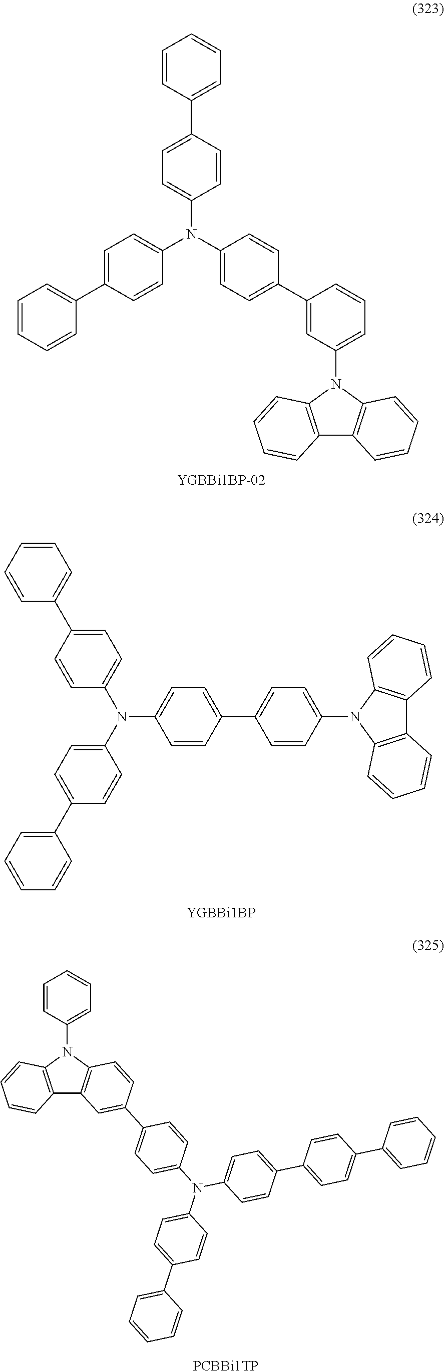

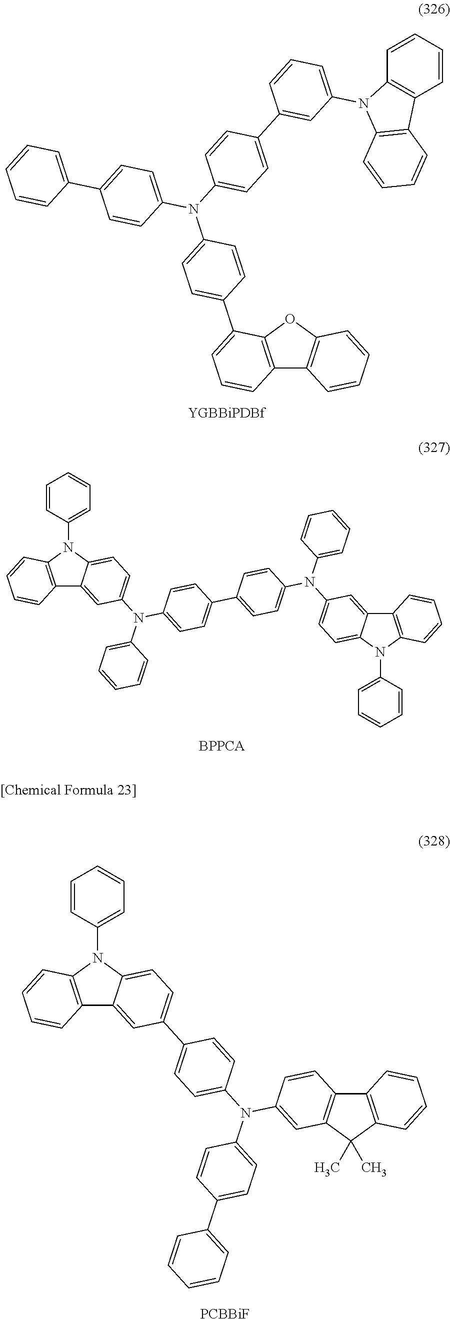

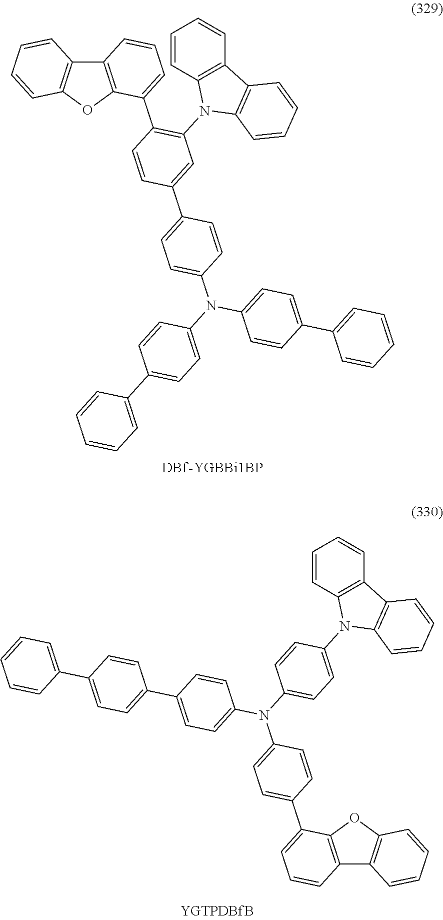 [SMILES: c1ccc(-c2ccc(N(c3ccc(-c4ccccc4)cc3)c3ccc(-c4ccc(-c5cccc6c5oc5ccccc56)c(-n5c6ccccc6c6ccccc65)c4)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

Among the organic compounds represented by Structural Formulae (300) to (330), for example, an organic compound having an amine skeleton and a polycyclic heteroaromatic ring is preferably used for the first hole-transport layer 112_1 and the second hole-transport layer 112_2.

An organic compound having no amine skeleton and a π-electron rich polycyclic heteroaromatic ring is preferably used for the layer that is included in the first hole-transport layer 112_1 or the second hole-transport layer 112_2 and in contact with the light-emitting layer. Specific examples of the organic compound used for the layer that is included in the first hole-transport layer 112_1 or the second hole-transport layer 112_2 and in contact with the light-emitting layer include 9-[3-(triphenylsilyl)phenyl]-3,9′-bi-9H-carbazole (abbreviation: PSiCzCz) represented by Structural Formula (350), 9′-[3-(triphenylsilyl)phenyl]-9′H-9,3′:6′,9″-tercarbazole (abbreviation: PSiCzGI) represented by Structural Formula (351), 9,9″-(1,3-phenylene)bis(3,9′-bi-9H-carbazole) (abbreviation: mCzCz2P) represented by Structural Formula (352), 1,3-bis(N-carbazolyl)benzene (abbreviation: mCP) represented by Structural Formula (353), 9,9″-[3,3′-(diphenylsilyl)diphenyl]bis(3,9′-bi-9H-carbazole) (abbreviation: mCzCz2PSi) represented by Structural Formula (354), 3,3′-9H-carbazol-9-yl-biphenyl (abbreviation: mCBP) represented by Structural Formula (359), 9′-phenyl-9′H-9,3′:6′,9″-tercarbazole (abbreviation: PhCzGI) represented by Structural Formula (360), 12-[3-(9H-carbazol-9-yl)phenyl]-5,12-dihydro-5-phenyl-indolo[3,2-a]carbazole (abbreviation: mCzPICz) represented by Structural Formula (361), 5,12-bis[3-(9H-carbazol-9-yl)phenyl]-5,12-dihydro-indolo[3,2-a]carbazole (abbreviation: mCzP2ICz) represented by Structural Formula (362), 5-[3-(9H-carbazol-9-yl)phenyl]-5,12-dihydro-12-phenyl-indolo[3,2-a]carbazole (abbreviation: mCzPICz-02) represented by Structural Formula (363), 12,12′-(1,4-phenylene)bis(5,12-dihydro-5-phenyl-indolo[3,2-a]carbazole) (abbreviation: ICz2P) represented by Structural Formula (364), 12,12′-(1,3-phenylene)bis(5,12-dihydro-5-phenyl-indolo[3,2-a]carbazole) (abbreviation: mICz2P) represented by Structural Formula (365), and 5,5′-(1,3-phenylene)bis(5,12-dihydro-12-phenyl-indolo[3,2-a]carbazole) (abbreviation: mICz2P-02) represented by Structural Formula (366). Other examples include organic compounds represented by Structural Formulae (355) to (358). The organic compound represented by any of Structural Formulae (350) to (366) can be used for the layer that is included in the first hole-transport layer 112_1 or the second hole-transport layer 112_2 and in contact with the light-emitting layer in the case of a blue-light-emitting device, for example. The organic compound represented by any of Structural Formulae (350) to (366) can be used as the host material of the light-emitting layer of a blue-light-emitting device, for example.

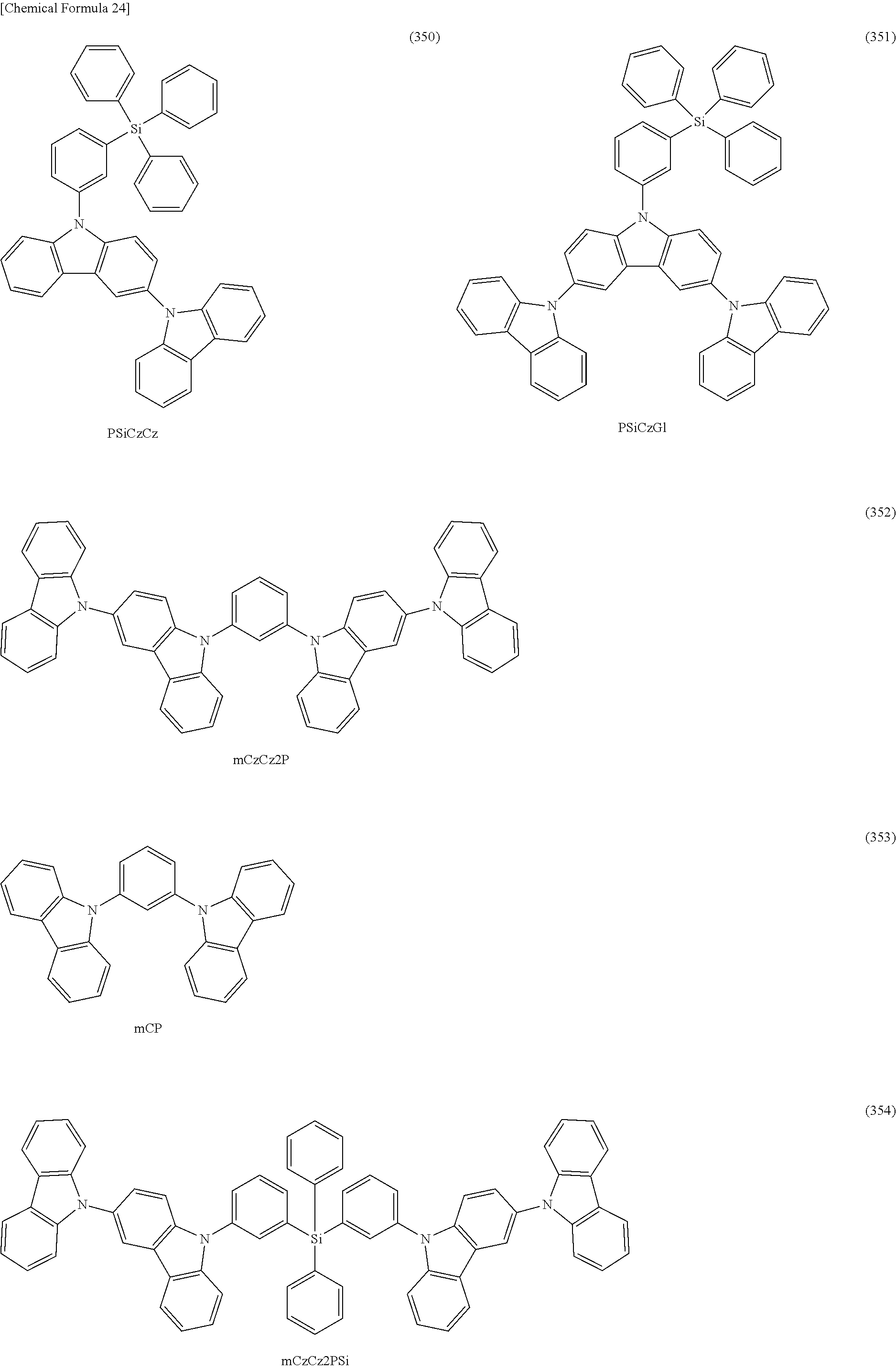 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-n3c4ccc(-n5c6ccccc6c6ccccc65)cc4c4cc(-n5c6ccccc6c6ccccc65)ccc43)c2)cc1 ; c1cc(-n2c3ccccc3c3cc(-n4c5ccccc5c5ccccc54)ccc32)cc(-n2c3ccccc3c3cc(-n4c5ccccc5c5ccccc54)ccc32)c1 ; c1cc(-n2c3ccccc3c3ccccc32)cc(-n2c3ccccc3c3ccccc32)c1 ; c1ccc([Si](c2ccccc2)(c2cccc(-n3c4ccccc4c4cc(-n5c6ccccc6c6ccccc65)ccc43)c2)c2cccc(-n3c4ccccc4c4cc(-n5c6ccccc6c6ccccc65)ccc43)c2)cc1]

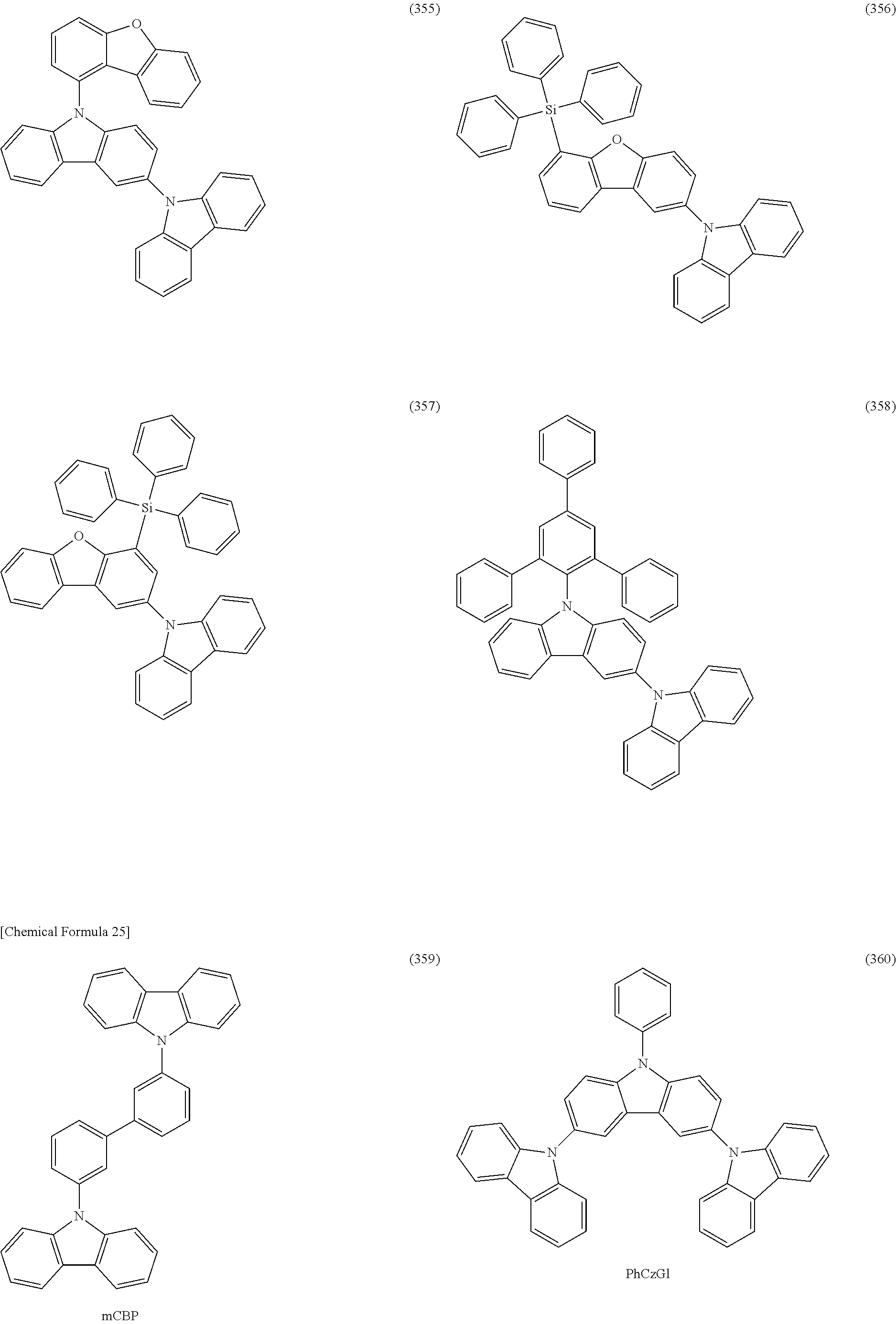 [SMILES: c1ccc2c(c1)oc1cccc(-n3c4ccccc4c4cc(-n5c6ccccc6c6ccccc65)ccc43)c12 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1 ; c1ccc(-c2cc(-c3ccccc3)c(-n3c4ccccc4c4cc(-n5c6ccccc6c6ccccc65)ccc43)c(-c3ccccc3)c2)cc1 ; c1cc(-c2cccc(-n3c4ccccc4c4ccccc43)c2)cc(-n2c3ccccc3c3ccccc32)c1 ; c1ccc(-n2c3ccc(-n4c5ccccc5c5ccccc54)cc3c3cc(-n4c5ccccc5c5ccccc54)ccc32)cc1]

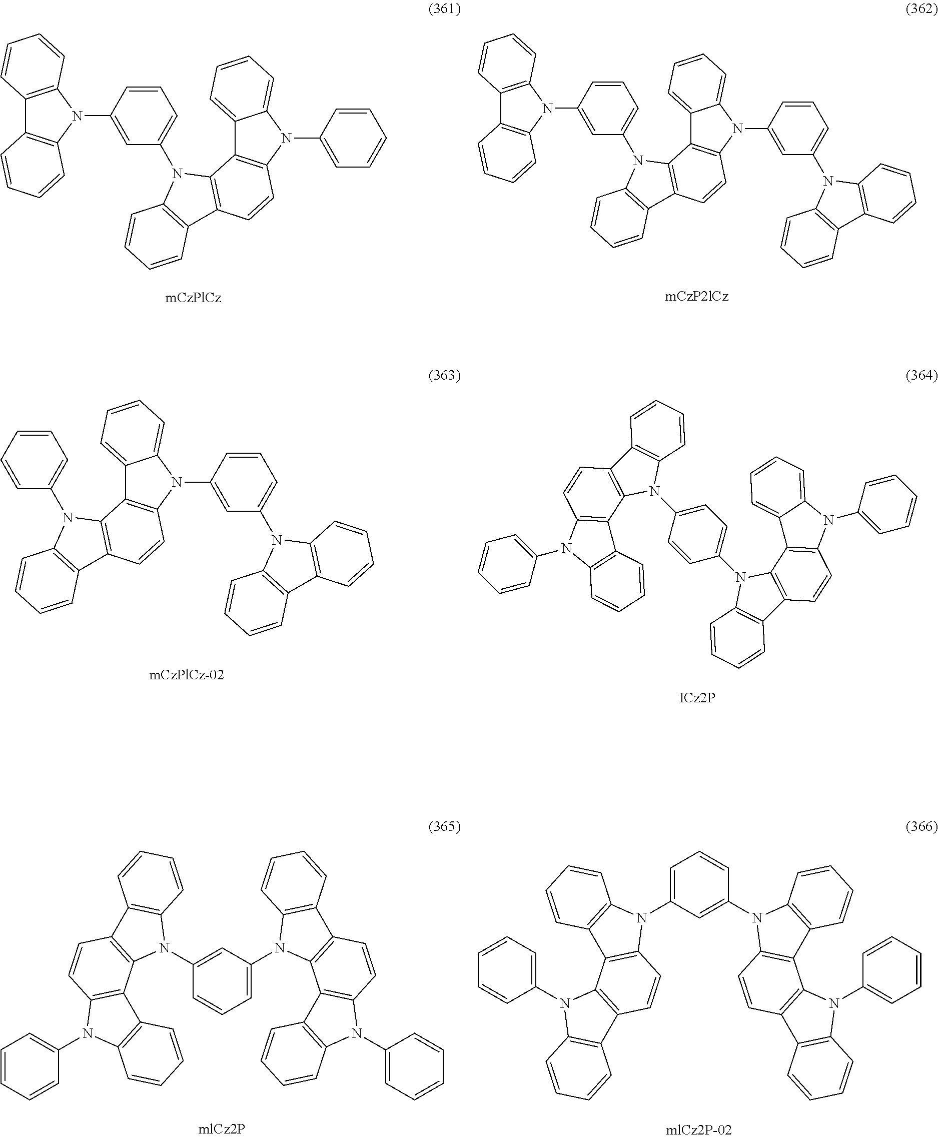

For the layer in contact with the light-emitting layer in the case where the first hole-transport layer 112_1 and the second hole-transport layer 112_2 each have a stacked-layer structure, an organic compound having a higher LUMO level and a higher T₁ level than a material included in the light-emitting layer (at least the host material, preferably a material included in the light-emitting layer) is preferably selected and used as appropriate. Specifically, an organic compound having a π-electron rich heteroaromatic ring or a polycyclic heteroaromatic ring can be used. A carbazole skeleton is given as a specific example of a π-electron rich heteroaromatic ring or a polycyclic heteroaromatic ring. A carbazole skeleton is preferable because of its high stability and high reliability. An organic compound having two or more carbazole skeletons can be further preferably used. A bicarbazole skeleton is preferable because of its high stability and high reliability. In particular, a bicarbazole skeleton in which any of the 2- to 4-positions of a carbazolyl group is bonded to any of the 2- to 4-positions of the other carbazolyl group is preferable because of its high donor property. Examples of such a bicarbazole skeleton include a 2,2′-bi-9H-carbazole skeleton, a 3,3′-bi-9H-carbazole skeleton, a 4,4′-bi-9H-carbazole skeleton, a 2,3′-bi-9H-carbazole skeleton, a 2,4′-bi-9H-carbazole skeleton, and a 3,4′-bi-9H-carbazole skeleton. Moreover, a bicarbazole skeleton in which any of the 2- to 4-positions of a carbazolyl group is bonded to the 9-position of the other carbazolyl group is suitable for a blue-light-emitting device because of its high excitation energy level due to a wide band gap. Examples of such a bicarbazole skeleton include a 2,9′-bi-9H-carbazole skeleton, a 3,9′-bi-9H-carbazole skeleton, and a 4,9′-bi-9H-carbazole skeleton. Specific examples include 9-[3-(triphenylsilyl)phenyl]-3,9′-bi-9H-carbazole (abbreviation: PSiCzCz), 9′-phenyl-9′H-9,3′:6′,9″-tercarbazole (abbreviation: PhCzGI), 12-[3-(9H-carbazol-9-yl)phenyl]-5,12-dihydro-5-phenyl-indolo[3,2-a]carbazole (abbreviation: mCzPICz), and 3,3′-bis(9-phenyl-9H-carbazole) (abbreviation: PCCP).

Here, in a plurality of layers (e.g., a hole-transport layer, an intermediate layer, a light-emitting layer, an electron-transport layer, and a cap layer) included in a light-emitting device, a compound in one layer and a compound in another layer may include the same aromatic rings (monocyclic aromatic rings or polycyclic aromatic rings) as substituents while the compounds are different from each other. Even when they are different compounds, including the same aromatic rings can lead to a reduction in raw material costs or synthesis steps in producing the compounds.

Examples of the aromatic ring that can be used for the different compounds include fused rings (also referred to as fused structures) such as a naphthalene ring, a fluorene ring, a benzofluorene ring, a triphenylene ring, a benzonaphthofuran ring, a xanthene ring, a benzoxanthene ring, a spirofluorenexanthene ring (also referred to as SFx), a spirobenzofluorenexanthene ring (also referred to as Sbfx), a carbazole ring, a benzocarbazole ring, a dibenzofuran ring, a dibenzothiophene ring, and a benzonaphthothiophene ring. The structural formulae of these structures are shown below. When any of the aromatic rings shown below has a substituent, one of the carbon or nitrogen atoms is a bonding site.

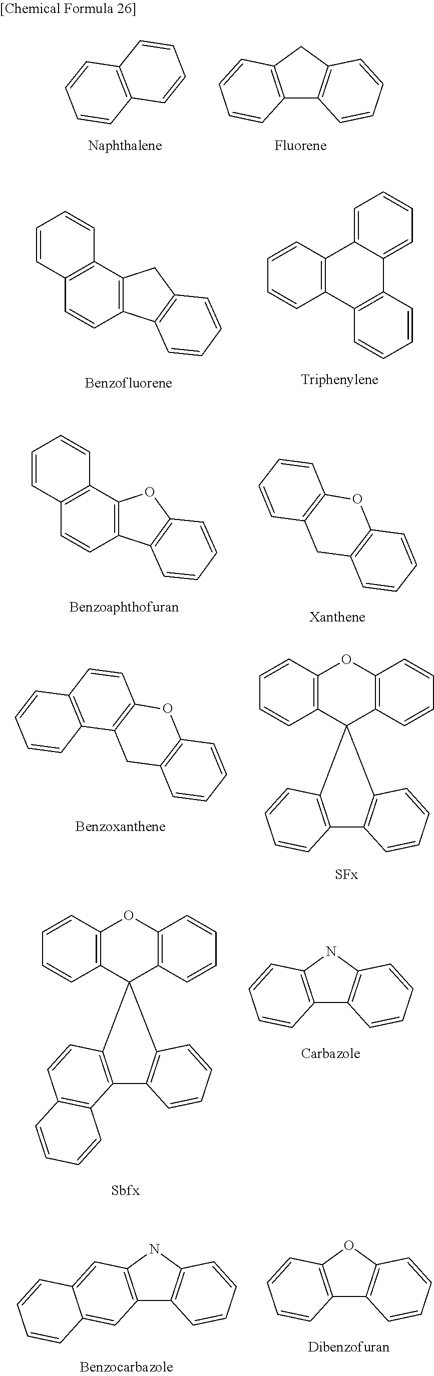

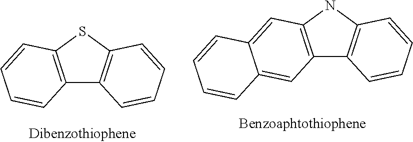

These fused rings can be used as skeletons in materials included in a variety of layers because the carrier-transport property can be adjusted or T_{g} can be adjusted depending on the position bonded to another group (also referred to as a bonding position). Preferably, a material including a naphthalene ring having a bonding position at the 1-position is used as an electron-transport layer material, and a material including a naphthalene ring having a bonding position at the 2-position is used as a hole-transport layer material, for example. It is also suitable that a material including a naphthalene ring having a bonding position at the 2-position is used as a host material of a light-emitting layer and a material including a naphthalene ring having a bonding position at the 1-position is used as a hole-transport layer material. Moreover, it is preferable that a material including a naphthalene ring having bonding positions at the 1- and 2-positions be used as an electron-transport layer material and a material including a naphthalene ring having bonding positions at the 1- and 6-positions be used as a host material of a light-emitting layer in the case where such naphthalene rings are used as linking groups. As described here, the same fused rings having different bonding positions are suitably used for the compound in one layer and the compound in another layer.

In the case where the same fused rings are used for a plurality of layers, different substituents are suitably used as follows: a fused ring to which a cyano group is bonded (e.g., a naphthalene ring) is used for the electron-transport layer material and a fused ring to which an alkyl group is bonded (e.g., a naphthalene ring) is used for the hole-transport layer material. Materials suited to the properties required for the layers can be provided.

In the case where aromatic rings are used for a plurality of layers, not only the same aromatic rings but also structurally isomeric aromatic rings may be used. Even when structurally isomeric aromatic rings are used, they might be produced using the same raw material as described above, which can lead to a reduction in raw material costs or synthesis steps. Examples of the structural isomers of a benzonaphthofuran ring include three fused structures depending on the fused positions of the benzene ring: a benzo[b]naphtho[2,1-d]furan ring (also referred to as an aBnf skeleton); a benzo[b]naphtho[2,3-d]furan ring (also referred to as a Bnf(II)skeleton); and a benzo[b]naphtho[1,2-d]furan ring (also referred to as a Bnf skeleton). Specific structures of these skeletons are shown below. In the case where any of benzonaphthofuran rings shown below has a substituent, one of the carbon or nitrogen atoms is a bonding site.

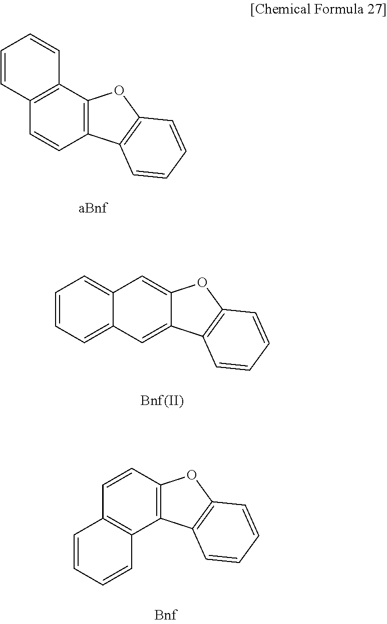 [SMILES: c1ccc2c(c1)ccc1c3ccccc3oc21 ; c1ccc2cc3c(cc2c1)oc1ccccc13 ; c1ccc2c(c1)ccc1oc3ccccc3c12]

In the case of using structurally isomeric aromatic rings, a material including the above-described aBnf skeleton can be used as a material of the electron-transport layer, a material including the above-described Bnf(II)skeleton can be used as the host material of the light-emitting layer, and a material including the above-described Bnf skeleton can be used as a material of the hole-transport layer. Since materials using structurally isomeric aromatic rings have different properties (e.g., carrier-transport properties, HOMO, and LUMO), using the aromatic rings suitable for the properties required for the layers can even achieve improvement in characteristics in addition to the adjustment of T_{g} and the reductions in raw material costs and synthesis steps described above.

Moreover, structurally isomeric aromatic rings are preferably included in the host materials of the light-emitting layers in a red-light-emitting device, a green-light-emitting device, and a blue-light-emitting device. Structurally isomeric aromatic rings may be included in different materials that are used for the hole-transport layer materials in the devices of different colors. Structurally isomeric aromatic rings are also suitably included in a plurality of electron-transport layers. The same applies to the case where a plurality of hole-transport layers are included. Thus, a plurality of materials used in the light-emitting device preferably include structurally isomeric aromatic rings. Structurally isomeric aromatic rings can also be referred to as aromatic rings that have the same molecular weight and different fused positions when including a fused ring structure. The same applies to not only a benzonaphthofuran ring but also the other aromatic rings described above (e.g., a benzofluorene ring, a benzoxanthene ring, a spirobenzofluorenexanthene ring, a benzocarbazole ring, and a benzonaphthothiophene ring). As described above, the term “benzonaphthofuran ring” encompasses structural isomers such as aBnf, Bnf (II), and Bnf. Similarly, each of the other fused rings also represents a structural isomer.

Note that each of the fused rings represented by the structural formulae may have a substituent. Different compounds may have the same substituents or different substituents.

The first light-emitting unit 501 and the second light-emitting unit 502 may include a functional layer in addition to the above-described light-emitting layers, hole-transport layers, electron-transport layers, and the like. Their structure is not limited to that in FIG. 1A, and any of the layers may be omitted or other layers may be added. Typical examples of the other layers include a carrier-blocking layer and an exciton-blocking layer.

In the case where a phosphorescent substance that emits red or green light is used, the T₁ level of the organic compound used for the carrier-blocking layer is preferably higher than the T₁ level of the phosphorescent substance. This structure prevents excitation energy of excitons, which are generated by recombination of carriers in the light-emitting layer, from diffusing into the carrier-blocking layer; consequently, the light-emitting device can have high emission efficiency. Meanwhile, in the case where a phosphorescent substance that emits blue light is used for the light-emitting layer, an organic compound having a lower T₁ level than the phosphorescent substance is used for the carrier-blocking layer, whereby the light-emitting device can be highly stable and highly reliable. When the T₁ level of the phosphorescent substance is lower than that of the organic compound used for one of the carrier-blocking layers in contact with the light-emitting layer which are respectively on the anode side and the cathode side and is higher than that of the organic compound used for the other of the layers, the light-emitting device can have high emission efficiency, high stability, and high reliability. However, a significantly low T₁ level of the organic compound used for the carrier-blocking layer is likely to decrease the emission efficiency. The energy difference between the T₁ levels of the phosphorescent substance and each of the organic compounds used for the carrier-blocking layers is therefore greater than or equal to 0.1 eV, preferably greater than or equal to 0.2 eV, and less than or equal to 1.0 eV, preferably less than or equal to 0.5 eV, which avoids a reduction in emission efficiency and makes the light-emitting device highly stable and highly reliable.

The first electrode 101 includes the anode. The first electrode 101 may have a stacked-layer structure, in which case a layer in contact with the organic compound layer 103 functions as the anode. The anode is preferably formed using a metal, an alloy, a conductive compound, or a mixture thereof each having a high work function (specifically, higher than or equal to 4.0 eV), for example. Specific examples include indium oxide-tin oxide (ITO: indium tin oxide), indium oxide-tin oxide containing silicon or silicon oxide, indium oxide-zinc oxide, and indium oxide containing tungsten oxide and zinc oxide (IWZO). Films of such conductive metal oxides are usually formed by a sputtering method, but may be formed by a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used for the anode. Graphene can also be used for the anode. Note that an electrode material can be selected regardless of the work function when the composite material forming the first layer 161 (also referred to as a p-type layer) in the above intermediate layer 160 is used for the layer (typically the hole-injection layer) in contact with the anode.

The hole-injection layer 111 is provided in contact with the anode and has a function of facilitating injection of holes into the organic compound layer 103 (the first light-emitting unit 501). The hole-injection layer 111 can be formed using a phthalocyanine-based compound or a complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example.

The hole-injection layer 111 may be formed using a substance having an electron-acceptor property. Examples of the substance having an acceptor property include organic compounds having an electron-withdrawing group (e.g., a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene) malononitrile. A compound in which electron-withdrawing groups are bonded to a fused aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-acceptor property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds. Alternatively, the hole-injection layer 111 can be formed using a phthalocyanine-based compound or a complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example. The substance having an acceptor property can extract electrons from an adjacent hole-transport layer (or hole-transport material) by application of an electric field.

The hole-injection layer 111 is preferably formed using a composite material containing any of the aforementioned materials having an acceptor property and a hole-transport substance.

As the hole-transport substance used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the hole-transport substance used for the composite material preferably has a hole mobility higher than or equal to 1×10⁻⁶ cm²/Vs. The hole-transport substance used in the composite material is preferably a compound having a fused aromatic hydrocarbon ring or a π-electron rich heteroaromatic ring. As the fused aromatic hydrocarbon ring, an anthracene ring, a naphthalene ring, or the like is preferable. As the π-electron rich heteroaromatic ring, a fused aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further fused to a carbazole ring or a dibenzothiophene ring is preferable.

Such a hole-transport substance further preferably has any one or more of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the hole-transport substance preferably has an N,N-bis(4-biphenyl)amino group to enable fabricating a light-emitting device having a long lifetime. An organic compound having a carbazole skeleton and a dibenzofuran skeleton is preferable because the heat resistance can be improved and the hole-transport property can be adjusted. When a dibenzothiophene skeleton is used in addition to a carbazole skeleton and a dibenzofuran skeleton, the hole-transport property can be further adjusted. With the use of two, three, or more of the above skeletons in consideration of desired element characteristics and compatibility with other layers (the light-emitting layer and the electron-transport layer), improvements in the physical properties and element characteristics can be expected.

Specific examples of the hole-transport substance include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf (6)), N,N-bis(4-biphenyl)benzo[b]naphtho[1,2-d]furan-8-amine (abbreviation: BBABnf (8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-[3-(triphenylsilyl)phenyl]-9′H-9,3′:6′,9″-tercarbazole (abbreviation: PSiCzGI).

Examples of the aromatic amine compounds that can be used as the hole-transport substance include N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N′-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances having an acceptor property, an organic compound having an acceptor property is easy to use because the organic compound is easily deposited by evaporation as a film.

The hole-transport layer (the first hole-transport layer 112_1 or the second hole-transport layer 112_2) includes a hole-transport organic compound. The hole-transport organic compound preferably has a hole mobility higher than or equal to 1×10⁻⁶ cm²/Vs. Other than the above-described organic compound having an amine skeleton and a fluorene skeleton, the hole-transport organic compound can also be used as needed.

Examples of the aforementioned hole-transport organic compound include the following compounds: compounds having an aromatic amine skeleton, such as 4,4′-bis[N-(1-naphthyl)-N-phenylamino]biphenyl (abbreviation: NPB), N,N-diphenyl-N,N′-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: BNCCmBP), 9-(4-biphenyl)-9′-(2-naphthyl)-3,3′-bi-9H-carbazole (abbreviation: BNCCBP), 9,9′-di-2-naphthyl-3,3′-9H,9′H-bicarbazole (abbreviation: BisBNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, and 9-[3-(triphenylsilyl)phenyl]-3,9′-bi-9H-carbazole (abbreviation: PSiCzCz); compounds having skeleton, such a thiophene as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. A compound having both an aromatic amine skeleton and a carbazole skeleton can be expected to further improve the reliability and reduce the driving voltage. A compound having an aromatic amine skeleton, a carbazole skeleton, and a dibenzofuran skeleton is further preferable because the heat resistance can be improved. Any of the organic compounds given as examples of the hole-transport substance that is used for the composite material in the hole-injection layer 111 can also be suitably used as the material included in the hole-transport layer 112 (the first hole-transport layer 112_1 and the second hole-transport layer 112_2).

Note that the first hole-transport layer 112_1 and the second hole-transport layer 112_2 preferably include organic compounds having the same skeleton, and further preferably include the same compound.

The light-emitting layer (the first light-emitting layer 113_1 and the second light-emitting layer 113_2) preferably includes an emission center substance and a host material. The light-emitting layers may additionally include another material. At least one of the light-emitting layers includes a material that emits phosphorescent light as the emission center substance. In particular, the above-described phosphorescent substance that emits blue light is preferably used as the emission center substance.

The first light-emitting layer 113_1 and the second light-emitting layer 113_2 preferably emit light of similar colors. For example, red, green, and blue pixels are often used in a full-color display device. In a light-emitting device used in a red pixel, both the first light-emitting layer 113_1 and the second light-emitting layer 113_2 emit red light. In a green pixel, both of the two light-emitting layers emit green light. In a blue pixel, both of the two light-emitting layers emit blue light. In that case, the difference in maximum peak wavelength between the PL spectrum of the compound as the emission center substance of the first light-emitting layer 113_1 and the PL spectrum of the compound as the emission center substance of the second light-emitting layer 113_2 is preferably less than or equal to 30 nm, further preferably less than or equal to 20 nm, still further preferably less than or equal to 10 nm. Note that it is further preferable that the first light-emitting layer 113_1 and the second light-emitting layer 113_2 include the same emission center substance.

The emission center substance may be a fluorescent substance, a phosphorescent substance, a substance exhibiting thermally activated delayed fluorescence (TADF), or any other light-emitting substance.

Examples of the fluorescent substance that can be used as the emission center substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N″″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene) propanedinitrile (abbreviation: DCM1), 2-{2-methyl-6-[2-(2,3,6,7-tetrahydro-1H,5H-benzo[ij]quinolizin-9-yl) ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl) ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl) ethenyl]-4H-pyran-4-ylidene}propanedinitrile (abbreviation: DCJTB), 2-(2,6-bis {2-[4-(dimethylamino)phenyl]ethenyl}-4H-pyran-4-ylidene) propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl) ethenyl]-4H-pyran-4-ylidene}propanedinitrile (abbreviation: BisDCJTM), N,N-diphenyl-N,N′-(1,6-pyrene-diyl)bis[(6-phenylbenzo[b]naphtho[1,2-d]furan)-8-amine](abbreviation: 1,6BnfAPrn-03), N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf (IV)-02), and 3,10-bis[N-(dibenzofuran-3-yl)-N-phenylamino]naphtho[2,3-b;6,7-b′]bisbenzofuran (abbreviation: 3,10FrA2Nbf (IV)-02). Fused aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

As well as the above-described phosphorescent substance that emits blue light, a material that emits green light or a material that emits red light can be used as the phosphorescent substance that can be used as the emission center substance in the light-emitting layer.

For example, in the case where red, green, and blue pixels are used to achieve a full-color display device, using phosphorescent substances in all the red, green, and blue pixels enables fabrication of light-emitting devices with high emission efficiency.

Examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C^{2′})iridium(III) (abbreviation: [Ir(ppy) 3]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N, (2′)iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d₆)₂(mbfpypy-iPr-d₄)), [2-d₃-methyl-(2-pyridinyl-κN)benzofuro[2,3-b]pyridine-κC]bis[2-(2-pyridinyl-κN)phenyl-κ(]iridium(III) (abbreviation: Ir(ppy)₂(mbfpypy-d₃)), [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)), [2-(4-d₃-methyl-5-phenyl-2-pyridinyl-κN²)phenyl-κC]bis[2-(5-d₃-methyl-2-pyridinyl-κNV2)phenyl-κC]iridium(III) (abbreviation: [Ir(5mppy-d₃)₂(mdppy-d₃)]), [2-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), [2-(4-methyl-5-phenyl-2-pyridinyl-κN)phenyl-κC]bis[2-(2-pyridinyl-κN)phenyl-κC]iridium (abbreviation: [Ir(ppy)₂(mdppy)]), and tris {2-[5-(methyl-d₃)-4-phenyl-2-pyridinyl-κN]phenyl-κ(}iridium(III) (abbreviation: Ir(5m4dppy-d₃)₃); platinum complexes such as (2-{1-(5-tert-butylbiphenyl-2-yl)-4-[3-tert-butyl-5-(4-phenyl-2-pyridinyl-κN)phenyl-κC⁶]-2-benzimidazolyl-κN³}-4,6-di-tert-butylphenolato-κO)platinum(II) (abbreviation: Pt(tBudppymmtBubiz-tBubp)) and [2-(4-(3,5-di-tert-butylphenyl)-6-{3-[4-(5′-tert-butyl[1,1′:3′,1″-terphenyl]-2′-yl)-2-pyridinyl-κN]phenyl-κC²}-2-pyridinyl-κN) phenolato-κO]platinum(II) (abbreviation: Pt(4tButpppypyp-mmtBup)); and rare earth metal complexes such as tris(acetylacetonato) (monophenanthroline) terbium (III) (abbreviation: [Tb (acac) 3 (Phen)]). These are mainly compounds that emit green phosphorescent light and have an emission peak at a wavelength longer than 500 nm and shorter than or equal to 600 nm. Note that organometallic iridium complexes having a pyrimidine skeleton have distinctively high reliability or emission efficiency and thus are particularly preferable. A compound obtained by substituting deuterium for part of hydrogen in any of these compounds can also be used.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl) quinoxalinato]iridium(III) (abbreviation: [Ir(Fdpq)₂(acac)]); organometallic iridium complexes having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-κN]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12, 13, 17, 18-octaethyl-21H,23H-porphyrinplatinum(II) (abbreviation: PtOEP); and rare earth metal complexes such as tris(1,3-diphenyl-1,3-propanedionato) (monophenanthroline) europium (III) (abbreviation: [Eu(DBM)₃(Phen)]) and tris[1-(2-thenoyl)-3,3,3-trifluoroacetonato](monophenanthroline) europium (III) (abbreviation: [Eu(TTA)₃(Phen)]). These compounds emit red phosphorescent light and have an emission peak in the wavelength range from 600 nm to 700 nm. Furthermore, the organometallic iridium complexes having a pyrazine skeleton can provide red light emission with favorable chromaticity. A compound obtained by substituting deuterium for part of hydrogen in any of these compounds can also be used.

Note that in one embodiment of the present invention, the use of a deuterated compound as the emission center substance improves the emission efficiency. Thus, the emission center substance is preferably a deuterated material.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

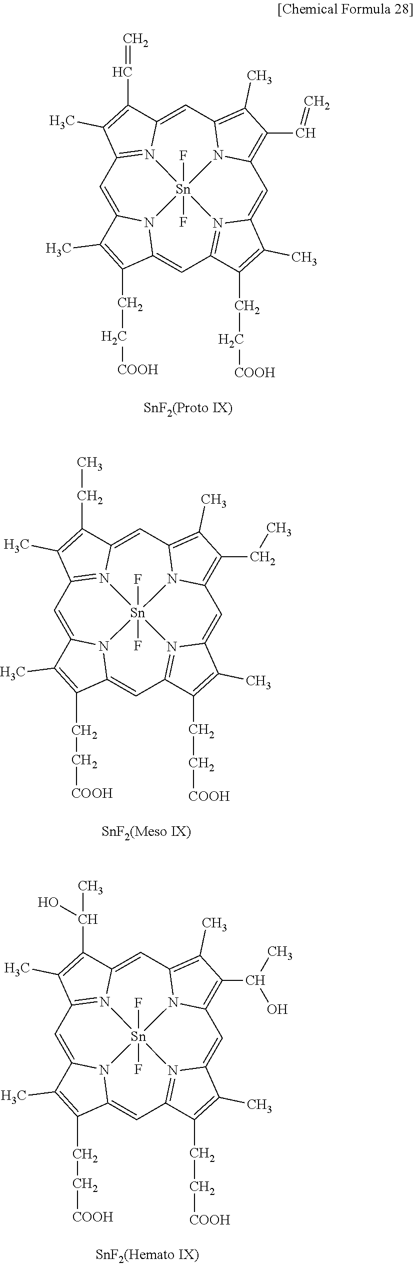

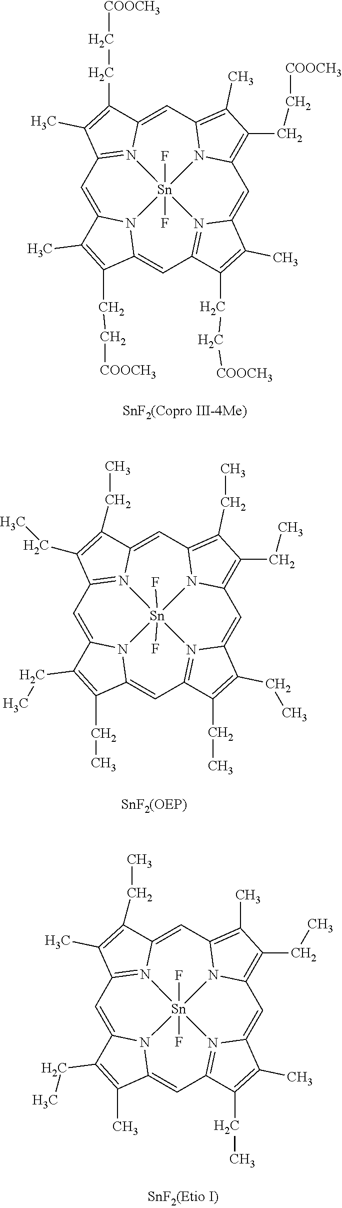

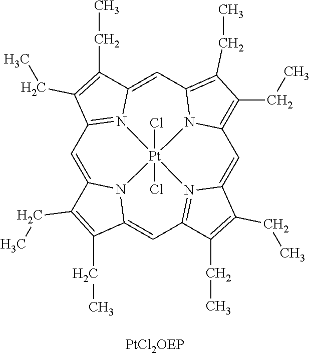

Alternatively, it is possible to use a heterocyclic compound having one or both of a π-electron rich heteroaromatic ring and a π-electron deficient heteroaromatic ring that is represented by any of the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-acceptor property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton including boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the T-electron rich heteroaromatic ring.

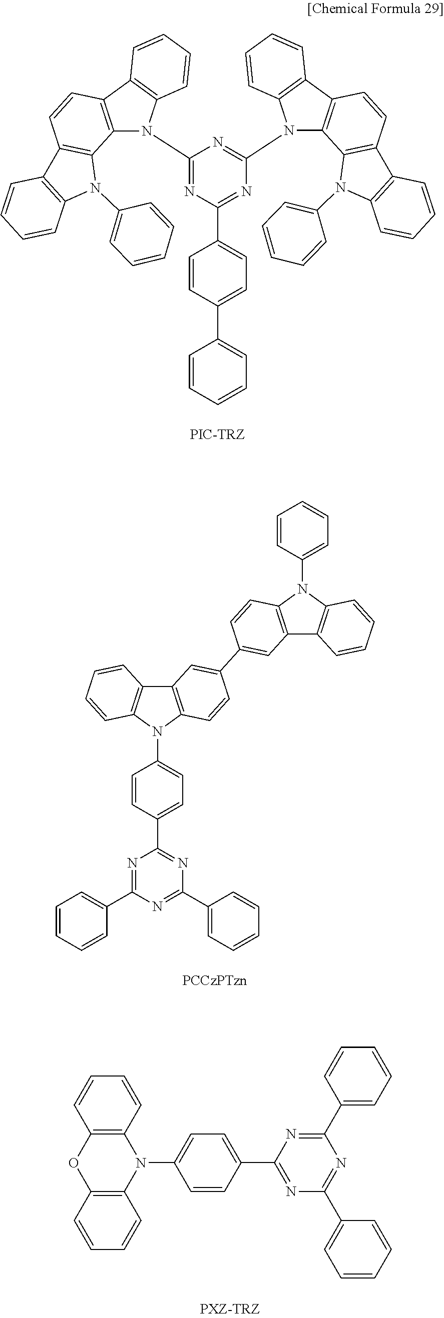 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-c3ccc(N4c5ccccc5Oc5ccccc54)cc3)n2)cc1]

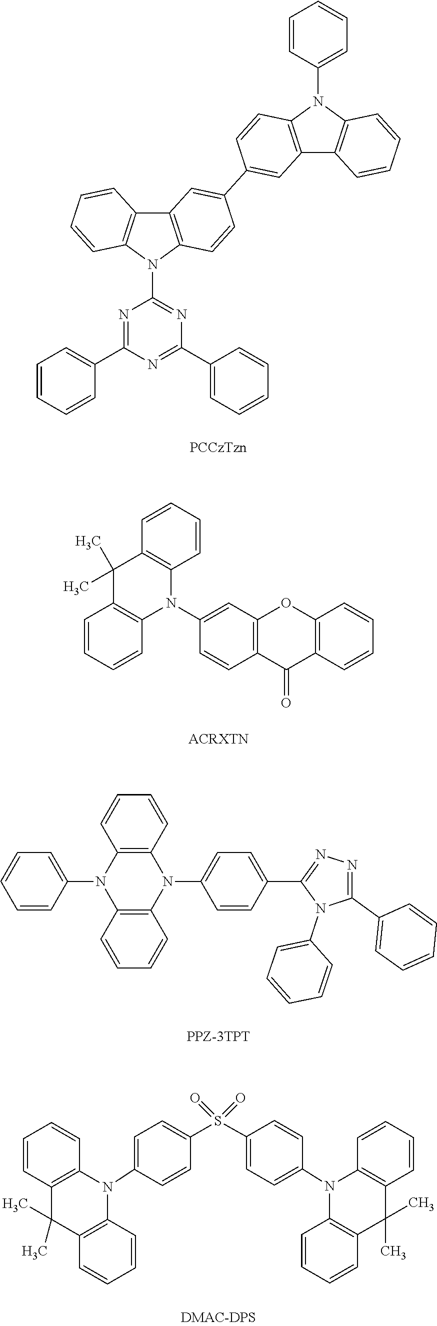 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; CC1(C)c2ccccc2N(c2ccc3c(=O)c4ccccc4oc3c2)c2ccccc21 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc(S(=O)(=O)c3ccc(N4c5ccccc5C(C)(C)c5ccccc54)cc3)cc2)c2ccccc21]

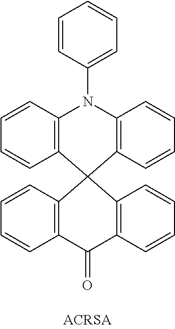 [SMILES: O=C1c2ccccc2C2(c3ccccc31)c1ccccc1N(c1ccccc1)c1ccccc12]

Alternatively, a TADF material whose singlet excited state and triplet excited state are in a thermal equilibrium state may be used. Since such a TADF material enables a short emission lifetime (excitation lifetime), the efficiency of a light-emitting device in a high-luminance region can be less likely to decrease. Specifically, a material having the following molecular structure can be used.

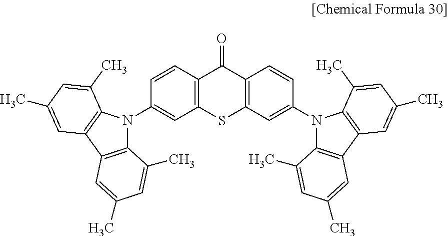

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescence spectrum observed at a low temperature (e.g., 77 K to 10 K) is used for an index of the T₁ level. When the level of energy with a wavelength of a line obtained by extrapolating a tangent to the fluorescence spectrum at a tail on the shorter wavelength side is the S₁ level and the level of energy with a wavelength of a line obtained by extrapolating a tangent to the phosphorescence spectrum at a tail on the shorter wavelength side is the T₁ level, the difference between the S₁ level and the T₁ level of the TADF material is preferably less than or equal to 0.3 eV, further preferably less than or equal to 0.2 eV.

When the TADF material is used as a light-emitting substance, the S₁ level of the host material is preferably higher than that of the TADF material, and the T₁ level of the host material is preferably higher than that of the TADF material.

As the host material in the light-emitting layer, any of various carrier-transport materials such as materials having an electron-transport property and/or materials having a hole-transport property, and the TADF materials can be used in addition to the above organic compounds.

The hole-transport material is preferably an organic compound having an amine skeleton or a π-electron rich heteroaromatic ring, for example. As the π-electron rich heteroaromatic ring, a fused aromatic ring having at least one of an acridine skeleton, a phenoxazine skeleton, a phenothiazine skeleton, a furan skeleton, a thiophene skeleton, and a pyrrole skeleton in the ring is preferable; specifically, a carbazole ring, a dibenzothiophene ring, or a ring in which an aromatic ring or a heteroaromatic ring is further fused to a carbazole ring or a dibenzothiophene ring is preferable.

Such a hole-transport substance further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the hole-transport substance is preferably an organic compound having an N,N-bis(4-biphenyl)amino group to enable fabricating a light-emitting device having a long lifetime.

Preferable examples of such organic compounds include the following organic compounds: compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 3,9-bis(9-phenyl-9H-carbazol-3-yl)-9H-carbazole (abbreviation: PCCzPC), 9-(biphenyl-4-yl)-9′-phenyl-3,3′-bi-9H-carbazole (abbreviation: PCCzBP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: BNCCmBP), 9-(4-biphenyl)-9′-(2-naphthyl)-3,3′-bi-9H-carbazole (abbreviation: BNCCBP), 9,9′-di-2-naphthyl-3,3′-9H,9′H-bicarbazole (abbreviation: BisBNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-[3-(triphenylsilyl)phenyl]-9′H-9,3′:6′,9″-tercarbazole (abbreviation: PSiCzGI); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. In addition, the organic compounds given as examples of the hole-transport material that can be used for the hole-transport layer can also be used.

The electron-transport material is preferably an organic compound having a π-electron deficient heteroaromatic ring. Examples of the organic compound having a π-electron deficient heteroaromatic ring include an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above organic compounds, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

Preferable examples of the organic compound having a π-electron deficient heteroaromatic ring include the following organic compounds: organic compounds having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl) stilbene (abbreviation: BzOS); organic compounds that have a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthryl)-1-naphthyl]-1,10-phenanthroline (abbreviation: PnNPhen), and 2-[4-(2-triphenylenyl)phenyl]-1,10-phenanthroline (abbreviation: pTpPPhen); organic compounds having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2-[4-(3,6-diphenyl-9H-carbazol-9-yl)phenyl]dibenzo[f,h]quinoxaline 2mpPCBPDBq), (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl) (1,1′-biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8 (BN2)-4mDBtPBfpm), 2,2′-(pyridine-2,6-diyl)bis(4-phenylbenzo[h]quinazoline) (abbreviation: 2,6 (P-Bqn) 2Py), 2,2′-(pyridine-2,6-diyl)bis {4-[4-(2-naphthyl)phenyl]-6-phenylpyrimidine}(abbreviation: 2,6 (NP-PPm) 2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 7-[4-(9-phenyl-9H-carbazol-2-yl) quinazolin-2-yl]-7H-dibenzo[c,g]carbazole (abbreviation: PC-cgDBCzQz), and 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm); and organic compounds that have a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthryl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-[4-(2-naphthyl)phenyl]-4-phenyl-6-spiro[9H-fluorene-9,9′-[9]xanthen]-4-yl-1,3,5-triazine (abbreviation: BNP-SFx (4) Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl)indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 3-phenyl-9-[4-phenyl-6-(9-phenyl-3-dibenzofuranyl)-1,3,5-triazin-2-yl]-9H-carbazole (abbreviation: PDBf-PCzTzn), and 9-[4-(4,6-diphenyl-1,3,5-triazin-2-yl)-2-dibenzothienyl]-2-phenyl-9H-carbazole (abbreviation: PCzDBtTzn). The organic compound that has a heteroaromatic ring having a diazine skeleton, the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage.

As the TADF material that can be used as the host material, the above materials mentioned as the TADF material that can be used as the emission center substance can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength of the lowest-energy absorption band of the fluorescent substance. This enables smooth transfer of excitation energy from the TADF material to the fluorescent substance and accordingly enables efficient light emission, which is preferable.

In order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that brings about light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transportation or carrier recombination. Here, the luminophore refers to an atomic group (skeleton) that brings about light emission in a fluorescent substance. The luminophore is preferably a skeleton having a π bond, further preferably has an aromatic ring, and still further preferably has a fused aromatic ring or a fused heteroaromatic ring. Examples of the luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the emission center substance, a material having an anthracene skeleton is suitably used as the host material. The use of a substance having an anthracene skeleton as the host material for the fluorescent substance makes it possible to obtain a light-emitting layer with high emission efficiency and high durability. Among the substances having an anthracene skeleton, a substance having a diphenylanthracene skeleton, in particular, a substance having a 9,10-diphenylanthracene skeleton, is chemically stable and thus is preferably used as the host material. The host material preferably has a carbazole skeleton to have higher hole-injection and hole-transport properties; further preferably, the host material has a benzocarbazole skeleton in which a benzene ring is further fused to a carbazole skeleton, because the HOMO level of the host material having a benzocarbazole skeleton is higher than that of the host material having a carbazole skeleton by approximately 0.1 eV and the host material having a benzocarbazole skeleton is thus easier for holes to enter than the host material having a carbazole skeleton. In particular, the host material preferably has a dibenzocarbazole skeleton, because the HOMO level of the host material having a dibenzocarbazole skeleton is higher than that of the host material having a carbazole skeleton by approximately 0.1 eV, the host material having a dibenzocarbazole skeleton is thus easier for holes to enter than the host material having a carbazole skeleton, and the host material having a dibenzocarbazole skeleton has a higher hole-transport property and higher heat resistance than the host material having a carbazole skeleton. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthryl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: «N-BNPAnth), 9-(1-naphthyl)-10-(2-naphthyl) anthracene (abbreviation: a,BADN), 2-(10-phenylanthracen-9-yl)dibenzofuran, 2-(10-phenyl-9-anthryl)benzo[b]naphtho[2,3-d]furan (abbreviation: Bnf(II)PhA), 9-(2-naphthyl)-10-[3-(2-naphthyl)phenyl]anthracene (abbreviation: BN-mBNPAnth), and 1-{4-[10-(biphenyl-4-yl)-9-anthryl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

The host material may be a mixture of a plurality of kinds of substances; in the case of using a mixed host material, it is preferable to mix an electron-transport material with a hole-transport material. By mixing the electron-transport material with the hole-transport material, the transport property of the light-emitting layer 113 can be easily adjusted and a recombination region can be easily controlled. The weight ratio of the content of the hole-transport material to the content of the electron-transport material is 1:19 to 19:1, preferably 1:9 to 9:1, further preferably 3:7 to 7:3.

Note that a phosphorescent substance can be used as part of the mixed material. When a fluorescent substance is used as a light-emitting substance, a phosphorescent substance can be used as an energy donor for supplying excitation energy to the fluorescent substance.

These mixed materials may form an exciplex. These mixed materials are preferably selected so as to form an exciplex that exhibits light emission whose wavelength overlaps with the wavelength of the lowest-energy absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

The first electron-transport layer 114_1 is a layer including an electron-transport substance. The electron-transport substance preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has a property of transporting more electrons than holes. The above substance is preferably an organic compound that has a π-electron deficient heteroaromatic ring. The organic compound that has a π-electron deficient heteroaromatic ring is preferably one or more of an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton, and is particularly preferably an organic compound that has a heteroaromatic ring having a triazine skeleton.

As the electron-transport organic compound that can be used in the first electron-transport layer 114_1, any of the aforementioned organic compounds that can be used as the electron-transport organic compound that serves as the host material in the first light-emitting layer 113_1 and the second light-emitting layer 113_2 can be used. Among the above organic compounds, the organic compound that has a heteroaromatic ring having a diazine skeleton, the organic compound that has a heteroaromatic ring having a pyridine skeleton, and the organic compound that has a heteroaromatic ring having a triazine skeleton are preferable because of having high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage.

The second electron-transport layer 114_2 is, as described above, a layer including the organic compound having a triazine skeleton. Since the details have already been described, the description is omitted here.

Note that the first electron-transport layer 114_1 preferably includes the organic compound having a triazine skeleton to reduce power consumption. In particular, the first electron-transport layer 114_1 preferably includes the same organic compound having a triazine skeleton as the organic compound having a triazine skeleton that is included in the second electron-transport layer 114_2, which inhibits the complication of a manufacturing apparatus and is advantageous also in terms of raw material procurement cost.

In the case where the first electron-transport layer 114_1 includes an organic compound having no triazine skeleton, the light-emitting device can have favorable characteristics owing to easy control of carrier transport. The organic compound having no triazine skeleton is preferably an organic compound that has a heteroaromatic ring having a pyridine skeleton or an organic compound that has a heteroaromatic ring having a diazine (pyrimidine or pyrazine) skeleton.

The intermediate layer 160 includes the organic compound having a phenanthroline skeleton. As illustrated in FIG. 1A, the intermediate layer 160 preferably includes the first layer 161 including the organic compound having a phenanthroline skeleton. The intermediate layer 160 preferably includes the second layer 162 including a hole-transport organic compound and the substance having an acceptor property. The second layer 162 is positioned closer to the second electrode 102 than the first layer 161 is. The intermediate layer 160 may include the third layer 163 between the first layer 161 and the second layer 162.

The details of the first layer are described above and not repeated here.

The first layer 161 may further include an electron-transport organic compound. As the electron-transport organic compound, any of the aforementioned organic compounds that can be used as the electron-transport organic compound that serves as the host material in the first light-emitting layer 113_1 and the second light-emitting layer 113_2 can also be used. The electron-transport organic compound is preferably an organic compound having two or more heteroaromatic rings that are bonded or fused to each other and that have three or more heteroatoms in total, in which case the resistance to a photolithography method can be improved and an increase in driving voltage can be inhibited.

Note that the first layer 161 may have a stacked-layer structure of a layer including an organic compound and a layer including a metal or a metal compound and positioned closer to the cathode than the layer including an organic compound is, or may be a mixed layer of an organic compound and a metal or a metal compound. The first layer 161 is preferably the mixed layer because it requires a smaller number of film formation chambers and a lower manufacturing cost and contributes to an improvement in the stability of the light-emitting device.

In the case where the organic compound and the metal or the metal compound are mixed, the organic compound and the metal or the metal compound tend to show substantially the same distribution when the first layer 161 is analyzed in the thickness direction. That is, when the organic compound is uniformly distributed, the metal or the metal compound is also substantially uniformly distributed. In the case of the stacked-layer structure of the layer including the organic compound and the layer including the metal or the metal compound, the metal or the metal compound is sometimes diffused from the layer including the metal or the metal compound and detected also in a region other than the layer but shows a distribution different from that of the organic compound; thus, the analysis results of diffusion and mixing can be distinguished from each other.

The second layer 162 preferably includes a hole-transport organic compound. The second layer 162 preferably further includes a substance exhibiting an acceptor property, and the substance exhibiting an acceptor property is preferably an organic compound exhibiting an acceptor property with respect to the hole-transport organic compound.

In the case where the second layer 162 includes the hole-transport organic compound and the substance exhibiting an acceptor property with respect to the hole-transport organic compound, holes are generated by charge separation, and the holes are injected into the first light-emitting unit 501 on the cathode side through the hole-transport organic compound when voltage is applied between the first electrode 101 and the second electrode 102. Thus, the light-emitting device 130 of one embodiment of the present invention can have a low driving voltage.

As the hole-transport organic compound, any of a variety of organic compounds such as aromatic amine compounds, heteroaromatic compounds, aromatic hydrocarbons, and high molecular compounds (e.g., oligomers, dendrimers, and polymers) can be used. Note that the hole-transport organic compound preferably has a hole mobility higher than or equal to 1×10⁻⁶ cm²/Vs. The hole-transport organic compound preferably has a fused aromatic hydrocarbon ring or a T-electron rich heteroaromatic ring. As the fused aromatic hydrocarbon ring, an anthracene ring, a naphthalene ring, or the like is preferable. As the π-electron rich heteroaromatic ring, a fused aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further fused to a carbazole ring or a dibenzothiophene ring is preferable.

Such a hole-transport organic compound further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the hole-transport organic compound preferably has an N,N-bis(4-biphenyl)amino group to enable fabricating a light-emitting device having a long lifetime.

The above-described hole-transport organic compound can specifically be any of the organic compounds given as examples of the hole-transport organic compound that can be used in the hole-injection layer 111.

The substance having an acceptor property can be, for example, any of the substances given as examples of the organic compound having an acceptor property that can be used in the hole-injection layer 111. An organic compound having at least one of a halogen group and a cyano group is particularly preferable, and an organic compound having at least one of fluorine and a cyano group is further preferable. Note that it is further preferable that the total number of halogen groups (fluorines) and cyano groups of the organic compound be four or more. Examples of the organic compound having at least one of a halogen group and a cyano group include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile].

Note that the substance having an acceptor property preferably has an electron-accepting property with respect to the hole-transport organic compound. When the substance having an acceptor property has an electron-accepting property with respect to the hole-transport organic compound, charge separation occurs and the second layer 162 can function as a charge-generation layer and functions as an intermediate layer of the tandem light-emitting device. A signal is preferably observed by electron spin resonance in the second layer 162. For example, the density of spins attributed to a signal observed at a g-factor of approximately 2.00 is preferably higher than or equal to 1×10¹⁷ spins/cm³, further preferably higher than or equal to 1×10¹⁸ spins/cm³, still further preferably higher than or equal to 1×10¹⁹ spins/cm³.

The third layer 163 includes an electron-transport substance and has functions of preventing the interaction between the first layer 161 and the second layer 162 and smoothly transferring and receiving electrons therebetween to reduce the driving voltage, and reducing the interaction between the first layer 161 and the second layer 162 to improve the reliability, for example.

The LUMO level of the electron-transport substance that is included in the third layer 163 is preferably between the LUMO level of the substance having an acceptor property in the second layer 162 and the LUMO level of the organic compound included in a layer (e.g., the first electron-transport layer 114_1 in the first light-emitting unit 501 in FIG. 1A) which is in contact with the first layer 161 in the light-emitting unit on the anode side.

A specific energy level of the LUMO level of the electron-transport substance that is used in the third layer 163 is preferably higher than or equal to −5.0 eV, further preferably higher than or equal to −5.0 eV and lower than or equal to −3.0 eV, still further preferably higher than or equal to −4.30 eV and lower than or equal to −3.00 eV, yet further preferably higher than or equal to −4.30 eV and lower than or equal to −3.30 eV, in which case an increase in driving voltage can be inhibited. Note that the electron-transport substance that is used in the third layer 163 is preferably a phthalocyanine-based material or a metal complex having a metal-oxygen bond and an aromatic ligand.

Specific examples of the electron-transport substance that is used in the third layer 163 include perylenetetracarboxylic acid derivatives such as diquinoxalino[2,3-a: 2′,3′-c]phenazine (abbreviation: HATNA), 2,3,8,9,14,15-hexafluorodiquinoxalino[2,3-a: 2′,3′-c]phenazine (abbreviation: HATNA-F6), 3,4,9,10-perylenetetracarboxylic diimide (abbreviation: PTCDI), and 3,4,9,10-perylenetetracarboxyl-bis-benzimidazole (abbreviation: PTCBI), (C₆₀-Iₕ) [5,6]fullerene (abbreviation: C60), and (C₇₀-D₅ₕ) [5,6]fullerene (abbreviation: C70). It is also possible to use a compound having a heterophane skeleton, which is a cyclophane skeleton having a hetero ring; for example, a phthalocyanine compound such as phthalocyanine (abbreviation: H₂Pc) can be used as the compound. Alternatively, it is possible to use a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use a phthalocyanine-based metal complex such as copper phthalocyanine or zinc phthalocyanine or 2,3,8,9,14,15-hexafluorodiquinoxalino[2,3-a:2′,3′-c]phenazine.

The thickness of the third layer 163 is preferably greater than or equal to 1 nm and less than or equal to 10 nm, further preferably greater than or equal to 2 nm and less than or equal to 5 nm.

Note that the second light-emitting unit 502 includes no hole-injection layer because the second layer 162 in the intermediate layer 160 functions as a hole-injection layer; however, the second light-emitting unit 502 may include a hole-injection layer.

The second electrode 102 includes the cathode. The second electrode 102 may have a stacked-layer structure, in which case a layer in contact with the organic compound layer 103 functions as the cathode. The cathode is preferably formed using a metal, an alloy, an electrically conductive compound, or a mixture thereof each having a low work function (specifically, lower than or equal to 3.8 eV), for example. Specific examples of such a cathode material include elements belonging to Group 1 and Group 2 of the periodic table, such as alkali metals (e.g., lithium (Li) or cesium (Cs)), magnesium (Mg), calcium (Ca), and strontium (Sr), alloys containing any of these elements (e.g., MgAg and AlLi), rare earth metals such as europium (Eu) and ytterbium (Yb), and alloys containing any of these rare earth metals. Specific examples thereof include alkali metals, alkaline earth metals, rare earth metals, compounds thereof, and complexes thereof, such as lithium fluoride (LiF), cesium fluoride (CsF), calcium fluoride (CaF₂), 8-quinolinolato-lithium (abbreviation: Liq), and ytterbium (Yb), and electrides. Examples of an electride include substances in which electrons are added at high concentration to calcium oxide-aluminum oxide. Note that a mixture of two or more of these materials may be used as a cathode material. In the case where the second electrode 102 has a stacked-layer structure, a material having high conductivity can be used for the layer(s) other than the cathode, regardless of the work function.

Note that the second electron-transport layer 114_2 is preferably in contact with the second electrode 102. When the second electron-transport layer 114_2 is in contact with the second electrode 102, the light-emitting device can have excellent electron-injection and electron-transport properties, a low driving voltage, and low power consumption.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

The organic compound layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different film formation methods may be used to form the electrodes or the layers described above.

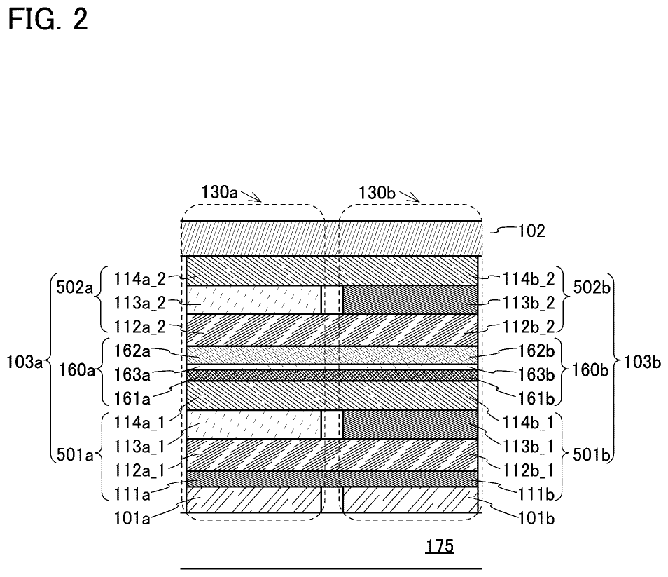

FIG. 2 illustrates two adjacent light-emitting devices (a light-emitting device 130a and a light-emitting device 130b) included in a display device of one embodiment of the present invention.

The light-emitting device 130a includes an organic compound layer 103a between a first electrode 101a and the second electrode 102 over an insulating layer 175. The organic compound layer 103a has a structure in which a first light-emitting unit 501a and a second light-emitting unit 502a are stacked with an intermediate layer 160a therebetween. Although FIG. 2 illustrates an example in which the two light-emitting units are stacked, three or more light-emitting units may be stacked. The first light-emitting unit 501a includes a hole-injection layer 111a, a first hole-transport layer 112a_1, a first light-emitting layer 113a_1, and a first electron-transport layer 114a_1. The intermediate layer 160a includes a second layer 162a, a third layer 163a, and a first layer 161a. The third layer 163a may be present or absent. The second light-emitting unit 502a includes a second hole-transport layer 112a_2, a second light-emitting layer 113a_2, and a second electron-transport layer 114a_2.

The light-emitting device 130b includes an organic compound layer 103b between a first electrode 101b and the second electrode 102 over the insulating layer 175. The organic compound layer 103b has a structure in which a first light-emitting unit 501b and a second light-emitting unit 502b are stacked with an intermediate layer 160b therebetween. Although FIG. 2 illustrates an example in which the two light-emitting units are stacked, three or more light-emitting units may be stacked. The first light-emitting unit 501b includes a hole-injection layer 111b, a first hole-transport layer 112b_1, a first light-emitting layer 113b_1, and a first electron-transport layer 114b_1. The intermediate layer 160b includes a second layer 162b, a third layer 163b, and a first layer 161b. The third layer 163b may be present or absent. The second light-emitting unit 502b includes a second hole-transport layer 112b_2, a second light-emitting layer 113b_2, and a second electron-transport layer 114b_2.

The first hole-transport layer 112a_1 and the second hole-transport layer 112a_2 each have a stacked-layer structure. In the stacked-layer structure, the layer in contact with the light-emitting layer is formed using a material whose LUMO level is higher than the LUMO level of a material included in the light-emitting layer (at least the host material, preferably the material included in the light-emitting layer, the material having the highest constituent ratio among the materials included in the light-emitting layer, or the material having the highest LUMO level among the materials included in the light-emitting layer).

The second electron-transport layer 114a_2 and the second electron-transport layer 114b_2 preferably include the organic compound having a triazine skeleton. The first layer 161a and the first layer 161b each include the organic compound having a phenanthroline skeleton.

The first light-emitting layer 113a_1 and the second light-emitting layer 113a_2 preferably emit light of similar colors. The emission center substance included in the first light-emitting layer 113a_1 and the emission center substance included in the second light-emitting layer 113a_2 are preferably compounds whose PL spectra have a difference in maximum peak wavelength less than or equal to 30 nm, further preferably less than or equal to 20 nm, still further preferably less than or equal to 10 nm. It is further preferable that the first light-emitting layer 113a_1 and the second light-emitting layer 113a_2 include the same emission center substance. The first light-emitting layer 113b_1 and the second light-emitting layer 113b_2 preferably emit light of similar colors. The emission center substance included in the first light-emitting layer 113b_1 and the emission center substance included in the second light-emitting layer 113b_2 are preferably compounds whose PL spectra have a difference in maximum peak wavelength less than or equal to 30 nm, further preferably less than or equal to 20 nm, still further preferably less than or equal to 10 nm. It is further preferable that the first light-emitting layer 113b_1 and the second light-emitting layer 113b_2 include the same emission center substance.

It is preferable that the first light-emitting layer 113a_1 and the first light-emitting layer 113b_1 be separated from each other and the second light-emitting layer 113a_2 and the second light-emitting layer 113b_2 be separated from each other. It is preferable that the emission color(s) of the first light-emitting layer 113a_1 and the second light-emitting layer 113a_2 be different from the emission color(s) of the first light-emitting layer 113b_1 and the second light-emitting layer 113b_2. It is preferable that the emission center substance included in the first light-emitting layer 113a_1 and the emission center substance included in the first light-emitting layer 113b_1 be different from each other and the emission center substance included in the second light-emitting layer 113a_2 and the emission center substance included in the second light-emitting layer 113b_2 be different from each other.

Note that each of the pairs of the hole-injection layers 111a and 111b, the first hole-transport layers 112a_1 and 112b_1, the first electron-transport layers 114a_1 and 114b_1, the intermediate layers 160a and 160b (the second layers 162a and 162b, the third layers 163a and 163b, and the first layers 161a and 161b), the second hole-transport layers 112a_2 and 112b_2, and the second electron-transport layers 114a_2 and 114b_2 may be one continuous layer or may be separate layers independent of each other between the light-emitting device 130a and the light-emitting device 130b. When these layers are continuous layers, the light-emitting devices can be fabricated with high productivity at low cost. When the layers are separate layers between the light-emitting devices, the layers can be formed using materials suitable for their emission colors, thereby enabling the light-emitting devices or a display device to have favorable characteristics. In particular, the second electron-transport layer 114a_2 and the second electron-transport layer 114b_2 are preferably one continuous layer, in which case both the light-emitting device 130a and the light-emitting device 130b can have favorable characteristics.

The second electron-transport layer 114a_2 and the second electron-transport layer 114b_2 being one continuous layer means that the second electron-transport layer 114a_2 and the second electron-transport layer 114b_2 are made of the same material. That is, when the second electron-transport layer 114a_2 and the second electron-transport layer 114b_2 are made of the same material, both the light-emitting device 130a and the light-emitting device 130b can have favorable characteristics. It is further preferable that the second electron-transport layer 114a_2 and the second electron-transport layer 114b_2 have similar structures, and it is still further preferable that the second electron-transport layer 114a_2 and the second electron-transport layer 114b_2 have the same structure.

Furthermore, in the case where the emission center substances included in the first light-emitting layers 113a_1 and 113b_1 are different from each other and the emission center substances included in the second light-emitting layers 113a_2 and 113b_2 are different from each other (e.g., in the case where the first light-emitting layer 113a_1 and the second light-emitting layer 113a_2 are blue fluorescent layers and the first light-emitting layer 113b_1 and the second light-emitting layer 113b_2 are green phosphorescent layers, in the case where the first light-emitting layer 113a_1 and the second light-emitting layer 113a_2 are blue fluorescent layers and the first light-emitting layer 113b_1 and the second light-emitting layer 113b_2 are red phosphorescent layers, or in the case where the first light-emitting layer 113a_1 and the second light-emitting layer 113a_2 are green phosphorescent layers and the first light-emitting layer 113b_1 and the second light-emitting layer 113b_2 are red phosphorescent layers), the light-emitting layers of the light-emitting devices 130a and 130b have different carrier balances. Therefore, in order to improve the performance of each of the light-emitting devices 130a and 130b, it is usually necessary to select and use an appropriate intermediate layer and an appropriate electron-transport layer for each light-emitting device. However, even when the second electron-transport layers 114a_2 and 114b_2 have the same structure, the use of the organic compound having a triazine skeleton in the second electron-transport layers 114a_2 and 114b_2 and the use of the organic compound having a phenanthroline skeleton in the first layers 161a and 161b can improve the performance of each of the light-emitting devices 130a and 130b. That is, both the productivity and the performance can be improved. Note that the first layers 161a and 161b may have the same structure.

Note that one continuous layer is a so-called common layer formed across the light-emitting devices 130a and 130b.

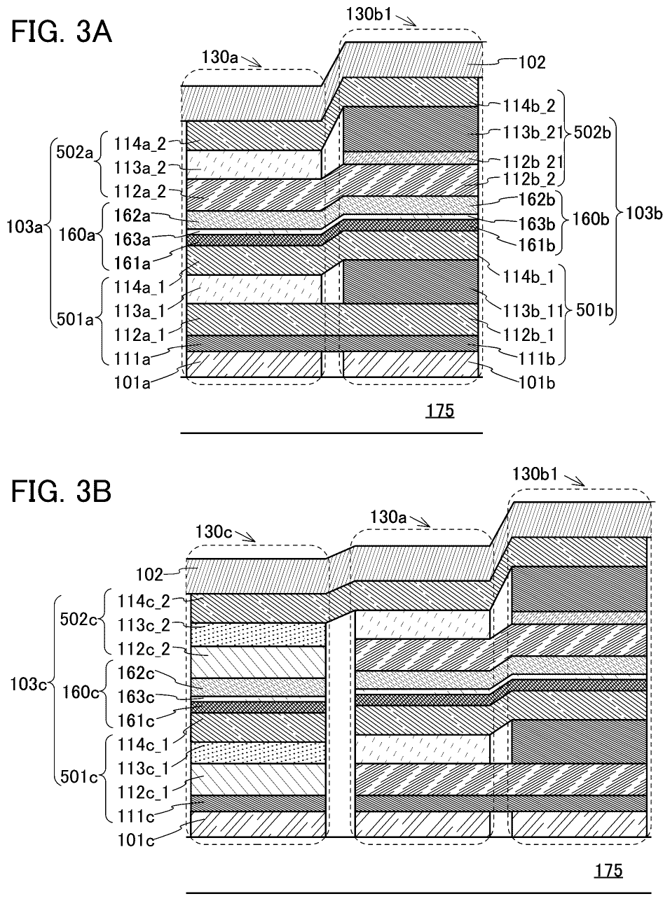

FIG. 3A is a modification example of FIG. 2. The light-emitting devices 130a and 130b emit light of different colors and thus have different optical path lengths between the electrodes for amplification of emitted light using a microcavity structure. In a light-emitting device 130b1, the distance between the electrodes can be adjusted by thickening light-emitting layers such as a light-emitting layer 113b_11 and a light-emitting layer 113b_21. Alternatively, the optical path length may be changed by thickening or adding a functional layer such as a hole-transport layer 112b_21.

FIG. 3B illustrates three adjacent light-emitting devices (the light-emitting device 130a, the light-emitting device 130b1, and a light-emitting device 130c) included in a display device of one embodiment of the present invention.

The light-emitting device 130c includes an organic compound layer 103c between a first electrode 101c and the second electrode 102 over the insulating layer 175. The organic compound layer 103c has a structure where a first light-emitting unit 501c and a second light-emitting unit 502c are stacked with an intermediate layer 160c therebetween. Although FIG. 3B illustrates an example in which the two light-emitting units are stacked, three or more light-emitting units May be stacked. The first light-emitting unit 501c includes a hole-injection layer 111c, a first hole-transport layer 112c_1, a first light-emitting layer 113c_1, and a first electron-transport layer 114c_1. The intermediate layer 160c includes a second layer 162c, a third layer 163c, and a first layer 161c. The third layer 163c may be present or absent. The second light-emitting unit 502c includes a second hole-transport layer 112c_2, a second light-emitting layer 113c_2, and a second electron-transport layer 114c_2.

It is assumed here that the light-emitting device 130c emits light whose wavelength is shorter than those of light from the light-emitting devices 130a and 130b1. The distance between the electrodes in the light-emitting device 130c is adjusted by the thicknesses of the first light-emitting layer 113c_1 and the second light-emitting layer 113c_2, which are smaller than those of the light-emitting layers in the other two light-emitting devices.

The second electron-transport layer 114c_2 includes the organic compound having a triazine skeleton. The first layer 161c includes the organic compound having a phenanthroline skeleton.

The first light-emitting layer 113c_1 and the second light-emitting layer 113c_2 preferably emit light of similar colors. The emission center substance included in the first light-emitting layer 113c_1 and the emission center substance included in the second light-emitting layer 113c_2 are preferably compounds whose PL spectra have a difference in maximum peak wavelength less than or equal to 30 nm, further preferably less than or equal to 20 nm, still further preferably less than or equal to 10 nm. It is further preferable that the first light-emitting layer 113c_1 and the second light-emitting layer 113c_2 include the same emission center substance.

It is preferable that the first light-emitting layer 113a_1 and the first light-emitting layer 113c_1 be separated from each other and the second light-emitting layer 113a_2 and the second light-emitting layer 113c_2 be separated from each other. It is preferable that the emission color(s) of the first light-emitting layer 113a_1 and the second light-emitting layer 113a_2 be different from the emission color(s) of the first light-emitting layer 113c_1 and the second light-emitting layer 113c_2. It is preferable that the emission center substance included in the first light-emitting layer 113a_1 and the emission center substance included in the first light-emitting layer 113c_1 be different from each other and the emission center substance included in the second light-emitting layer 113a_2 and the emission center substance included in the second light-emitting layer 113c_2 be different from each other.

Note that each of the pairs of the hole-injection layers 111a and 111c, the first hole-transport layers 112a_1 and 112c_1, the first electron-transport layers 114a_1 and 114c_1, the intermediate layers 160a and 160c (the second layers 162a and 162c, the third layers 163a and 163c, and the first layers 161a and 161c), and the second hole-transport layers 112a_2 and 112c_2 in this example are separate layers independent of each other between the light-emitting device 130a and the light-emitting device 130c, and the second electron-transport layers 114a_2 and 114c_2 in this example are a continuous layer. In this manner, one light-emitting device may include both continuous and separate layers. This allows the light-emitting device or the display device to balance productivity and characteristics. In particular, the second electron-transport layer 114a_2 and the second electron-transport layer 114c_2 are preferably one continuous layer, in which case both the light-emitting device 130a and the light-emitting device 130c can have favorable characteristics.

In the case where light-emitting devices exhibiting three colors consist of, for example, two light-emitting devices including fluorescent emission center substances and one light-emitting device including a phosphorescent emission center substance, the light-emitting devices including the fluorescent emission center substances preferably have one continuous carrier-transport layer, and the light-emitting device including the phosphorescent emission center substance preferably has a carrier-transport layer separated from that in the light-emitting devices exhibiting the other emission colors. Alternatively, in the case where light-emitting devices exhibiting three colors consist of two light-emitting devices including phosphorescent emission center substances and one light-emitting device including a fluorescent emission center substance, the light-emitting devices including the phosphorescent emission center substances preferably have one continuous carrier-transport layer, and the light-emitting device including the fluorescent emission center substance preferably has a carrier-transport layer separated from that in the light-emitting devices exhibiting the other emission colors.

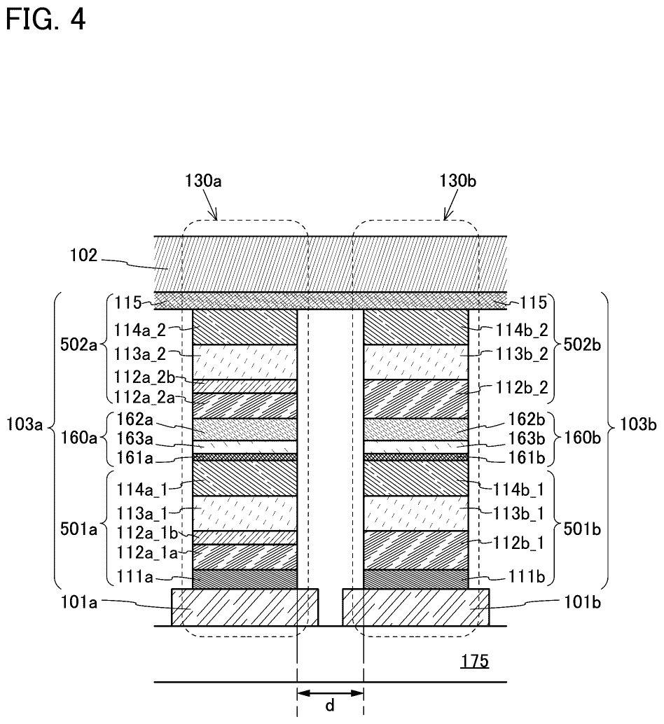

A light-emitting device of one embodiment of the present invention will be described with reference to FIG. 4. FIG. 4 is a schematic view of light-emitting devices, which are modification examples of the light-emitting devices illustrated in FIG. 2 and FIGS. 3A and 3B. The light-emitting devices 130a and 130b are two adjacent light-emitting devices that are formed over the same insulating surface and included in a light-emitting apparatus.

The light-emitting device 130a is located over an insulating layer 175 and includes a first electrode 101a that includes an anode, a second electrode 102 that includes a cathode, and an organic compound layer 103a. The organic compound layer 103a is located between the first electrode 101a and the second electrode 102. In the organic compound layer 103a, a first light-emitting unit 501a and a second light-emitting unit 502a are stacked with an intermediate layer 160a sandwiched therebetween.

The first light-emitting unit 501a includes a first hole-transport layer 112a_1 (a hole-transport layer 112a_1a and a hole-transport layer 112a_1b), a first light-emitting layer 113a_1, and a first electron-transport layer 114a_1. The intermediate layer 160a includes a first layer 161a and a second layer 162a. The second light-emitting unit 502a includes a second hole-transport layer 112a_2 (a hole-transport layer 112a_2a and a hole-transport layer 112a_2b), a second light-emitting layer 113a_2, a second electron-transport layer 114a_2, and an electron-injection layer 115. It can be said that the intermediate layer 160a is positioned between the first light-emitting layer 113a_1 and the second light-emitting layer 113a_2.

In the light-emitting device 130a, the first light-emitting unit 501a preferably includes a hole-injection layer 111a. The intermediate layer 160a can include a third layer 163a between the first layer 161a and the second layer 162a. In the case where the surface of the light-emitting unit on the anode side is in contact with the intermediate layer 160a like that of the second light-emitting unit 502a, the second layer 162a of the intermediate layer 160a, which is positioned on the cathode side, can also function as a hole-injection layer of the second light-emitting unit 502a, and thus, providing the hole-injection layer 111 in such a light-emitting unit is optional. That is, the hole-injection layer 111 is provided as needed for the required performance of the light-emitting device.

Here, the light-emitting device 130b may have a structure different from that of the light-emitting device 130a. For example, the light-emitting device 130b illustrated in FIG. 4 is different from the light-emitting device 130a in the structures of the first hole-transport layer 112a_1 and the second hole-transport layer 112a_2. In the case where different light-emitting materials are used for the light-emitting layers of the light-emitting devices 130a and 130b, layer structures suitable for the respective light-emitting materials are preferably formed. Through structural optimization for each light-emitting device, the characteristics of the light-emitting apparatus as a whole can be improved.

The light-emitting device 130b is located over the insulating layer 175 and includes a first electrode 101b that includes an anode, the second electrode 102 that includes the cathode, and an organic compound layer 103b. The organic compound layer 103b is located between the first electrode 101b and the second electrode 102. In the organic compound layer 103b, a first light-emitting unit 501b and a second light-emitting unit 502b are stacked with an intermediate layer 160b sandwiched therebetween.

The first light-emitting unit 501b includes a first light-emitting layer 113b_1. The intermediate layer 160b includes a first layer 161b and a second layer 162b. The second light-emitting unit 502b includes a second light-emitting layer 113b_2 and the electron-injection layer 115. The above structure can be regarded as a structure in which the intermediate layer 160b is located between the first light-emitting layer 113b_1 and the second light-emitting layer 113b_2.

In the light-emitting device 130b, the first light-emitting unit 501b preferably includes a hole-injection layer 111b, a first hole-transport layer 112b_1, and a first electron-transport layer 114b_1 in addition to the first light-emitting layer 113b_1. The second light-emitting unit 502b preferably includes a second hole-transport layer 112b_2 and a second electron-transport layer 114b_2 in addition to the second light-emitting layer 113b_2 and the electron-injection layer 115.

The intermediate layer 160b can include the third layer 163b between the first layer 161b and the second layer 162b. In the case where the surface of the light-emitting unit on the anode side is in contact with the intermediate layer 160b like that of the second light-emitting unit 502b, the second layer 162b of the intermediate layer 160b, which is positioned on the cathode side, can also function as a hole-injection layer of the second light-emitting unit 502b, and thus, providing the hole-injection layer 111 in such a light-emitting unit is optional. That is, the hole-injection layer 111 is provided as needed for the required performance of the light-emitting device.

The light-emitting apparatus of one embodiment of the present invention does not necessarily need to include a light-emitting device having the structure of the light-emitting device 130b and may include a plurality of light-emitting devices having only the structure of the light-emitting device 130a. In the case where the light-emitting devices in the light-emitting apparatus have the same structure, the complexity of the manufacturing apparatus can be reduced.

Although FIG. 4 illustrates an example in which each of the organic compound layers includes two light-emitting units, one embodiment of the present invention is not limited to this example. Each of the organic compound layers may include three or more light-emitting units. When a plurality of light-emitting units are stacked between a pair of electrodes with an intermediate layer sandwiched between the plurality of light-emitting units, the light-emitting device can perform high-luminance light emission with the current density kept low and can have high reliability. In addition, the light-emitting device can have low power consumption.

The light-emitting device 130, the light-emitting device 130a, or the light-emitting device 130b may be fabricated by a lithography method, for example. In other words, part of the organic compound layer in each of the light-emitting devices 130, 130a, and 130b can be fabricated through a processing step by a lithography method. In the case of the light-emitting device fabricated using a lithography method, at least the first light-emitting layer 113_1 or the second light-emitting layer 113_2 and the layer(s) that is/are closer to the first electrode 101 than the light-emitting layer is are formed by processing at the same time; consequently, their end portions are substantially aligned in the perpendicular direction.

The light-emitting device of one embodiment of the present invention that has such a structure can have high current efficiency, low energy loss, and favorable characteristics. A display device of one embodiment of the present invention that includes such a light-emitting device can achieve low power consumption, high reliability, high-luminance display, and high visibility. This embodiment can be freely combined with any of the other embodiments.

The above structure has a significant effect when used for the tandem light-emitting device of one embodiment of the present invention fabricated by side-by-side patterning. With the tandem structure fabricated by side-by-side patterning, red-, green-, and blue-light-emitting devices have different layer structures in which layers are stacked, and a layer structure is further stacked on another layer structure in each light-emitting device, which involves use of many kinds of materials or a large amount of materials, as described later. In view of the problems, a structure in which the same fused rings are included, a structure in which the same fused rings are bonded at different positions, or a structure in which structurally isomeric fused rings are included is employed for the plurality of layers as described above, thereby achieving the adjustment of T_{g} and the effect on physical properties, such as adjustment of the carrier-transport properties, in addition to a reduction in raw material costs or simplification of synthesis steps. Furthermore, by using such materials for the tandem light-emitting device of one embodiment of the present invention fabricated by side-by-side patterning, a light-emitting apparatus suitable for mass production can be formed.

### Embodiment 2

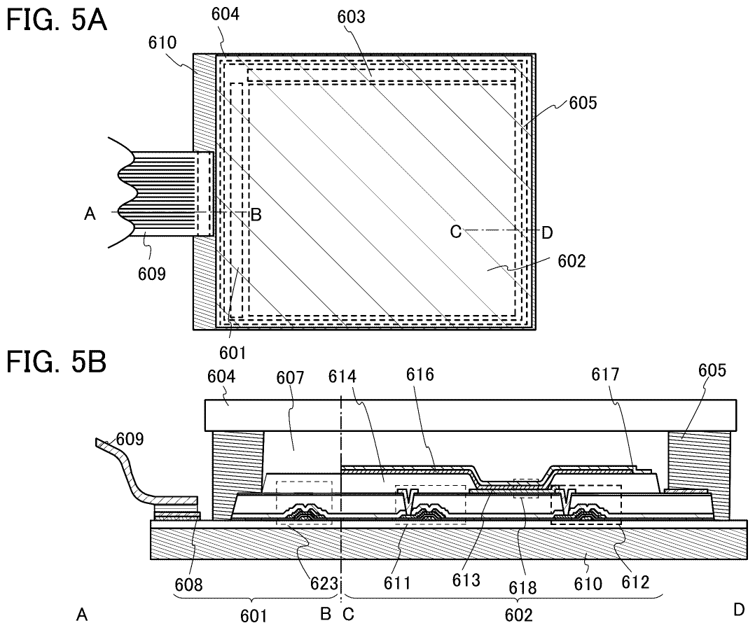

In this embodiment, a display device manufactured using the light-emitting device described in Embodiment 1 is described with reference to FIGS. 5A and 5B. Note that FIG. 5A is a top view of the display device, and FIG. 5B is a cross-sectional view taken along the lines A-B and C-D in FIG. 5A. This display device includes a driver circuit portion (source line driver circuit) 601, a pixel portion 602, and a driver circuit portion (gate line driver circuit) 603, which are to control light emission of the light-emitting device and illustrated with dotted lines. Reference numeral 604 denotes a sealing substrate; 605, a sealing material; and 607, a space surrounded by the sealing material 605.

Reference numeral 608 denotes a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The display device in this specification includes, in its category, not only the display device itself but also the display device provided with the FPC or the PWB.

Next, a cross-sectional structure is described with reference to FIG. 5B. The driver circuit portions and the pixel portion are formed over an element substrate 610; FIG. 5B illustrates the source line driver circuit 601, which is a driver circuit portion, and one pixel in the pixel portion 602.

The element substrate 610 may be a substrate formed of glass, quartz, an organic resin, a metal, an alloy, or a semiconductor or a plastic substrate formed of fiber reinforced plastic (FRP), polyvinyl fluoride (PVF), polyester, or an acrylic resin.

The structure of transistors used in the pixels and the driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. It is preferable to use a semiconductor having crystallinity, in which case degradation of transistor characteristics can be inhibited.

Here, an oxide semiconductor is preferably used for semiconductor devices such as the transistors provided in the pixels and the driver circuits and transistors used for touch sensors described later, and the like. In particular, an oxide semiconductor having a wider band gap than silicon is preferably used. When an oxide semiconductor having a wider band gap than silicon is used, off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which no grain boundary can be observed between the adjacent crystal parts.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of each pixel is maintained. As a result, an electronic appliance with extremely low power consumption can be obtained.

For stable characteristics of the transistor and the like, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

Note that an FET 623 is illustrated as a transistor formed in the source line driver circuit 601. In addition, the driver circuit may be formed with any of a variety of circuits such as a CMOS circuit, a PMOS circuit, or an NMOS circuit. Although a driver integrated type in which the driver circuit is formed over the substrate is described in this embodiment, the driver circuit is not necessarily formed over the substrate, and can be formed outside.

The pixel portion 602 includes a plurality of pixels including a switching FET 611, a current controlling FET 612, and a first electrode 613 electrically connected to a drain of the current controlling FET 612. One embodiment of the present invention is not limited to the structure, and the pixel portion 602 may include three or more FETs and a capacitor in combination.

Note that an insulator 614 is formed to cover an end portion of the first electrode 613. Here, the insulator 614 can be formed using a positive photosensitive acrylic resin film.

In order to improve coverage with an organic compound layer or the like which is formed later, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 μm to 3 μm). For the insulator 614, either a negative photosensitive resin or a positive photosensitive resin can be used.

An organic compound layer 616 and a second electrode 617 are formed over the first electrode 613. Here, as a material used for the first electrode 613 functioning as an anode, a material having a high work function is preferably used. For example, a single-layer film of an ITO film, an indium tin oxide film including silicon, an indium oxide film including zinc oxide at 2 wt % to 20 wt %, a titanium nitride film, a chromium film, a tungsten film, a Zn film, a Pt film, or the like, a stack of a titanium nitride film and a film including aluminum as its main component, a stack of three layers of a titanium nitride film, a film including aluminum as its main component, and a titanium nitride film, or the like can be used. The stacked-layer structure enables low wiring resistance, favorable ohmic contact, and a function as an anode.

The organic compound layer 616 is formed by any of a variety of methods such as an evaporation method using an evaporation mask, an ink-jet method, and a spin coating method. The organic compound layer 616 has the structure described in Embodiment 1. As another material included in the organic compound layer 616, a low molecular compound or a high molecular compound (including an oligomer or a dendrimer) may be used.

As a material used for the second electrode 617, which is formed over the organic compound layer 616 and functions as a cathode, a material having a low work function (e.g., Al, Mg, Li, and Ca, or an alloy or a compound thereof, such as MgAg, MgIn, and AlLi) is preferably used. In the case where light generated in the organic compound layer 616 is transmitted through the second electrode 617, a stack of a thin metal film and a transparent conductive film (e.g., ITO, indium oxide containing zinc oxide at 2 wt % to 20 wt %, indium tin oxide containing silicon, or zinc oxide (ZnO)) is preferably used for the second electrode 617.

Note that the light-emitting device is formed with the first electrode 613, the organic compound layer 616, and the second electrode 617. The light-emitting device is the light-emitting device described in Embodiment 1. In the display device of this embodiment, the pixel portion, which includes a plurality of light-emitting devices, may include both the light-emitting device described in Embodiment 1 and a light-emitting device having a different structure.

The sealing substrate 604 is bonded to the element substrate 610 with the sealing material 605, so that a light-emitting device 618 is provided in the space 607 surrounded by the element substrate 610, the sealing substrate 604, and the sealing material 605. The space 607 may be filled with a filler and may be filled with an inert gas (such as nitrogen or argon), or the sealing material. It is preferable that the sealing substrate be provided with a recessed portion and a drying agent be provided in the recessed portion, in which case deterioration due to the influence of moisture can be suppressed.

An epoxy-based resin or glass frit is preferably used for the sealing material 605. It is desirable that such a material not be permeable to moisture or oxygen as much as possible. As the sealing substrate 604, a glass substrate, a quartz substrate, or a plastic substrate formed of fiber reinforced plastic (FRP), polyvinyl fluoride (PVF), polyester, an acrylic resin, or the like can be used.

Although not illustrated in FIGS. 5A and 5B, a protective film may be provided over the second electrode. As the protective film, an organic resin film or an inorganic insulating film may be formed. The protective film may be formed so as to cover an exposed portion of the sealing material 605. The protective film may be provided so as to cover surfaces and side surfaces of the pair of substrates and exposed side surfaces of a sealing layer, an insulating layer, and the like.

The protective film can be formed using a material that is less likely to transmit an impurity such as water. Thus, diffusion of an impurity such as water from the outside into the inside can be effectively suppressed.

As a material for the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a film formation method with favorable step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

As described above, the display device manufactured using the light-emitting device described in Embodiment 1 can be obtained.

The display device in this embodiment is manufactured using the light-emitting device described in Embodiment 1 and thus can have favorable characteristics. Specifically, since the light-emitting device described in Embodiment 1 has high emission efficiency, the display device can achieve low power consumption. Since the light-emitting device described in Embodiment 1 has high reliability, the display device can be highly reliable. In addition, since the light-emitting device described in Embodiment 1 can have favorable chromaticity and high color purity, the display device can achieve high display quality.

This embodiment can be freely combined with any of the other embodiments.

### Embodiment 3

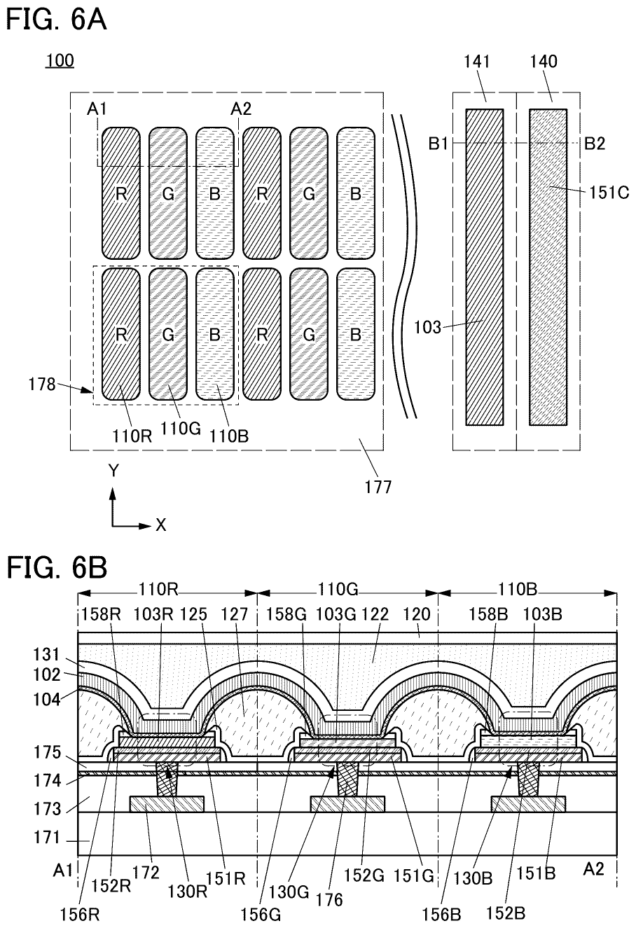

As illustrated in FIGS. 6A and 6B, a plurality of light-emitting devices 130 are formed over the insulating layer 175 to constitute a display device. In this embodiment, the display device of one embodiment of the present invention will be described in detail.

A display device 100 includes a pixel portion 177 in which a plurality of pixels 178 are arranged in a matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example. FIG. 6A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The organic compound layer 103 is provided in the region 141. A conductive layer 151C is provided in the connection portion 140.

Although FIG. 6A illustrates an example where the region 141 and the connection portion 140 are positioned on the right side of the pixel portion 177, the positions of the region 141 and the connection portion 140 are not particularly limited. The number of the regions 141 and the number of the connection portions 140 can each be one or more.

FIG. 6B is an example of a cross-sectional view along the dashed-dotted line A1-A2 in FIG. 6A. As illustrated in FIG. 6B, the display device 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 6B illustrates cross sections of a plurality of inorganic insulating layers 125 and a plurality of insulating layers 127, the inorganic insulating layers 125 are preferably connected to each other and the insulating layers 127 are preferably connected to each other when the display device 100 is seen from above. That is, the inorganic insulating layer 125 and the insulating layer 127 preferably include opening portions over first electrodes.

In FIG. 6B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display device of one embodiment of the present invention can be, for example, a top-emission display device where light is emitted in the direction opposite to a substrate over which light-emitting devices are formed. Note that the display device of one embodiment of the present invention may be of a bottom emission type.

Examples of a light-emitting substance included in the light-emitting device 130 include organometallic complexes and organic compounds such as a substance emitting fluorescent light (a fluorescent material), a substance emitting phosphorescent light (a phosphorescent material), and a substance exhibiting thermally activated delayed fluorescence (a thermally activated delayed fluorescent (TADF) material). Other examples include inorganic compounds (e.g., a quantum dot material).

The light-emitting device 130R has a structure described in Embodiment 1. The light-emitting device 130R includes the first electrode (pixel electrode) including a conductive layer 151R and a conductive layer 152R, an organic compound layer 103R over the first electrode, a common layer 104 over the organic compound layer 103R, and the second electrode (common electrode) 102 over the common layer 104. Although the common layer 104 is not necessarily provided, it is preferable to provide the common layer 104 to reduce damage to the organic compound layer 103R during processing. In the case where the common layer 104 is provided, the common layer 104 is preferably an electron-injection layer. Furthermore, in the case where the common layer 104 is provided, the stacked-layer structure of the organic compound layer 103R and the common layer 104 corresponds to the organic compound layer 103.

The light-emitting device 130G has a structure described in Embodiment 1. The light-emitting device 130G includes the first electrode (pixel electrode) including a conductive layer 151G and a conductive layer 152G, an organic compound layer 103G over the first electrode, the common layer 104 over the organic compound layer 103G, and the second electrode (common electrode) 102 over the common layer 104. Although the common layer 104 is not necessarily provided, it is preferable to provide the common layer 104 to reduce damage to the organic compound layer 103G during processing. In the case where the common layer 104 is provided, the common layer 104 is preferably an electron-injection layer. Furthermore, in the case where the common layer 104 is provided, the stacked-layer structure of the organic compound layer 103G and the common layer 104 corresponds to the organic compound layer 103.

The light-emitting device 130B has a structure described in Embodiment 1. The light-emitting device 130B includes the first electrode (pixel electrode) including a conductive layer 151B and a conductive layer 152B, an organic compound layer 103B over the first electrode, the common layer 104 over the organic compound layer 103B, and the second electrode (common electrode) 102 over the common layer 104. Although the common layer 104 is not necessarily provided, it is preferable to provide the common layer 104 to reduce damage to the organic compound layer 103B during processing. In the case where the common layer 104 is provided, the common layer 104 is preferably an electron-injection layer. Furthermore, in the case where the common layer 104 is provided, the stacked-layer structure of the organic compound layer 103B and the common layer 104 corresponds to the organic compound layer 103.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, 103G, and 103B are island-shaped layers that are independent of each other on a light-emitting device basis. Providing the island-shaped organic compound layer 103 in each of the light-emitting devices 130 can inhibit leakage current between the adjacent light-emitting devices 130 even in a high-resolution display device. This can prevent crosstalk, so that a display device with extremely high contrast can be obtained. Specifically, a display device having high current efficiency at low luminance can be obtained.

The island-shaped organic compound layer 103 is formed by forming an EL film and processing the EL film by a lithography method.

In the display device of one embodiment of the present invention, the first electrode (pixel electrode) of the light-emitting device preferably has a stacked-layer structure. For example, in the example illustrated in FIG. 6B, the first electrode of the light-emitting device 130 is a stack of the conductive layer 151 (the conductive layer 151R, the conductive layer 151G, and the conductive layer 151B) and the conductive layer 152 (the conductive layer 152R, the conductive layer 152G, and the conductive layer 152B). In the case where the display device 100 is of a top-emission type and the pixel electrode of the light-emitting device 130 functions as the anode, for example, the conductive layer 151 preferably has high reflectance for visible light, and the conductive layer 152 preferably has a visible-light-transmitting property and a high work function. In the case where the display device 100 is of a top-emission type, the higher the visible light reflectance of the pixel electrode is, the higher the efficiency of extraction of the light emitted by the organic compound layer 103 is. In the case where the pixel electrode functions as the anode, the higher the work function of the pixel electrode is, the easier hole injection into the organic compound layer 103 is. Accordingly, when the pixel electrode of the light-emitting device 130 has a stacked-layer structure of the conductive layer 151 with high reflectance for visible light and the conductive layer 152 with a high work function, the light-emitting device 130 can have high light extraction efficiency and a low driving voltage.

In the case where the conductive layer 151 has high reflectance for visible light, the visible light reflectance of the conductive layer 151 is preferably higher than or equal to 40% and lower than or equal to 100%, further preferably higher than or equal to 70% and lower than or equal to 100%, for example. When used as an electrode having a visible-light-transmitting property, the conductive layer 152 preferably has a visible light transmittance higher than or equal to 40%, for example.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a work function higher than or equal to 4.0 eV, for example.

The conductive layer 151 and the conductive layer 152 may each be a stack of a plurality of layers including different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

The conductive layer 151 or the conductive layer 152 preferably has a tapered side surface. Specifically, the side surface of the conductive layer 151 or the conductive layer 152 preferably has a tapered shape with a taper angle less than 90°. In addition, an end portion of an insulating layer 156 (an insulating layer 156R, an insulating layer 156G, or an insulating layer 156B) may also have a tapered shape. Specifically, the end portion of the insulating layer 156 has a tapered shape with a taper angle less than 90°, in which case a component with higher coverage can be provided along the side surface of the insulating layer 156.

The conductive layer 151 may have a stacked-layer structure of three or more layers. In the case where the conductive layer 151 has a stacked-layer structure of a plurality of layers, the visible light reflectance of at least one of the layers in the conductive layer 151 is made higher than that of the conductive layer 152. In the case where the conductive layer 151 has a structure of three or more layers, a material that is less likely to deteriorate than a material used for the middle conductive layer is preferably used for the outermost conductive layer. For the layer in contact with the insulating layer 175, for example, a material that is less likely to cause migration than the materials used for other layers can be used. Alternatively, for the layer in contact with the insulating layer 175, a material which is less likely to be oxidized than the materials used for the other layers and whose oxide has lower electrical resistivity than oxides of the materials used for the other layers can be used.

Thus, the range of choices of materials for the conductive layer 151 can be widened. Thus, with use of aluminum or an alloy containing aluminum for a material of the conductive layer 151, the conductive layer 151 can have high reflectance for visible light. As a material of the conductive layer 151, aluminum may be combined with titanium, which has a lower reflectance for visible light than aluminum but is less likely to migrate even when in contact with the insulating layer 175 than aluminum.

The conductive layer 151 may be formed using silver or an alloy containing silver. Silver has a feature of higher reflectance for visible light than titanium. In addition, silver has a feature of being less likely to be oxidized than aluminum, and silver oxide has a feature of lower electrical resistivity than aluminum oxide. Thus, the conductive layer 151 formed using silver or an alloy containing silver can favorably increase the visible light reflectance of the conductive layer 151 and inhibit an increase in the electrical resistance of the pixel electrode due to oxidation. Here, as the alloy containing silver, an alloy of silver, palladium, and copper (also referred to as Ag—Pd—Cu or APC) can be used, for example.

For example, in the case where the light-emitting device 130 has a microcavity structure, use of silver or an alloy containing silver, i.e., a material with high reflectance for visible light, for the conductive layer 151 can favorably increase the light extraction efficiency of the display device 100.

When the conductive layer 152 has a stacked-layer structure, the visible light reflectance (e.g., reflectance for light with a predetermined wavelength longer than or equal to 400 nm and shorter than 750 nm) of the stacked-layer structure is made different from that of the conductive layer 151, so that a microcavity structure can be formed in combination with the conductive layer 151.

The conductive layer 151 or 152 having a stacked-layer structure of a plurality of layers as described above can improve the characteristics of the display device. For example, the display device 100 can have high light extraction efficiency and high reliability.

The conductive layer 151 can be formed by a lithography method. Specifically, first, a conductive film to be the conductive layer 151 is formed. Next, a resist mask is formed over the conductive film to be the conductive layer 151. Then, the conductive film in the region not overlapping with the resist mask is removed by etching. Here, when the conductive film is processed under conditions where the resist mask is easily recessed (reduced in size) as compared to the case where the conductive layer 151 is formed such that the side surface does not have a tapered shape (i.e., the conductive layer 151 is formed to have a perpendicular side surface), the side surface of the conductive layer 151 can have a tapered shape.

The conductive layer 152 may be processed by a lithography method at the same time as the conductive layer 151. In that case, a side surface of the conductive layer 152 can also have a tapered shape.

Here, when the conductive film is processed under conditions where the resist mask is easily recessed (reduced in size), the conductive film might be easily processed in the horizontal direction. That is, the etching sometimes might become isotropic as compared to the case where the conductive layer 151 is formed to have a perpendicular side surface.

In the case where the conductive layer 151 is a stack of a plurality of layers formed of different materials, the plurality of layers sometimes differ in processability in the horizontal direction.

In view of the above, the insulating layer 156 is provided as illustrated in FIG. 6B, inhibiting occurrence of corrosion in the conductive layer 151. Thus, the display device 100 can be manufactured by a method with a high yield. Moreover, the display device 100 can have high reliability since generation of defects is inhibited therein.

Here, the insulating layer 156 preferably has a curved surface as illustrated in FIG. 6B. In that case, step disconnection in the conductive layer 152 covering the insulating layer 156 is less likely to occur than in the case where the insulating layer 156 has a perpendicular side surface (a side surface parallel to the Z direction), for example. In addition, step disconnection in the conductive layer 152 covering the insulating layer 156 is less likely to occur also in the case where the side surface of the insulating layer 156 has a tapered shape, or specifically, a tapered shape with a taper angle less than 90°, than in the case where the insulating layer 156 has a perpendicular side surface, for example. As described above, the display device 100 can be fabricated by a high-yield method. Moreover, the display device 100 can have high reliability since generation of defects is inhibited therein.

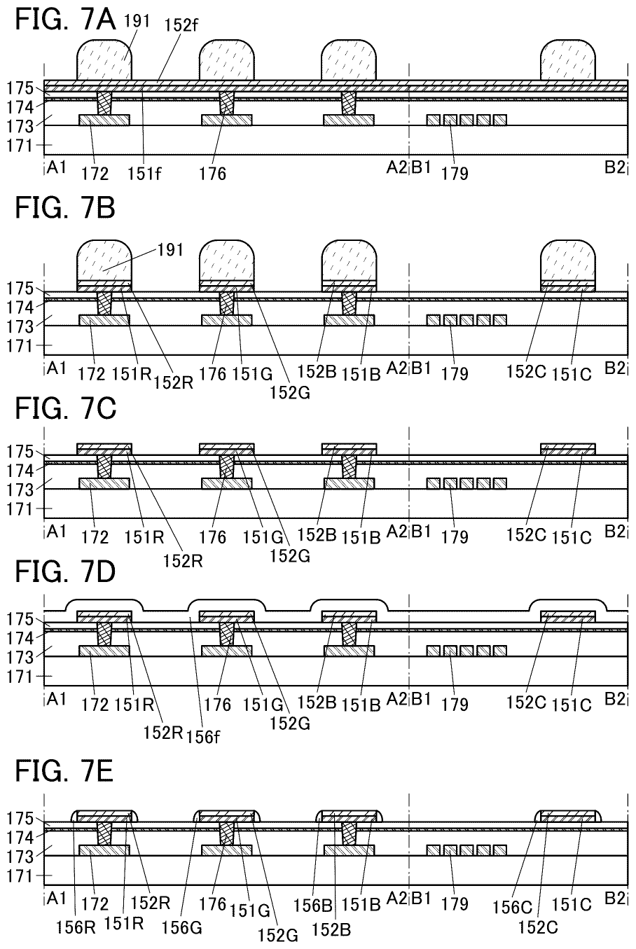

Next, an exemplary method for manufacturing the display device 100 having the structure illustrated in FIG. 6A is described with reference to FIG. 7A to FIG. 12C. An organic layer of the light-emitting device included in the display device 100 is formed by a manufacturing process including treatment using water. The use of the organic compound of one embodiment of the present invention for the organic layer of the light-emitting device included in the display device of one embodiment of the present invention prevents problems such as dissolution of the layer containing the organic compound and permeation of a chemical solution into the layer containing the organic compound even in the manufacturing process including treatment using water; consequently, the light-emitting device can have favorable characteristics.

### Manufacturing Method Example

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a plasma-enhanced CVD (PECVD) method and a thermal CVD method. An example of a thermal CVD method is a metal organic CVD (MOCVD) method.

Thin films included in the display device (e.g., insulating films, semiconductor films, and conductive films) can also be formed by a wet process such as spin coating, dipping, spray coating, ink-jetting, dispensing, screen printing, offset printing, doctor blade coating, slit coating, roll coating, curtain coating, or knife coating.

Specifically, for fabrication of the light-emitting device, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the hole-blocking layer, the light-emitting layer, the electron-blocking layer, the electron-transport layer, and the electron-injection layer) included in the organic compound layer can be formed by an evaporation method (e.g., a vacuum evaporation method), a coating method (e.g., a dip coating method, a die coating method, a bar coating method, a spin coating method, or a spray coating method), a printing method (e.g., ink-jetting, screen printing (stencil), offset printing (planography), flexography (relief printing), gravure printing, or micro-contact printing), or the like.

Thin films included in the display device can be processed by a photolithography method, for example. Alternatively, a nanoimprinting method, a sandblasting method, a lift-off method, or the like may be used to process thin films. Alternatively, island-shaped thin films may be directly formed by a film formation method using a shielding mask such as a metal mask.

As a lithography method, for example, a photolithography method can be used. There are two typical examples of photolithography methods. In one of the methods, a resist mask is formed over a thin film that is to be processed, the thin film is processed by etching, for example, and then the resist mask is removed. In the other method, a photosensitive thin film is formed and then processed into a desired shape by light exposure and development.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used. EUV, X-rays, or an electron beam is preferably used to enable extremely minute processing. When exposure is performed by scanning with a beam such as an electron beam, a photomask is not needed.

For etching of thin films, a dry etching method, a wet etching method, a sandblast method, or the like can be used.

In a fabrication process of a light-emitting device, an organic compound that is excited by absorbing light is handled. The excited organic compound reacts with water or oxygen in the air in some cases. In other words, when the organic compound is irradiated with light having a wavelength that is absorbed by the organic compound in the presence of oxygen, a degradation product might be generated in the organic compound.

In view of the above, in the case where a substrate provided with the organic compound is exposed to the air during processing by a photolithography method, the processing is preferably performed in an environment where lighting is controlled appropriately. The processing is ideally performed under lighting with a wavelength which does not excite the organic compound that would be excited by absorbing light; to ensure illuminance or color rendering properties high enough to prevent a reduction in work efficiency, as the lighting, a light source whose PL spectrum has the shortest-wavelength emission edge at 600 nm or shorter, preferably 580 nm or shorter is preferably used.

For the lighting, yellow light (light of a fluorescent lamp or light of a light-emitting diode (LED)) that does not include light with a wavelength shorter than 500 nm is preferably used, for example. Orange light which does not include light with a wavelength shorter than 530 nm is preferably used. As the light source used for the lighting, light of a low-pressure sodium lamp can also be used. Light of an incandescent lamp, light of a fluorescent lamp, light of a light-emitting diode (LED), light of a halogen lamp, or sunlight can be used, for example, as long as an optical filter that can block short-wavelength light is used. As the optical filter that can block short-wavelength light, for example, a band-pass filter or a long-pass filter (short-wavelength cut filter) can be used. The above lighting can result in low illuminance.

First, as illustrated in FIG. 7A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. When an insulating substrate is used, it is possible to use a glass substrate, a quartz substrate, a sapphire substrate, a ceramic substrate, an organic resin substrate, or the like. Alternatively, it is possible to use a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 7A, an opening reaching the conductive layer 172 is formed in the insulating layers 175, 174, and 173. Then, the plug 176 is formed to fill the opening.

Next, as illustrated in FIG. 7A, a conductive film 151f to be the conductive layers 151R, 151G, 151B, and 151C is formed over the plug 176 and the insulating layer 175. The conductive film 151f can be formed by a sputtering method or a vacuum evaporation method, for example. A metal material can be used for the conductive film 151f, for example.

Next, as illustrated in FIG. 7A, a conductive film 152f to be the conductive layers 152R, 152G, and 152B and a conductive layer 152C is formed over the conductive film 151f. The conductive film 152f can be formed by a sputtering method or a vacuum evaporation method, for example. A conductive oxide can be used for the conductive film 152f, for example. The conductive film 152f can have a stacked-layer structure of a film formed using a metal material and a film formed thereover using a conductive oxide. For example, the conductive film 152f can have a stacked-layer structure of a film formed using titanium, silver, or an alloy containing silver and a film formed thereover using a conductive oxide.

The conductive film 152f can be formed by an ALD method. In this case, for the conductive film 152f, an oxide containing one or more selected from indium, tin, zinc, gallium, titanium, aluminum, and silicon can be used. In this case, the conductive film 152f can be formed by repeating a cycle of introduction of a precursor (generally referred to as a metal precursor or the like in some cases), purge of the precursor, introduction of an oxidizer (generally referred to as a reactant, a non-metal precursor, or the like in some cases), and purge of the oxidizer. Here, in the case where an oxide film including a plurality of kinds of metals (e.g., an indium tin oxide film) is formed as the conductive film 152f, the composition of the metals can be controlled by varying the number of cycles for different kinds of precursors.

For example, in the case where an indium tin oxide film is formed as the conductive film 152f, after a precursor containing indium is introduced, the precursor is purged, and an oxidizer is introduced to form an In—O film, and then a precursor containing tin is introduced, the precursor is purged, and an oxidizer is introduced to form a Sn—O film. Here, when the number of cycles of forming an In—O film is larger than the number of cycles of forming a Sn—O film, the number of In atoms included in the conductive film 152f can be larger than the number of Sn atoms included therein.

For example, to form a zinc oxide film as the conductive film 152f, a Zn—O film is formed in the above procedure. For another example, to form an aluminum zinc oxide film as the conductive film 152f, a Zn—O film and an Al—O film are formed in the above procedure. For another example, to form a titanium oxide film as the conductive film 152f, a Ti—O film is formed in the above procedure. For another example, to form an indium tin oxide film including silicon as the conductive film 152f, an In—O film, a Sn—O film, and a Si—O film are formed in the above procedure. For another example, to form a zinc oxide film including gallium, a Ga—O film and a Zn—O film are formed in the above procedure.

As a precursor containing indium, it is possible to use, for example, triethylindium, trimethylindium, or [1,1,1-trimethyl-N-(trimethylsilyl)amide]-indium. As a precursor containing tin, it is possible to use, for example, tin chloride or tetrakis(dimethylamido)tin. As a precursor containing zinc, it is possible to use, for example, diethylzinc or dimethylzinc. As a precursor containing gallium, it is possible to use, for example, triethylgallium. As a precursor containing titanium, it is possible to use, for example, titanium chloride, tetrakis(dimethylamido) titanium, or tetraisopropyl titanate. As a precursor containing aluminum, it is possible to use, for example, aluminum chloride or trimethylaluminum. As a precursor containing silicon, it is possible to use, for example, trisilylamine, bis(diethylamino) silane, tris(dimethylamino) silane, bis(tert-butylamino) silane, or bis(ethylmethylamino) silane. As the oxidizer, water vapor, oxygen plasma, or an ozone gas can be used.

Subsequently, a resist mask 191 is formed over the conductive films 151f and 152f as illustrated in FIG. 7A. The resist mask 191 can be formed by application of a photosensitive material (photoresist), light exposure, and development.

Subsequently, as illustrated in FIG. 7B, the conductive films 151f and 152f in a region not overlapping with the resist mask 191, for example, are removed by an etching method, specifically, a dry etching method, for instance, so that the pixel electrodes each including the conductive layers 151 and 152 are formed. Note that in the case where the conductive film 151f includes a layer formed using a conductive oxide such as indium tin oxide, for example, the layer may be removed by a wet etching method. In this manner, the conductive layers 151 and 152 are formed. In the case where part of the conductive film 151f is removed by a dry etching method, for example, a depressed portion may be formed in a region of the insulating layer 175 not overlapping with the conductive layer 151.

The conductive film 152f may be processed by a lithography method to form the conductive layers 152R, 152G, 152B, and 152C, and then the conductive film 151f may be processed using the conductive layers 152R, 152G, 152B, and 152C as masks. Specifically, after a resist mask is formed, part of the conductive film 152f is removed by an etching method, for example. The conductive film 152f can be removed by a wet etching method, for example. The conductive film 152f may be removed by a dry etching method. After that, the conductive film 151f is preferably removed by a wet etching method.

Here, hydrophobization treatment is preferably performed on the conductive layer 152. The hydrophobization treatment can change the hydrophilic properties of the subject surface to hydrophobic properties or increase the hydrophobic properties of the subject surface. The hydrophobization treatment for the conductive layer 152 can increase the adhesion between the conductive layer 152 and the organic compound layer 103 formed in a later step and inhibit film peeling. Note that the hydrophobization treatment is not necessarily performed.

Next, the resist mask 191 is removed as illustrated in FIG. 7C. The resist mask 191 can be removed by ashing using oxygen plasma, for example. Alternatively, an oxygen gas and any of CF₄, C₄F₈, SF₆, CHF₃, Cl₂, H₂O, BCl₃, and a Group 18 element such as He may be used. Alternatively, the resist mask 191 may be removed by wet etching.

Then, as illustrated in FIG. 7D, an insulating film 156f to be the insulating layers 156R, 156G, and 156B and an insulating layer 156C is formed over the conductive layers 151R and 152R, the conductive layers 151G and 152G, the conductive layers 151B and 152B, the conductive layers 151C and 152C, and the insulating layer 175. The insulating film 156f can be formed by a CVD method, an ALD method, a sputtering method, or a vacuum evaporation method, for example.

For the insulating film 156f, an inorganic material can be used. As the insulating film 156f, an inorganic insulating film such as an oxide insulating film, a nitride insulating film, an oxynitride insulating film, or a nitride oxide insulating film can be used, for example. For example, an oxide insulating film including silicon, a nitride insulating film including silicon, an oxynitride insulating film including silicon, a nitride oxide insulating film including silicon, or the like can be used as the insulating film 156f. For the insulating film 156f, silicon oxynitride can be used, for example.

Subsequently, as illustrated in FIG. 7E, the insulating film 156f is processed to form the insulating layers 156R, 156G, 156B, and 156C. The insulating layer 156 can be formed by performing etching substantially uniformly on the top surface of the insulating film 156f, for example. Such uniform etching for planarization is also referred to as etch back treatment. Note that the insulating layer 156 may be formed by a lithography method.

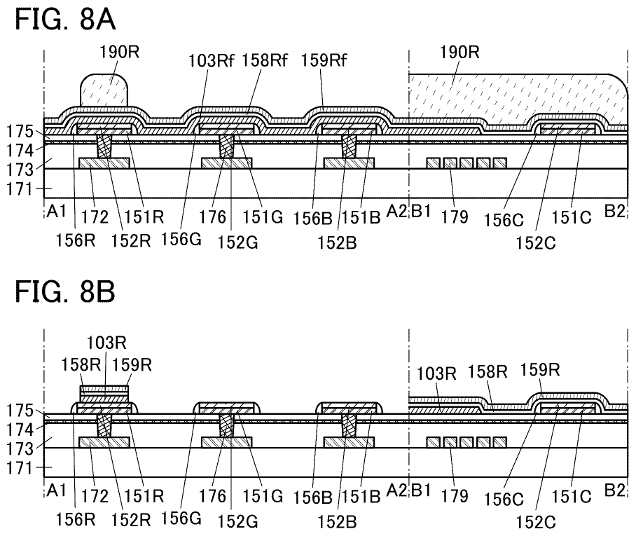

Next, as illustrated in FIG. 8A, an organic compound film 103Rf to be the organic compound layer 103R is formed over the conductive layers 152R, 152G, and 152B, the insulating layers 156R, 156G, and 156B, and the insulating layer 175.

As illustrated in FIG. 8A, the organic compound film 103Rf is not formed over the conductive layer 152C. For example, a mask for defining a film formation area (also referred to as an area mask, a rough metal mask, or the like to be distinguished from a fine metal mask) is used, so that the organic compound film 103Rf can be formed only in a desired region. Employing a film formation step using an area mask and a processing step using a resist mask enables a light-emitting device to be fabricated by a relatively easy process.

The organic compound film 103Rf can be formed by an evaporation method, specifically a vacuum evaporation method, for example. The organic compound film 103Rf may be formed by a transfer method, a printing method, an ink-jet method, a coating method, or the like.

Next, as illustrated in FIG. 8A, a sacrificial film 158Rf to be a sacrificial layer 158R and a mask film 159Rf to be a mask layer 159R are sequentially formed over the organic compound film 103Rf, the conductive layer 152C, and the insulating layer 175.

Although this embodiment shows an example in which a mask film having a two-layer structure of the sacrificial film 158Rf and the mask film 159Rf is formed, the mask film may have a single-layer structure or a stacked-layer structure of three or more layers.

Providing the sacrificial layer over the organic compound film 103Rf can reduce damage to the organic compound film 103Rf in the manufacturing process of the display device, resulting in an increase in the reliability of the light-emitting device.

As the sacrificial film 158Rf, a film that is highly resistant to the process conditions for the organic compound film 103Rf, specifically, a film having high etching selectivity with respect to the organic compound film 103Rfis used. For the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each lower than or equal to 200° C., preferably lower than or equal to 150° C., further preferably lower than or equal to 120° C., still further preferably lower than or equal to 100° C., and yet further preferably lower than or equal to 80° C.

The sacrificial film 158Rf and the mask film 159Rf are preferably films that can be removed by a wet etching method. The use of a wet etching method can reduce damage to the organic compound film 103Rf in processing of the sacrificial film 158Rf and the mask film 159Rf, as compared to the case of using a dry etching method.

The sacrificial film 158Rf and the mask film 159Rf can be formed by a sputtering method, an ALD method (including a thermal ALD method and a PEALD method), a CVD method, or a vacuum evaporation method, for example. Alternatively, the sacrificial film 158Rf and the mask film 159Rf may be formed by the above-described wet film formation method.

Note that the sacrificial film 158Rf formed over and in contact with the organic compound film 103Rf is preferably formed by a formation method that is less likely to damage the organic compound film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, an inorganic insulating film, and the like can be used, for example.

For each of the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. A metal material that can block ultraviolet rays is preferably used for one or both of the sacrificial film 158Rf and the mask film 159Rf, in which case the organic compound film 103Rf can be inhibited from being irradiated with ultraviolet rays and deteriorating.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Tl—Zn oxide), indium gallium tin zinc oxide (In—Ga—Sn—Zn oxide), or indium tin oxide containing silicon.

In place of gallium described above, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

As each of the sacrificial film and the mask film, a film including a material having a light-blocking property, particularly with respect to ultraviolet rays, is preferably used. Although a variety of materials such as a metal, an insulator, a semiconductor, and a metalloid that have a property of blocking ultraviolet rays can be used as a light-blocking material, each of the sacrificial film and the mask film is preferably a film capable of being processed by etching and is particularly preferably a film having good processability because part or the whole of each of the sacrificial film and the mask film is removed in a later step.

The sacrificial film and the mask film are preferably formed using a semiconductor material such as silicon or germanium, for example, for excellent compatibility with a semiconductor manufacturing process. Alternatively, an oxide or a nitride of the semiconductor material can be used. A non-metallic material such as carbon or a compound thereof can be used. A metal such as titanium, tantalum, tungsten, chromium, or aluminum or an alloy containing at least one of these metals can be used. Alternatively, an oxide containing the above-described metal, such as titanium oxide or chromium oxide, or a nitride such as titanium nitride, chromium nitride, or tantalum nitride can be used.

When a film including a material having a property of blocking ultraviolet rays is used as each of the sacrificial film and the mask film, the organic compound layer can be inhibited from being irradiated with ultraviolet rays in a light exposure step, for example. The organic compound layer is inhibited from being damaged by ultraviolet rays, so that the reliability of the light-emitting device can be improved.

The same effect is obtained when a film including a material having a property of blocking ultraviolet rays is used for a later-described inorganic insulating film 125f.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film. For example, an inorganic insulating material such as aluminum oxide, hafnium oxide, or silicon oxide can be used for the sacrificial film 158Rf and the mask film 159Rf. As the sacrificial film 158Rf and the mask film 159Rf, aluminum oxide films can be formed by an ALD method, for example. An ALD method is preferably used, in which case damage to a base (in particular, the organic compound layer) can be reduced.

For example, an inorganic insulating film (e.g., an aluminum oxide film) formed by an ALD method can be used as the sacrificial film 158Rf, and an inorganic film (e.g., an In—Ga—Zn oxide film, an aluminum film, or a tungsten film) formed by a sputtering method can be used as the mask film 159Rf.

The same inorganic insulating film can be used for both the sacrificial film 158Rf and the inorganic insulating layer 125 that is to be formed later. For example, an aluminum oxide film formed by an ALD method can be used for both the sacrificial film 158Rf and the inorganic insulating layer 125. For the sacrificial film 158Rf and the inorganic insulating layer 125, the same film formation conditions may be used or different film formation conditions may be used. For example, when the sacrificial film 158Rf is formed under conditions similar to those of the inorganic insulating layer 125, the sacrificial film 158Rf can be an insulating layer having a high barrier property against at least one of water and oxygen. Meanwhile, since the sacrificial film 158Rf is a layer a large part or the whole of which is to be removed in a later step, it is preferable that the processing of the sacrificial film 158Rf be easy. Therefore, the sacrificial film 158Rf is preferably formed with a substrate temperature lower than that for formation of the inorganic insulating layer 125.

One or both of the sacrificial film 158Rf and the mask film 159Rf may be formed using an organic material. For example, as the organic material, a material that can be dissolved in a solvent chemically stable with respect to at least the uppermost film of the organic compound film 103Rf may be used. Specifically, a material that will be dissolved in water or an alcohol can be suitably used. In forming a film of such a material, it is preferable to apply the material dissolved in a solvent such as water or an alcohol by a wet film formation method and then perform heat treatment for evaporating the solvent. At this time, the heat treatment is preferably performed in a reduced-pressure atmosphere, in which case the solvent can be removed at a low temperature in a short time and thermal damage to the organic compound film 103Rf can be reduced accordingly.

The sacrificial film 158Rf and the mask film 159Rf may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluorine resin like perfluoropolymer.

For example, an organic film (e.g., a PVA film) formed by an evaporation method or any of the above wet film formation methods can be used as the sacrificial film 158Rf, and an inorganic film (e.g., a silicon nitride film) formed by a sputtering method can be used as the mask film 159Rf. Subsequently, a resist mask 190R is formed over the mask film 159Rf as illustrated in FIG. 8A. The resist mask 190R can be formed by application of a photosensitive material (photoresist), light exposure, and development.

The resist mask 190R may be formed using either a positive resist material or a negative resist material.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display device. Note that the resist mask 190R is not necessarily provided over the conductive layer 152C. The resist mask 190R is preferably provided to cover the area from an end portion of the organic compound film 103Rf to an end portion of the conductive layer 152C (the end portion closer to the organic compound film 103Rf), as illustrated in the cross-sectional view along the line B1-B2 in FIG. 8A.

Next, as illustrated in FIG. 8B, part of the mask film 159Rf is removed using the resist mask 190R, so that the mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), whereby the sacrificial layer 158R is formed.

Each of the sacrificial film 158Rf and the mask film 159Rf can be processed by a wet etching method or a dry etching method. The sacrificial film 158Rf and the mask film 159Rf are preferably processed by isotropic etching.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a chemical solution containing a mixed solution of any of these acids, for example.

Since the organic compound film 103Rf is not exposed in the processing of the mask film 159Rf, the range of choices of processing methods for the mask film 159Rfis wider than that for the sacrificial film 158Rf. Specifically, even in the case where a gas containing oxygen is used as the etching gas in the processing of the mask film 159Rf, deterioration of the organic compound film 103Rf can be inhibited.

In the case of using a dry etching method to process the sacrificial film 158Rf, deterioration of the organic compound film 103Rf can be inhibited by not using a gas containing oxygen as the etching gas. In the case of using a dry etching method, it is preferable to use a gas containing CF₄, C₄F₈, SF₆, CHF₃, Cl₂, H₂O, BCl₃, or a Group 18 element such as He, for example, as the etching gas.

For example, in the case where an aluminum oxide film formed by an ALD method is used as the sacrificial film 158Rf, part of the sacrificial film 158Rf can be removed by a dry etching method using CHF₃ and He or using CHF₃, He, and CH₄. In the case where an In—Ga—Zn oxide film formed by a sputtering method is used as the mask film 159Rf, part of the mask film 159Rf can be removed by a wet etching method using diluted phosphoric acid. Alternatively, part of the mask film 159Rf may be removed by a dry etching method using CH₄ and Ar. Alternatively, part of the mask film 159Rf can be removed by a wet etching method using diluted phosphoric acid.

In the case where a tungsten film formed by a sputtering method is used as the mask film 159Rf, part of the mask film 159Rf can be removed by a dry etching method using SF₆, CF₄, and O₂ or using CF₄, Cl₂, and O₂.

The resist mask 190R can be removed by a method similar to that for the resist mask 191. For example, the resist mask 190R can be removed by ashing using oxygen plasma. Alternatively, an oxygen gas and any of CF₄, C₄F₈, SF₆, CHF₃, Cl₂, H₂O, BCl₃, and a Group 18 element such as He may be used. Alternatively, the resist mask 190R may be removed by wet etching. At this time, the sacrificial film 158Rf is located on the outermost surface, and the organic compound film 103Rf is not exposed; thus, the organic compound film 103Rf can be inhibited from being damaged in the step of removing the resist mask 190R. In addition, the range of choices of methods for removing the resist mask 190R can be widened.

Next, as illustrated in FIG. 8B, the organic compound film 103Rf is processed, so that the organic compound layer 103R is formed. For example, part of the organic compound film 103Rf is removed using the mask layer 159R and the sacrificial layer 158R as a hard mask, whereby the organic compound layer 103R is formed.

Accordingly, as illustrated in FIG. 8B, the stacked-layer structure of the organic compound layer 103R, the sacrificial layer 158R, and the mask layer 159R remains over the conductive layer 152R. The conductive layers 152G and 152B are exposed.

In the example illustrated in FIG. 8B, an end portion of the organic compound layer 103R is located inward from an end portion of the conductive layer 152R. With this structure, a pixel can be miniaturized, so that a high-resolution display can be formed. Although not illustrated in FIG. 8B, by the above etching treatment, a depressed portion may be formed in a region of the insulating layer 175 not overlapping with the organic compound layer 103R.

As described above, the resist mask 190R is preferably provided to cover the area from the end portion of the organic compound layer 103R to the end portion of the conductive layer 152C (the end portion closer to the organic compound layer 103R) in the cross section along the dashed-dotted line B1-B2. In that case, as illustrated in FIG. 8B, the sacrificial layer 158R and the mask layer 159R are provided to cover the area from the end portion of the organic compound layer 103R to the end portion of the conductive layer 152C (the end portion closer to the organic compound layer 103R) in the cross section along the dashed-dotted line B1-B2. Hence, the insulating layer 175 can be inhibited from being exposed in the cross section along the dashed-dotted line B1-B2, for example. This can prevent the insulating layers 175, 174, and 173 from being partly removed by etching or the like and thus prevent the conductive layer 179 from being exposed. Accordingly, the conductive layer 179 can be inhibited from being unintentionally electrically connected to another conductive layer. For example, a short circuit between the conductive layer 179 and a common electrode 155 formed in a later step can be inhibited.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

A gas containing oxygen may be used as the etching gas. When the etching gas contains oxygen, the etching rate can be increased. Thus, the etching can be performed under a low-power condition while an adequately high etching rate is maintained. Accordingly, damage to the organic compound film 103Rf can be reduced. Furthermore, a defect such as attachment of a reaction product generated during the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. For another example, a gas containing CF₄, He, and oxygen can be used as the etching gas. For another example, a gas containing H₂ and Ar and a gas containing oxygen can be used as the etching gas.

As described above, in one embodiment of the present invention, the mask layer 159R is formed in the following manner: the resist mask 190R is formed over the mask film 159Rf and part of the mask film 159Rf is removed using the resist mask 190R. After that, part of the organic compound film 103Rf is removed using the mask layer 159R as a hard mask, so that the organic compound layer 103R is formed. In other words, the organic compound layer 103R is formed by processing the organic compound film 103Rf by a lithography method. In addition, part of the organic compound film 103Rf may be removed using the resist mask 190R. Then, the resist mask 190R may be removed.

Next, hydrophobization treatment for the conductive layer 152G, for example, is preferably performed. At the time of processing the organic compound film 103Rf, the properties of a surface of the conductive layer 152G change to hydrophilic properties in some cases, for example. The hydrophobization treatment for the conductive layer 152G, for example, can increase the adhesion between the conductive layer 152G and a layer to be formed in a later step (which is the organic compound layer 103G here) and inhibit film peeling. Note that the hydrophobization treatment is not necessarily performed.

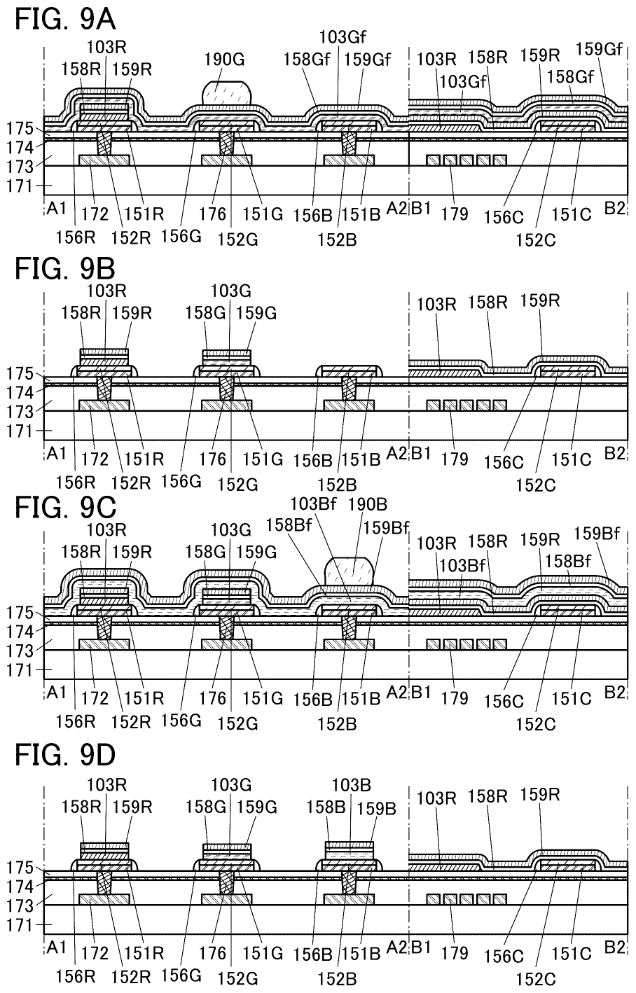

Next, as illustrated in FIG. 9A, an organic compound film 103Gf to be the organic compound layer 103G is formed over the conductive layers 152G and 152B, the insulating layers 156R, 156G, and 156B, the mask layer 159R, and the insulating layer 175.

The organic compound film 103Gf can be formed by a method similar to that for forming the organic compound film 103Rf. The organic compound film 103Gf can have a structure similar to that of the organic compound film 103Rf.

Then, as illustrated in FIG. 9A, a sacrificial film 158Gf to be a sacrificial layer 158G and a mask film 159Gf to be a mask layer 159G are sequentially formed over the organic compound film 103Gf and the mask layer 159R. After that, a resist mask 190G is formed. The materials and the formation methods of the sacrificial film 158Gf and the mask film 159Gf are similar to those for the sacrificial film 158Rf and the mask film 159Rf. The material and the formation method of the resist mask 190G are similar to those for the resist mask 190R.

The resist mask 190G is provided at a position overlapping with the conductive layer 152G.

Subsequently, as illustrated in FIG. 9B, part of the mask film 159Gf is removed using the resist mask 190G, so that the mask layer 159G is formed. The mask layer 159G remains over the conductive layer 152G. After that, the resist mask 190G is removed. Then, part of the sacrificial film 158Gf is removed using the mask layer 159G as a mask, whereby the sacrificial layer 158G is formed. Next, the organic compound film 103Gf is processed to form the organic compound layer 103G. For example, part of the organic compound film 103Gf is removed using the mask layer 159G and the sacrificial layer 158G as a hard mask to form the organic compound layer 103G.

Accordingly, as illustrated in FIG. 9B, the stacked-layer structure of the organic compound layer 103G, the sacrificial layer 158G, and the mask layer 159G remains over the conductive layer 152G. The mask layer 159R and the conductive layer 152B are exposed.

Next, hydrophobization treatment for the conductive layer 152B, for example, is preferably performed. At the time of processing the organic compound film 103Gf, the properties of a surface of the conductive layer 152B change to hydrophilic properties in some cases, for example. The hydrophobization treatment for the conductive layer 152B, for example, can increase the adhesion between the conductive layer 152B and a layer to be formed in a later step (which is the organic compound layer 103B here) and inhibit film peeling. Note that the hydrophobization treatment is not necessarily performed.

Next, as illustrated in FIG. 9C, an organic compound film 103Bf to be the organic compound layer 103B is formed over the conductive layer 152B, the mask layer 159R, the insulating layers 156R, 156G, and 156B, the mask layer 159G, and the insulating layer 175. The organic compound film 103Bf can be formed by a method similar to that for forming the organic compound film 103Rf. The organic compound film 103Bf can have a structure similar to that of the organic compound film 103Rf.

Then, as illustrated in FIG. 9C, a sacrificial film 158Bf to be a sacrificial layer 158B and a mask film 159Bf to be a mask layer 159B are sequentially formed over the organic compound film 103Bf and the mask layer 159R. After that, a resist mask 190B is formed. The materials and the formation methods of the sacrificial film 158Bf and the mask film 159Bf are similar to those for the sacrificial film 158Rf and the mask film 159Rf. The material and the formation method of the resist mask 190B are similar to those for the resist mask 190R.

The resist mask 190B is provided at a position overlapping with the conductive layer 152B.

Subsequently, as illustrated in FIG. 9D, part of the mask film 159Bf is removed using the resist mask 190B, whereby the mask layer 159B is formed. The mask layer 159B remains over the conductive layer 152B. After that, the resist mask 190B is removed. Then, part of the sacrificial film 158Bf is removed using the mask layer 159B as a mask, whereby the sacrificial layer 158B is formed. Next, the organic compound film 103Bf is processed to form the organic compound layer 103B. For example, part of the organic compound film 103Bf is removed using the mask layer 159B and the sacrificial layer 158B as a hard mask, whereby the organic compound layer 103B is formed.

Accordingly, as illustrated in FIG. 9D, the stacked-layer structure of the organic compound layer 103B, the sacrificial layer 158B, and the mask layer 159B remains over the conductive layer 152B. The mask layers 159R and 159G are exposed.

Note that the side surfaces of the organic compound layers 103R, 103G, and 103B are preferably perpendicular or substantially perpendicular to their formation surfaces. For example, the angle between the formation surfaces and these side surfaces is preferably greater than or equal to 60° and less than or equal to 90°.

The distance between two adjacent layers among the organic compound layers 103R, 103G, and 103B, which are formed by a lithography method as described above, can be reduced to less than or equal to 8 μm, less than or equal to 5 μm, less than or equal to 3 μm, less than or equal to 2 μm, or less than or equal to 1 um. Here, the distance can be specified, for example, by a distance between facing end portions of two adjacent layers among the organic compound layers 103R, 103G, and 103B. Reducing the distance between the island-shaped organic compound layers makes it possible to provide a display device having a high resolution and a high aperture ratio. In addition, the distance between the first electrodes of adjacent light-emitting devices can also be reduced to, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 um.

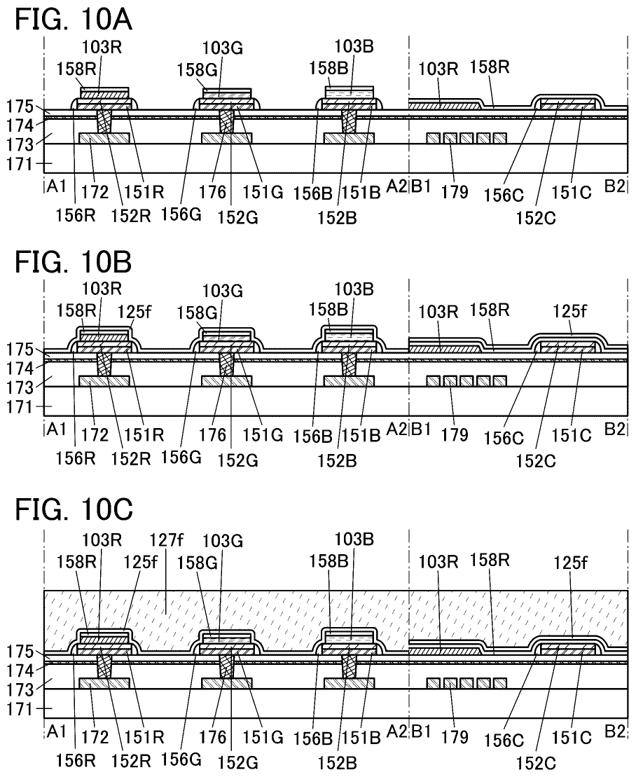

Next, as illustrated in FIG. 10A, the mask layers 159R, 159G, and 159B are preferably removed. The sacrificial layers 158R, 158G, and 158B and the mask layers 159R, 159G, and 159B remain in the display device in some cases depending on the subsequent steps. Removing the mask layers 159R, 159G, and 159B at this stage can inhibit the mask layers 159R, 159G, and 159B from being left in the display device. For example, in the case where a conductive material is used for the mask layers 159R, 159G, and 159B, removing the mask layers 159R, 159G, and 159B in advance can inhibit generation of a leakage current, formation of a capacitor, and the like due to the remaining mask layers 159R, 159G, and 159B.

This embodiment describes an example in which the mask layers 159R, 159G, and 159B are removed; however, the mask layers 159R, 159G, and 159B are not necessarily removed. For example, in the case where the mask layers 159R, 159G, and 159B include the above-described material having a property of blocking ultraviolet rays, the procedure preferably proceeds to the next step without removing the mask layers 159R, 159G, and 159B, in which case the organic compound layers can be protected from ultraviolet rays.

The step of removing the mask layers can be performed by a method similar to that for the step of processing the mask films. Specifically, by using a wet etching method, damage to the organic compound layers 103R, 103G, and 103B at the time of removing the mask layers can be reduced as compared to the case of using a dry etching method.

The mask layers may be removed by being dissolved in a solvent such as water or an alcohol. Examples of an alcohol include ethyl alcohol, methyl alcohol, isopropyl alcohol (IPA), and glycerin.

After the mask layers are removed, drying treatment may be performed in order to remove water included in the organic compound layers 103R, 103G, and 103B and water adsorbed onto the surfaces of the organic compound layers 103R, 103G, and 103B. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, as illustrated in FIG. 10B, the inorganic insulating film 125f to be the inorganic insulating layer 125 is formed to cover the organic compound layers 103R, 103G, and 103B and the sacrificial layers 158R, 158G, and 158B.

As described later, an insulating film to be the insulating layer 127 is formed in contact with the top surface of the inorganic insulating film 125f. Therefore, the top surface of the inorganic insulating film 125f preferably has a high affinity for the material used for the insulating film (e.g., a photosensitive resin composition containing an acrylic resin). To improve the affinity, surface treatment is preferably performed so that the top surface of the inorganic insulating film 125f is made hydrophobic (or its hydrophobic property is improved). For example, it is preferable to perform the treatment using a silylation agent such as hexamethyldisilazane (HMDS). By making the top surface of the inorganic insulating film 125f hydrophobic in such a manner, an insulating film 127f can be formed with favorable adhesion. Note that the above-described hydrophobization treatment may be performed as the surface treatment.

Then, as illustrated in FIG. 10C, the insulating film 127f to be the insulating layer 127 is formed over the inorganic insulating film 125f.

The inorganic insulating film 125f and the insulating film 127f are preferably formed by a formation method by which the organic compound layers 103R, 103G, and 103B are less damaged. The inorganic insulating film 125f, which is formed in contact with the side surfaces of the organic compound layers 103R, 103G, and 103B, is particularly preferably formed by a formation method that causes less damage to the organic compound layers 103R, 103G, and 103B than the formation method of the insulating film 127f.

Each of the inorganic insulating film 125f and the insulating film 127f is formed at a temperature lower than the upper temperature limits of the organic compound layers 103R, 103G, and 103B. When the inorganic insulating film 125f is formed at a high substrate temperature, the formed inorganic insulating film 125f, even with a small thickness, can have a low impurity concentration and a high barrier property against at least one of water and oxygen. The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case film formation damage is reduced and a film with good coverage can be formed. As the inorganic insulating film 125f, an aluminum oxide film is preferably formed by an ALD method, for example.

Alternatively, the inorganic insulating film 125f may be formed by a sputtering method, a CVD method, or a PECVD method, each of which has a higher deposition rate than an ALD method. In that case, a highly reliable display device can be manufactured with high productivity.

The insulating film 127f is preferably formed by the aforementioned wet process. The insulating film 127f is preferably formed by spin coating using a photosensitive material, for example, and specifically preferably formed using a photosensitive resin composition containing an acrylic resin.

The insulating film 127f is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 127f is formed. The heat treatment is performed at a temperature lower than the upper temperature limits of the organic compound layers 103R, 103G, and 103B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, the solvent included in the insulating film 127f can be removed.

Then, part of the insulating film 127f is exposed to visible light or ultraviolet rays. Here, when a positive photosensitive resin composition containing an acrylic resin is used for the insulating film 127f, a region where the insulating layer 127 is not formed in a later step is irradiated with visible light or ultraviolet rays. The insulating layer 127 is formed in regions that are interposed between any two of the conductive layers 152R, 152G, and 152B and around the conductive layer 152C. Thus, the top surfaces of the conductive layers 152R, 152G, 152B, and 152C are irradiated with visible light or ultraviolet rays. Note that when a negative photosensitive material is used for the insulating film 127f, the region where the insulating layer 127 is to be formed is irradiated with visible light or ultraviolet rays.

The width of the insulating layer 127 formed later can be controlled with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). Furthermore, light used for the exposure may include at least one of the g-line (wavelength: 436 nm) and the h-line (wavelength: 405 nm).

Here, when a barrier insulating layer against oxygen (e.g., an aluminum oxide film) is provided as one or both of the sacrificial layer 158 (the sacrificial layers 158R, 158G, and 158B) and the inorganic insulating film 125f, diffusion of oxygen into the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen may be bonded to the organic compound included in the organic compound layer. By providing the sacrificial layer 158 and the inorganic insulating film 125f over the island-shaped organic compound layer, bonding of oxygen in the atmosphere to the organic compound included in the organic compound layer can be inhibited.

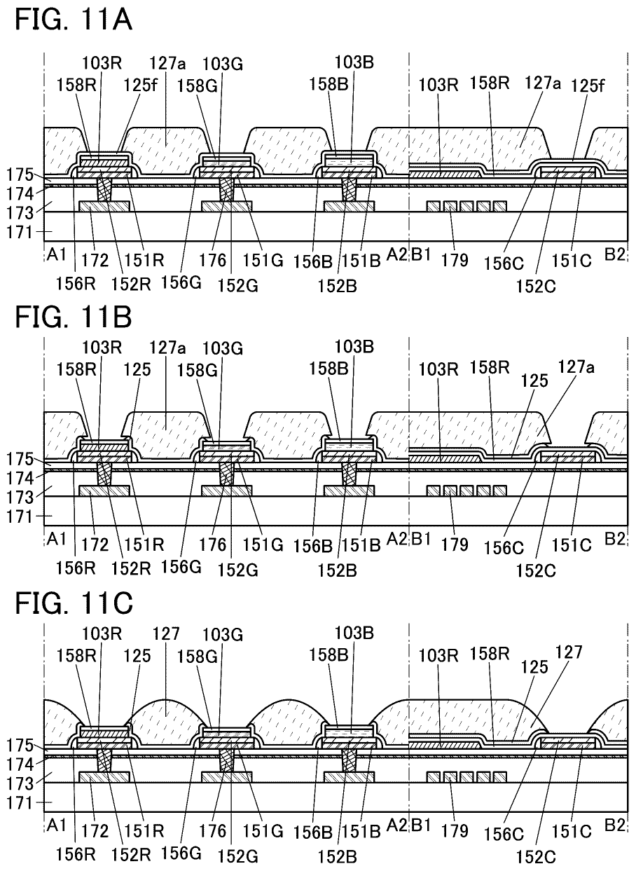

Next, as illustrated in FIG. 11A, development is performed to remove the exposed region of the insulating film 127f, so that an insulating layer 127a is formed. The insulating layer 127a is formed in regions that are sandwiched between any two of the conductive layers 152R, 152G, and 152B and a region surrounding the conductive layer 152C. Here, when an acrylic resin is used for the insulating film 127f, an alkaline solution, such as TMAH, can be used as a developer.

Then, a residue (scum) due to the development may be removed. For example, the residue can be removed by ashing using oxygen plasma.

Etching may be performed to adjust the surface level of the insulating layer 127a. The insulating layer 127a may be processed by ashing using oxygen plasma, for example. In the case where a non-photosensitive material is used for the insulating film 127f, the surface level of the insulating film 127f can be adjusted by the ashing, for example.

Next, as illustrated in FIG. 11B, etching treatment is performed using the insulating layer 127a as a mask to remove part of the inorganic insulating film 125f and reduce the thickness of part of the sacrificial layers 158R, 158G, and 158B. Thus, the inorganic insulating layer 125 is formed under the insulating layer 127a. Moreover, the surfaces of the thin portions of the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that for the sacrificial layers 158R, 158G, and 158B, in which case the first etching treatment can be performed concurrently.

By etching using the insulating layer 127a with a tapered side surface as a mask, the side surface of the inorganic insulating layer 125 and upper end portions of the side surfaces of the sacrificial layers 158R, 158G, and 158B can each be made to have a tapered shape relatively easily.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel-plate electrodes can be used. The capacitively coupled plasma etching apparatus including parallel-plate electrodes may have a structure where a high-frequency voltage is applied to one of the parallel-plate electrodes. Alternatively, the capacitively coupled plasma etching apparatus may have a structure where different high-frequency voltages are applied to one of the parallel-plate electrodes. Alternatively, the capacitively coupled plasma etching apparatus may have a structure where high-frequency voltages with the same frequency are applied to the parallel-plate electrodes. Alternatively, the capacitively coupled plasma etching apparatus may have a structure where high-frequency voltages with different frequencies are applied to the parallel-plate electrodes.

In the case of performing dry etching, a by-product or the like generated by the dry etching is sometimes deposited on the top surface and the side surface of the insulating layer 127a, for example. Accordingly, a component of the etching gas, a component of the inorganic insulating film 125f, a component of the sacrificial layers 158R, 158G, and 158B, and the like are included in the insulating layer 127 in the completed display device in some cases.

The first etching treatment is preferably performed by wet etching. The use of wet etching can reduce damage to the organic compound layers 103R, 103G, and 103B, as compared to the case of using dry etching. Wet etching can be performed using an alkaline solution, for example. For instance, TMAH, which is an alkaline solution, can be used for the wet etching of an aluminum oxide film. In this case, puddle wet etching can be performed. Note that the inorganic insulating film 125f is preferably formed using a material similar to that for the sacrificial layers 158R, 158G, and 158B, in which case the above etching treatment can be performed concurrently.

The sacrificial layers 158R, 158G, and 158B are not removed completely by the first etching treatment, and the etching treatment is stopped when the thickness of the sacrificial layers 158R, 158G, and 158B is reduced. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (e.g., an aluminum oxide film) exists as each of the sacrificial layers 158R, 158G, and 158B, diffusion of oxygen to the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen may be bonded to the organic compound included in the organic compound layer. By providing the sacrificial layers 158R, 158G, and 158B over the island-shaped organic compound layers, bonding of oxygen in the atmosphere to the organic compounds included in the organic compound layers can be inhibited.

Then, heat treatment (also referred to as post-baking) is performed. The heat treatment can change the insulating layer 127a into the insulating layer 127 having a tapered side surface (FIG. 11C). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. The substrate temperature in the heat treatment of this step is preferably higher than that in the heat treatment (prebaking) after the formation of the insulating film 127f. Accordingly, adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the organic compound layers 103R, 103G, and 103B can be prevented from being damaged and deteriorating in the heat treatment. This can increase the reliability of the light-emitting devices.

The side surface of the insulating layer 127 may have a concave shape depending on the material of the insulating layer 127 and the temperature, time, and atmosphere of the post-baking. For example, when the temperature of the post-baking is higher or the duration of the post-baking is longer, the insulating layer 127 is more likely to change in shape and thus a concave shape may be more likely to be formed.

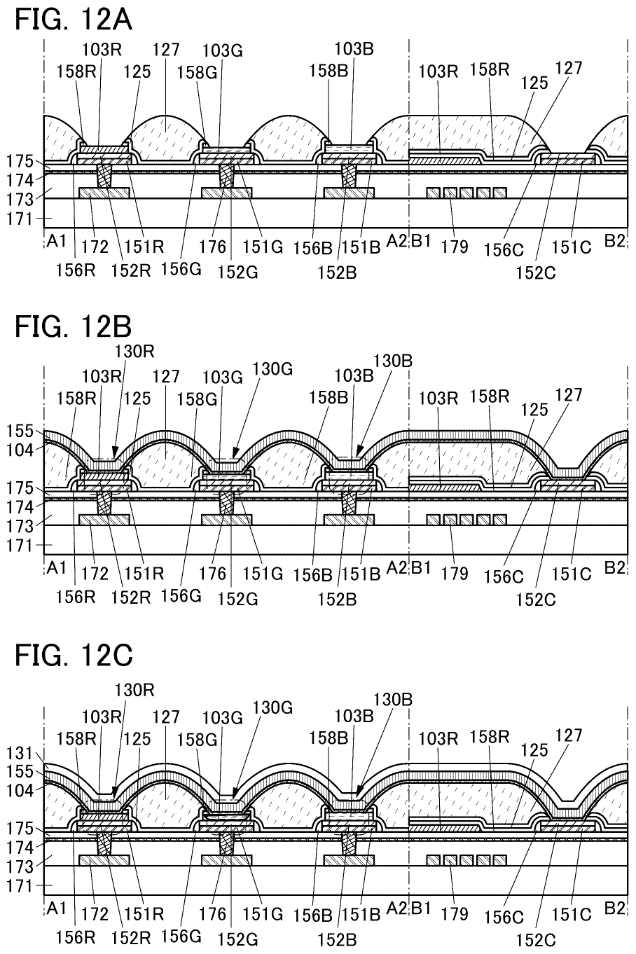

Next, as illustrated in FIG. 12A, etching treatment is performed using the insulating layer 127 as a mask to partly remove the sacrificial layers 158R, 158G, and 158B. Note that part of the inorganic insulating layer 125 is also removed in some cases. Thus, openings are formed in the sacrificial layers 158R, 158G, and 158B, and the top surfaces of the organic compound layers 103R, 103G, and 103B and the conductive layer 152C are exposed. Note that the etching treatment using the insulating layer 127 as a mask may be hereinafter referred to as second etching treatment.

An end portion of the inorganic insulating layer 125 is covered with the insulating layer 127. FIG. 12A illustrates an example where part of an end portion of the sacrificial layer 158G (specifically a tapered portion formed by the first etching treatment) is covered with the insulating layer 127 and a tapered portion formed by the second etching treatment is exposed.

If the first etching treatment is not performed and the inorganic insulating layer 125 and the mask layer are collectively etched after the post-baking, the inorganic insulating layer 125 and the mask layer under an end portion of the insulating layer 127 may disappear because of side etching and a void may be formed. The void causes unevenness on the formation surface of the common electrode 155, so that step disconnection is more likely to be caused in the common electrode 155. Even when a void is formed owing to side etching of the inorganic insulating layer 125 and the mask layer by the first etching treatment, the post-baking performed subsequently can make the insulating layer 127 fill the void. After that, the thinned mask layer is etched by the second etching treatment; thus, the amount of side etching decreases, a void is less likely to be formed, and even if a void is formed, it can be extremely small. Consequently, the formation surface of the common electrode 155 can be made flatter.

Note that the insulating layer 127 may cover the entire end portion of the sacrificial layer 158G. For example, the end portion of the insulating layer 127 may droop to cover the end portion of the sacrificial layer 158G. For another example, the end portion of the insulating layer 127 may be in contact with the top surface of at least one of the organic compound layers 103R, 103G, and 103B. As described above, when light exposure is not performed on the insulating layer 127a after the development, the shape of the insulating layer 127 may be likely to change.

The second etching treatment is performed by wet etching. The use of wet etching can reduce damage to the organic compound layers 103R, 103G, and 103B, as compared to the case of using dry etching. Wet etching can be performed using an alkaline solution such as TMAH, for example.

Meanwhile, in the case where the second etching treatment is performed by a wet etching method and gaps due to, for example, poor adhesion between the organic compound layer 103 and another layer exist at the interface between the organic compound layer 103 and the sacrificial layer 158, the interface between the organic compound layer 103 and the inorganic insulating layer 125, and the interface between the organic compound layer 103 and the insulating layer 175, the chemical solution used in the second etching treatment sometimes enters the gaps to come into contact with the pixel electrode. Here, when the chemical solution comes into contact with both the conductive layer 151 and the conductive layer 152, one of the conductive layers 151 and 152 that has a lower spontaneous potential than the other suffers from galvanic corrosion in some cases. For example, when the conductive layer 151 is formed using aluminum and the conductive layer 152 is formed using indium tin oxide, the conductive layer 152 sometimes corrodes. As a result, the yield of the display device decreases in some cases. Moreover, the reliability of the display device decreases in some cases.

When the insulating layer 156 is formed to have a region overlapping with the side surface of the conductive layer 151 and the insulating layer 156 is formed to cover the side surfaces of the conductive layers 151 and 152 as described above, step disconnection in the inorganic insulating layer 125 can be prevented, whereby the chemical solution can be prevented from coming into contact with a lower-layer structure such as the conductive layer 151 in the second etching treatment, for example. Thus, corrosion of the pixel electrode can be prevented.

As described above, by providing the insulating layer 127, the inorganic insulating layer 125, and the sacrificial layers 158R, 158G, and 158B, poor connection due to a disconnected portion and an increase in electrical resistance due to a locally thinned portion can be inhibited from occurring in the common electrode 155 between the light-emitting devices. Thus, the display device of one embodiment of the present invention can have improved display quality.

Heat treatment is performed after the organic compound layers 103R, 103G, and 103B are partly exposed. By the heat treatment, water included in the organic compound layers and water adsorbed onto the surfaces of the organic compound layers, for example, can be removed. The shape of the insulating layer 127 may be changed by the heat treatment. Specifically, the insulating layer 127 may be widened to cover at least one of the end portion of the inorganic insulating layer 125, the end portions of the sacrificial layers 158R, 158G, and 158B, and the top surfaces of the organic compound layers 103R, 103G, and 103B.

If the temperature of the heat treatment is too low, water included in the organic compound layers and water adsorbed onto the surfaces of the organic compound layers, for example, cannot be sufficiently removed. If the temperature of the heat treatment is too high, the organic compound layer 103 may deteriorate and the insulating layer 127 may change in shape excessively. Therefore, the temperature of the heat treatment is preferably higher than the temperature at which water is released from the organic compound layer 103 and lower than the glass transition temperature of the organic compound included in the organic compound layer 103, further preferably lower than the glass transition temperature of the organic compound included in the upper surface of the organic compound layer 103. Specifically, the substrate temperature is preferably higher than or equal to 80° C. and lower than or equal to 130° C., further preferably higher than or equal to 90° C. and lower than or equal to 120° C., still further preferably higher than or equal to 100° C. and lower than or equal to 120° C., and yet still further preferably higher than or equal to 100° C. and lower than or equal to 110° C. The heating atmosphere may be an air atmosphere or an inert gas atmosphere. Although the heating atmosphere may be an atmospheric-pressure atmosphere or a reduced-pressure atmosphere, a reduced-pressure atmosphere is preferably employed to prevent re-adsorption of water released from the organic compound layer 103.

By the heat treatment, water included in the organic compound layers and water adsorbed onto the surfaces of the organic compound layers, for example, can be sufficiently removed without deterioration of the organic compound layers 103R, 103G, and 103B and an excessive change in the shape of the insulating layer 127. Thus, degradation of the characteristics of the light-emitting device can be prevented.

Next, as illustrated in FIG. 12B, the common layer 104 and the common electrode 155 are formed over the organic compound layers 103R, 103G, and 103B, the conductive layer 152C, and the insulating layer 127. The common layer 104 and the common electrode 155 can be formed by a sputtering method, a vacuum evaporation method, or the like. The common layer 104 may be formed by an evaporation method while the common electrode 155 may be formed by a sputtering method.

Next, as illustrated in FIG. 12C, the protective layer 131 is formed over the common electrode 155. The protective layer 131 can be formed by a vacuum evaporation method, a sputtering method, a CVD method, an ALD method, or the like. Note that the protective layer 131 may also function as a cap layer. The protective layer 131 functioning as the cap layer can be inhibited from totally reflecting light from the organic compound layer 103 by using, for the protective layer 131, a material whose ordinary refractive index (no) at a wavelength of 450 nm is greater than or equal to 1.90, ordinary refractive index (no) at a wavelength of 520 nm is greater than or equal to 1.80, or ordinary refractive index (no) at a wavelength of 630 nm is greater than or equal to 1.75, which leads to an improvement in light extraction efficiency, for example.

In order to prevent air exposure of the light-emitting device that has yet to be incorporated in a display device or a light-emitting apparatus, a sealing film may be provided over the protective layer 131. The sealing film can be formed using a material that is less likely to transmit impurities such as water easily. Specifically, an aluminum oxide film is preferably provided by an ALD method. Providing the sealing film can inhibit entry of impurities into the light-emitting device.

Then, the substrate 120 bonds to the protective layer 131 or the sealing film using the resin layer 122, so that the display device can be manufactured. In the method for manufacturing the display device of one embodiment of the present invention, the insulating layer 156 is provided on the side surfaces of the conductive layer 151 and the conductive layer 152 as described above. This can increase the yield of the display device and inhibit generation of defects.

As described above, in the method for manufacturing the display device of one embodiment of the present invention, the island-shaped organic compound layers 103R, 103G, and 103B are formed not by using a fine metal mask but by processing a film formed on the entire surface; thus, the island-shaped layers can be formed to have a uniform thickness. In addition, a high-resolution display device or a display device with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of leakage current between the subpixels can be inhibited. This can prevent crosstalk, so that a display device with extremely high contrast can be obtained. Moreover, even a display device that includes tandem light-emitting devices formed by a lithography method can have favorable characteristics.

The structure described in this embodiment can be used in combination with any of the structures described in other embodiments as appropriate.

### Embodiment 4

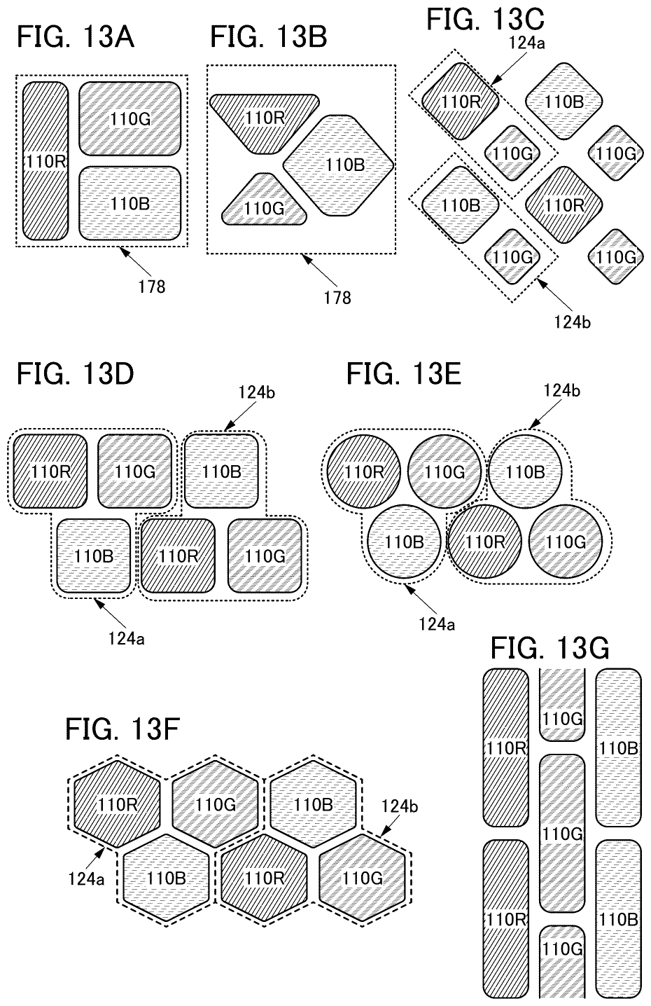

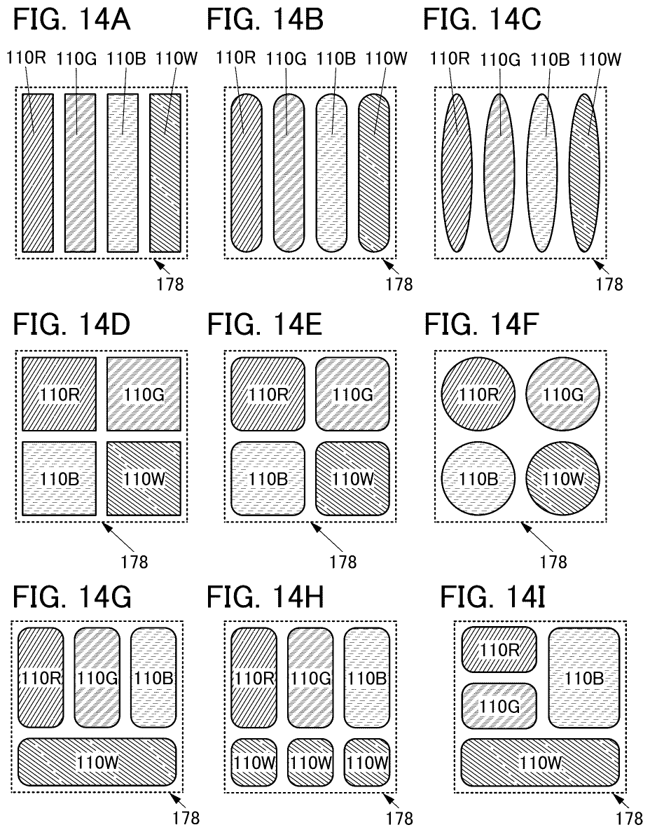

In this embodiment, the light-emitting apparatus of one embodiment of the present invention will be described with reference to FIGS. 13A to 13G and FIGS. 14A to 14I.

### [Pixel Layout]

In this embodiment, pixel layouts different from that in FIG. 6A will be mainly described. There is no particular limitation on the subpixel layout, and a variety of methods can be employed.

Examples of the subpixel layout include stripe layout, S-stripe layout, matrix layout, delta layout, Bayer layout, and PenTile layout.

In this embodiment, the top surface shapes of the subpixels shown in the diagrams correspond to top surface shapes of light-emitting regions.

Examples of a top surface shape of the subpixel include polygons such as a triangle, a tetragon (including a rectangle and a square), and a pentagon; these polygons with rounded corners; an ellipse; and a circle.

The circuit constituting the subpixel is not necessarily placed within the dimensions of the subpixel illustrated in the diagrams and may be placed outside the subpixel.

The pixel 178 illustrated in FIG. 13A employs S-stripe layout. The pixel 178 illustrated in FIG. 13A includes three subpixels, the subpixel 110R, the subpixel 110G, and the subpixel 110B.

The pixel 178 illustrated in FIG. 13B includes the subpixel 110R whose top surface has a rough trapezoidal or rough triangle shape with rounded corners, the subpixel 110G whose top surface has a rough trapezoidal or rough triangle shape with rounded corners, and the subpixel 110B whose top surface has a rough tetragonal or rough hexagonal shape with rounded corners. The subpixel 110R has a larger light-emitting area than the subpixel 110G. In this manner, the shapes and sizes of the subpixels can be determined independently. For example, the size of a subpixel including a light-emitting device with higher reliability can be smaller.

Pixels 124a and 124b illustrated in FIG. 13C employ PenTile layout. FIG. 13C illustrates an example in which the pixels 124a including the subpixels 110R and 110G and the pixels 124b including the subpixels 110G and 110B are alternately arranged.

The pixels 124a and 124b illustrated in FIGS. 13D to 13F employ delta layout. The pixel 124a includes two subpixels (the subpixels 110R and 110G) in the upper row (first row) and one subpixel (the subpixel 110B) in the lower row (second row). The pixel 124b includes one subpixel (the subpixel 110B) in the upper row (first row) and two subpixels (the subpixels 110R and 110G) in the lower row (second row).

FIG. 13D illustrates an example where the top surface of each subpixel has a rough tetragonal shape with rounded corners. FIG. 13E illustrates an example where the top surface of each subpixel is circular. FIG. 13F illustrates an example where the top surface of each subpixel has a rough hexagonal shape with rounded corners.

In FIG. 13F, subpixels are placed in respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110R, the subpixel 110R is surrounded by three subpixels 110G and three subpixels 110B that are alternately arranged.

FIG. 13G illustrates an example where subpixels of different colors are arranged in a zigzag manner. Specifically, the positions of the top sides of two subpixels arranged in the row direction (e.g., the subpixels 110R and 110G or the subpixels 110G and 110B) are not aligned in the top view.

In the pixels illustrated in FIGS. 13A to 13G, for example, it is preferable that the subpixel 110R be a subpixel R that emits red light, the subpixel 110G be a subpixel G that emits green light, and the subpixel 110B be a subpixel B that emits blue light. Note that the structures of the subpixels are not limited thereto, and the colors and the order of the subpixels can be determined as appropriate. For example, the subpixel 110G may be the subpixel R emitting red light, and the subpixel 110R may be the subpixel G emitting green light.

In a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for manufacturing the light-emitting apparatus of one embodiment of the present invention, the organic compound layer is processed into an island shape with the use of a resist mask. A resist film formed over the organic compound layer needs to be cured at a temperature lower than the upper temperature limit of the organic compound layer. Therefore, the resist film is insufficiently cured in some cases depending on the upper temperature limit of the material of the organic compound layer and the curing temperature of the resist material. An insufficiently cured resist film may have a shape different from a desired shape by processing. As a result, the top surface of the organic compound layer may have a polygonal shape with rounded corners, an elliptical shape, a circular shape, or the like. For example, when a resist mask with a square top surface is intended to be formed, a resist mask with a circular top surface may be formed, and the top surface of the organic compound layer may be circular.

To obtain a desired top surface shape of the organic compound layer, a technique of correcting a mask pattern in advance so that a transferred pattern agrees with a design pattern (an optical proximity correction (OPC) technique) may be used. Specifically, with the OPC technique, a pattern for correction is added to a corner portion of a figure on a mask pattern, for example.

As illustrated in FIGS. 14A to 14I, the pixel can include four types of subpixels.

The pixels 178 illustrated in FIGS. 14A to 14C employ stripe layout.

FIG. 14A illustrates an example where each subpixel has a rectangular top surface shape. FIG. 14B illustrates an example where each subpixel has a top surface shape formed by combining two half circles and a rectangle. FIG. 14C illustrates an example where each subpixel has an elliptical top surface shape.

The pixels 178 illustrated in FIGS. 14D to 14F employ matrix layout.

FIG. 14D illustrates an example where each subpixel has a square top surface shape. FIG. 14E illustrates an example where each subpixel has a substantially square top surface shape with rounded corners. FIG. 14F illustrates an example where each subpixel has a circular top surface shape.

FIGS. 14G and 14H each illustrate an example where one pixel 178 is composed of two rows and three columns.

The pixel 178 illustrated in FIG. 14G includes three subpixels (the subpixels 110R, 110G, and 110B) in the upper row (first row) and one subpixel (a subpixel 110W) in the lower row (second row). In other words, the pixel 178 includes the subpixel 110R in the left column (first column), the subpixel 110G in the middle column (second column), the subpixel 110B in the right column (third column), and the subpixel 110W across these three columns.

The pixel 178 illustrated in FIG. 14H includes three subpixels (the subpixels 110R, 110G, and 110B) in the upper row (first row) and three of the subpixels 110W in the lower row (second row). In other words, the pixel 178 includes the subpixels 110R and 110W in the left column (first column), the subpixels 110G and 110W in the middle column (second column), and the subpixels 110B and 110W in the right column (third column). Matching the positions of the subpixels in the upper row and the lower row as illustrated in FIG. 14H enables dust that would be produced in the fabrication process, for example, to be removed efficiently. Thus, a light-emitting apparatus having high display quality can be provided.

In the pixel 178 illustrated in each of FIGS. 14G and 14H, the subpixels 110R, 110G, and 110B are arranged in a stripe layout, whereby the display quality can be improved.

FIG. 14I illustrates an example where one pixel 178 is composed of three rows and two columns.

The pixel 178 illustrated in FIG. 14I includes the subpixel 110R in the upper row (first row), the subpixel 110G in the middle row (second row), the subpixel 110B across the first row and the second row, and one subpixel (the subpixel 110W) in the lower row (third row). In other words, the pixel 178 includes the subpixels 110R and 110G in the left column (first column), the subpixel 110B in the right column (second column), and the subpixel 110W across these two columns.

In the pixel 178 illustrated in FIG. 141, the subpixels 110R, 110G, and 110B are arranged in what is called an S-stripe layout, whereby the display quality can be improved.

The pixel 178 illustrated in each of FIGS. 14A to 14I is composed of four kinds of subpixels, which are the subpixels 110R, 110G, 110B, and 110W. For example, the subpixel 110R can be a subpixel that emits red light, the subpixel 110G can be a subpixel that emits green light, the subpixel 110B can be a subpixel that emits blue light, and the subpixel 110W can be a subpixel that emits white light. Note that at least one of the subpixels 110R, 110G, 110B, and 110W may be a subpixel that emits cyan light, magenta light, yellow light, or near-infrared light.

As described above, the pixel composed of the subpixels each including the light-emitting device can employ any of a variety of layouts in the light-emitting apparatus of one embodiment of the present invention.

This embodiment can be combined as appropriate with the other embodiments or the examples. In this specification, in the case where a plurality of structure examples are shown in one embodiment, the structure examples can be combined as appropriate.

### Embodiment 5

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

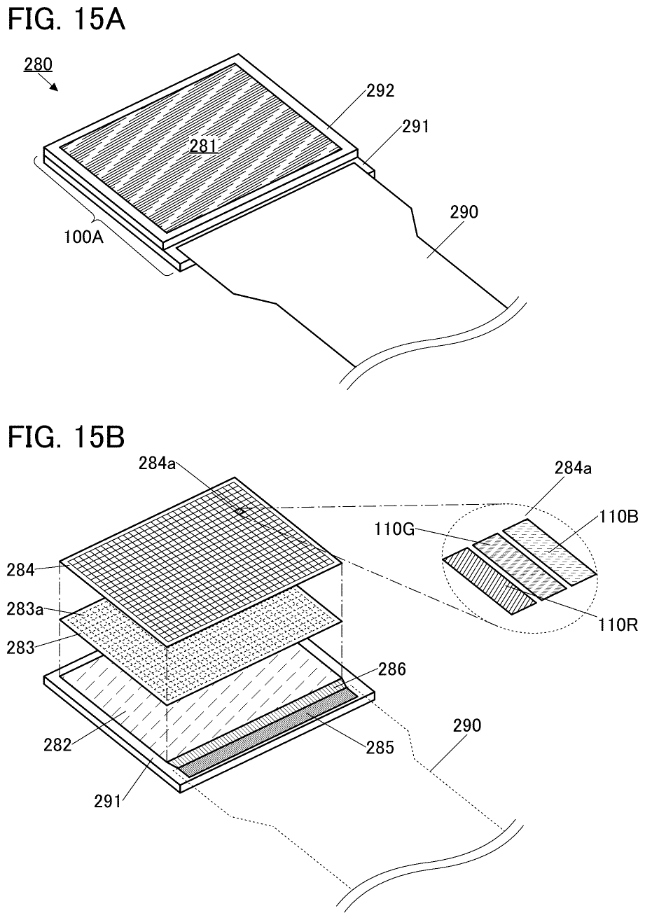

FIG. 15A is a perspective view of a display module 280. The display module 280 includes a display device 100A and an FPC 290. Note that the display device included in the display module 280 is not limited to the display device 100A and may be any of display devices 100B to 100E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 15B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 15B. The pixels 284a can employ any of the structures described in the above embodiments. FIG. 15B illustrates an example where the pixel 284a has a structure similar to that of the pixel 178 illustrated in FIG. 6A.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Device 100A]

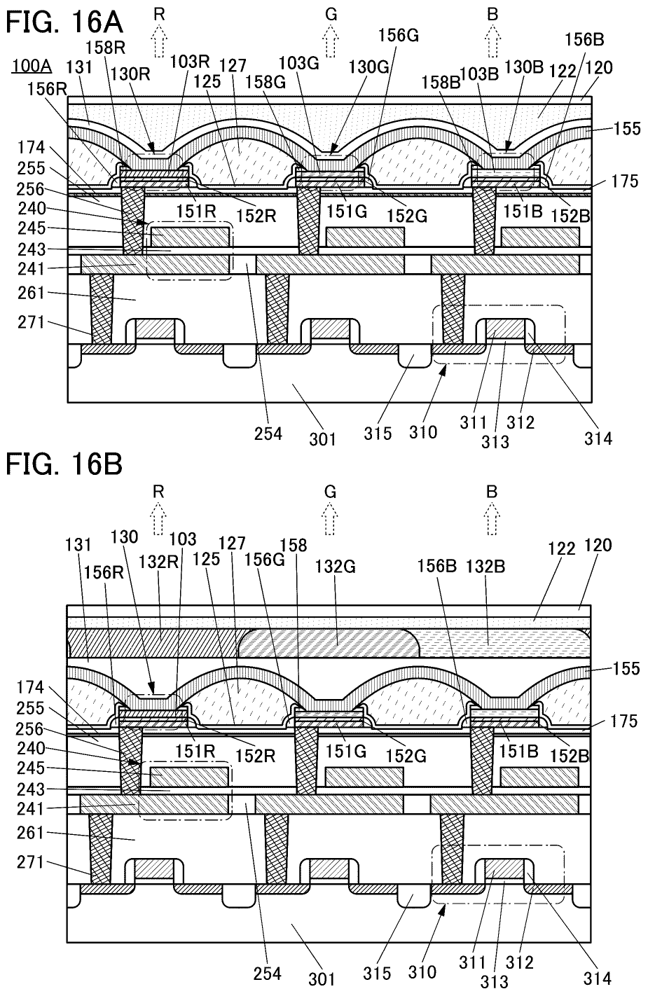

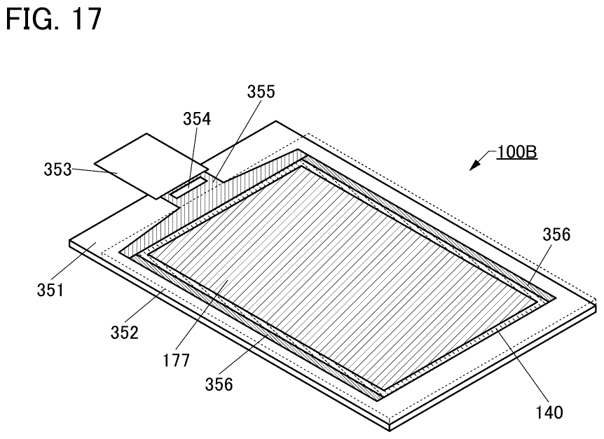

The display device 100A illustrated in FIG. 16A includes a substrate 301, the light-emitting devices 130R, 130G, and 130B, a capacitor 240, and a transistor 310.

The substrate 301 corresponds to the substrate 291 in FIGS. 15A and 15B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. Note that the insulating layer 156 is not necessarily provided.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B with the common electrode 155 therebetween. The substrate 120 is bonded to the protective layer 131 with the resin layer 122. Embodiment 3 can be referred to for the details of the light-emitting device 130 and the components thereover up to the substrate 120. The substrate 120 corresponds to the substrate 292 in FIG. 15A.

FIG. 16B illustrates a variation example of the display device 100A illustrated in FIG. 16A. The display device illustrated in FIG. 16B includes a coloring layer 132R, a coloring layer 132G, and a coloring layer 132B, and each of the light-emitting devices 130 includes a region overlapping with one of the coloring layers 132R, 132G, and 132B. In the display device illustrated in FIG. 16B, the light-emitting device 130 can emit white light, for example. The coloring layer 132R, the coloring layer 132G, and the coloring layer 132B can transmit red light, green light, and blue light, respectively, for example.

### [Display Device 100B]

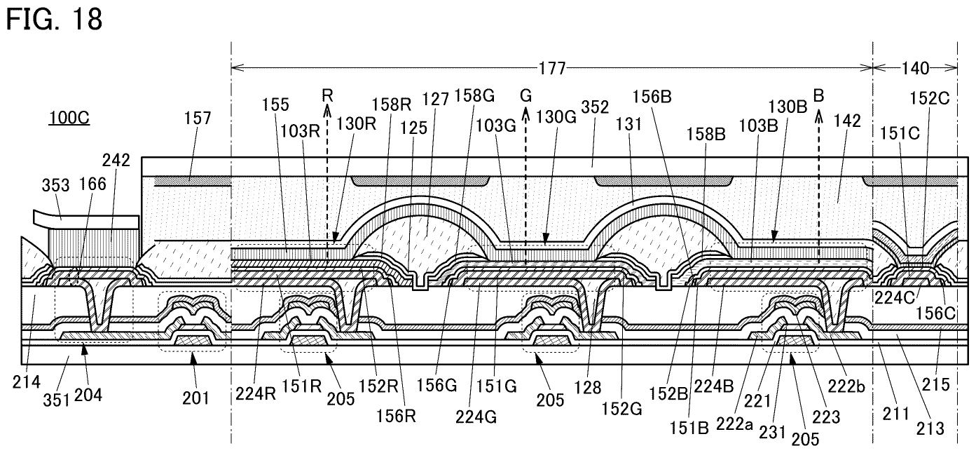

FIG. 17 is a perspective view of the display device 100B, and FIG. 18 is a cross-sectional view of the display device 100C.

In the display device 100B, a substrate 352 and a substrate 351 are bonded to each other. In FIG. 17, the substrate 352 is denoted by a dashed line.

The display device 100B includes the pixel portion 177, the connection portion 140, a circuit 356, a wiring 355, and the like. FIG. 17 illustrates an example where an IC 354 and an FPC 353 are mounted on the display device 100B. Thus, the structure illustrated in FIG. 17 can be regarded as a display module including the display device 100B, the integrated circuit (IC), and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 17 illustrates an example where the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

FIG. 18 illustrates an example of cross sections of part of a region including the FPC 353, part of the circuit 356, part of the pixel portion 177, part of the connection portion 140, and part of a region including an end portion of the display device 100C.

### [Display Device 100C]

The display device 100C illustrated in FIG. 18 includes a transistor 201, a transistor 205, the light-emitting device 130R that emits red light, the light-emitting device 130G that emits green light, the light-emitting device 130B that emits blue light, and the like between the substrate 351 and the substrate 352.

The above embodiment can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depressed portion covering the opening provided in the insulating layer 214. A layer 128 is embedded in the depressed portion.

The layer 128 has a function of filling the depressed portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depressed portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B with the common electrode 155 therebetween. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 18, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Furthermore, the space may be filled with a resin other than the frame-shaped adhesive layer 142.

FIG. 18 illustrates an example where the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 18, the insulating layer 156C is provided to include a region overlapping with the side surface of the conductive layer 151C.

The display device 100C has a top-emission structure. Light from the light-emitting device is emitted toward the substrate 352. For the substrate 352, a material with a high visible-light-transmitting property is preferably used. The pixel electrode includes a material that reflects visible light, and the counter electrode (second electrode 102) and the common electrode 155 each include a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, one of the source electrode and the drain electrode of the transistor 201 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352. A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

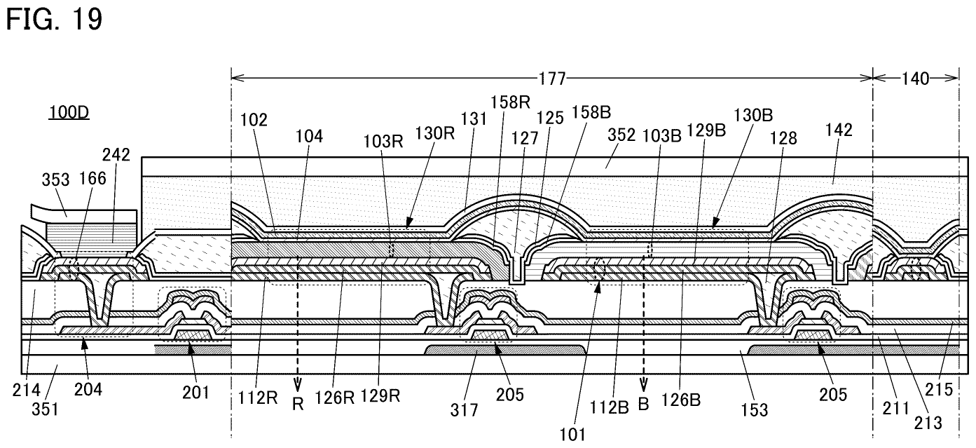

The display device 100D illustrated in FIG. 19 differs from the display device 100C illustrated in FIG. 18 mainly in having a bottom-emission structure.

Light from the light-emitting device is emitted toward the substrate 351. For the substrate 351, a material with a high visible-light-transmitting property is preferably used. By contrast, there is no limitation on the light-transmitting property of a material used for the substrate 352.

A light-blocking layer 317 is preferably formed between the substrate 351 and the transistor 201 and between the substrate 351 and the transistor 205. FIG. 19 illustrates an example where the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material with a high visible-light-transmitting property is used for each of the conductive layers 112R, 112B, 126R, 126B, 129R, and 129B. A material that reflects visible light is preferably used for the second electrode 102.

Although not illustrated in FIG. 19, the light-emitting device 130G is also provided.

Although FIG. 19 and the like illustrate an example where the top surface of the layer 128 includes a flat portion, the shape of the layer 128 is not particularly limited.

### [Display Device 100D2]

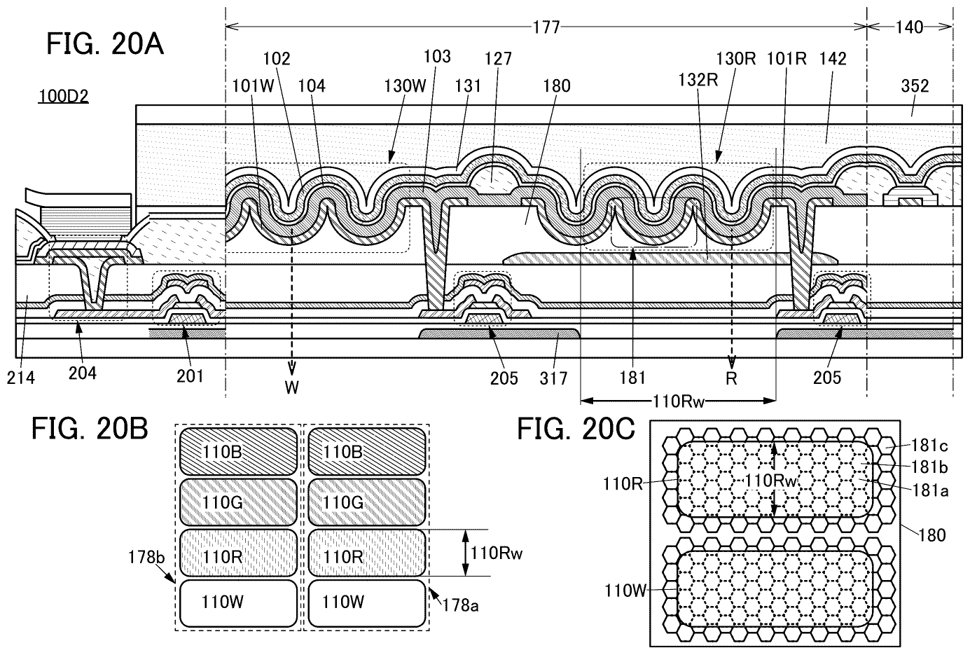

The display device 100D2 illustrated in FIG. 20A is an example of a bottom-emission display device different from the display device 100D illustrated in FIG. 19. The display device 100D2 is different from the display device 100D in including an organic resin layer 180. Note that in the drawings, reference numerals of some of the components that are shown in FIG. 19 are omitted; for the details of the components, the description made with reference to FIG. 19 can be referred to.

FIG. 20B shows a top-view layout of the pixels 178 (pixels 178a and 178b) each including the subpixels 110 (the subpixels 110R, 110G, 110B, and 110W), and FIG. 20C shows a top view of the organic resin layer 180 in a region where the subpixels 110R and 110W of the pixel 178 are formed. Note that the width between the light-blocking layer 317 and another light-blocking layer 317 corresponds to a width 110Rw in the light-emitting region of the subpixel 110R.

As illustrated in FIG. 20A, the organic resin layer 180 is provided over the insulating layer 214. As illustrated in FIG. 20C and the region surrounded by the dashed-dotted line in FIG. 20A, the organic resin layer 180 includes a depressed portion 181 (depressed portions 181a and 181b) having a curved surface at least in a region where the subpixel is formed. Note that the depressed portion 181 outside the light-emitting region, like a depressed portion 181c, may also be provided. With the depressed portion 181c, light emission caused in a region overlapping with the light-blocking layer 317 or light that has progressed to the region overlapping with the light-blocking layer 317 can be refracted and extracted from the light-emitting region, whereby emission efficiency can be improved.

A plurality of the depressed portions 181 may be formed in a matrix. The depressed portions 181a and 181b may be provided in contact with each other or may be provided to have a flat surface therebetween.

Although the top-view shape and the cross-sectional shape of the depressed portion are hexagonal (FIG. 20C) and semicircular (FIG. 20A), respectively, other shapes may be employed as needed. Examples of the top-view shape of the depressed portion include polygons such as a triangle, a tetragon (including a rectangle and a square), and a pentagon; these polygons with rounded corners; an ellipse; and a circle.

An insulating layer including an organic material can be used as the organic resin layer 180. Examples of materials that can be used for the organic resin layer 180 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. The organic resin layer 180 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

A photosensitive resin can also be used for the organic resin layer 180. A photoresist may be used as the photosensitive resin. As the photosensitive resin, a positive photosensitive material or a negative photosensitive material can be used.

The organic resin layer 180 may include a material absorbing visible light. For example, the organic resin layer 180 itself may be made of a material absorbing visible light, or the organic resin layer 180 may include a pigment absorbing visible light. For example, the organic resin layer 180 can be formed using a resin that can be used as a color filter transmitting red, blue, or green light and absorbing light of the other colors or a resin that contains carbon black as a pigment and functions as a black matrix.

The first electrode 101 is over the organic resin layer 180, the organic compound layer 103 is over the first electrode 101, and the second electrode 102 is over the organic compound layer 103. End portions of the first electrode 101, the organic compound layer 103, and the second electrode 102 may be covered with the insulating layer 127.

Along the depressed portion of the organic resin layer 180, the first electrode 101 formed over the organic resin layer 180 has a depressed portion in a manner similar to that of the organic resin layer 180. Furthermore, along the depressed portion of the first electrode 101, the organic compound layer 103 formed over the first electrode 101 has a depressed portion in a manner similar to that of the first electrode 101. The second electrode 102 formed over the organic compound layer 103 also has a depressed portion along the depressed portion of the organic compound layer 103. The common electrode 155 formed over the second electrode 102 also has a depressed portion along the depressed portion of the second electrode 102. That is, the depressed portions of the organic resin layer 180, the first electrode 101, the organic compound layer 103, the second electrode 102, and the common electrode 155 overlap with each other.

The second electrode 102 is over the organic compound layer 103 and the insulating layer 127, and the common electrode 155 is over the second electrode 102. The protective layer 131 is provided over the common electrode 155 and bonded to the substrate 352 with the adhesive layer 142.

Although the light-emitting devices 130G and 130B are not illustrated in FIGS. 20A to 20C, the light-emitting devices 130G and 130B are also provided.

The light-emitting device of one embodiment of the present invention including the above-described organic resin layer 180 has a structure described in the above embodiment. Accordingly, an organic semiconductor device with a low driving voltage and favorable characteristics can be provided.

### [Display Device 100E]

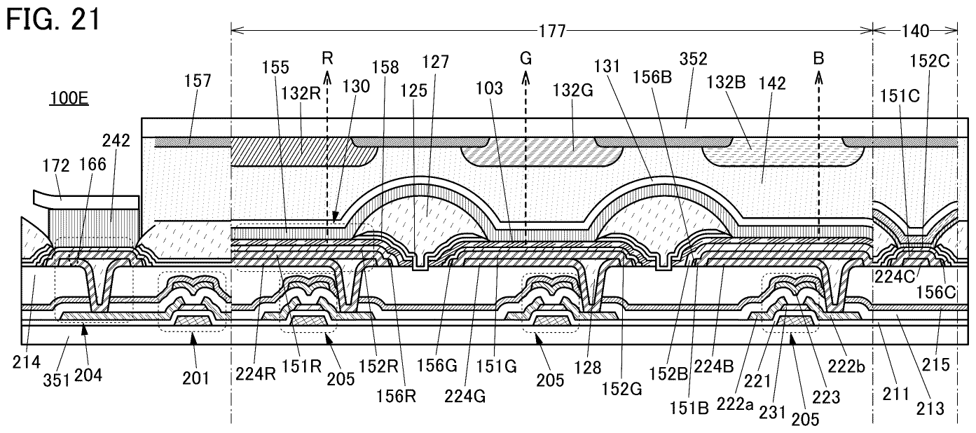

The display device 100E illustrated in FIG. 21 is a variation example of the display device 100C illustrated in FIG. 18 and differs from the display device 100C mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

In the display device 100E, the coloring layer 132R, the coloring layer 132G, and the coloring layer 132B can transmit red light, green light, and blue light, respectively, for example. Note that in the display device 100E, the coloring layers 132R, 132G, and 132B may be provided between the protective layer 131 and the adhesive layer 142.

### [Display Device 100E2]

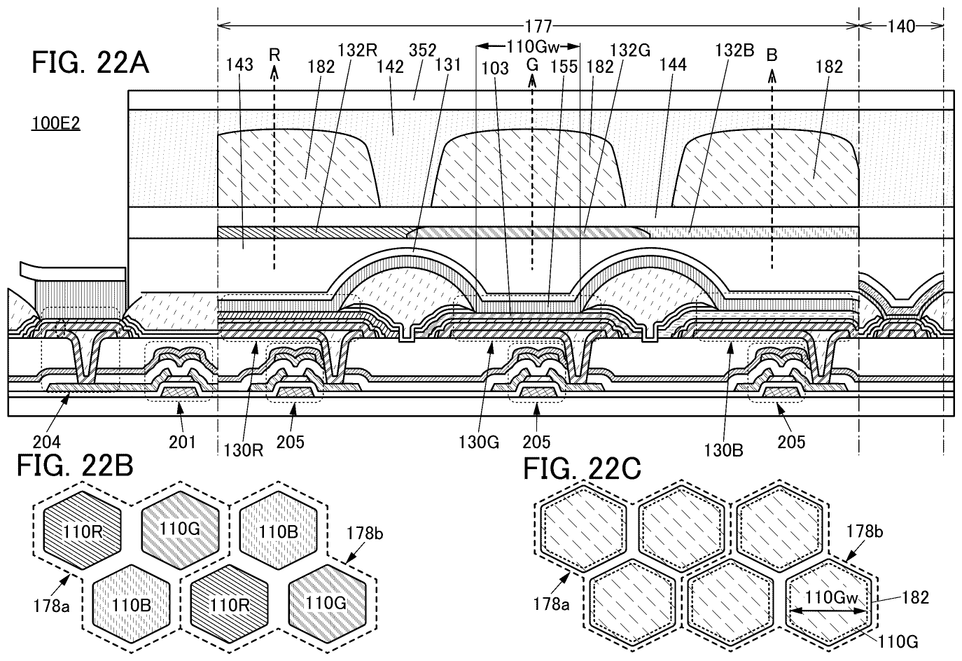

The display device 100E2 illustrated in FIG. 22A is a variation example of the display device 100E illustrated in FIG. 21 and includes microlenses 182 over the coloring layers 132R, 132G, and 132B. Note that in the drawings, reference numerals of some of the components that are shown in FIG. 21 are omitted; for the details of the components, the description made with reference to FIG. 21 can be referred to.

FIG. 22B shows a top-view layout of the pixels 178 (pixels 178a and 178b) each including the subpixels 110 (subpixels 110R, 110G, and 110B), and FIG. 22C shows a top view of the microlenses 182 in a region where the subpixels 110R, 110G, and 110B of the pixels 178 are formed. Note that the width of the region where the common electrode 155 and the organic compound layer 103 are in contact with each other corresponds to a width 110Gw in the light-emitting region of the subpixel 110G.

In the display device 100E2 illustrated in FIG. 22A, a planarization film 143 is provided over the protective layer 131, and the coloring layers 132R, 132G, and 132B are provided over the planarization film 143. A planarization film 144 is provided to cover the coloring layers 132R, 132G, and 132B. The microlenses 182 are provided over the planarization film 144.

Note that as illustrated in FIG. 22C, the microlens 182 is preferably provided for each of the subpixels in the region where the subpixels are formed.

Although the top-view shape of the microlens 182 is hexagonal in FIG. 22C, a different shape may be employed as needed. Examples of the top-view shape of the microlens 182 include polygons such as a triangle, a tetragon (including a rectangle and a square), and a pentagon; these polygons with rounded corners; an ellipse; and a circle.

The microlenses 182 can be formed using a material similar to that for the organic resin layer 180.

The microlens is suitably used in the light-emitting device of one embodiment of the present invention (e.g., a light-emitting device or a tandem light-emitting device fabricated by side-by-side patterning using the above-described fused heteroaromatic ring containing nitrogen). Since the microlens can condense light and increase light extraction efficiency, the light emission performance of the whole display device can be increased in combination with the microcavity effect described above. Furthermore, the use of the protective layer 131 (see FIG. 12C) or the sealing film over the protective layer 131 improves characteristics and resistance to impurities, which is preferable.

When a region between two adjacent microlenses overlaps with a region between two adjacent light-emitting devices as illustrated in FIGS. 22A to 22C, the effect of the microlenses can be enhanced. It is also suitable that a region where two adjacent coloring layers (e.g., 132B and 132G) overlap with each other, the region between the microlenses, and the region between the light-emitting devices overlap with each other. It is also preferable that the insulating layer 127 overlap with the region where the coloring layers overlap with each other, the region between the microlenses, and the region between the light-emitting devices. The regions preferably overlap with the protective layer 131 or the sealing film over the protective layer 131. Although the region between the microlenses might serve as a path through which impurities enter the light-emitting device, the protective layer 131 or the sealing film can inhibit entry of impurities.

This embodiment can be combined as appropriate with the other embodiments or the examples. In this specification, in the case where a plurality of structure examples are shown in one embodiment, the structure examples can be combined as appropriate.

### Embodiment 6

In this embodiment, electronic appliances of embodiments of the present invention will be described.

Electronic appliances in this embodiment each include the display device of one embodiment of the present invention in a display portion. The display device of one embodiment of the present invention has high display performance and can be easily increased in resolution and definition. Thus, the display device of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display device of one embodiment of the present invention can have high resolution, and thus can be favorably used for an electronic appliance having a relatively small display portion. Examples of such an electronic appliance include watch-type and bracelet-type information terminals (wearable devices) and wearable devices capable of being worn on a head, such as a VR device like a head-mounted display, a glasses-type AR device, and an MR device.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

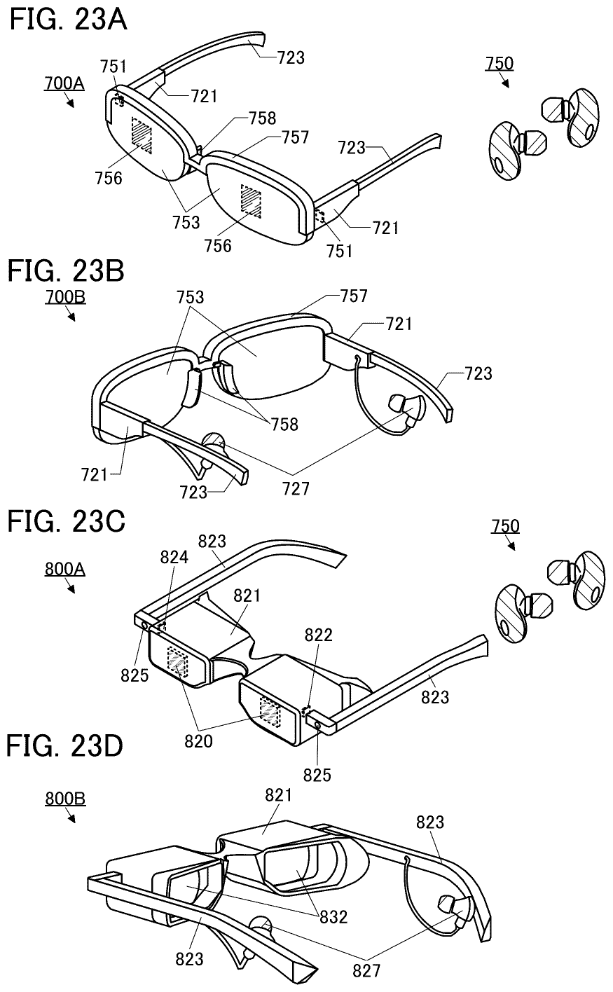

Examples of wearable devices capable of being worn on a head are described with reference to FIGS. 23A to 23D.

An electronic appliance 700A illustrated in FIG. 23A and an electronic appliance 700B illustrated in FIG. 23B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, a highly reliable electronic appliance is obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 23C and an electronic appliance 800B illustrated in FIG. 23D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, a highly reliable electronic appliance is obtained.

The display portions 820 are positioned inside the housing 821 so as to be seen through the lenses 832. When the pair of display portions 820 display different images, three-dimensional display using parallax can be performed.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

The electronic appliance 800A may include a vibration mechanism that functions as bone-conduction earphones.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B illustrated in FIG. 23B includes earphone portions 727. Part of a wiring that connects the earphone portion 727 and the control portion may be positioned inside the housing 721 or the wearing portion 723.

Similarly, the electronic appliance 800B illustrated in FIG. 23D includes earphone portions 827. For example, the earphone portion 827 can be connected to the control portion 824 by wire.

As described above, both the glasses-type device (e.g., the electronic appliances 700A and 700B) and the goggles-type device (e.g., the electronic appliances 800A and 800B) are preferable as the electronic appliance of one embodiment of the present invention.

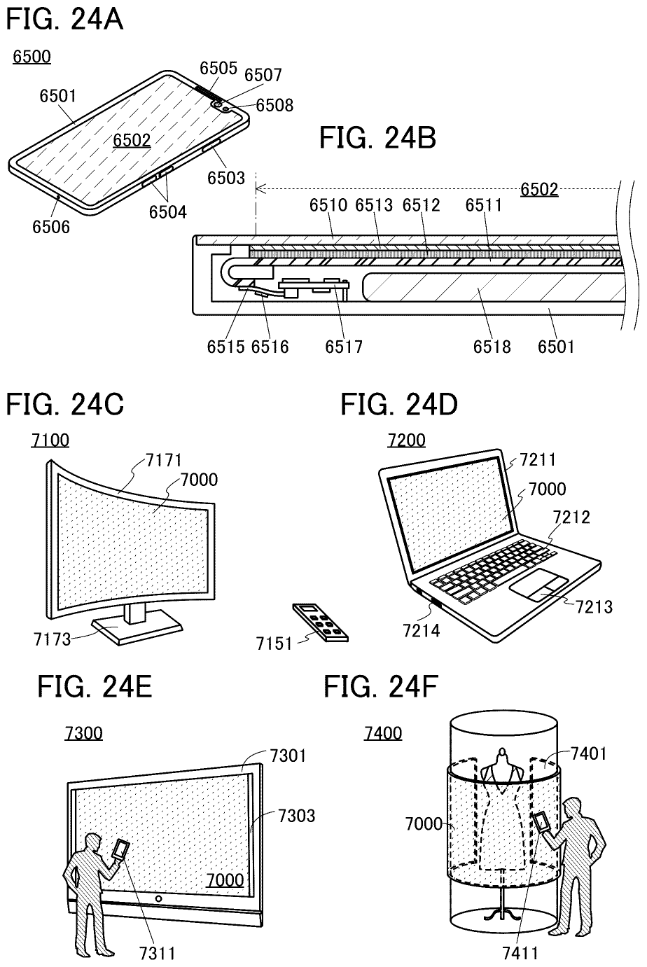

An electronic appliance 6500 illustrated in FIG. 24A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, a highly reliable electronic appliance is obtained.

FIG. 24B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with a bonding layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be obtained.

FIG. 24C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, a highly reliable electronic appliance is obtained.

Operation of the television device 7100 illustrated in FIG. 24C can be performed with an operation switch provided in the housing 7171 and a separate remote control 7151.

FIG. 24D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, a highly reliable electronic appliance is obtained.

FIGS. 24E and 24F illustrate examples of digital signage that can be used for store windows, showcases, and the like.

Digital signage 7300 illustrated in FIG. 24E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 24F illustrates digital signage 7400 attached to a cylindrical pillar 7401. The digital signage 7400 includes the display portion 7000 provided along a curved surface of the pillar 7401.

In FIGS. 24E and 24F, the display device of one embodiment of the present invention can be used in the display portion 7000. Thus, a highly reliable electronic appliance is obtained.

A larger area of the display portion 7000 can increase the amount of information that can be provided at a time. The larger display portion 7000 attracts more attention, so that the effectiveness of the advertisement can be increased, for example.

Specifically, in the case where the display device of one embodiment of the present invention is used for the digital signage 7400 illustrated in FIG. 24F and the like that display advertisements and the like, the display device being a light-transmitting panel can increase the flexibility of representation in advertising. A light-transmitting display device can be manufactured, for example, by using a wiring and a support member each of which is formed of a conductive film that transmits visible light and adjusting the distance between pixel electrodes. When the pillar 7401 is formed of tempered glass or the like, the pillar 7401 can also be used as a show case.

The tandem light-emitting device of one embodiment of the present invention in addition to the wiring and the support member each of which is formed of the conductive film that transmits visible light can increase the luminance per pixel. That is, favorable display can be performed even when the aperture ratio of the display device is decreased; thus, the light-transmitting property of the display portion of the display device can be increased. Accordingly, such a structure is suitably used in the light-transmitting display device of one embodiment of the present invention.

As illustrated in FIGS. 24E and 24F, it is preferable that the digital signage 7300 or the digital signage 7400 can work with an information terminal 7311 or an information terminal 7411, such as a smartphone that a user has, through wireless communication.

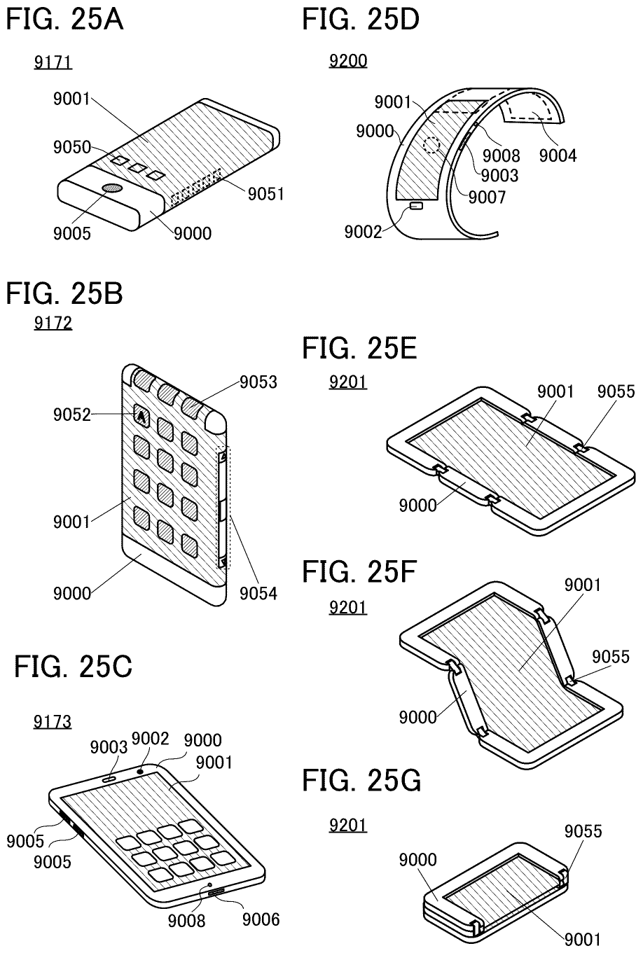

Electronic appliances illustrated in FIGS. 25A to 25G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 25A to 25G have a variety of functions.

For example, the electronic appliances can have a function of displaying a variety of information (e.g., a still image, a moving image, and a text image) on the display portion, a touch panel function, a function of displaying a calendar, date, time, and the like, a function of controlling processing with use of a variety of software (programs), a wireless communication function, and a function of reading out and processing a program or data stored in a recording medium.

The electronic appliances illustrated in FIGS. 25A to 25G are described in detail below.

FIG. 25A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 25A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 25B is a perspective view of a portable information terminal 9172. The portable information terminal 9172 has a function of displaying information on three or more surfaces of the display portion 9001. In the example illustrated here, information 9052, information 9053, and information 9054 are displayed on different surfaces. For example, the user of the portable information terminal 9172 can check the information 9053 displayed such that it can be seen from above the portable information terminal 9172, with the portable information terminal 9172 put in a breast pocket of his/her clothes.

FIG. 25C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 25D is a perspective view of a watch-type portable information terminal 9200. The portable information terminal 9200 can be used as a Smartwatch (registered trademark), for example. The portable information terminal 9200 may include the operation key 9005 as a button for operation on the left side surface of the housing 9000 and the sensor 9007 on the bottom surface of the housing 9000. Although the housing 9000 having a curved bangle shape is illustrated as an example, a belt or the like may be used in combination with the housing 9000 to make the portable information terminal 9200 wearable. The display surface of the display portion 9001 is curved, and an image can be displayed on the curved display surface. A power storage device 9004 may have a curved shape along the housing 9000. The power storage device 9004 has flexibility and can be bent in accordance with a change in shape when the user puts on or takes off the portable information terminal 9200. Note that a charge control IC connected to the power storage device 9004 may be provided. In particular, the tandem light-emitting device of one embodiment of the present invention has low power consumption and can be driven for a long time when used in the display portion 9001. Since the tandem light-emitting device of one embodiment of the present invention has high emission efficiency, high visibility can be obtained even when used outdoors. Furthermore, for example, mutual communication between the portable information terminal 9200 and a headset capable of wireless communication can be performed, and thus hands-free calling is possible. The portable information terminal 9200 can perform mutual data transmission wirelessly with another information terminal and can be charged with wireless power feeding. Note that the connection terminal 9006 may be provided in the housing 9000 so that data transmission and charging operation may be performed by wire.

FIGS. 25E to 25G are perspective views of a foldable portable information terminal 9201. FIG. 25E is a perspective view illustrating the portable information terminal 9201 that is opened. FIG. 25G is a perspective view illustrating the portable information terminal 9201 that is folded. FIG. 25F is a perspective view illustrating the portable information terminal 9201 that is shifted from one of the states in FIGS. 25E and 25G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

### Example 1

In this example, light-emitting devices 1B (a light-emitting device 1B_1, a light-emitting device 1B_2, and a light-emitting device 1B_3), a light-emitting device 1R, and a light-emitting device 1G were fabricated, and the characteristics thereof were evaluated. In addition, comparative light-emitting devices 1 (a comparative light-emitting device 1b, a comparative light-emitting device 1r, and a comparative light-emitting device 1g) were fabricated, and the characteristics thereof were evaluated.

The light-emitting devices 1B (the light-emitting devices 1B_1 to 1B_3) are each a light-emitting device of one embodiment of the present invention, where a first light-emitting layer 912 and a second light-emitting layer 917 each include a phosphorescent substance as an emission center substance and include host materials at least one of which is deuterated. Furthermore, a second electron-transport layer 918_2 includes an organic compound having a triazine skeleton.

The comparative light-emitting device 1b is a light-emitting device in which the first light-emitting layer 912 and the second light-emitting layer 917 each include a phosphorescent substance and host materials neither or none of which is deuterated. Furthermore, the second electron-transport layer 918_2 does not include an organic compound having a triazine skeleton.

The light-emitting devices 1R and 1G are each a light-emitting device in which the second electron-transport layer 918_2 includes an organic compound having a triazine skeleton.

The comparative light-emitting devices 1r and 1g are each a light-emitting device in which the second electron-transport layer 918_2 does not include an organic compound having a triazine skeleton.

The light-emitting devices 1B (the light-emitting devices 1B_1 to 1B_3), the light-emitting device IR, the light-emitting device 1G, and the comparative light-emitting devices 1 were each fabricated by a continuous vacuum process. Structural formulae of the organic compounds used for the light-emitting devices 1 and the comparative light-emitting devices 1 are shown below.

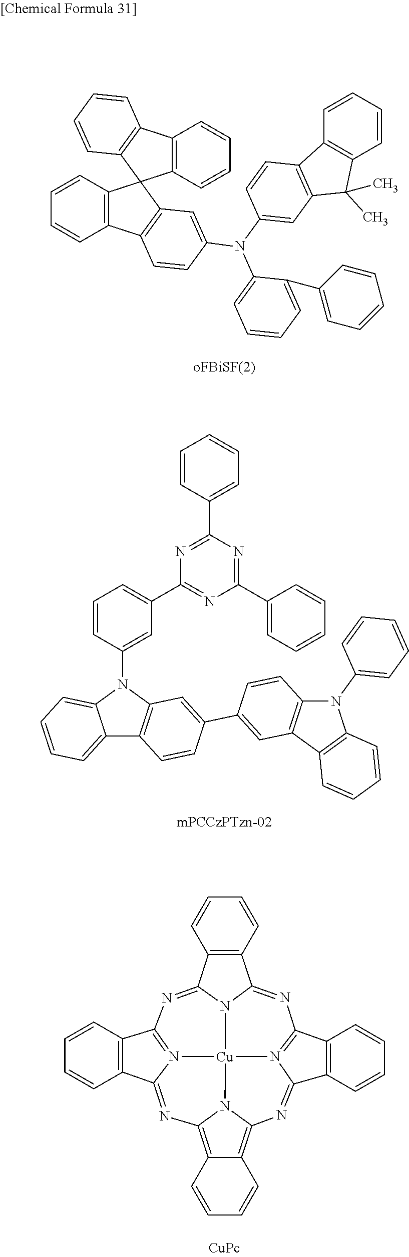

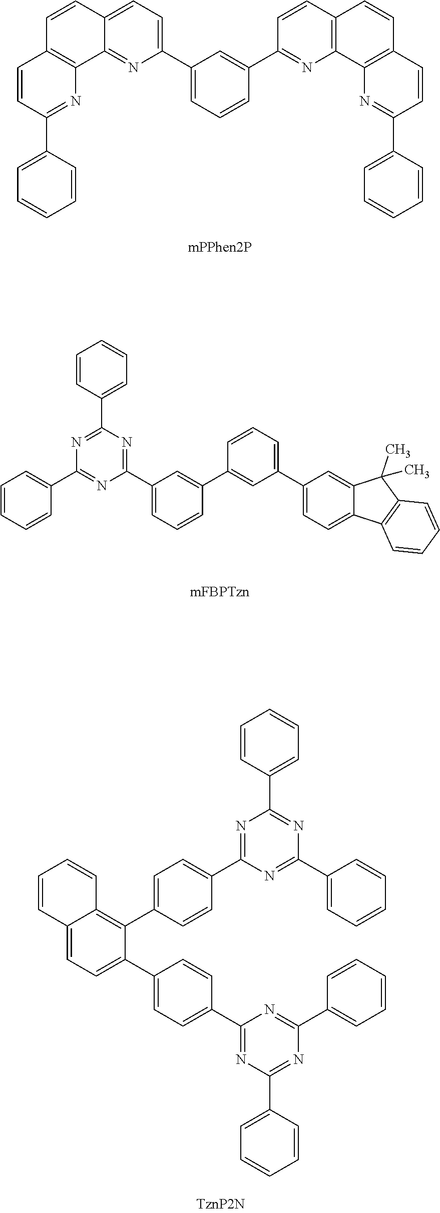

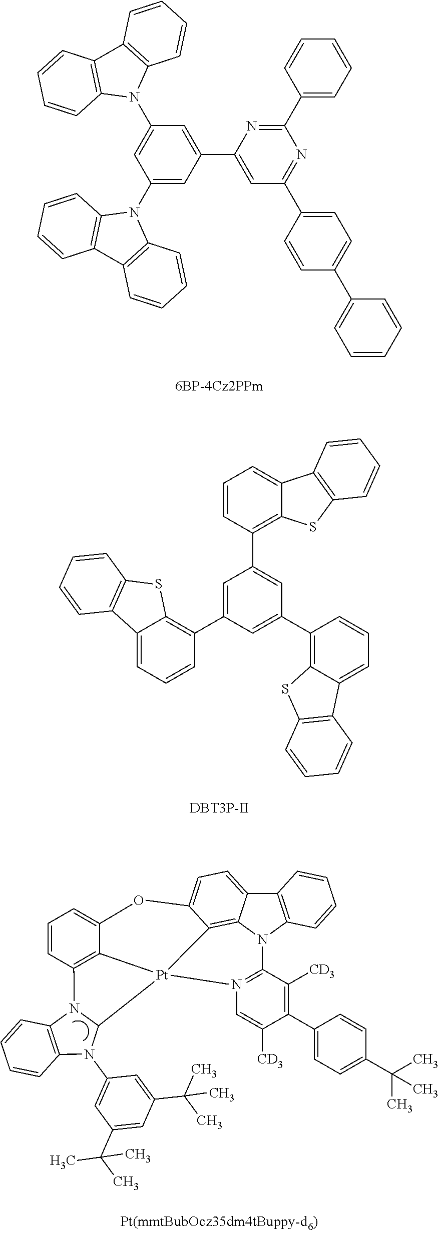

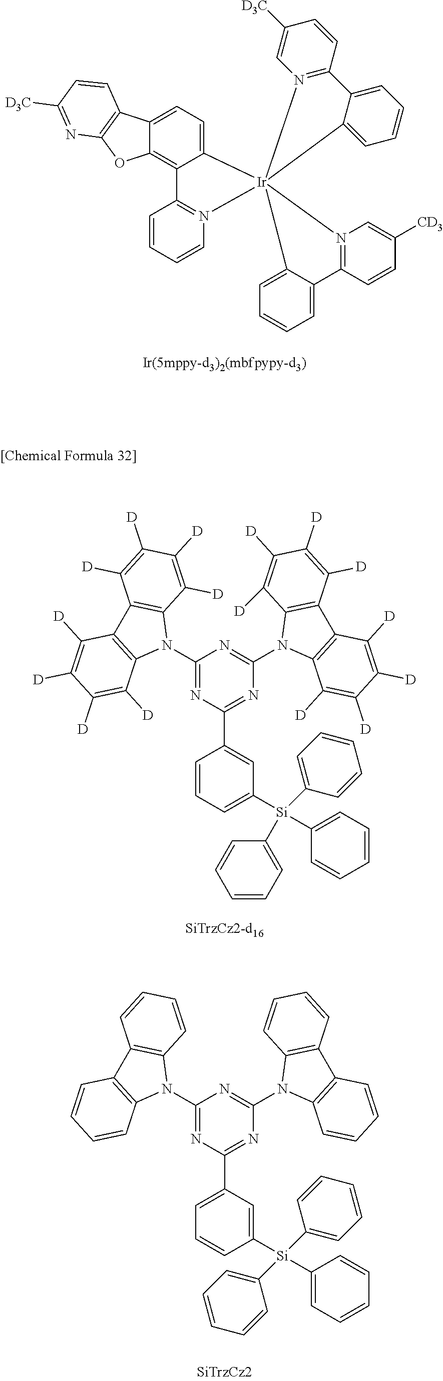

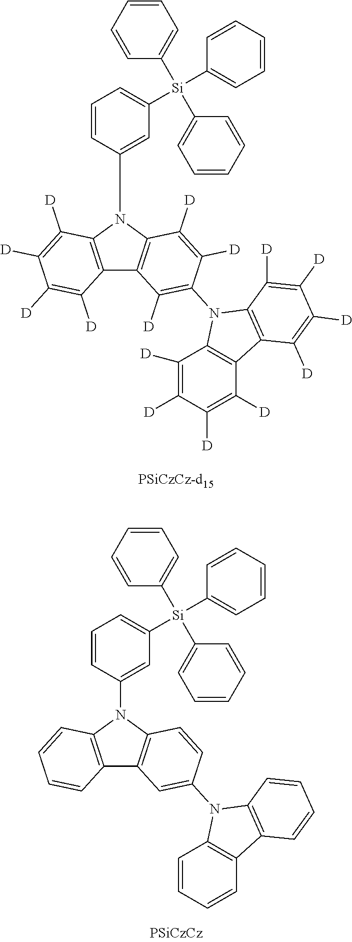 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cccc([Si](c2ccccc2)(c2ccccc2)c2ccccc2)c1 ; c1ccc([Si](c2ccccc2)(c2ccccc2)c2cccc(-n3c4ccccc4c4cc(-n5c6ccccc6c6ccccc65)ccc43)c2)cc1]

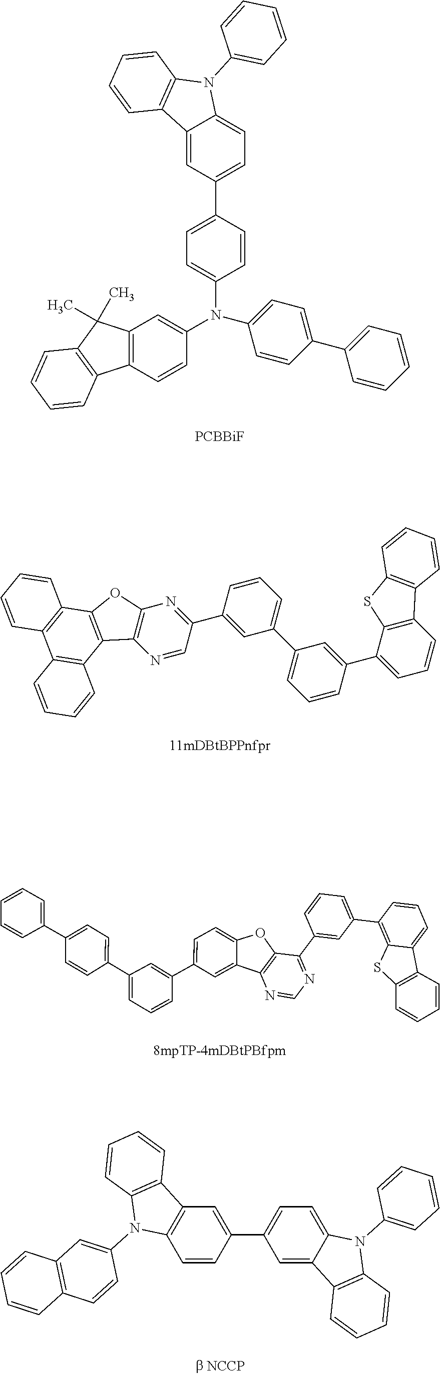

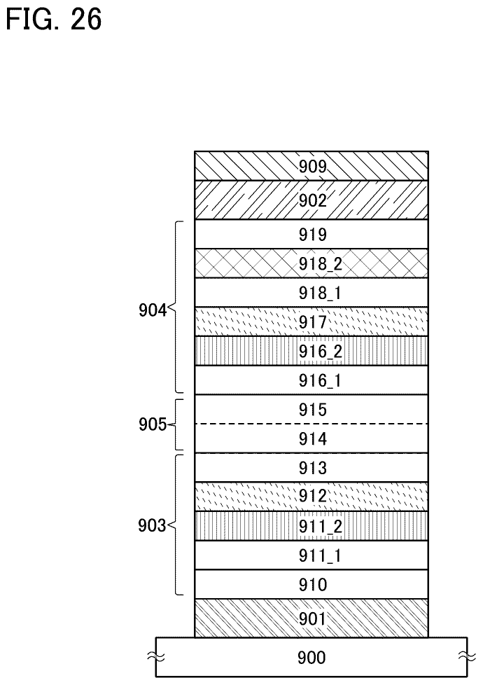

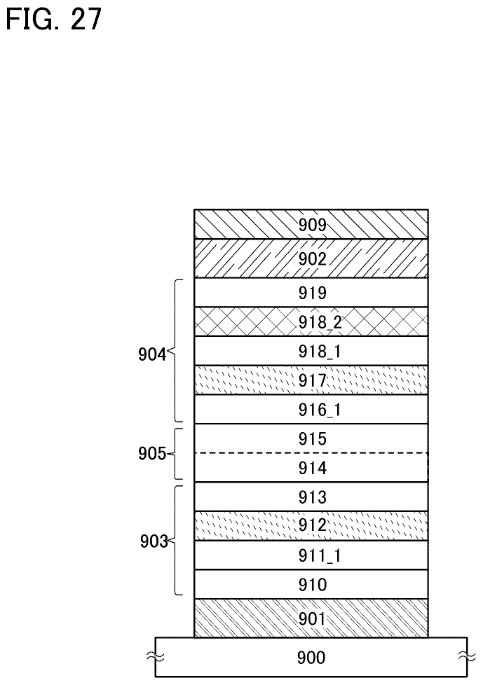

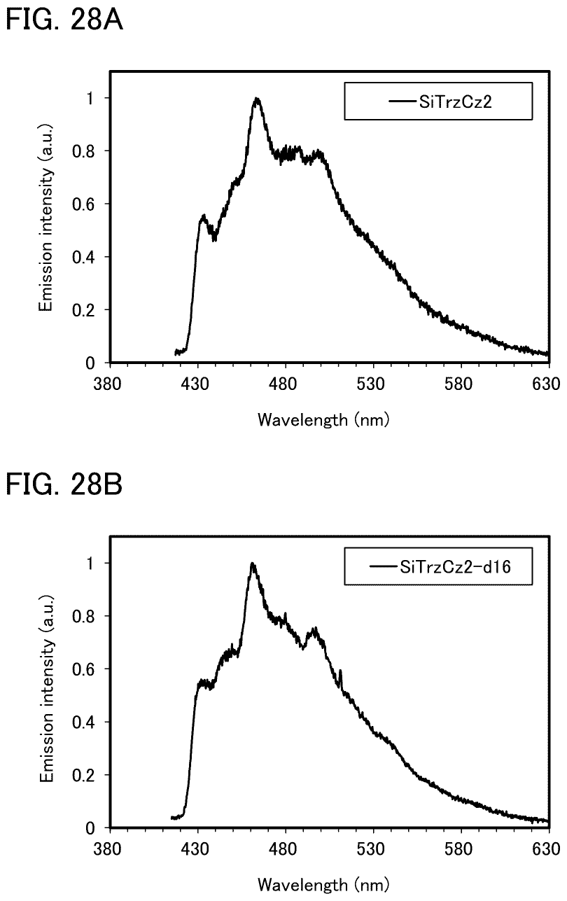

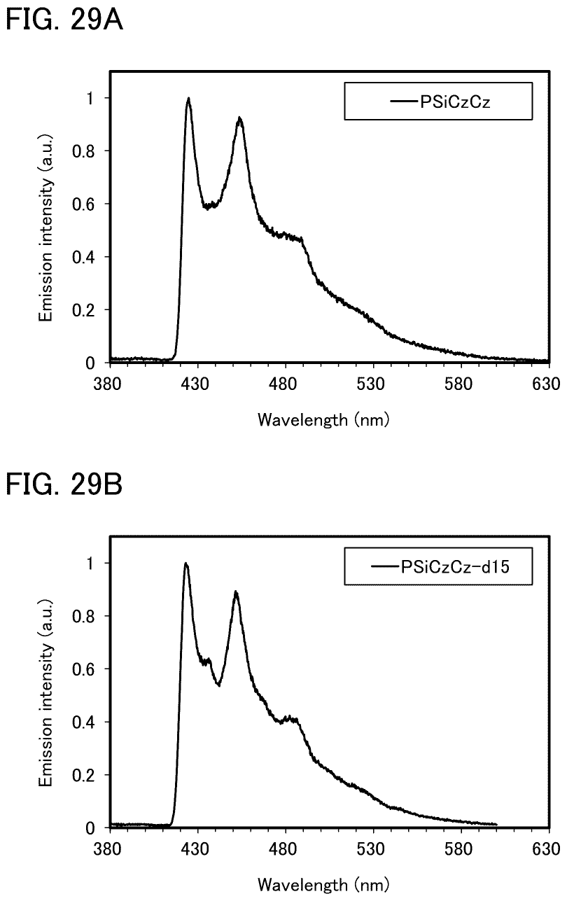

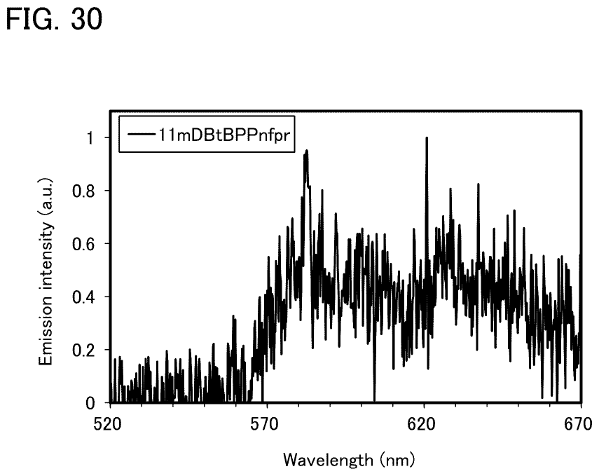

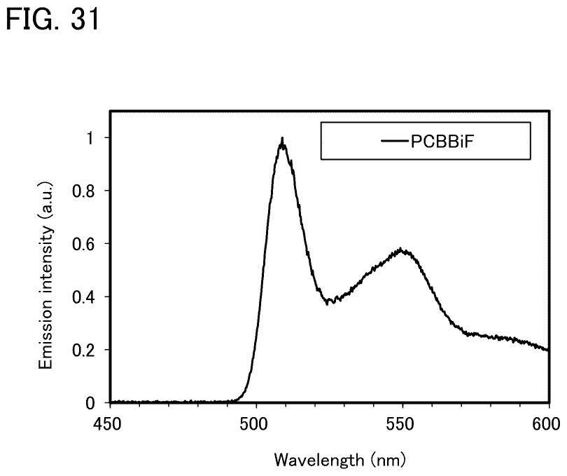

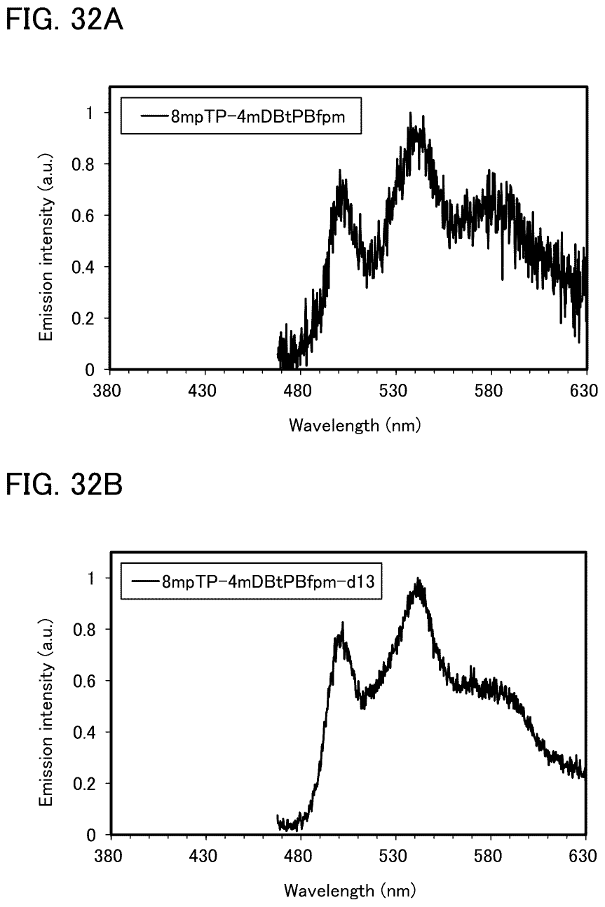

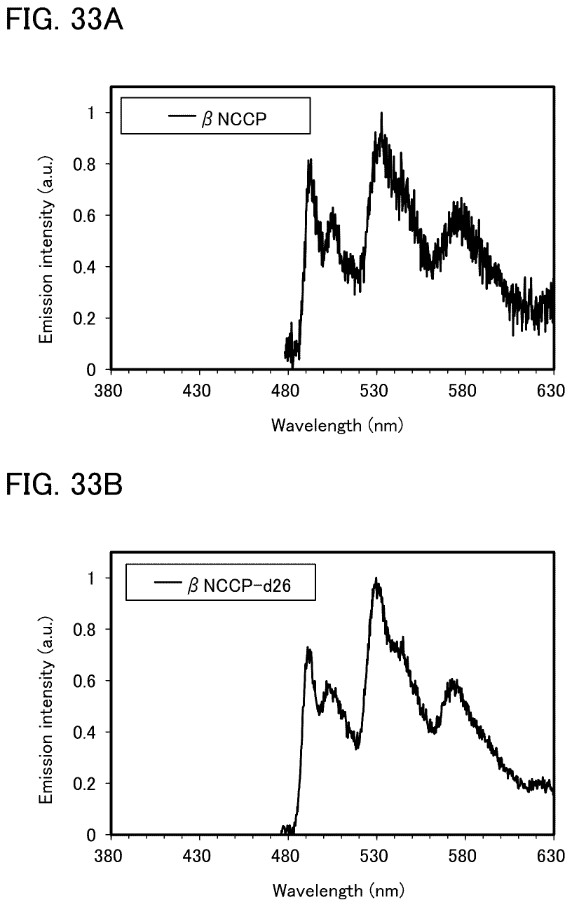

FIG. 26 illustrates the structures of the light-emitting devices 1B and the comparative light-emitting device 1b. FIG. 27 illustrates the structures of the light-emitting devices 1R and 1G and the comparative light-emitting devices 1r and 1g. The light-emitting devices 1 and the comparative light-emitting devices 1 each have a tandem structure in which a first EL layer 903, an intermediate layer 905, a second EL layer 904, and a second electrode 902 are stacked over a first electrode 901 formed over a substrate 900 that is a glass substrate. Furthermore, a cap layer 909 is provided over the second electrode.

As illustrated in FIG. 26, the first EL layer 903 of each of the light-emitting devices 1B (the light-emitting devices 1B_1 to 1B_3) and the comparative light-emitting device 1b has a structure in which a hole-injection layer 910, a first hole-transport layer 911 (a first hole-transport layer 911_1 and a first hole-transport layer 911_2), the first light-emitting layer 912, and a first electron-transport layer 913 are stacked in this order. The second EL layer 904 of each of the light-emitting devices 1B and the comparative light-emitting device 1b has a structure in which a second hole-transport layer 916 (a second hole-transport layer 916_1 and a second hole-transport layer 916_2), the second light-emitting layer 917, a second electron-transport layer 918 (a second electron-transport layer 918_1 and the second electron-transport layer 918_2), and an electron-injection layer 919 are stacked in this order.

Meanwhile, as illustrated in FIG. 27, the first EL layer 903 of each of the light-emitting devices 1R and 1G and the comparative light-emitting devices 1r and 1g has a structure in which the hole-injection layer 910, the first hole-transport layer 911_1, the first light-emitting layer 912, and the first electron-transport layer 913 are stacked in this order. The second EL layer 904 thereof has a structure in which the second hole-transport layer 916_1, the second light-emitting layer 917, the second electron-transport layer 918 (the second electron-transport layers 918_1 and 918_2), and the electron-injection layer 919 are stacked in this order.

In each of the light-emitting devices 1 and the comparative light-emitting devices 1, the intermediate layer 905 includes an electron-injection buffer region 914 and a layer 915 including an electron-relay region and a charge-generation region.

### <Fabrication Method of Light-Emitting Device 1B_1>

First, as a reflective electrode, silver (Ag) was deposited over a glass substrate to a thickness of 100 nm by a sputtering method, and then, as a transparent electrode, indium tin oxide containing silicon oxide (ITSO) was deposited to a thickness of 85 nm by a sputtering method, so that the first electrode was formed. Note that the transparent electrode serves as an anode, and the transparent electrode and the reflective electrode can be collectively regarded as the first electrode. The first electrode was 2 mm×2 mm.

Next, in pretreatment for fabricating the light-emitting device over the substrate, the surface of the substrate was washed with water, and baking was performed at 200° C. for one hour. After that, the substrate was transferred into a vacuum evaporation apparatus where the pressure was reduced to approximately 1×10⁻⁴ Pa, and was subjected to heat treatment at 170° C. for 30 minutes in a heating chamber of the vacuum evaporation apparatus, and then the substrate was cooled down for approximately 30 minutes.

Next, the substrate provided with the first electrode 901 was fixed to a holder provided in the vacuum evaporation apparatus such that the surface on which the first electrode 901 was formed faced downward. Then, the hole-injection layer 910 was formed on the first electrode 901 by co-evaporation of N-(biphenyl-2-yl)-N-(9,9-dimethylfluoren-2-yl)-9,9′-spirobi[9H-fluoren]-2-amine (abbreviation: oFBiSF (2)) and a fluorine-containing material having an electron-acceptor property with a molecular weight of 672 (OCHD-003) at a weight ratio of 1:0.03 to a thickness of 10 nm by an evaporation method using resistance heating.

Subsequently, the first hole-transport layer 911 (the first hole-transport layers 911_1 and 911_2) was formed over the hole-injection layer 910. By an evaporation method using resistance heating, the first hole-transport layer 911_1 was formed by evaporation of oFBiSF (2) to a thickness of 45 nm, and then the first hole-transport layer 911_2 was formed over the first hole-transport layer 911_1 by evaporation of 9-[3-(triphenylsilyl)phenyl]-3,9′-bi-9H-carbazole (abbreviation: PSiCzCz) to a thickness of 5 nm.

Next, the first light-emitting layer 912 was formed over the first hole-transport layer 911. By an evaporation method using resistance heating, the first light-emitting layer 912 was formed by co-evaporation of 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d₁₆) (abbreviation: SiTrzCz2-d₁₆), PSiCzCz, and (2-{3-[3-(3,5-di-tert-butylphenyl)benzimidazol-1-yl-2-ylidene-κC²]phenoxy-κC²}-9-[4-tert-butylphenyl-3,5-di(methyl-d₃)-2-pyridinyl-κN]carbazole-2,1-diyl-κC)platinum(II) (abbreviation: Pt(mmtBubOcz35dm4tBuppy-d₆)) at a weight ratio of 0.45:0.45:0.10 to a thickness of 25 nm.

Next, the first electron-transport layer 913 was formed over the first light-emitting layer 912 by evaporation of 9-[3-(4,6-diphenyl-1,3,5-triazin-2-yl)phenyl]-9′-phenyl-2,3′-bi-9H-carbazole (abbreviation: mPCCzPTzn-02) to a thickness of 10 nm.

Next, the intermediate layer 905 was provided. First, by an evaporation method using resistance heating, a layer to be the electron-injection buffer region 914 was formed over the first electron-transport layer 913 by co-evaporation of 2,2′-(1,3-phenylene)bis(9-phenyl-1,10-phenanthroline) (abbreviation: mPPhen2P) and Li₂O at a volume ratio of 1:0.02 to a thickness of 5 nm.

Then, as the electron-relay region, copper phthalocyanine (abbreviation: CuPc) was deposited to a thickness of 2 nm. Next, as the charge-generation region, oFBiSF (2) and a fluorine-containing material having an electron-acceptor property with a molecular weight of 672 (OCHD-003) were deposited by co-evaporation to a thickness of 10 nm at a weight ratio of 1:0.15 by an evaporation method using resistance heating. Thus, the layer 915 including the electron-relay region and the charge-generation region was formed.

Next, the second EL layer 904 was provided over the intermediate layer 905.

First, the second hole-transport layer 916 (the second hole-transport layers 916_1 and 916_2) was formed. After the second hole-transport layer 916_1 was formed by evaporation of oFBiSF (2) to a thickness of 50 nm, the second hole-transport layer 916_2 was formed over the second hole-transport layer 916_1 by evaporation of PSiCzCz to a thickness of 5 nm.

Next, the second light-emitting layer 917 was formed over the second hole-transport layer 916 by co-evaporation of SiTrzCz2-d₁₆, PSiCzCz, and Pt(mmtBubOcz35dm4tBuppy-d₆) at a weight ratio of 0.45:0.45:0.10 to a thickness of 25 nm by an evaporation method using resistance heating.

Next, the second electron-transport layer 918 (the second electron-transport layers 918_1 and 918_2) was formed over the second light-emitting layer 917. By an evaporation method using resistance heating, the second electron-transport layer 918_1 was formed by evaporation of 2-[3′-(9,9-dimethyl-9H-fluoren-2-yl)biphenyl-3-yl]-4,6-diphenyl-1,3,5-triazine (abbreviation: mFBPTzn) to a thickness of 10 nm, and then the second electron-transport layer 918_2 was formed by co-evaporation of 2,2′-(1,2-naphthalenediyldi-4,1-phenylene)bis[4,6-diphenyl-1,3,5-triazine](abbreviation: TznP2N) and 8-quinolinolato-lithium (abbreviation: Liq) at a volume ratio of 1:1 to a thickness of 25 nm.

Next, the electron-injection layer 919 was formed over the second electron-transport layer 918 by evaporation of Liq to a thickness of 1 nm.

Next, the second electrode 902 was formed over the electron-injection layer 919 by co-evaporation of Ag and Mg at a volume ratio of 1:0.1 to a thickness of 15 nm. Note that the second electrode 902 is a transflective electrode having functions of transmitting light and reflecting light.

Then, as the cap layer 909, 4,4′,4″-(benzene-1,3,5-triyl)tri(dibenzothiophene) (abbreviation: DBT3P-II) was deposited to a thickness of 70 nm by evaporation, which leads to an improved light extraction efficiency.

Through the above process, the light-emitting device 1B_1 was fabricated.

### <Fabrication Method of Light-Emitting Device 1B_2>

The light-emitting device 1B_2 is different from the light-emitting device 1B_1 in the structures of the first light-emitting layer 912 and the second light-emitting layer 917. Other components were fabricated in a manner similar to that for the light-emitting device 1B_1.

Specifically, the first light-emitting layer 912 of the light-emitting device 1B_2 was formed by co-evaporation of 9,9′-{6-[3-(triphenylsilyl)phenyl]-1,3,5-triazine-2,4-diyl}bis(9H-carbazole) (abbreviation: SiTrzCz2), 9-[3-(triphenylsilyl)phenyl]-3,9′-(bi-9H-carbazole-d₁₅) (abbreviation: PSiCzCz-d₁₅), and Pt(mmtBubOcz35dm4tBuppy-d₆) at a weight ratio of 0.45:0.45:0.10 to a thickness of 25 nm by an evaporation method using resistance heating.

Like the first light-emitting layer 912, the second light-emitting layer 917 was formed over the second hole-transport layer 916 by co-evaporation of SiTrzCz2, PSiCzCz-dis, and Pt(mmtBubOcz35dm4tBuppy-d₆) at a weight ratio of 0.45:0.45:0.10 to a thickness of 25 nm by an evaporation method using resistance heating.

### <Fabrication Method of Light-Emitting Device 1B_3>

The light-emitting device 1B_3 is different from the light-emitting device 1B_1 in the structures of the first light-emitting layer 912 and the second light-emitting layer 917. Other components were fabricated in a manner similar to that for the light-emitting device 1B_1. Specifically, the first light-emitting layer 912 of the light-emitting device 1B_3 was formed by co-evaporation of SiTrzCz2-d₁₆, PSiCzCz-dis, and Pt(mmtBubOcz35dm4tBuppy-d₆) at a weight ratio of 0.45:0.45:0.10 to a thickness of 25 nm by an evaporation method using resistance heating.

Like the first light-emitting layer 912, the second light-emitting layer 917 was formed over the second hole-transport layer 916 by co-evaporation of SiTrzCz2-d₁₆, PSiCzCz-dis, and Pt(mmtBubOcz35dm4tBuppy-d₆) at a weight ratio of 0.45:0.45:0.10 to a thickness of 25 nm by an evaporation method using resistance heating.

<Fabrication Method of Comparative Light-Emitting Device 1b>

The comparative light-emitting device 1b is different from the light-emitting devices 1B in the structures of the first light-emitting layer 912, the second light-emitting layer 917, and the second electron-transport layer 918. Other components were fabricated in a manner similar to those for the light-emitting devices 1B.

Specifically, the first light-emitting layer 912 of the comparative light-emitting device 1b was formed by co-evaporation of SiTrzCz2, PSiCzCz, and Pt(mmtBubOcz35dm4tBuppy-d₆) at a weight ratio of 0.45:0.45:0.10 to a thickness of 25 nm by an evaporation method using resistance heating.

Like the first light-emitting layer 912, the second light-emitting layer 917 of the comparative light-emitting device 1b was formed over the second hole-transport layer 916 by co-evaporation of SiTrzCz2, PSiCzCz, and Pt(mmtBubOcz35dm4tBuppy-d₆) at a weight ratio of 0.45:0.45:0.10 to a thickness of 25 nm by an evaporation method using resistance heating.

The second electron-transport layer 918 was formed over the second light-emitting layer 917 in the following manner: by an evaporation method using resistance heating, the second electron-transport layer 918_1 was formed by evaporation of mFBPTzn to a thickness of 10 nm, and then the second electron-transport layer 918_2 was formed by co-evaporation of 4-[3,5-bis(9H-carbazol-9-yl)phenyl]-2-phenyl-6-(biphenyl-4-yl)pyrimidine (abbreviation: 6BP-4Cz2PPm) and Liq at a volume ratio of 1:1 to a thickness of 25 nm.

Table 1 lists the structures of the light-emitting devices 1B and the comparative light-emitting device 1b. Note that Condition 1B in Table 1 is shown in Table 2.

TABLE 1

| | Thickness | Light-emitting devices | Comparative light- |
|---|---|---|---|
| | [nm] | 1B_1 to 1B_3 | emitting device 1b |
| Cap layer | 70 | DBT3P-II | |
| Second electrode 902 | 15 | Ag:Mg (1:0.1) | |
| Electron-injection layer 919 | 1 | Liq | |
| Second electron-transport layer 918_2 | 25 | TznP2N:Liq (1:1) | 6BP-4Cz2PPm:Liq (1:1) |

| | | |
|---|---|---|
| Second electron-transport layer 918_1 | 10 | mFBPTzn |
| Second light-emitting layer 917 | 25 | Condition 1B |
| Second hole-transport layer 916_2 | 5 | PSiCzCz |
| Second hole-transport layer 916_1 | 50 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Li₂O (1:0.02) |
| First electron-transport layer 913 | 10 | mPCCzPTzn-02 |
| First light-emitting layer 912 | 25 | Condition 1B |
| First hole-transport layer 911_2 | 5 | PSiCzCz |
| First hole-transport layer 911_1 | 45 | oFBiSF(2) |
| Hole-injection layer 910 | 10 | oFBiSF(2):OCHD-003 (1:0.03) |
| First electrode 901 | 85 | ITSO |
| | 100 | Ag |

TABLE 2

| | Condition 1B |
|---|---|
| Light-emitting | SiTrzCz2-d₁₆:PSiCzCz:Pt(mmtBubOcz35dm4tBuppy-d₆) |
| device 1B_1 | (0.45:0.45:0.10) |
| Light-emitting | SiTrzCz2:PSiCzCz-d₁₅:Pt(mmtBubOcz35dm4tBuppy-d₆) |
| device 1B_2 | (0.45:0.45:0.10) |
| Light-emitting | SiTrzCz2-d₁₆:PSiCzCz- |
| device 1B_3 | d₁₅:Pt(mmtBubOcz35dm4tBuppy-d₆) |
| | (0.45:0.45:0.10) |
| Comparative | SiTrzCz2:PSiCzCz:Pt(mmtBubOcz35dm4tBuppy-d₆) |
| light-emitting | (0.45:0.45:0.10) |
| device 1b | |

### <Fabrication Method of Light-Emitting Device 1R>

The light-emitting device 1R is different from the light-emitting device 1B_1 in the structures and thicknesses of the first and second light-emitting layers 912 and 917 and the first and second hole-transport layers 911 and 916. Other components were fabricated in a manner similar to that for the light-emitting device 1B_1.

Specifically, each of the first and second light-emitting layers 912 and 917 in the light-emitting device 1R was formed by co-evaporation of 11-[3′-(dibenzothiophen-4-yl)biphenyl-3-yl]phenanthro[9′,10′:4,5]furo[2,3-b]pyrazine (abbreviation: 11mDBtBPPnfpr), N-(biphenyl-4-yl)-N-[4-(9-phenyl-9H-carbazol-3-yl)phenyl]-9,9-dimethyl-9H-fluoren-2-amine (abbreviation: PCBBiF), and OCPG-006 as a material that emits red phosphorescent light at a weight ratio of 0.7:0.3:0.05 to a thickness of 40 nm.

As the first hole-transport layer 911_1 of the light-emitting device IR, oFBiSF (2) was deposited to a thickness of 150 nm, and as the second hole-transport layer 916_1, oFBiSF (2) was deposited to a thickness of 65 nm.

<Fabrication Method of Comparative Light-Emitting Device 1r>

The comparative light-emitting device Ir is different from the light-emitting device 1R in the structure of the second electron-transport layer 918_2. Other components were fabricated in a manner similar to that for the light-emitting device 1R.

Specifically, the second electron-transport layer 918_2 was formed by co-evaporation of 6BP-4Cz2PPm and Liq at a volume ratio of 1:1 to a thickness of 25 nm by an evaporation method using resistance heating.

Table 3 lists the structures of the light-emitting device 1R and the comparative light-emitting device 1r.

TABLE 3

| | Thickness | Light-emitting | Comparative light- |
|---|---|---|---|
| | [nm] | device 1R | emitting device 1r |
| Cap layer | 70 | DBT3P-II | |
| Second electrode 902 | 15 | Ag:Mg (1:0.1) | |
| Electron-injection layer 919 | 1 | Liq | |
| Second electron-transport layer 918_2 | 25 | TznP2N:Liq (1:1) | 6BP-4Cz2PPm:Liq (1:1) |

| | | |
|---|---|---|
| Second electron-transport layer 918_1 | 10 | mFBPTzn |
| Second light-emitting layer 917 | 40 | 11mDBtBPPnfpr:PCBBiF:OCPG-006 |
| | | (0.7:0.3:0.05) |
| Second hole-transport layer 916_1 | 65 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Li₂O (1:0.02) |
| First electron-transport layer 913 | 10 | mPCCzPTzn-02 |
| First light-emitting layer 912 | 40 | 11mDBtBPPnfpr:PCBBiF:OCPG-006 |
| | | (0.7:0.3:0.05) |
| First hole-transport layer 911_1 | 150 | oFBiSF(2) |
| Hole-injection layer 910 | 10 | oFBiSF(2):OCHD-003 (1:0.03) |
| First electrode 902 | 85 | ITSO |
| | 100 | Ag |

### <Fabrication Method of Light-Emitting Device 1G>

The light-emitting device 1G is different from the light-emitting device IR in the thicknesses of the first and second hole-transport layers 911 and 916 and the structures of the first and second light-emitting layers 912 and 917. Other components were fabricated in a manner similar to that for the light-emitting device 1R.

Specifically, the first light-emitting layer 912 and the second light-emitting layer 917 in the light-emitting device 1G were each formed by co-evaporation of 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), 9-(2-naphthyl)-9′-phenyl-3,3′-bi-9H-carbazole (abbreviation: βNCCP), and [2-d₃-methyl-8-(2-pyridinyl-κN)benzofuro[2,3-b]pyridine-κC]bis[2-(5-d₃-methyl-2-pyridinyl-κN²)phenyl-C]iridium(III) (abbreviation: Ir(5mppy-d₃)₂(mbfpypy-d₃)) at a weight ratio of 0.5:0.5:0.1 to a thickness of 40 nm by an evaporation method using resistance heating.

In the light-emitting device 1G, the thickness of the first hole-transport layer 911 was set to 80 nm, and the thickness of the second hole-transport layer 916 was set to 50 nm.

<Fabrication Method of Comparative Light-Emitting Device 1g>

The comparative light-emitting device 1g is different from the light-emitting device 1G in the structure of the second electron-transport layer 918_2. Other components were fabricated in a manner similar to that for the light-emitting device 1G.

Specifically, the second electron-transport layer 918_2 was formed by co-evaporation of 6BP-4Cz2PPm and Liq at a volume ratio of 1:1 to a thickness of 25 nm by an evaporation method using resistance heating.

Table 4 lists the structures of the light-emitting device 1G and the comparative light-emitting device 1g.

TABLE 4

| | Thickness | Light-emitting | Comparative light- |
|---|---|---|---|
| | [nm] | device 1G | emitting device 1g |
| Cap layer | 70 | DBT3P-II | |
| Second electrode 902 | 15 | Ag:Mg (1:0.1) | |
| Electron-injection layer 919 | 1 | Liq | |
| Second electron-transport layer 918_2 | 25 | TznP2N:Liq (1:1) | 6BP-4Cz2PPm:Liq (1:1) |

| | | |
|---|---|---|
| Second electron-transport layer 918_1 | 10 | mFBPTzn |
| Second light-emitting layer 917 | 40 | 8mpTP-4mDBtPBfpm:βNCCP:Ir(5mppy-d₃)₂(mbfpypy-d₃) |
| | | (0.5:0.5:0.1) |
| Second hole-transport layer 916_1 | 50 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Li₂O (1:0.02) |
| First electron-transport layer 913 | 10 | mPCCzPTzn-02 |
| First light-emitting layer 912 | 40 | 8mpTP-4mDBtPBfpm:βNCCP:Ir(5mppy-d₃)₂(mbfpypy-d₃) |
| | | (0.5:0.5:0.1) |
| First hole-transport layer 911_1 | 80 | oFBiSF(2) |
| Hole-injection layer 910 | 10 | oFBiSF(2):OCHD-003 (1:0.03) |
| First electrode 902 | 85 | ITSO |
| | 100 | Ag |

### <Measurement Results of PL Spectra of Host Materials Used in Light-Emitting Devices>

PL spectra of thin films of host materials used in the devices were measured at room temperature. Specifically, PL spectra of thin films of SiTrzCz2, SiTrzCz2-d₁₆, PSiCzCz, and PSiCzCz-d₁₅, which were used in the light-emitting devices 1B_1 to 1B_3 and the comparative light-emitting device 1b, were measured at room temperature. In addition, PL spectra of a mixed film of SiTrzCz2 and PSiCzCz-dis, a mixed film of SiTrzCz2-d₁₆ and PSiCzCz-dis, and a mixed film of SiTrzCz2 and PSiCzCz were measured at room temperature.

Furthermore, PL spectra of thin films of 11mDBtBPPnfpr and PCBBiF and a mixed film of 11mDBtBPPnfpr and PCBBiF were measured at room temperature; these materials were used in the light-emitting device 1R and the comparative light-emitting device 1r. Moreover, PL spectra of thin films of 8mpTP-4mDBtPBfpm and βNCCP and a mixed film of 8mpTP-4mDBtPBfpm and βNCCP were measured at room temperature; these materials were used in the light-emitting device 1G and the comparative light-emitting device 1g.

Each of the above PL spectra was measured using a 50-nm-thick thin film deposited over a quartz substrate. Each of the mixed films was deposited by co-evaporation of the organic compounds at a weight ratio of 1:1. A spectrofluorometer FP-8600DS produced by JASCO Corporation was used for the measurement of the PL spectra.

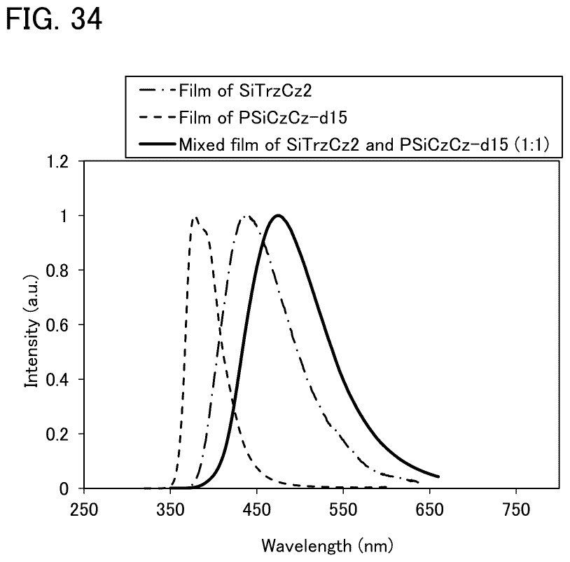

FIG. 34 shows the PL spectra of the film of SiTrzCz2, the film of PSiCzCz-d₁₅, and the mixed film of SiTrzCz2 and PSiCzCz-dis; these materials were used in the light-emitting device 1B_2. Peak wavelengths of the PL spectra of the film of SiTrzCz2, the film of PSiCzCz-dis, and the mixed film of SiTrzCz2 and PSiCzCz-dis are 437 nm, 378 nm, and 475 nm, respectively, revealing that the peak wavelength of the PL spectrum of the mixed film of SiTrzCz2 and PSiCzCz-dis is longer than that of the PL spectrum of each of the film of SiTrzCz2 and the film of PSiCzCz-d₁₅. It has been found that the PL spectrum of the mixed film of SiTrzCz2 and PSiCzCz-dis is different from the spectrum obtained by superimposing the spectra of the films of SiTrzCz2 and PSiCzCz-dis, and shifted to a longer wavelength than each of the PL spectra of the films of SiTrzCz2 and PSiCzCz-d₁₅. The above indicates that the observed PL spectrum originates from an exciplex formed by SiTrzCz2 and PSiCzCz-dis in the mixed film, which were excited at room temperature.

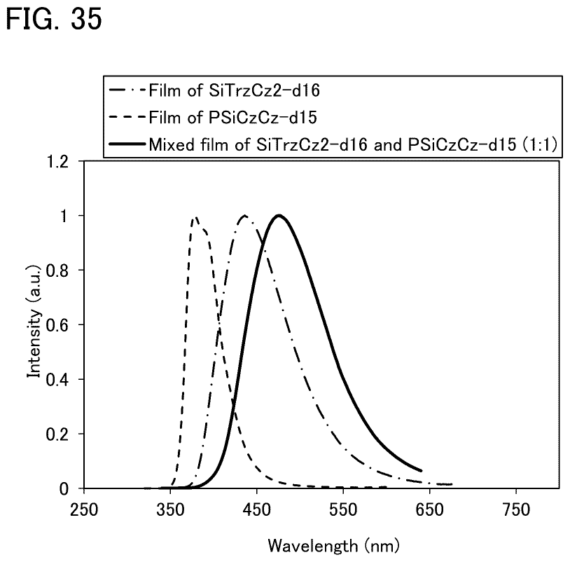

FIG. 35 shows the PL spectra of the film of SiTrzCz2-d₁₆, the film of PSiCzCz-dis, and the mixed film of SiTrzCz2-d₁₆ and PSiCzCz-dis; these materials were used in the light-emitting device 1B 3. Peak wavelengths of the PL spectra of the film of SiTrzCz2-d₁₆, the film of PSiCzCz-d₁₅, and the mixed film of SiTrzCz2-d₁₆ and PSiCzCz-dis are 436 nm, 378 nm, and 475 nm, respectively, revealing that the peak wavelength of the PL spectrum of the mixed film of SiTrzCz2-d₁₆ and PSiCzCz-dis is longer than that of the PL spectrum of each of the film of SiTrzCz2-d₁₆ and the film of PSiCzCz-dis. It has been found that the PL spectrum of the mixed film of SiTrzCz2-d₁₆ and PSiCzCz-dis is different from the spectrum obtained by superimposing the spectra of the films of SiTrzCz2-d₁₆ and PSiCzCz-dis, and shifted to a longer wavelength than each of the PL spectra of the films of SiTrzCz2-d₁₆ and PSiCzCz-d₁₅. The above indicates that the observed PL spectrum originates from an exciplex formed by SiTrzCz2-d₁₆ and PSiCzCz-dis in the mixed film, which were excited at room temperature.

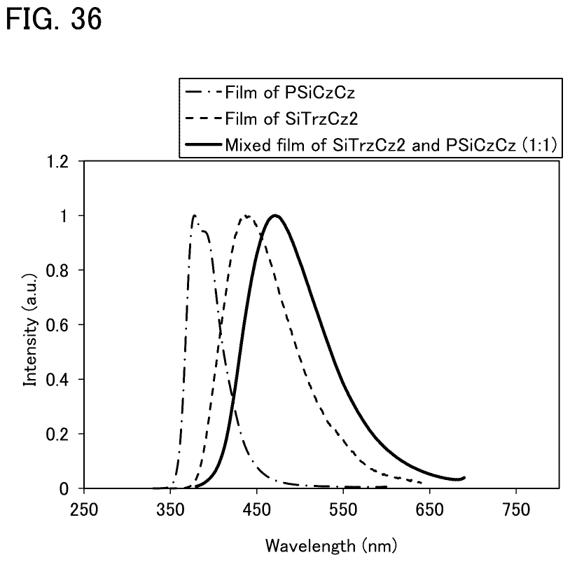

FIG. 36 shows the PL spectra of the film of PSiCzCz, the film of SiTrzCz2, and the mixed film of PSiCzCz and SiTrzCz2; these materials were used in the comparative light-emitting device 1b. Peak wavelengths of the PL spectra of the film of SiTrzCz2, the film of PSiCzCz, and the mixed film of SiTrzCz2 and PSiCzCz are 437 nm, 378 nm, and 471 nm, respectively, revealing that the peak wavelength of the PL spectrum of the mixed film of SiTrzCz2 and PSiCzCz is longer than that of the PL spectrum of each of the film of SiTrzCz2 and the film of PSiCzCz. It has been found that the PL spectrum of the mixed film of SiTrzCz2 and PSiCzCz is different from the spectrum obtained by superimposing the spectra of the films of PSiCzCz and SiTrzCz2, and shifted to a longer wavelength than each of the PL spectra of the films of PSiCzCz and SiTrzCz2. The above indicates that the observed PL spectrum originates from an exciplex formed by PSiCzCz and SiTrzCz2 in the mixed film, which were excited at room temperature.

Similarly, SiTrzCz2-d₁₆ and PSiCzCz in the mixed film which were used in the light-emitting device 1B_1 also form an exciplex when excited at room temperature.

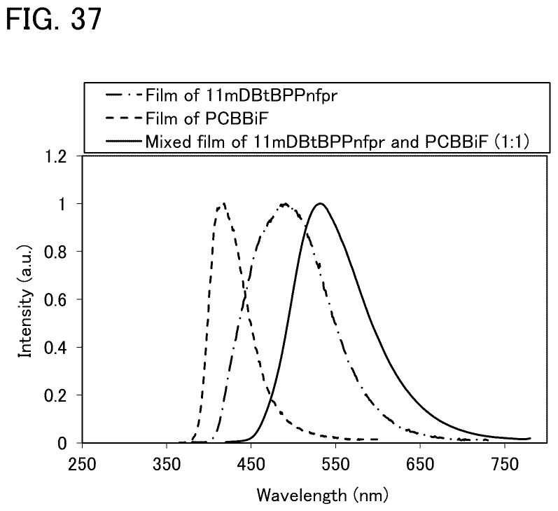

FIG. 37 shows the PL spectra of the film of 11mDBtBPPnfpr, the film of PCBBiF, and the mixed film of 11mDBtBPPnfpr and PCBBiF; these materials were used in the light-emitting device IR and the comparative light-emitting device 1r. Peak wavelengths of the PL spectra of the film of 11mDBtBPPnfpr, the film of PCBBiF, and the mixed film of 11mDBtBPPnfpr and PCBBiF are 491 nm, 419 nm, and 532 nm, respectively, revealing that the peak wavelength of the PL spectrum of the mixed film of 11mDBtBPPnfpr and PCBBiF is longer than that of the PL spectrum of each of the film of 11mDBtBPPnfpr and the film of PCBBiF. It has also been found that the PL spectrum of the mixed film of 11mDBtBPPnfpr and PCBBIF is different from the spectrum obtained by superimposing the spectra of the films of 11mDBtBPPnfpr and PCBBIF, and shifted to a longer wavelength than each of the PL spectra of the films of 11mDBtBPPnfpr and PCBBiF. The above indicates that the observed PL spectrum originates from an exciplex formed by 11mDBtBPPnfpr and PCBBiF in the mixed film, which were excited at room temperature.

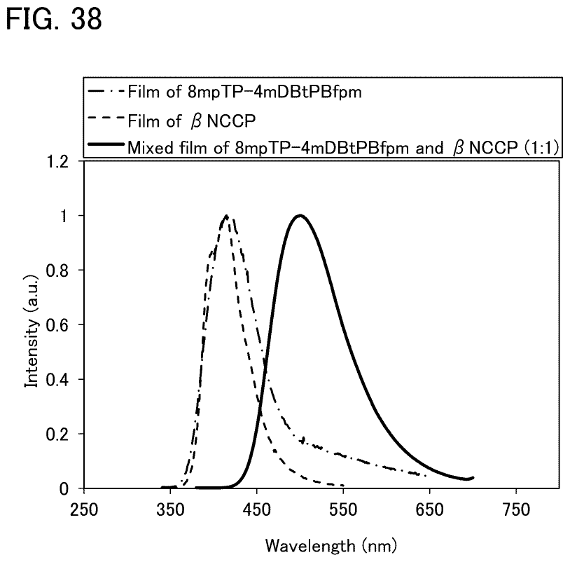

FIG. 38 shows the PL spectra of the film of 8mpTP-4mDBtPBfpm, the film of βNCCP, and the mixed film of 8mpTP-4mDBtPBfpm and βNCCP; these materials were used in the light-emitting device 1G and the comparative light-emitting device 1g. The peak wavelengths of the PL spectra of the film of 8mpTP-4mDBtPBfpm, the film of βNCCP, and the mixed film of 8mpTP-4mDBtPBfpm and βNCCP are 416 nm, 415 nm, and 500 nm, respectively, revealing that the peak wavelength of the PL spectrum of the mixed film of 8mpTP-4mDBtPBfpm and βNCCP is longer than that of the PL spectrum of each of the film of 8mpTP-4mDBtPBfpm and the film of βNCCP. It has also been found that the PL spectrum of the mixed film of 8mpTP-4mDBtPBfpm and βNCCP is different from the spectrum obtained by superimposing the spectra of the films of 8mpTP-4mDBtPBfpm and βNCCP, and shifted to a longer wavelength than each of the PL spectra of the films of 8mpTP-4mDBtPBfpm and βNCCP. The above indicates that the observed PL spectrum originates from an exciplex formed by 8mpTP-4mDBtPBfpm and βNCCP in the mixed film, which were excited at room temperature.

Absorption spectra and PL spectra of Pt(mmtBubOcz35dm4ppy-d₆), OCPG-006, and Ir(5mppy-d₃)₂(mbfpypy-d₃), which were emission center substances, were measured at room temperature. The absorption spectra of the emission center substances were measured with an ultraviolet-visible spectrophotometer (V-770DS, produced by JASCO Corporation). The PL spectra were measured with a fluorescence spectrophotometer (FP-8600, produced by JASCO Corporation). The absorption and PL spectra of the emission center substances were measured using solutions thereof with chloroform as a solvent.

The absorption edge of the absorption spectrum was determined as the intersection between a tangent and the horizontal axis or the baseline. The tangent was drawn at a point at which the slope on a longer wavelength side of the longest-wavelength peak (or the longest-wavelength shoulder peak) of the absorption spectrum has the maximum absolute value. The emission edge on the shorter wavelength side of the PL spectrum was determined as the intersection between a tangent and the horizontal axis or the baseline. The tangent was drawn at a point at which the slope on a shorter wavelength side of the shortest-wavelength peak (or the shortest-wavelength shoulder peak) of the PL spectrum has the maximum absolute value.

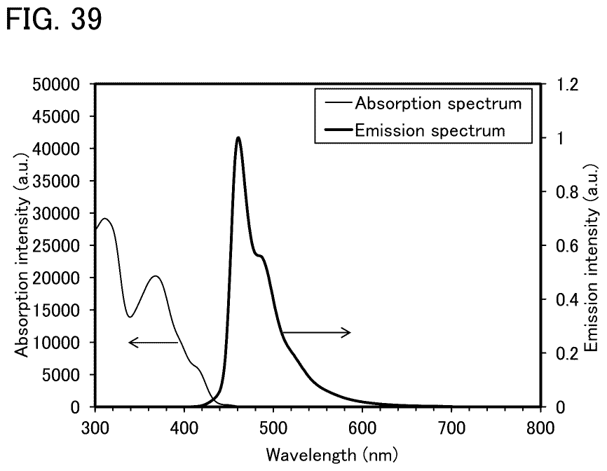

As shown in FIG. 39, the absorption edge on the longer wavelength side of the absorption spectrum of Pt(mmtBubOcz35dm4ppy-d₆) is at 463 nm. As shown in FIGS. 34 to 36, the emission edge on the shorter wavelength side of the PL spectrum of each of the mixed film of SiTrzCz2 and PSiCzCz-dis, the mixed film of SiTrzCz2-d₁₆ and PSiCzCz-dis, and the mixed film of SiTrzCz2 and PSiCzCz (the PL spectrum of the exciplex) is at 408 nm. These indicate that the absorption edge on the longer wavelength side of the absorption spectrum of Pt(mmtBubOcz35dm4ppy-d₆) used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting devices 1B_1 to 1B_3 and the comparative light-emitting device 1b.

The emission edge of the PL spectrum of Pt(mmtBubOcz35dm4ppy-d₆) is at 445 nm. This indicates that the emission edge on the shorter wavelength side of the PL spectrum of Pt(mmtBubOcz35dm4ppy-d₆) used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting devices 1B_1 to 1B_3 and the comparative light-emitting device 1b.

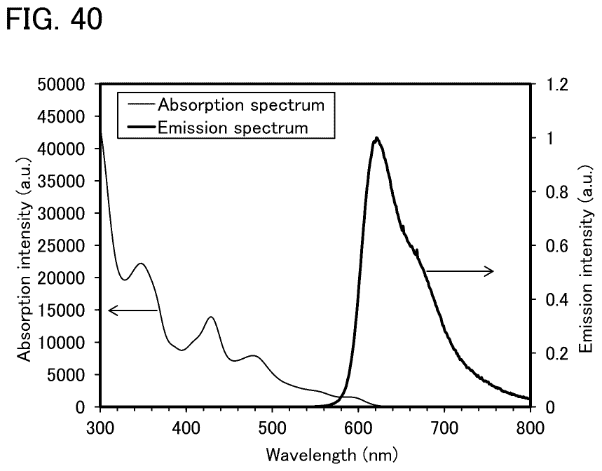

As shown in FIG. 40, the absorption edge on the longer wavelength side of the absorption spectrum of OCPG-006 is at 622 nm. As shown in FIG. 37, the emission edge on the shorter wavelength side of the PL spectrum of the mixed film of 11mDBtBPPnfpr and PCBBiF (the PL spectrum of the exciplex) is at 469 nm. These indicate that the absorption edge on the longer wavelength side of the absorption spectrum of OCPG-006 used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting device IR and the comparative light-emitting device 1r.

The emission edge of the PL spectrum of OCPG-006 is at 589 nm. This indicates that the emission edge on the shorter wavelength side of the PL spectrum of OCPG-006 used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting device 1R and the comparative light-emitting device 1r.

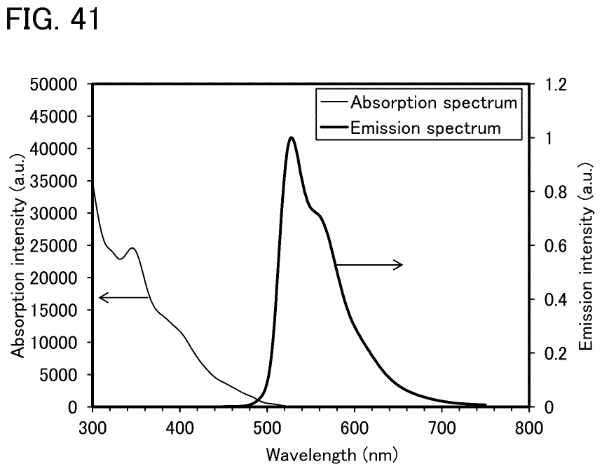

As shown in FIG. 41, the absorption edge on the longer wavelength side of the absorption spectrum of Ir(5mppy-d₃)₂(mbfpypy-d₃) is at 526 nm. As shown in FIG. 38, the emission edge on the shorter wavelength side of the PL spectrum of the mixed film of 8mpTP-4mDBtPBfpm and βNCCP (the PL spectrum of the exciplex) is at 442 nm. These indicate that the absorption edge on the longer wavelength side of the absorption spectrum of Ir(5mppy-d₃)₂(mbfpypy-d₃) used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting device 1G and the comparative light-emitting device 1g.

The emission edge of the PL spectrum of Ir(5mppy-d₃)₂(mbfpypy-d₃) is at 502 nm. This indicates that the emission edge on the shorter wavelength side of the PL spectrum of Ir(5mppy-d₃)₂(mbfpypy-d₃) used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting device 1G and the comparative light-emitting device 1g.

In addition, the HOMO levels and the LUMO levels of the host materials and the light-emitting substances used in the devices were measured. The values of the HOMO levels and the LUMO levels were obtained through a cyclic voltammetry (CV) measurement. In the cyclic voltammetry (CV) measurement, the values (E) of the HOMO and LUMO levels were calculated on the basis of an oxidation peak potential (Eₚₐ) and a reduction peak potential (E_{pc}), which were obtained by changing the potential of a working electrode with respect to a reference electrode. In the measurement, a HOMO level and a LUMO level were obtained by potential scanning in the positive direction and potential scanning in the negative direction, respectively. The scanning speed in the measurement was 0.1 V/s. Specifically, a standard oxidation-reduction potential (Eₒ) (=Eₚₐ+E_{pc})/2) was calculated from an oxidation peak potential (Eₚₐ) and a reduction peak potential (E_{pc}), which were obtained by the cyclic voltammogram of a material. Then, the standard oxidation-reduction potential (Eₒ) was subtracted from the potential energy (Eₓ) of the reference electrode with respect to a vacuum level, whereby each of the values (E) (=Eₓ−Eₒ) of HOMO and LUMO levels was obtained. Note that the reversible oxidation-reduction wave was obtained in the above case; in the case where an irreversible oxidation-reduction wave is obtained, the HOMO level is calculated as follows: a value obtained by subtracting a predetermined value (0.1 eV) from an oxidation peak potential (Eₚₐ) is assumed to be a reduction peak potential (E_{pc}), and a standard oxidation-reduction potential (Eₒ) is calculated to one decimal place. To calculate the LUMO level, a value obtained by adding a predetermined value (0.1 eV) to a reduction peak potential (E_{pc}) was assumed to be an oxidation peak potential (Eₚₐ), and a standard oxidation-reduction potential (Eₒ) was calculated to one decimal place.

The HOMO levels of PSiCzCz-dis and PSiCzCz as the hole-transport organic compounds were each −5.7 eV. Furthermore, the HOMO levels of SiTrzCz2-d₁₆ and SiTrzCz2 as the electron-transport organic compounds have each been found to be lower than or equal to −6.0 eV because the oxidation potential was not observed in cyclic voltammetry (CV) measurement. The LUMO levels of PSiCzCz-dis and PSiCzCz as the hole-transport organic compounds were −2.05 eV and −2.06 eV, respectively, and the LUMO levels of SiTrzCz2-d₁₆ and SiTrzCz2 as the electron-transport organic compounds were each −2.98 eV. Since the HOMO level of the hole-transport organic compound was higher than or equal to the HOMO level of the electron-transport organic compound and the LUMO level of the hole-transport organic compound was higher than or equal to the LUMO level of the electron-transport organic compound, the light-emitting devices 1B_1 to 1B_3 and the comparative light-emitting device 1b have each been found to include the host materials that can efficiently form an exciplex.

The HOMO level and the LUMO level of Pt(mmtBubOcz35dm4ppy-d₆) were −5.5 eV and −2.47 eV, respectively. This indicates that the energy difference between the HOMO level (−5.5 eV) and the LUMO level (−2.47 eV) of Pt(mmtBubOcz35dm4ppy-d₆), which corresponds to the band gap thereof, was 3.03 eV. The energy difference between the HOMO and LUMO levels of the exciplex formed by the host materials corresponds to the energy difference between the HOMO level (−5.7 eV) of PSiCzCz-dis or PSiCzCz as the hole-transport organic compound and the LUMO level (−2.98 eV) of SiTrzCz2-d₁₆ or SiTrzCz2 as the electron-transport organic compound. Thus, the energy difference between the HOMO and LUMO levels of each of the exciplex formed by SiTrzCz2-d₁₆ and PSiCzCz, the exciplex formed by SiTrzCz2 and PSiCzCz-d₁₅, the exciplex formed by SiTrzCz2-d₁₆ and PSiCzCz-dis, and the exciplex formed by SiTrzCz2 and PSiCzCz was 2.72 eV. This indicates that the energy difference between the HOMO and LUMO levels of Pt(mmtBubOcz35dm4ppy-d₆) was greater than the energy difference between the HOMO and LUMO levels of the exciplex.

The HOMO level of PCBBiF as the hole-transport organic compound was −5.36 eV, and the HOMO level of 11mDBtBPPnfpr as the electron-transport organic compound was −6.16 eV. The LUMO level of PCBBiF as the hole-transport organic compound was −2.00 eV, and the LUMO level of 11mDBtBPPnfpr as the electron-transport organic compound was −3.02 eV. Since the HOMO level of the hole-transport organic compound is higher than or equal to the HOMO level of the electron-transport organic compound and the LUMO level of the hole-transport organic compound is higher than or equal to the LUMO level of the electron-transport organic compound, the light-emitting device IR and the comparative light-emitting device Ir have each been found to include the host materials that can efficiently form an exciplex.

The HOMO level and the LUMO level of OCPG-006 were −5.26 eV and −2.69 eV, respectively. This indicates that the energy difference between the HOMO level (−5.26 eV) and the LUMO level (−2.69 eV) of OCPG-006, which corresponds to the band gap thereof, was 2.57 eV. The energy difference between the HOMO level and the LUMO level of the exciplex formed by the host materials was 2.34 eV, which corresponds to the energy difference between the HOMO level (−5.36 eV) of PCBBiF as the hole-transport organic compound and the LUMO level (−3.02 eV) of 11mDBtBPPnfpr as the electron-transport organic compound. This indicates that the energy difference between the HOMO and LUMO levels of OCPG-006 was greater than the energy difference between the HOMO and LUMO levels of the exciplex.

The HOMO level of βNCCP as the hole-transport organic compound was −5.62 eV, and the HOMO level of 8mpTP-4mDBtPBfpm as the electron-transport organic compound was −6.22 eV. The LUMO level of βNCCP as the hole-transport organic compound was −2.21 eV, and the LUMO level of 8mpTP-4mDBtPBfpm as the electron-transport organic compound was −3.01 eV. Since the HOMO level of the hole-transport organic compound is higher than or equal to the HOMO level of the electron-transport organic compound and the LUMO level of the hole-transport organic compound is higher than or equal to the LUMO level of the electron-transport organic compound, the light-emitting device 1G and the comparative light-emitting device 1g have each been found to include the host materials that can efficiently form an exciplex.

The HOMO level and the LUMO level of Ir(5mppy-d₃)₂(mbfpypy-d₃) were −5.32 eV and −2.39 eV, respectively. This indicates that the energy difference between the HOMO level (−5.32 eV) and the LUMO level (−2.39 eV) of Ir(5mppy-d₃)₂(mbfpypy-d₃), which corresponds to the band gap thereof, was 2.93 eV. The energy difference between the HOMO level and the LUMO level of the exciplex formed by the host materials was 2.61 eV, which corresponds to the energy difference between the HOMO level (−5.62 eV) of βNCCP as the hole-transport organic compound and the LUMO level (−3.01 eV) of 8mpTP-4mDBtPBfpm as the electron-transport organic compound. This indicates that the energy difference between the HOMO and LUMO levels of Ir(5mppy-d₃)₂(mbfpypy-d₃) was greater than the energy difference between the HOMO and LUMO levels of the exciplex.

The T₁ levels of the host materials of the light-emitting layer and the substances used for the first and second hole-transport layers and the first and second electron-transport layers were also measured. For calculation of each T₁ level, a PL spectrum (a phosphorescence spectrum) was observed at a measurement temperature of 10 K using a 50-nm-thick thin film of a sample formed over a quartz substrate. The measurement was performed with a PL microscope (LabRAM HR-PL, produced by HORIBA, Ltd.) and a He—Cd laser (325 nm) as excitation light. The emission edge was determined as the intersection between a tangent and the horizontal axis (representing wavelength) or the baseline. The tangent was drawn at a point at which the slope on a shorter wavelength side of the shortest-wavelength peak (or the shortest-wavelength shoulder peak) of the PL spectrum (phosphorescence spectrum) has the maximum absolute value.

FIGS. 28A and 28B show the results of SiTrzCz2 and SiTrzCz2-d₁₆ as the electron-transport organic compounds. According to FIGS. 28A and 28B, the T₁ levels of SiTrzCz2 and SiTrzCz2-d₁₆ are 2.92 eV (424 nm) and 2.93 eV (423 nm), respectively. FIGS. 29A and 29B show the results of PSiCzCz and PSiCzCz-dis as the hole-transport organic compounds. According to FIGS. 29A and 29B, the T₁ levels of PSiCzCz and PSiCzCz-dis are 2.97 eV (418 nm) and 2.97 eV (417 nm), respectively. The difference between the T₁ level of SiTrzCz2-d₁₆ and the T₁ level of PSiCzCz, the difference between the T₁ level of SiTrzCz2 and the T₁ level of PSiCzCz-dis, and the difference between the T₁ level of SiTrzCz2-d₁₆ and the T₁ level of PSiCzCz-dis are each less than or equal to 0.20 eV, and the efficiency of energy transfer from the triplet excited state is improved by the influence of deuterium; thus, deterioration of the host materials can be inhibited.

FIG. 30 shows the result of 11mDBtBPPnfpr as the electron-transport organic compound. According to FIG. 30, the T₁ level of 11mDBtBPPnfpr is 2.20 eV (563 nm). FIG. 31 shows the result of PCBBiF as the hole-transport organic compound. According to FIG. 31, the T₁ level of PCBBiF is 2.49 eV (498 nm). FIG. 32A shows the result of 8mpTP-4mDBtPBfpm as the electron-transport organic compound. According to FIG. 32A, the T₁ level of 8mpTP-4mDBtPBfpm is 2.55 eV (486 nm). FIG. 33A shows the result of βNCCP as the hole-transport organic compound. According to FIG. 33A, the T₁ level of βNCCP is 2.55 eV (486 nm).

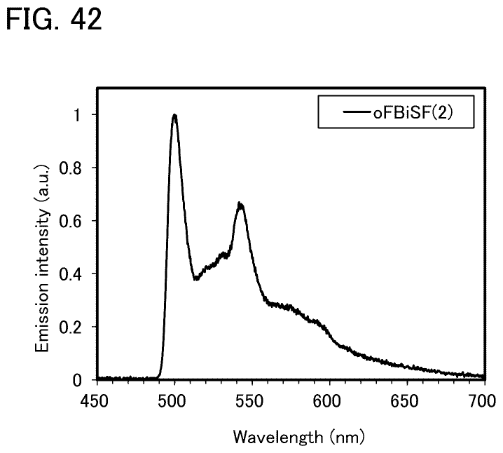

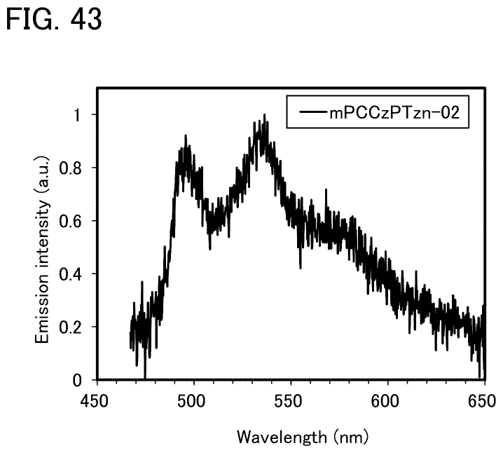

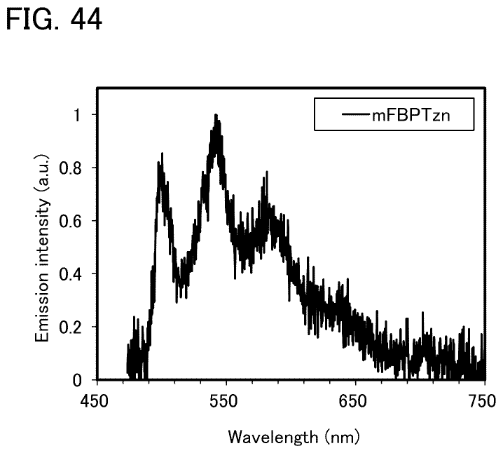

FIG. 42 shows the result of oFBiSF (2) as the hole-transport organic compound. According to FIG. 42, the T₁ level of oFBiSF (2) is 2.52 eV (492 nm). FIG. 43 shows the result of mPCCzPTzn-02 as the electron-transport organic compound. According to FIG. 43, the T₁ level of mPCCzPTzn-02 is 2.59 eV (478 nm). FIG. 44 shows the result of mFBPTzn as the electron-transport organic compound. According to FIG. 44, the T₁ level of mFBPTzn is 2.54 eV (488 nm).

Since each of the emission center substances used in the light-emitting devices 1B, 1R, and 1G is a phosphorescent substance, the T₁ level of each emission center substance can be measured from a PL spectrum. The emission edge was determined as the intersection between a tangent and the horizontal axis (representing wavelength) or the baseline. The tangent was drawn at a point at which the slope on a shorter wavelength side of the shortest-wavelength peak (or the shortest-wavelength shoulder peak) of the PL spectrum has the maximum absolute value. The T₁ level of Pt(mmtBubOcz35dm4ppy-d₆) is 2.79 eV (445 nm), the T₁ level of OCPG-006 is 2.10 eV (589 nm), and the T₁ level of Ir(5mppy-d₃)₂(mbfpypy-d₃) is 2.47 eV (502 nm).

The T₁ level (2.97 eV) of PSiCzCz-dis, the T₁ level (2.97 eV) of PSiCzCz, the T₁ level (2.93 eV) of SiTrzCz2-d₁₆, and the T₁ level (2.95 eV) of SiTrzCz2, which are the host materials, have each been found to be higher than the T₁ level (2.79 eV) of Pt(mmtBubOcz35dm4ppy-d₆) as the emission center substance. This indicates that the light-emitting device 1B emits light efficiently. Furthermore, the T₁ level (2.49 eV) of PCBBIF and the T₁ level (2.20 eV) of 11mDBtBPPnfpr, which are the host materials, have each been found to be higher than the T₁ level (2.10 eV) of OCPG-006 as the emission center substance. This indicates that the light-emitting device IR emits light efficiently. Furthermore, the T₁ level (2.55 eV) of βNCCP and the T₁ level (2.55 eV) of 8mpTP-4mDBtPBfpm, which are the host materials, have each been found to be higher than the T₁ level (2.47 eV) of Ir(5mppy-d₃)₂(mbfpypy-d₃) as the emission center substance. This indicates that the light-emitting device 1G emits light efficiently.

Furthermore, the T₁ level (2.97 eV) of PSiCzCz used for the first hole-transport layer and the second hole-transport layer has been found to be higher than the T₁ level (2.79 eV) of Pt(mmtBubOcz35dm4ppy-d₆) as the emission center substance. This indicates that the light-emitting device 1B emits light efficiently. Furthermore, the T₁ level (2.52 eV) of oFBiSF (2) used for the first hole-transport layer and the second hole-transport layer has been found to be higher than the T₁ level (2.10 eV) of OCPG-006 as the emission center substance. This indicates that the light-emitting device IR emits light efficiently. Furthermore, the T₁ level (2.52 eV) of oFBiSF (2) used for the first hole-transport layer and the second hole-transport layer has been found to be higher than the T₁ level (2.47 eV) of Ir(5mppy-d₃)₂(mbfpypy-d₃) as the emission center substance. This indicates that the light-emitting device 1G emits light efficiently.

The T₁ level (2.59 eV) of mPCCzPTzn-02 used for the first electron-transport layer and the T₁ level (2.54 eV) of mFBPTzn used for the second electron-transport layer have each been found to be lower than the T₁ level (2.79 eV) of Pt(mmtBubOcz35dm4ppy-d₆) as the emission center substance. This indicates that the light-emitting devices 1B have high stability. The T₁ level (2.59 eV) of mPCCzPTzn-02 used for the first electron-transport layer and the T₁ level (2.54 eV) of mFBPTzn used for the second electron-transport layer have each been found to be higher than the T₁ level (2.10 eV) of OCPG-006 as the emission center substance. This indicates that the light-emitting device IR emits light efficiently. Furthermore, the T₁ level (2.59 eV) of mPCCzPTzn-02 used for the first electron-transport layer and the T₁ level (2.54 eV) of mFBPTzn used for the second electron-transport layer have each been found to be higher than the T₁ level (2.47 eV) of Ir(5mppy-d₃)₂(mbfpypy-d₃) as the emission center substance. This indicates that the light-emitting device 1G emits light efficiently.

### <Measurement Results of Phosphorescence Lifetimes of Host Materials Used in Light-Emitting Devices 1B>

Here, the phosphorescence lifetimes of the host materials used in the light-emitting devices 1B were measured. The measurement was performed at liquid nitrogen temperature (77 K) with FP-8600 produced by JASCO Corporation, in which a liquid nitrogen cooling unit PMU-830 was set. A solution of a material was prepared in a glove box of LABstarM13 (1250/780) produced by MBRAUN in the following manner: a sample was dissolved in 2-MeTHF that had been subjected to freeze-pump-thaw, and the concentration of the solution was adjusted to approximately 1.2 E⁻⁴ M. The prepared solution was put in a liquid sample cell (sample tube) LPH-140 for cooling produced by JASCO Corporation, the sample cell was put in a sample cell holder, and the sample cell holder was capped with a fixing nut. After liquid nitrogen was injected into a dewar of the cooling unit of FP-8600, the sample cell was taken out from the globe box and then cooled in the dewar containing the liquid nitrogen.

Time-resolved measurement was performed in the following manner: the sample cell was irradiated with excitation light for approximately 30 seconds and the emission intensity attenuating after the excitation light was blocked by a shutter was measured at 10 ms intervals. For use in the phosphorescence lifetime measurement, a phosphorescence wavelength not overlapping with a fluorescent spectrum as much as possible was selected after comparison between a PL spectrum in the phosphorescence mode and a PL spectrum in the fluorescence mode. The excitation wavelength used for the measurement can be appropriately selected, and is preferably 330 nm. The band widths of the excitation light and the measured light are each approximately 10 nm. Since light emission ideally attenuates single-exponentially, the time taken for the emission intensity to attenuate to 1/e with reference to a given time can be defined as the phosphorescence lifetime.

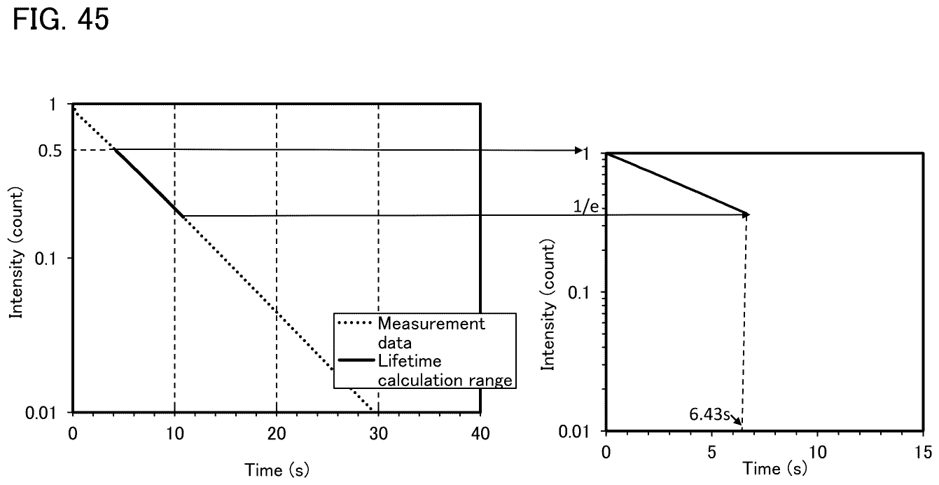

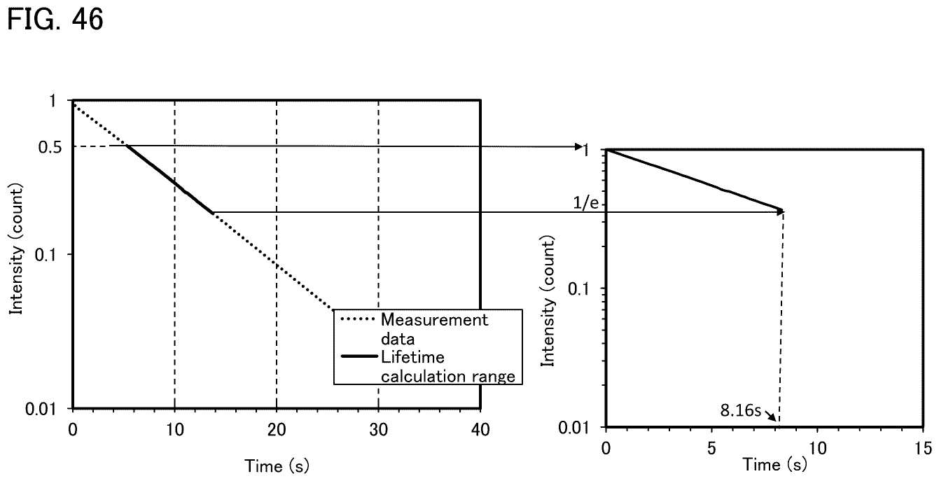

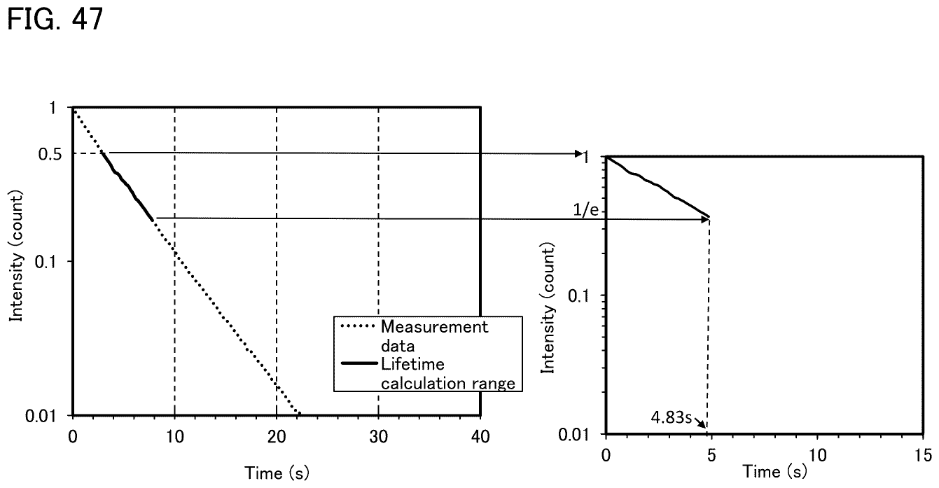

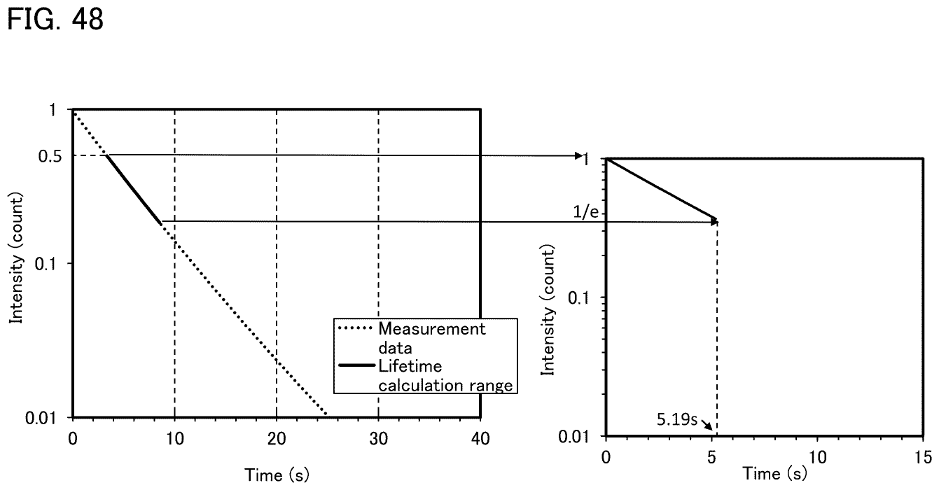

FIG. 45 shows measurement data of SiTrzCz2, FIG. 46 shows measurement data of SiTrzCz2-d₁₆, FIG. 47 shows measurement data of PSiCzCz, and FIG. 48 shows measurement data of PSiCzCz-d₁₅.

The phosphorescence lifetime was defined as follows: the time at which the light amount becomes 50% of that at the start of the measurement in the measured data was set as t=0, and the time taken for the light amount to attenuate to 1/e of that at t=0 was regarded as the phosphorescence lifetime. In the graphs in FIGS. 45 to 48, the time at which the intensity reaches 50% of that at the start of the measurement is set as time 0 s, the light amount at 0 s is regarded as 1, and the time taken for the light amount to become 1/e is the phosphorescence lifetime.

The measurement results show that the phosphorescence lifetime of SiTrzCz2 is 6.43 seconds and the phosphorescence lifetime of SiTrzCz2-d₁₆ is 8.16 seconds. Furthermore, the phosphorescence lifetime of PSiCzCz is 4.83 seconds and the phosphorescence lifetime of PSiCzCz-dis is 5.31 seconds. The phosphorescence lifetime of SiTrzCz2-d₁₆ is 1.27 times the phosphorescence lifetime of SiTrzCz2, and the phosphorescence lifetime of PSiCzCz-dis is 1.10 times the phosphorescence lifetime of PSiCzCz. The product of these multipliers is 1.40, which confirms that the phosphorescence lifetime is increased (extended) by deuteration. The phosphorescence lifetime is increased when a deuterated organic compound is used as a host material; hence, the efficiency of energy transfer from the host material to the phosphorescent substance is improved, and deterioration of the deuterated organic compound can be inhibited. Accordingly, a light-emitting device including a deuterated organic compound as an energy donor has less deterioration of the organic compound than a light-emitting device including a non-deuterated organic compound as an energy donor, and thus can have high reliability.

### <Characteristics of Light-Emitting Devices>

The light-emitting devices were sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting devices were measured.

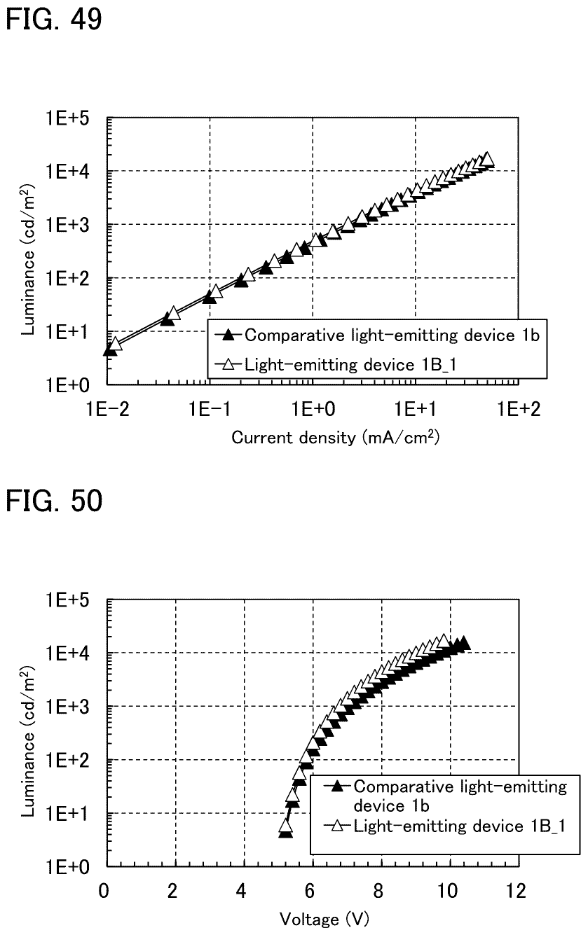

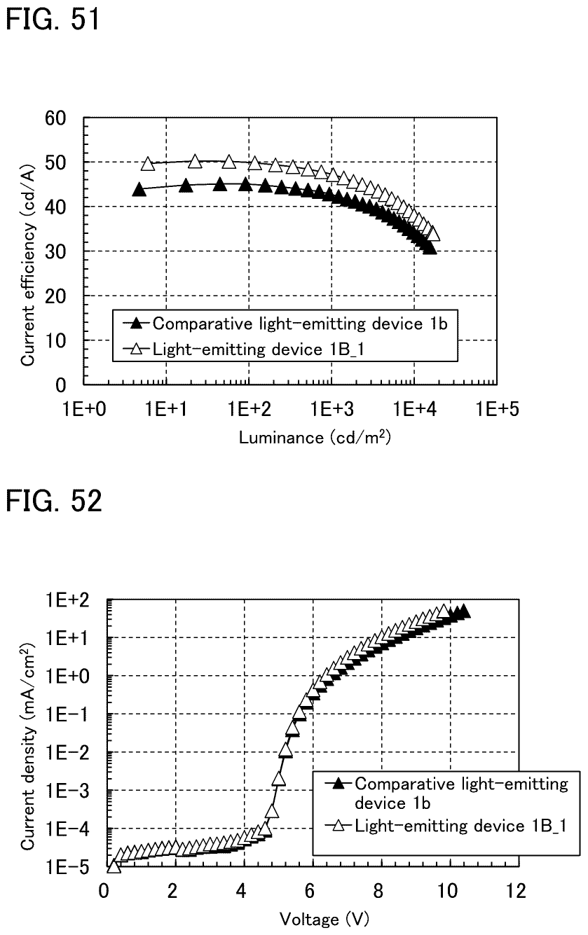

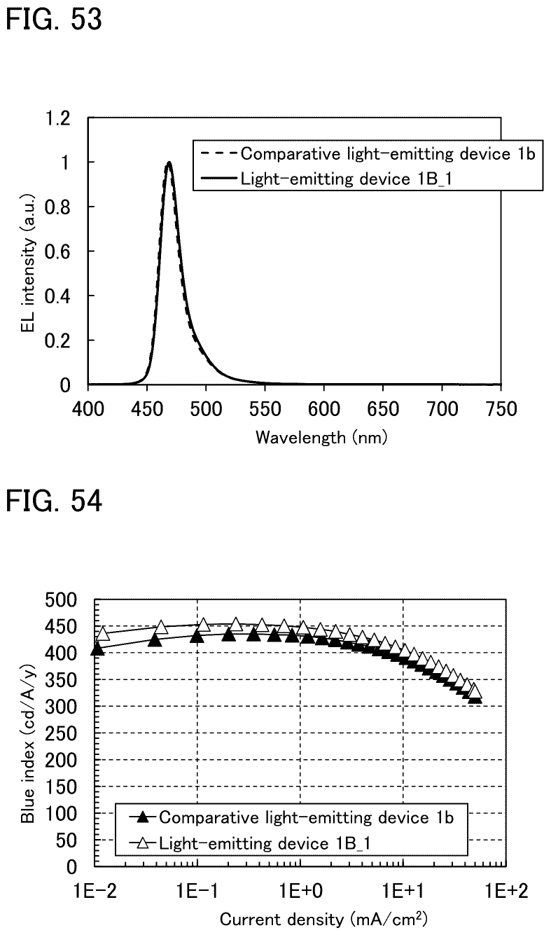

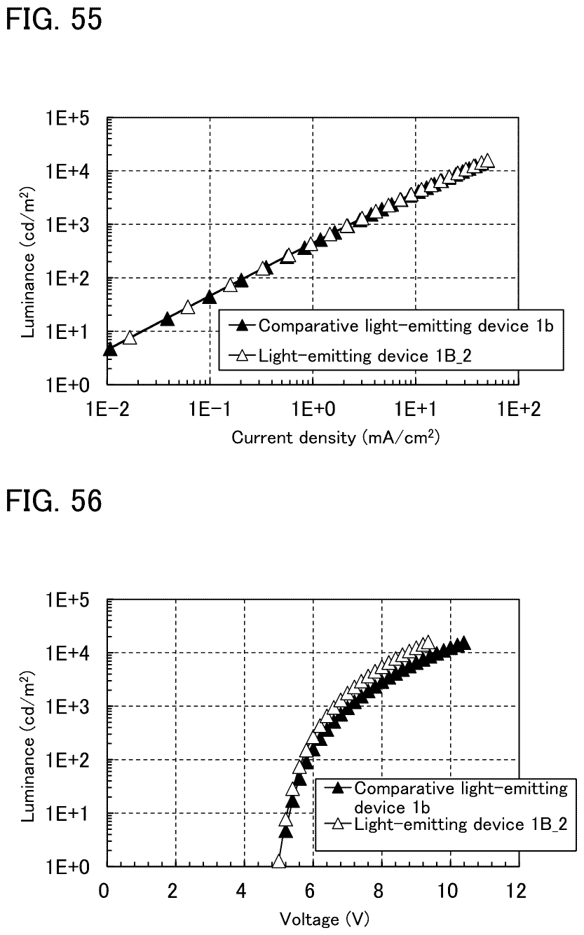

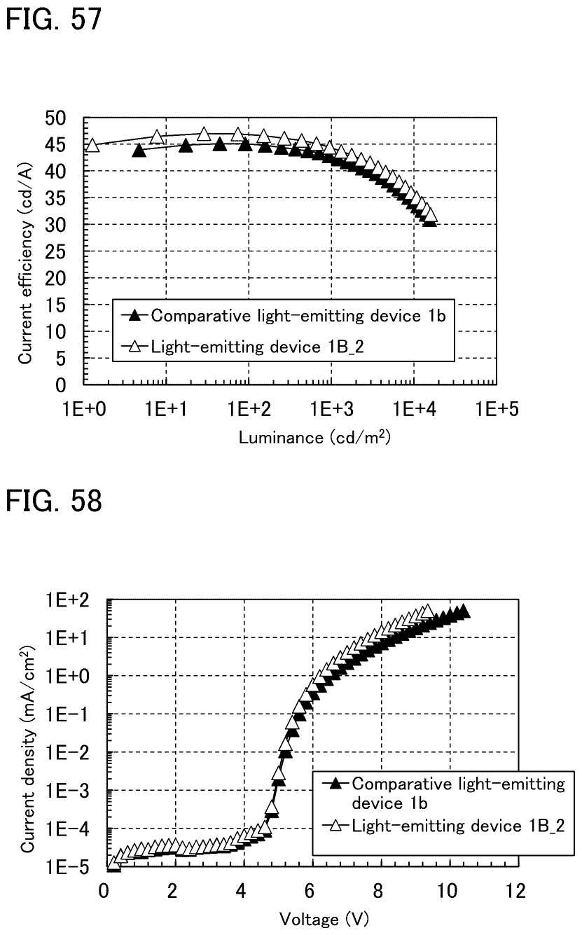

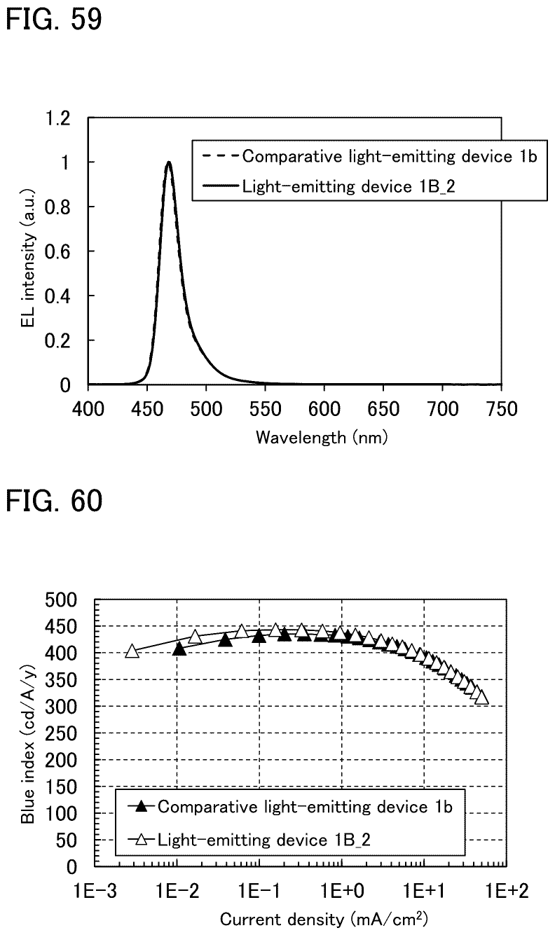

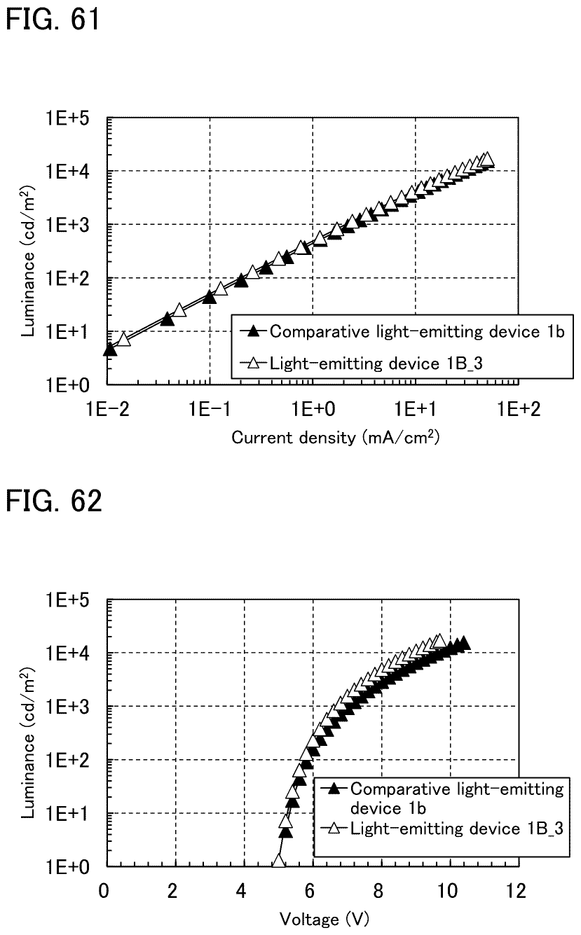

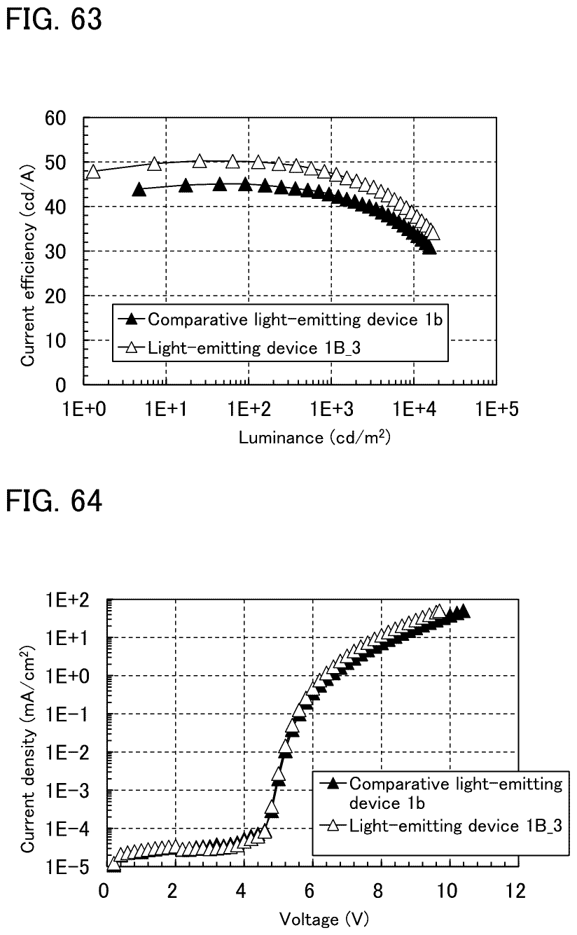

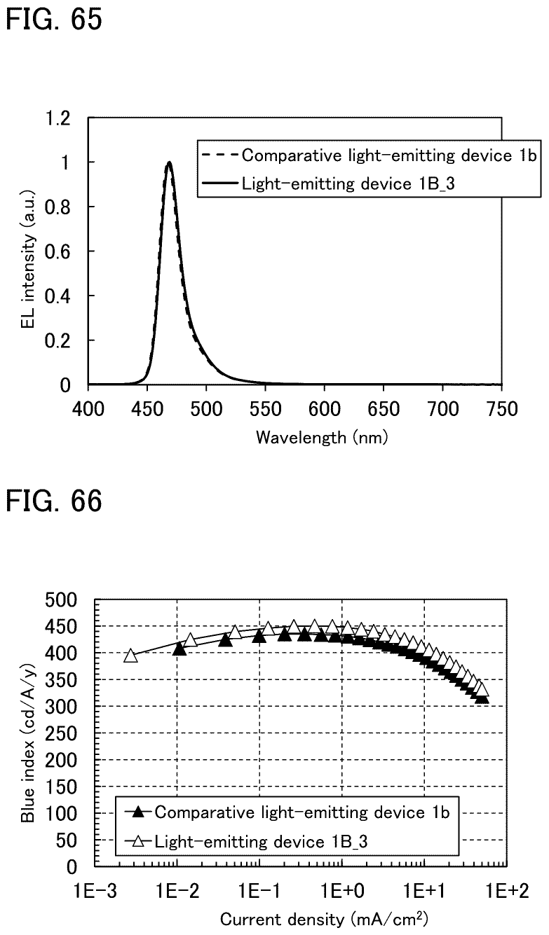

FIG. 49 shows the luminance-current density characteristics of the light-emitting device 1B_1 and the comparative light-emitting device 1b, FIG. 50 shows the luminance-voltage characteristics thereof, FIG. 51 shows the current efficiency-luminance characteristics thereof, FIG. 52 shows the current density-voltage characteristics thereof, FIG. 53 shows the electroluminescence spectra thereof, and FIG. 54 shows the blue index-current density characteristics thereof. FIG. 55 shows the luminance-current density characteristics of the light-emitting device 1B_2 and the comparative light-emitting device 1b, FIG. 56 shows the luminance-voltage characteristics thereof, FIG. 57 shows the current efficiency-luminance characteristics thereof, FIG. 58 shows the current density-voltage characteristics thereof, FIG. 59 shows the electroluminescence spectra thereof, and FIG. 60 shows the blue index-current density characteristics thereof. FIG. 61 shows the luminance-current density characteristics of the light-emitting device 1B_3 and the comparative light-emitting device 1b, FIG. 62 shows the luminance-voltage characteristics thereof, FIG. 63 shows the current efficiency-luminance characteristics thereof, FIG. 64 shows the current density-voltage characteristics thereof, FIG. 65 shows the electroluminescence spectra thereof, and FIG. 66 shows the blue index-current density characteristics thereof.

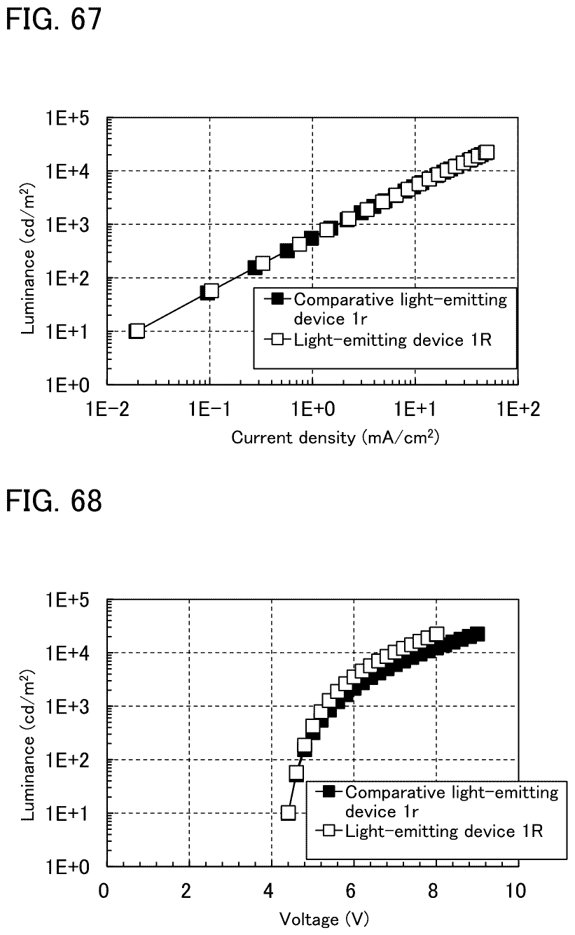

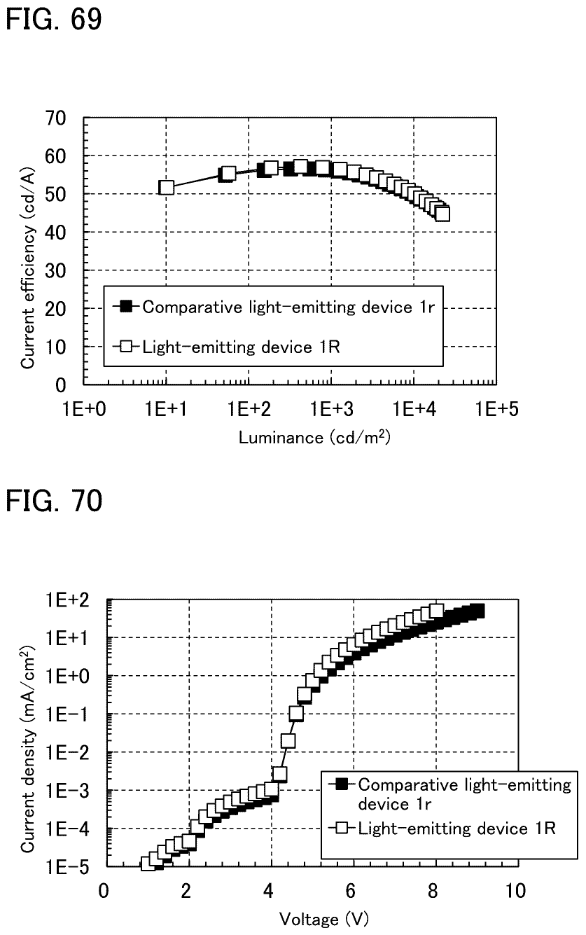

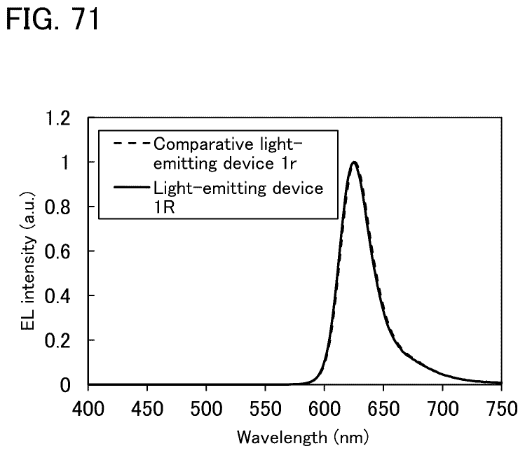

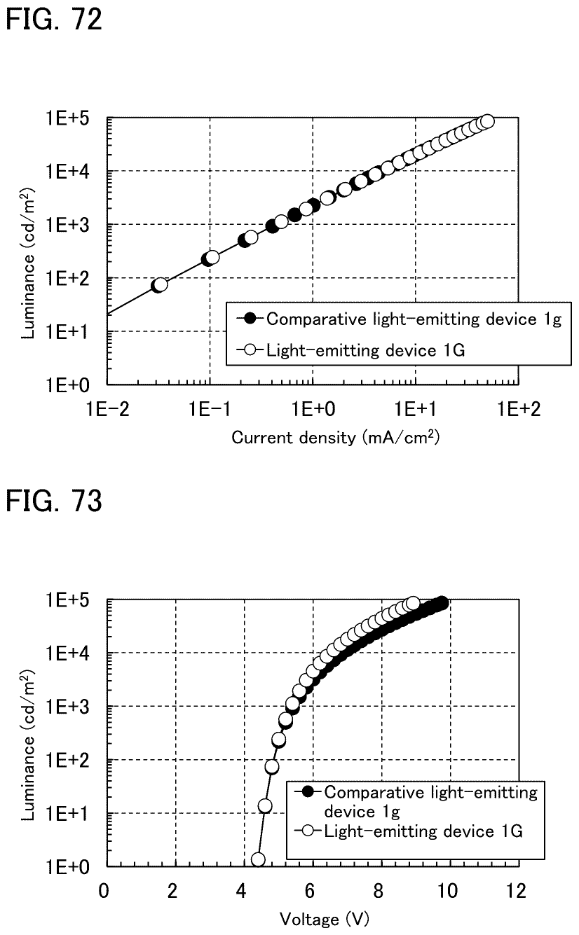

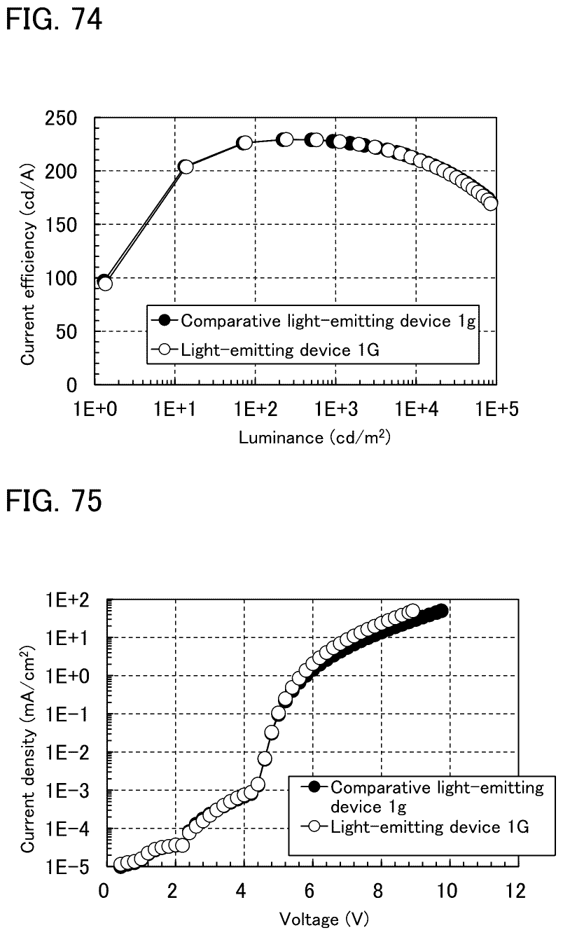

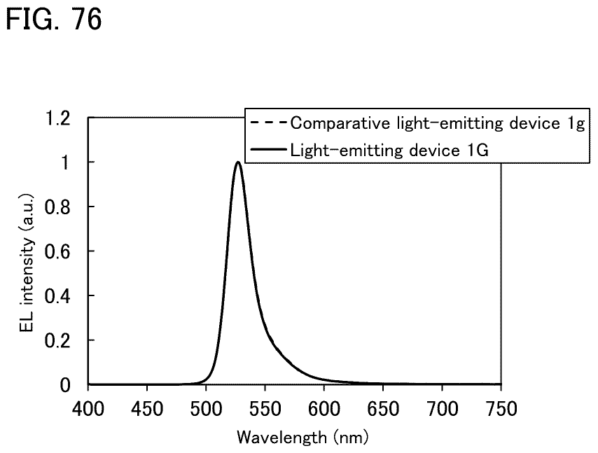

FIG. 67 shows the luminance-current density characteristics of the light-emitting device 1R and the comparative light-emitting device 1r, FIG. 68 shows the luminance-voltage characteristics thereof, FIG. 69 shows the current efficiency-luminance characteristics thereof, FIG. 70 shows the current density-voltage characteristics thereof, and FIG. 71 shows the electroluminescence spectra thereof. FIG. 72 shows the luminance-current density characteristics of the light-emitting device 1G and the comparative light-emitting device 1g, FIG. 73 shows the luminance-voltage characteristics thereof, FIG. 74 shows the current efficiency-luminance characteristics thereof, FIG. 75 shows the current density-voltage characteristics thereof, and FIG. 76 shows the electroluminescence spectra thereof.

The blue index (BI) is a value obtained by dividing current efficiency (cd/A) by the y value of CIE chromaticity (x, y), and is one of the indicators of characteristics of blue light emission. As the y chromaticity value of blue light emission becomes smaller, the color purity thereof tends to become higher. Blue light emission having a small y chromaticity value and high color purity enables expression of blue colors with a wide range of chromaticity in a display. Using blue light emission with high color purity reduces the luminance necessary for a display to express white, leading to lower power consumption of the display. Thus, BI, which is current efficiency based on a y chromaticity value as one of the indicators of color purity of blue, is suitably used as a means for showing efficiency of blue light emission. The light-emitting device with higher BI can be regarded as a blue-light-emitting device having higher efficiency for a display.

Table 5 shows the main characteristics of the light-emitting devices 1 and the comparative light-emitting devices 1 at a luminance of approximately 1000 cd/m². The luminance, CIE chromaticity, and electroluminescence spectra were measured at normal temperature with a spectroradiometer (SR-ULIR, produced by TOPCON TECHNOHOUSE CORPORATION).

TABLE 5

| | | | Current | | | | Current | BI |
|---|---|---|---|---|---|---|---|---|
| | Voltage | Current | density | Chroma- | Chroma- | Luminance | efficiency | value |
| | (V) | (mA) | (mA/cm²) | ticity x | ticity y | (cd/m²) | (cd/A) | (cd/A/y) |
| Light-emitting | 6.80 | 0.0885 | 2.21 | 0.123 | 0.107 | 1044 | 47.2 | 440 |
| device 1B_1 | | | | | | | | |
| Light-emitting | 6.60 | 0.0856 | 2.14 | 0.124 | 0.104 | 951 | 44.4 | 429 |
| device 1B_2 | | | | | | | | |
| Light-emitting | 6.80 | 0.0971 | 2.43 | 0.123 | 0.107 | 1147 | 47.2 | 440 |
| device 1B_3 | | | | | | | | |
| Comparative | 7.00 | 0.0876 | 2.19 | 0.126 | 0.101 | 937 | 42.8 | 424 |
| light-emitting | | | | | | | | |
| device 1b | | | | | | | | |
| Light-emitting | 5.20 | 0.0553 | 1.38 | 0.690 | 0.309 | 787 | 56.9 | — |
| device 1R | | | | | | | | |
| Comparative | 5.40 | 0.0602 | 1.51 | 0.692 | 0.308 | 847 | 56.3 | — |
| light-emitting | | | | | | | | |
| device 1r | | | | | | | | |
| Light-emitting | 5.40 | 0.0198 | 0.495 | 0.225 | 0.731 | 1125 | 227 | — |
| device 1G | | | | | | | | |
| Comparative | 5.40 | 0.0163 | 0.406 | 0.228 | 0.730 | 926 | 228 | — |
| light-emitting | | | | | | | | |
| device 1g | | | | | | | | |

According to FIGS. 49 to 66 and the above table, the light-emitting devices 1B emitted phosphorescent light originating from Pt(mmtBubOcz35dm4ppy-d₆). It has also been found that the light-emitting devices 1B have favorable emission characteristics and higher BI values than the comparative light-emitting device 1b, revealing their favorable efficiency as blue-light-emitting devices. It has also been found that the light-emitting devices 1B have higher current efficiencies and lower driving voltages than the comparative light-emitting device 1b.

According to FIGS. 67 to 71 and the above table, the light-emitting device 1R and the comparative light-emitting device Ir exhibited red light emission originating from OCPG-006. It has also been found that the light-emitting device 1R has favorable emission characteristics. It has also been found that the light-emitting device 1R has a lower driving voltage than the comparative light-emitting device 1r.

According to FIGS. 72 to 76 and the above table, the light-emitting device 1G and the comparative light-emitting device 1g exhibited green light emission originating from Ir(5mppy-d₃)₂(mbfpypy-d₃). It has also been found that the light-emitting device 1G has favorable emission characteristics.

The light-emitting devices 1B, the light-emitting device 1R, and the light-emitting device 1G have higher electron-injection properties, higher efficiencies as light-emitting devices, and lower driving voltages than the comparative light-emitting device 1b, the comparative light-emitting device 1r, and the comparative light-emitting device 1g, respectively, owing to the use of the organic compound (TznP2N) having a triazine skeleton in the second electron-transport layer 918_2.

### <Reliability Test Result>

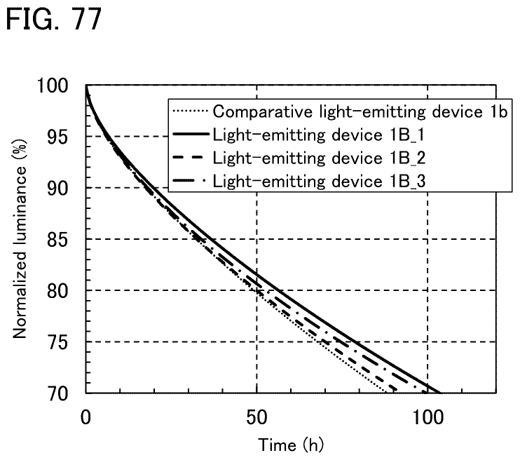

Furthermore, a reliability test was performed on the light-emitting devices 1B_1 to 1B_3 and the comparative light-emitting device 1b. FIG. 77 shows time-dependent changes in normalized luminance at the time of constant current density driving (10 [mA/cm²]). In FIG. 77, the vertical axis represents the luminance (%) normalized with the luminance at the time of the start of light emission as 100%, and the horizontal axis represent the time (h).

As shown in FIG. 77, the LT70 (h), which is the time that has elapsed until the measured luminance decreases to 70% of the initial luminance, of the light-emitting device 1B_1 is 100 hours. The LT70 (h) of the light-emitting device 1B_2 is 92 hours. The LT70 (h) of the light-emitting device 1B_3 is 100 hours.

In contrast, the LT70 (h) of the comparative light-emitting device 1b is 88 hours. Thus, it has been found that the light-emitting devices 1B_1 to 1B_3 have higher reliability than the comparative light-emitting device 1b.

### <Panel Characteristics>

Next, display devices 1 each including the light-emitting device 1B, the light-emitting device 1R, and the light-emitting device 1G respectively in blue, red, and green subpixels (a display device 1_1 including the light-emitting device 1B_1, a display device 1_2 including the light-emitting device 1B_2, and a display device 1_3 including the light-emitting device 1B_3) and a comparative display device 1 including the comparative light-emitting device 1b, the comparative light-emitting device 1r, and the comparative light-emitting device 1g respectively in blue, red, and green subpixels were assumed, and the power consumption of their display portions (except for the power consumption of a driving transistor, a driving circuit, and the like) was tentatively calculated. Note that each of the light-emitting devices assumed to be used in each display device is a tandem light-emitting device, and the same emission center substance is used in the plurality of light-emitting layers in each of the light-emitting devices. Thus, the use of a side-by-side patterning method was assumed for each display device.

The conditions of the display devices assumed for the tentative calculation are as follows.

TABLE 6

| | |
|---|---|
| Panel size | 5 inches (16:9) |
| Panel area | 68.9 cm² |

| | | |
|---|---|---|
| Aperture ratio | 30% | Red 10% |
| | | Green 10% |
| | | Blue 10% |

| | |
|---|---|
| Effective luminance | 1000 cd/m² in displaying white on the |
| | entire screen |
| Cirular polarizing plate | Not used |

First, in each display device under the above-described conditions, the luminances (effective luminances) of the light-emitting devices of RGB to obtain 1000 cd/m² emission of white light with CIE 1931 chromaticity coordinates (x, y)=(0.31, 0.33) when the display device is made to emit white light from the entire screen were calculated.

Next, the luminances (intrinsic luminances) required to obtain the calculated effective luminances of the light-emitting devices of RGB were calculated in consideration of the aperture ratios. The intrinsic luminance is the luminance at which each light-emitting device actually emits light in order to obtain the effective luminance of 1000 cd/m2 when the display device is made to emit white light with CIE 1931 chromaticity coordinates (x, y)=(0.31, 0.33) from the entire screen. Since the aperture ratio of the whole display device subjected to the tentative calculation is 30% and the aperture ratio per emission color is 10%, the intrinsic luminance is approximately ten times the effective luminance.

From the measurement results of the light-emitting devices 1 and the comparative light-emitting devices 1 described above and the intrinsic luminances, the current density and voltage for making each light-emitting device emit light at the intrinsic luminance can be obtained. In other words, in each display device under the above-described conditions, the current density and voltage of each light-emitting device to obtain 1000 cd/m² luminance emission of white light with CIE 1931 chromaticity coordinates (x, y)=(0.31, 0.33) when the display device is made to emit white light from the entire screen can be obtained.

The power consumption is calculated by multiplying the amount of current by the voltage. The amount of current is calculated by multiplying the current density, the panel area, and the aperture ratio. The display devices subjected to the tentative calculation each have a diagonal size of 5 inches, an aspect ratio of 16:9, a panel area of 68.9 cm², and an aperture ratio of the light-emitting device of each color of 10%, and the amount of current can be calculated by multiplying the current density calculated in the previous paragraph by these values. Furthermore, the power consumption of the light-emitting device of each emission color can be calculated by multiplying the amount of current by the voltage obtained in the previous paragraph. By calculating and summing up the power consumptions of the light-emitting devices of RGB, the total power consumption of the display portion of the display device (except for the power consumption of the driving transistor, the driving circuit, and the like) can be obtained.

Table 7 shows the results of calculating the power consumption of the display device 1_1 assumed to include the light-emitting devices 1B_1, IR, and 1G.

TABLE 7
Display device 1_1

| | | | Effective | Intrinsic | Current | Current | Current | | Power |
|---|---|---|---|---|---|---|---|---|---|
| | Chroma- | Chroma- | luminance | luminance | efficiency | density | amount | Voltage | consumption |
| | ticity x | ticity y | (cd/m²) | (cd/m²) | (cd/A) | (mA/cm²) | (mA) | (V) | (mW) |
| Red | 0.690 | 0.309 | 270.4 | 2704 | 54.9 | 4.92 | 33.9 | 5.81 | 197 |
| Green | 0.225 | 0.732 | 583.5 | 5835 | 217 | 2.69 | 18.5 | 6.14 | 114 |
| Blue | 0.123 | 0.107 | 146.2 | 1462 | 46.3 | 3.16 | 21.8 | 7.03 | 153 |
| Full | 0.313 | 0.329 | 1000 | — | 92.9 | — | 74.2 | — | 464 |
| white | | | | | | | | | |

Table 8 shows the results of calculating the power consumption of the display device 1_2 assumed to include the light-emitting devices 1B_2, 1R, and 1G.

TABLE 8
Display device 1_2

| | | | Effective | Intrinsic | Current | Current | Current | | Power |
|---|---|---|---|---|---|---|---|---|---|
| | Chroma- | Chroma- | luminance | luminance | efficiency | density | amount | Voltage | consumption |
| | ticity x | ticity y | (cd/m²) | (cd/m²) | (cd/A) | (mA/cm²) | (mA) | (V) | (mW) |
| Red | 0.690 | 0.309 | 269.2 | 2692 | 54.9 | 4.90 | 33.8 | 5.81 | 196 |
| Green | 0.225 | 0.732 | 590.1 | 5901 | 217 | 2.72 | 18.7 | 6.15 | 115 |
| Blue | 0.124 | 0.103 | 140.7 | 1407 | 43.5 | 3.23 | 22.3 | 6.84 | 152 |
| Full | 0.313 | 0.329 | 1000 | — | 92.2 | — | 74.8 | — | 464 |
| white | | | | | | | | | |

Table 9 shows the results of calculating the power consumption of the display device 1_3 assumed to include the light-emitting devices 1B_3, 1R, and 1G.

TABLE 9
Display device 1_3

| | | | Effective | Intrinsic | Current | Current | Current | | Power |
|---|---|---|---|---|---|---|---|---|---|
| | Chroma- | Chroma- | luminance | luminance | efficiency | density | amount | Voltage | consumption |
| | ticity x | ticity y | (cd/m²) | (cd/m²) | (cd/A) | (mA/cm²) | (mA) | (V) | (mW) |
| Red | 0.690 | 0.309 | 270.3 | 2703 | 54.9 | 4.92 | 33.9 | 5.81 | 197 |
| Green | 0.225 | 0.732 | 583.5 | 5835 | 217 | 2.69 | 18.5 | 6.14 | 114 |
| Blue | 0.123 | 0.107 | 146.2 | 1462 | 46.6 | 3.14 | 21.6 | 6.96 | 150 |
| Full | 0.313 | 0.329 | 1000 | — | 93.1 | — | 74.1 | — | 461 |
| white | | | | | | | | | |

Table 10 shows the results of calculating the power consumption of the comparative display device 1 assumed to include the comparative light-emitting devices 1b, 1r, and 1g.

TABLE 10
Comparative display device 1

| | | | Effective | Intrinsic | Current | Current | Current | | Power |
|---|---|---|---|---|---|---|---|---|---|
| | Chroma- | Chroma- | luminance | luminance | efficiency | density | amount | Voltage | consumption |
| | ticity x | ticity y | (cd/m²) | (cd/m²) | (cd/A) | (mA/cm²) | (mA) | (V) | (mW) |
| Red | 0.692 | 0.308 | 264.5 | 2645 | 54.5 | 4.85 | 33.4 | 6.16 | 205.9 |
| Green | 0.227 | 0.730 | 598.6 | 5986 | 217 | 2.76 | 19.0 | 6.43 | 122.2 |
| Blue | 0.126 | 0.101 | 136.8 | 1368 | 42.0 | 3.26 | 22.5 | 7.30 | 163.9 |
| Full | 0.313 | 0.329 | 1000 | — | 92.0 | — | 74.9 | — | 492.0 |
| white | | | | | | | | | |

The above tables show that the display devices 1_1, 1_2, and 1_3 each assumed to include the light-emitting devices including the organic compound having a triazine skeleton have higher current efficiencies and lower driving voltages in white light emission than the comparative display device 1. It has also been found that the display devices 1_1, 1_2, and 1_3 each assumed to include the blue-light-emitting device including the deuterated host material can be driven at low voltages. It has also been found that the power consumptions of the display devices 1 are lower than that of the comparative display device 1.

The above results show that the light-emitting devices 1 of embodiments of the present invention have favorable characteristics, and the light-emitting devices 1B_1 and 1B_3 each have a particularly low driving voltage and a particularly high emission efficiency.

### Example 2

In this example, light-emitting devices 2R (a light-emitting device 2R_1 and a light-emitting device 2R_2), light-emitting devices 2G (a light-emitting device 2G_1 and a light-emitting device 2G_2), and light-emitting devices 2B (a light-emitting device 2B_1 and a light-emitting device 2B_2) were fabricated, and the characteristics thereof were evaluated. In addition, comparative light-emitting devices 2 (a comparative light-emitting device 2b, a comparative light-emitting device 2r, and a comparative light-emitting device 2g) were fabricated, and the characteristics thereof were evaluated.

The light-emitting devices 2N_1 (the light-emitting devices 2R_1, 2G_1, and 2B_1) are each a light-emitting device of one embodiment of the present invention, where the first light-emitting layer 912 and the second light-emitting layer 917 each include a phosphorescent substance as an emission center substance and include host materials at least one of which includes deuterium. Furthermore, the second electron-transport layer 918_2 includes an organic compound having a triazine skeleton.

The light-emitting devices 2N_2 (the light-emitting devices 2R_2, 2G_2, and 2B_2) are each a light-emitting device in which the first light-emitting layer 912 and the second light-emitting layer 917 each include a phosphorescent substance. Note that the first light-emitting layer 912 and the second light-emitting layer 917 each include host materials which are not deuterated. Furthermore, the second electron-transport layer 918_2 includes an organic compound having a triazine skeleton.

The comparative light-emitting device 2b is a light-emitting device in which the first light-emitting layer 912 and the second light-emitting layer 917 each include a phosphorescent substance and host materials neither or none of which is deuterated. Furthermore, the second electron-transport layer 918_2 does not include an organic compound having a triazine skeleton.

The light-emitting devices 2 (the light-emitting devices 2R, 2G, and 2B) and the comparative light-emitting devices 2 were each fabricated by a continuous vacuum process. Structural formulae of the organic compounds used for the light-emitting devices 2 and the comparative light-emitting devices 2 are shown below.

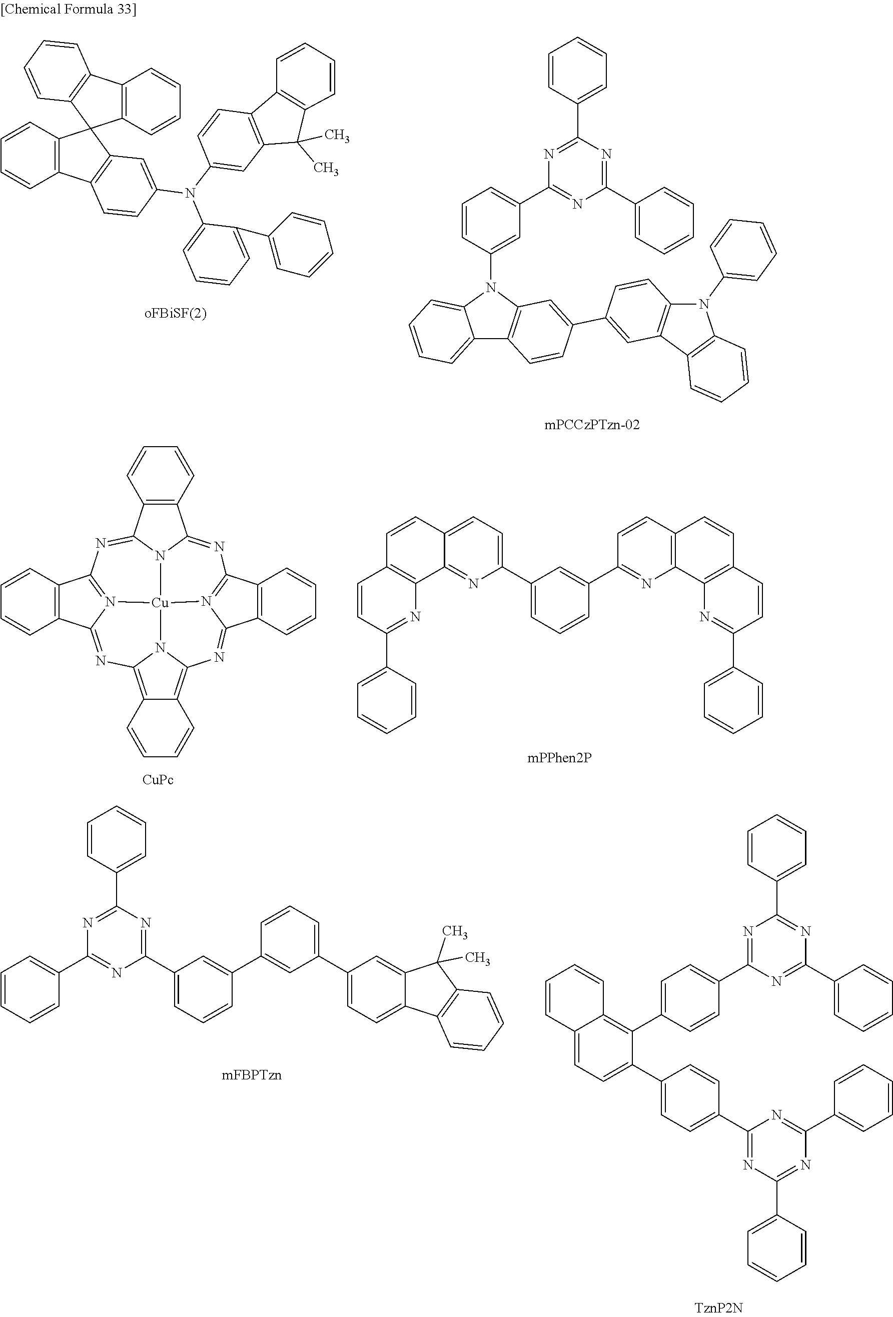

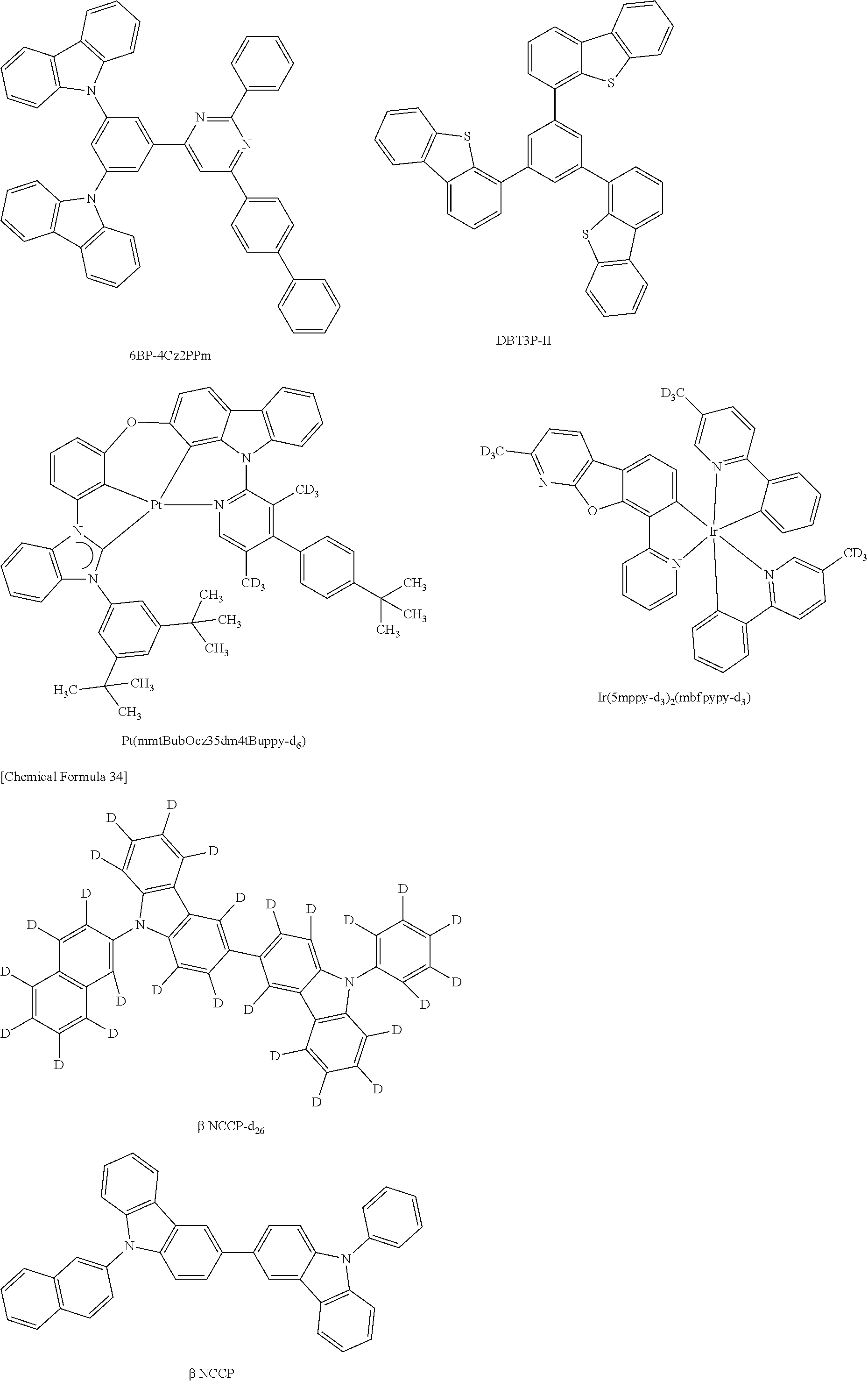

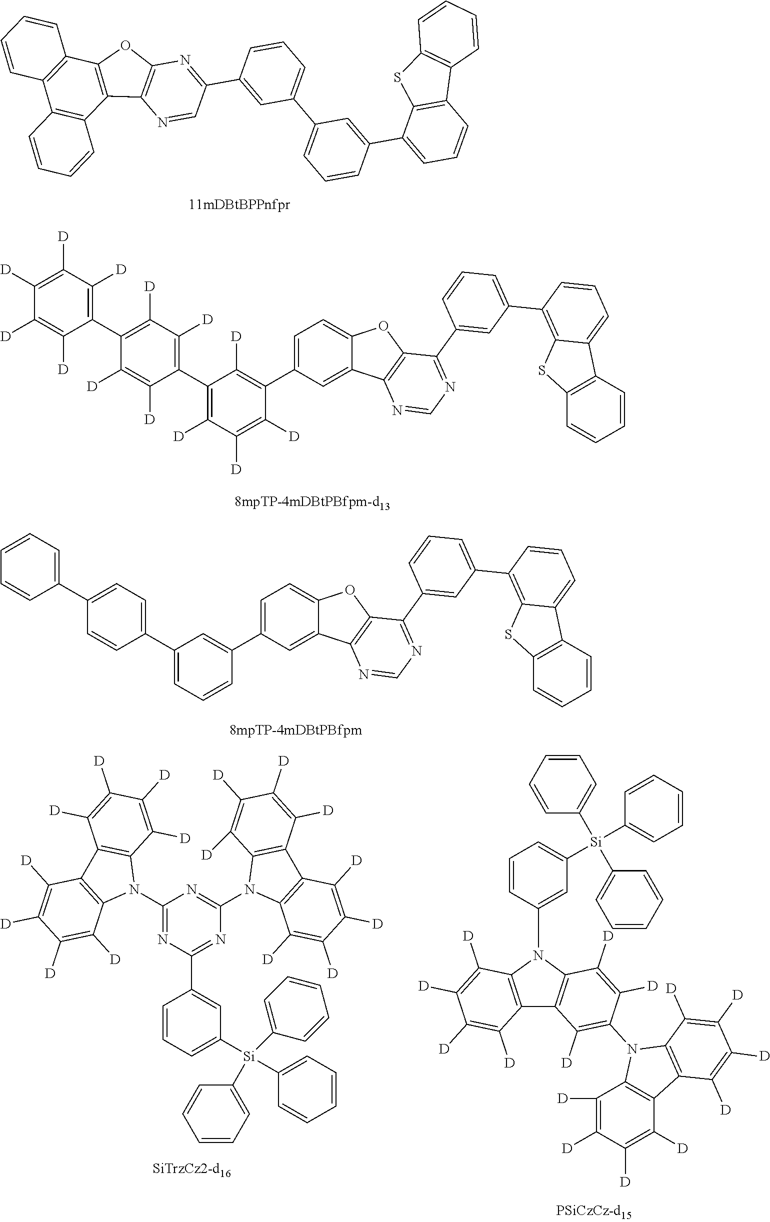

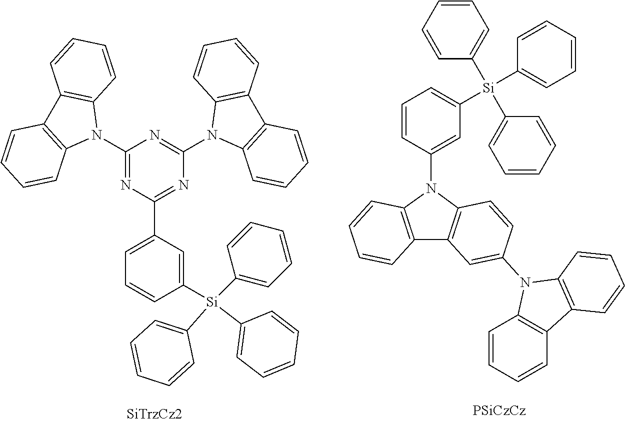 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2cccc(-n3c4ccccc4c4cc(-n5c6ccccc6c6ccccc65)ccc43)c2)cc1]

FIG. 26 illustrates the structures of the light-emitting devices 2B (the light-emitting devices 2B_1 and 2B_2) and the comparative light-emitting device 2b. FIG. 27 illustrates the structures of the light-emitting devices 2R and 2G and the comparative light-emitting devices 2r and 2g. The light-emitting devices 2 and the comparative light-emitting devices 2 each have a tandem structure in which the first EL layer 903, the intermediate layer 905, the second EL layer 904, and the second electrode 902 are stacked over the first electrode 901 formed over the substrate 900 that is a glass substrate. Furthermore, the cap layer 909 is provided over the second electrode.

As illustrated in FIG. 26, the first EL layer 903 of each of the light-emitting devices 2B (the light-emitting devices 2B_1 and 2B_2) and the comparative light-emitting device 2b has a structure in which the hole-injection layer 910, the first hole-transport layer 911 (the first hole-transport layer 911_1 and the first hole-transport layer 911_2), the first light-emitting layer 912, and the first electron-transport layer 913 are stacked in this order. The second EL layer 904 of each of the light-emitting devices 2B and the comparative light-emitting device 2b has a structure in which the second hole-transport layer 916 (the second hole-transport layer 916_1 and the second hole-transport layer 916_2), the second light-emitting layer 917, the second electron-transport layer 918 (the second electron-transport layer 918_1 and the second electron-transport layer 918_2), and the electron-injection layer 919 are stacked in this order.

Meanwhile, as illustrated in FIG. 27, the first EL layer 903 of each of the light-emitting devices 2R (the light-emitting devices 2R_1 and 2R_2), the light-emitting devices 2G (the light-emitting devices 2G_1 and 2G_2), and the comparative light-emitting devices 2r and 2g has a structure in which the hole-injection layer 910, the first hole-transport layer 911_1, the first light-emitting layer 912, and the first electron-transport layer 913 are stacked in this order. The second EL layer 904 thereof has a structure in which the second hole-transport layer 916_1, the second light-emitting layer 917, the second electron-transport layer 918 (the second electron-transport layers 918_1 and 918_2), and the electron-injection layer 919 are stacked in this order.

In each of the light-emitting devices 2 and the comparative light-emitting devices 2, the intermediate layer 905 includes the electron-injection buffer region 914 and the layer 915 including the electron-relay region and the charge-generation region.

### <Fabrication Method of Light-Emitting Device 2R_1>

First, as a reflective electrode, silver (Ag) was deposited over a glass substrate to a thickness of 100 nm by a sputtering method, and then, as a transparent electrode, indium tin oxide containing silicon oxide (ITSO) was deposited to a thickness of 85 nm by a sputtering method, so that the first electrode was formed. Note that the transparent electrode serves as an anode, and the transparent electrode and the reflective electrode can be collectively regarded as the first electrode. The first electrode was 2 mm×2 mm.

Next, in pretreatment for fabricating the light-emitting device over the substrate, the surface of the substrate was washed with water, and baking was performed at 200° C. for one hour. After that, the substrate was transferred into a vacuum evaporation apparatus where the pressure was reduced to approximately 1×10⁻⁴ Pa, and was subjected to heat treatment at 170° C. for 30 minutes in a heating chamber of the vacuum evaporation apparatus, and then the substrate was cooled down for approximately 30 minutes.

Next, the substrate provided with the first electrode 901 was fixed to a holder provided in the vacuum evaporation apparatus such that the surface on which the first electrode 901 was formed faced downward. Then, the hole-injection layer 910 was formed on the first electrode 901 by co-evaporation of N-(biphenyl-2-yl)-N-(9,9-dimethylfluoren-2-yl)-9,9′-spirobi[9H-fluoren]-2-amine (abbreviation: oFBiSF (2)) and a fluorine-containing material having an electron-acceptor property with a molecular weight of 672 (OCHD-003) at a weight ratio of 1:0.03 to a thickness of 10 nm by an evaporation method using resistance heating.

Subsequently, the first hole-transport layer 911 (the first hole-transport layer 911_1) was formed over the hole-injection layer 910. By an evaporation method using resistance heating, the first hole-transport layer 911_1 was formed by evaporation of oFBiSF (2) to a thickness of 140 nm.

Next, the first light-emitting layer 912 was formed over the first hole-transport layer 911. By an evaporation method using resistance heating, the first light-emitting layer 912 was formed by co-evaporation of 11-[3′-(dibenzothiophen-4-yl)biphenyl-3-yl]phenanthro[9′,10′:4,5]furo[2,3-b]pyrazine (abbreviation: 11mDBtBPPnfpr), 9-(2-naphthyl-1,3,4,5,6,7,8-d₇)-9′-(phenyl-2,3,4,5,6-d₅)-3,3′-bi-9H-carbazole-1,1′,2,2′,4,4′,5,5′,6,6′,7,7′,8,8′-d₁₄ (abbreviation: βNCCP-d₂₆), and OCPG-006 as a material that emits red phosphorescent light at a weight ratio of 0.4:0.6:0.05 to a thickness of 40 nm.

Next, the first electron-transport layer 913 was formed over the first light-emitting layer 912 by evaporation of 9-[3-(4,6-diphenyl-1,3,5-triazin-2-yl)phenyl]-9′-phenyl-2,3′-bi-9H-carbazole (abbreviation: mPCCzPTzn-02) to a thickness of 10 nm.

Next, the intermediate layer 905 was provided. First, by an evaporation method using resistance heating, a layer to be the electron-injection buffer region 914 was formed over the first electron-transport layer 913 by co-evaporation of 2,2′-(1,3-phenylene)bis(9-phenyl-1,10-phenanthroline) (abbreviation: mPPhen2P) and Li₂O at a volume ratio of 1:0.02 to a thickness of 5 nm.

Then, as the electron-relay region, copper phthalocyanine (abbreviation: CuPc) was deposited to a thickness of 2 nm. Next, as the charge-generation region, oFBiSF (2) and a fluorine-containing material having an electron-acceptor property with a molecular weight of 672 (OCHD-003) were deposited by co-evaporation at a weight ratio of 1:0.15 to a thickness of 10 nm by an evaporation method using resistance heating. Thus, the layer 915 including the electron-relay region and the charge-generation region was formed.

Next, the second EL layer 904 was provided over the intermediate layer 905.

First, the second hole-transport layer 916 (the second hole-transport layer 916_1) was formed. Specifically, oFBiSF (2) was deposited to a thickness of 75 nm by an evaporation method using resistance heating.

Next, the second light-emitting layer 917 was formed over the second hole-transport layer 916 by co-evaporation of 11mDBtBPPnfpr, βNCCP-d₂₆, and OCPG-006 at a weight ratio of 0.4:0.6:0.05 to a thickness of 40 nm by an evaporation method using resistance heating.

Next, the second electron-transport layer 918 (the second electron-transport layers 918_1 and 918_2) was formed over the second light-emitting layer 917. By an evaporation method using resistance heating, the second electron-transport layer 918_1 was formed by evaporation of 2-[3′-(9,9-dimethyl-9H-fluoren-2-yl)biphenyl-3-yl]-4,6-diphenyl-1,3,5-triazine (abbreviation: mFBPTzn) to a thickness of 10 nm, and then the second electron-transport layer 918_2 was formed by co-evaporation of 2,2′-(1,2-naphthalenediyldi-4,1-phenylene)bis[4,6-diphenyl-1,3,5-triazine] (abbreviation: TznP2N) and 8-quinolinolato-lithium (abbreviation: Liq) at a volume ratio of 1:1 to a thickness of 25 nm.

Next, the electron-injection layer 919 was formed over the second electron-transport layer 918 by evaporation of Liq to a thickness of 1 nm.

Next, the second electrode 902 was formed over the electron-injection layer 919 by co-evaporation of Ag and Mg at a volume ratio of 1:0.1 to a thickness of 15 nm. Note that the second electrode 902 is a transflective electrode having functions of transmitting light and reflecting light.

Then, as the cap layer 909, 4,4′,4″-(benzene-1,3,5-triyl)tri(dibenzothiophene) (abbreviation: DBT3P-II) was deposited to a thickness of 70 nm by evaporation, which leads to an improved light extraction efficiency.

Through the above process, the light-emitting device 2R_1 was fabricated.

### <Fabrication Method of Light-Emitting Device 2R_2>

The light-emitting device 2R_2 is different from the light-emitting device 2R_1 in the structures of the first light-emitting layer 912 and the second light-emitting layer 917. Other components were fabricated in a manner similar to that for the light-emitting device 2R_1. Specifically, the first light-emitting layer 912 of the light-emitting device 2R_2 was formed by co-evaporation of 11mDBtBPPnfpr, 9-(2-naphthyl)-9′-phenyl-3,3′-bi-9H-carbazole (abbreviation: βNCCP), and OCPG-006 at a weight ratio of 0.4:0.6:0.05 to a thickness of 40 nm by an evaporation method using resistance heating.

Like the first light-emitting layer 912, the second light-emitting layer 917 was formed over the second hole-transport layer 916 by co-evaporation of 11mDBtBPPnfpr, βNCCP, and OCPG-006 at a weight ratio of 0.4:0.6:0.05 to a thickness of 40 nm by an evaporation method using resistance heating.

<Fabrication Method of Comparative Light-Emitting Device 2r>

The comparative light-emitting device 2r is different from the light-emitting device 2R_2 in the structure of the second electron-transport layer 918_2. Other components were fabricated in a manner similar to that for the light-emitting device 2R_2.

Specifically, the second electron-transport layer 918_2 was formed by co-evaporation of 4-[3,5-bis(9H-carbazol-9-yl)phenyl]-2-phenyl-6-(biphenyl-4-yl)pyrimidine (abbreviation: 6BP-4Cz2PPm) and Liq at a volume ratio of 1:1 to a thickness of 25 nm by an evaporation method using resistance heating.

Table 11 lists the structures of the light-emitting devices 2R and the comparative light-emitting device 2r. Note that Condition 2R in Table 11 is shown in Table 12.

TABLE 11

| | | | |
|---|---|---|---|
| Thickness | Light-emitting | Light-emitting | Comparative light- |
| [nm] | device 2R_1 | device 2R_2 | emitting device 2r |

| Cap layer | 70 | DBT3P-II | |
|---|---|---|---|
| Second electrode 902 | 15 | Ag:Mg (1:0.1) | |
| Electron-injection layer 919 | 1 | Liq | |
| Second electron-transport layer 918_2 | 25 | TznP2N:Liq | 6BP-4Cz2PPm:Liq |
| | | (1:1) | (1:1) |

| | | |
|---|---|---|
| Second electron-transport layer 918_1 | 10 | mFBPTzn |
| Second light-emitting layer 917 | 40 | Condition 2R |
| Second hole-transport layer 916_1 | 75 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Li₂O (1:0.02) |
| First electron-transport layer 913 | 10 | mPCCzPTzn-02 |
| First light-emitting layer 912 | 40 | Condition 2R |
| First hole-transport layer 911_1 | 140 | oFBiSF(2) |
| Hole-injection layer 910 | 10 | oFBiSF(2):OCHD-003 (1:0.03) |
| First electrode 902 | 85 | ITSO |
| | 100 | Ag |

TABLE 12

| | Condition 2R |
|---|---|
| Light-emitting device 2R_1 | 11mDBtBPPnfpr:βNCCP-d₂₆:OCPG-006 |
| | (0.4:0.6:0.05) |
| Light-emitting device 2R_2 | 11mDBtBPPnfpr:βNCCP:OCPG-006 |
| Comparative light-emitting | (0.4:0.6:0.05) |
| device 2r | |

### <Fabrication Method of Light-Emitting Device 2G_1>

The light-emitting device 2G_1 is different from the light-emitting device 2R_1 in the thicknesses of the first and second hole-transport layers 911 and 916 and the structures of the first and second light-emitting layers 912 and 917. Other components were fabricated in a manner similar to that for the light-emitting device 2R_1.

Specifically, the first light-emitting layer 912 and the second light-emitting layer 917 in the light-emitting device 2G_1 were each formed by co-evaporation of 8-(1,1′:4′,1″-terphenyl-3-yl-2,4,5,6,2′,3′,5′,6′,2″,3″,4″,5″,6″-d₁₃)-4-[3-(dibenzothiophen-4-yl)phenyl]-[1]benzofuro[3,2-d]pyrimidine (abbreviation: 8mpTP-4mDBtPBfpm-d₁₃), βNCCP-d₂₆, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) at a weight ratio of 0.5:0.5:0.1 to a thickness of 40 nm.

In the light-emitting device 2G_1, the thickness of the first hole-transport layer 911 was set to 80 nm, and the thickness of the second hole-transport layer 916 was set to 50 nm.

### <Fabrication Method of Light-Emitting Device 2G_2>

The light-emitting device 2G_2 is different from the light-emitting device 2G_1 in the structures of the first light-emitting layer 912 and the second light-emitting layer 917. Other components were fabricated in a manner similar to that for the light-emitting device 2G_1.

Specifically, the first light-emitting layer 912 of the light-emitting device 2G_2 was formed by co-evaporation of 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), βNCCP, and Ir(5mppy-d₃)₂(mbfpypy-d₃) at a weight ratio of 0.5:0.5:0.1 to a thickness of 40 nm by an evaporation method using resistance heating.

Like the first light-emitting layer 912, the second light-emitting layer 917 was formed over the second hole-transport layer 916 by co-evaporation of 8mpTP-4mDBtPBfpm, βNCCP, and Ir(5mppy-d₃)₂(mbfpypy-d₃) at a weight ratio of 0.5:0.5:0.1 to a thickness of 40 nm by an evaporation method using resistance heating.

<Fabrication Method of Comparative Light-Emitting Device 2g>

The comparative light-emitting device 2g is different from the light-emitting device 2G_2 in the structure of the second electron-transport layer 918_2. Other components were fabricated in a manner similar to that for the light-emitting device 2G_2.

Specifically, the second electron-transport layer 918_2 was formed by co-evaporation of 6BP-4Cz2PPm and Liq at a volume ratio of 1:1 to a thickness of 25 nm by an evaporation method using resistance heating.

Table 13 lists the structures of the light-emitting devices 2G and the comparative light-emitting device 2g. Note that Condition 2G in Table 13 is shown in Table 14.

TABLE 13

| | | | |
|---|---|---|---|
| Thickness | Light-emitting | Light-emitting | Comparative light- |
| [nm] | device 2G_1 | device 2G_2 | emitting device 2g |

| Cap layer | 70 | DBT3P-II | |
|---|---|---|---|
| Second electrode 902 | 15 | Ag:Mg (1:0.1) | |
| Electron-injection layer 919 | 1 | Liq | |
| Second electron-transport layer 918_2 | 25 | TznP2N:Liq | 6BP-4Cz2PPm:Liq |
| | | (1:1) | (1:1) |

| | | |
|---|---|---|
| Second electron-transport layer 918_1 | 10 | mFBPTzn |
| Second light-emitting layer 917 | 40 | Condition 2G |
| Second hole-transport layer 916_1 | 50 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Li₂O (1:0.02) |
| First electron-transport layer 913 | 10 | mPCCzPTzn-02 |
| First light-emitting layer 912 | 40 | Condition 2G |
| First hole-transport layer 911_1 | 80 | oFBiSF(2) |
| Hole-injection layer 910 | 10 | oFBiSF(2):OCHD-003 (1:0.03) |
| First electrode 902 | 85 | ITSO |
| | 100 | Ag |

TABLE 14

| | Condition 2G |
|---|---|
| Light-emitting device 2G_1 | 8mpTP-4mDBtPBfpm-d₁₃:βNCCP-d₂₆:Ir(5mppy-d₃)₂(mbfpypy-d₃) |
| | (0.5:0.5:0.1) |
| Light-emitting device 2G_2 | 8mpTP-4mDBtPBfpm:βNCCP:Ir(5mppy-d₃)₂(mbfpypy-d₃) |
| Comparative light-emitting device 2g | (0.5:0.5:0.1) |

### <Fabrication Method of Light-Emitting Device 2B_1>

The light-emitting device 2B_1 is different from the light-emitting device 2R_1 in the structures and thicknesses of the first and second light-emitting layers 912 and 917 and the first and second hole-transport layers 911 and 916. Other components were fabricated in a manner similar to that for the light-emitting device 2R_1.

Specifically, each of the first and second light-emitting layers 912 and 917 in the light-emitting device 2B_1 was formed by co-evaporation of 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d₁₆) (abbreviation: SiTrzCz2-d₁₆), 9-[3-(triphenylsilyl)phenyl]-3,9′-(bi-9H-carbazole-dis) (abbreviation: PSiCzCz-d₁₅), and (2-{3-[3-(3,5-di-tert-butylphenyl)benzimidazol-1-yl-2-ylidene-κC²]phenoxy-κC²}-9-[4-tert-butylphenyl-3,5-di(methyl-d₃)-2-pyridinyl-κN]carbazole-2,1-diyl-κC)platinum(II) (abbreviation: Pt(mmtBubOcz35dm4tBuppy-d₆)) at a weight ratio of 0.45:0.45:0.10 to a thickness of 25 nm by an evaporation method using resistance heating.

In the light-emitting device 2B_1, the first hole-transport layer 911_2 and the second hole-transport layer 916_2 were provided. In other words, the first hole-transport layer 911 (the first hole-transport layer 911_1 and the first hole-transport layer 911_2) was formed in the following manner: the first hole-transport layer 911_1 was formed by evaporation of oFBiSF(2) to a thickness of 45 nm, and then the first hole-transport layer 911_2 was formed over the first hole-transport layer 911_1 by evaporation of 9-[3-(triphenylsilyl)phenyl]-3,9′-bi-9H-carbazole (abbreviation: PSiCzCz) to a thickness of 5 nm.

Furthermore, the second hole-transport layer 916 (the second hole-transport layer 916_1 and the second hole-transport layer 916_2) was formed in the following manner: the second hole-transport layer 916_1 was formed by evaporation of oFBiSF (2) to a thickness of 50 nm, and then the second hole-transport layer 916_2 was formed over the second hole-transport layer 916_1 by evaporation of PSiCzCz to a thickness of 5 nm.

### <Fabrication Method of Light-Emitting Device 2B_2>

The light-emitting device 2B_2 is different from the light-emitting device 2B_1 in the structures of the first light-emitting layer 912 and the second light-emitting layer 917. Other components were fabricated in a manner similar to that for the light-emitting device 2B_1.

Specifically, the first light-emitting layer 912 of the light-emitting device 2B_2 was formed by co-evaporation of 9,9′-{6-[3-(triphenylsilyl)phenyl]-1,3,5-triazine-2,4-diyl}bis(9H-carbazole) (abbreviation: SiTrzCz2), 9-[3-(triphenylsilyl)phenyl]-3,9′-bi-9H-carbazole (abbreviation: PSiCzCz), and Pt(mmtBubOcz35dm4tBuppy-d₆) at a weight ratio of 0.45:0.45:0.10 to a thickness of 25 nm by an evaporation method using resistance heating.

Like the first light-emitting layer 912, the second light-emitting layer 917 was formed over the second hole-transport layer 916 by co-evaporation of SiTrzCz2, PSiCzCz, and Pt(mmtBubOcz35dm4tBuppy-d₆) at a weight ratio of 0.45:0.45:0.10 to a thickness of 25 nm by an evaporation method using resistance heating.

<Fabrication Method of Comparative Light-Emitting Device 2b>

The comparative light-emitting device 2b is different from the light-emitting device 2B_2 in the structure of the second electron-transport layer 918_2. Other components were fabricated in a manner similar to that for the light-emitting device 2B_2.

Specifically, the second electron-transport layer 918_2 was formed by co-evaporation of 6BP-4Cz2PPm and Liq at a volume ratio of 1:1 to a thickness of 25 nm by an evaporation method using resistance heating.

Table 15 lists the structures of the light-emitting devices 2B and the comparative light-emitting device 2b. Note that Condition 2B in Table 15 is shown in Table 16.

TABLE 15

| | | | |
|---|---|---|---|
| Thickness | Light-emitting | Light-emitting | Comparative light- |
| [nm] | device 2B_1 | device 2B_2 | emitting device 2b |

| Cap layer | 70 | DBT3P-II | |
|---|---|---|---|
| Second electrode 902 | 15 | Ag:Mg (1:0.1) | |
| Electron-injection layer 919 | 1 | Liq | |
| Second electron-transport layer 918_2 | 25 | TznP2N:Liq | 6BP-4Cz2PPm:Liq |
| | | (1:1) | (1:1) |

| | | |
|---|---|---|
| Second electron-transport layer 918_1 | 10 | mFBPTzn |
| Second light-emitting layer 917 | 25 | Condition 2B |
| Second hole-transport layer 916_2 | 5 | PSiCzCz |
| Second hole-transport layer 916_1 | 50 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Li₂O (1:0.02) |
| First electron-transport layer 913 | 10 | mPCCzPTzn-02 |
| First light-emitting layer 912 | 25 | Condition 2B |
| First hole-transport layer 911_2 | 5 | PSiCzCz |
| First hole-transport layer 911_1 | 45 | oFBiSF(2) |
| Hole-injection layer 910 | 10 | oFBiSF(2):OCHD-003 (1:0.03) |
| First electrode 901 | 85 | ITSO |
| | 100 | Ag |

TABLE 16

| | Condition 2B |
|---|---|
| Light-emitting device 2B_1 | SiTrzCz2-d₁₆:PSiCzCz-d₁₅:Pt(mmtBubOcz35dm4tBuppy-d₆) |
| | (0.45:0.45:0.10) |
| Light-emitting device 2B_2 | SiTrzCz2:PSiCzCz:Pt(mmtBubOcz35dm4tBuppy-d₆) |
| Comparative light-emitting device 2b | (0.45:0.45:0.10) |

### <Measurement Results of PL Spectra of Host Materials Used in Light-Emitting Devices>

PL spectra of thin films of host materials used in the light-emitting devices fabricated in this example were measured at room temperature. Specifically, PL spectra of a mixed film of 11mDBtBPPnfpr and βNCCP-d₂₆ used in the light-emitting device 2R_1 and a mixed film of 8mpTP-4mDBtPBfpm-d₁₃ and βNCCP-d₂₆ used in the light-emitting device 2G_1 were measured.

Each of the above PL spectra was measured using a 50-nm-thick thin film deposited over a quartz substrate. Each of the mixed films was deposited by co-evaporation of the organic compounds at a weight ratio of 1:1. A spectrofluorometer FP-8600DS produced by JASCO Corporation was used for the measurement of the PL spectra.

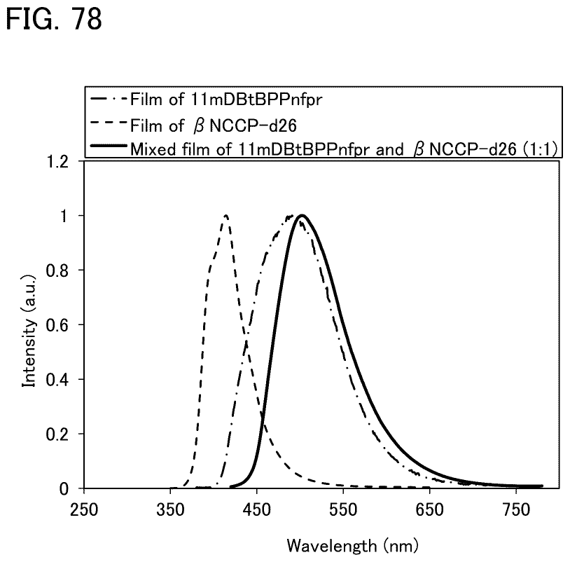

FIG. 78 shows the PL spectra of a film of 11mDBtBPPnfpr, a film of βNCCP-d₂₆, and a mixed film of 11mDBtBPPnfpr and βNCCP-d₂₆; these materials were used in the light-emitting device 2R_1. Peak wavelengths of the PL spectra of the film of 11mDBtBPPnfpr, the film of βNCCP-d₂₆, and the mixed film of 11mDBtBPPnfpr and βNCCP-d₂₆ are 491 nm, 414 nm, and 503 nm, respectively, revealing that the peak wavelength of the PL spectrum of the mixed film of 11mDBtBPPnfpr and βNCCP-d₂₆ is longer than that of the PL spectrum of each of the film of 11mDBtBPPnfpr and the film of βNCCP-d₂₆. It has been found that the PL spectrum of the mixed film of 11mDBtBPPnfpr and βNCCP-d₂₆ is different from the spectrum obtained by superimposing the spectra of the films of 11mDBtBPPnfpr and βNCCP-d₂₆, and shifted to a longer wavelength than each of the PL spectra of the films of 11mDBtBPPnfpr and βNCCP-d₂₆. The above indicates that the observed PL spectrum originates from an exciplex formed by 11mDBtBPPnfpr and βNCCP-d₂₆ in the mixed film, which were excited at room temperature.

Similarly, 11mDBtBPPnfpr and βNCCP in the mixed film which were used in the light-emitting device 2R_2 also form an exciplex when excited at room temperature.

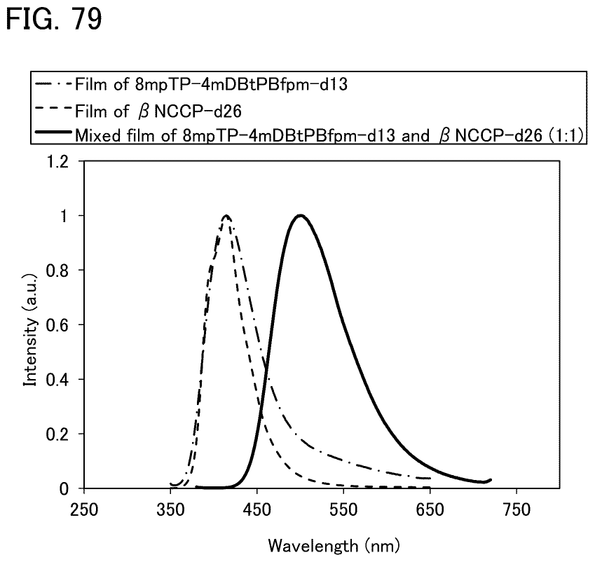

FIG. 79 shows the PL spectra of the film of 8mpTP-4mDBtPBfpm-d₁₃, the film of βNCCP-d₂₆, and the mixed film of 8mpTP-4mDBtPBfpm-d₁₃ and βNCCP-d₂₆; these materials were used in the light-emitting device 2G_1. Peak wavelengths of the PL spectra of the film of 8mpTP-4mDBtPBfpm-d₁₃, the film of βNCCP-d₂₆, and the mixed film of 8mpTP-4mDBtPBfpm-d₁₃ and βNCCP-d₂₆ are 415 nm, 414 nm, and 501 nm, respectively, revealing that the peak wavelength of the PL spectrum of the mixed film of 8mpTP-4mDBtPBfpm-d₁₃ and βNCCP-d₂₆ is longer than that of the PL spectrum of each of the film of 8mpTP-4mDBtPBfpm-d₁₃ and the film of βNCCP-d₂₆. It has also been found that the PL spectrum of the mixed film of 8mpTP-4mDBtPBfpm-d₁₃ and βNCCP-d₂₆ is different from the spectrum obtained by superimposing the spectra of the films of 8mpTP-4mDBtPBfpm-d₁₃ and βNCCP-d₂₆, and shifted to a longer wavelength than each of the PL spectra of the films of 8mpTP-4mDBtPBfpm-d₁₃ and βNCCP-d₂₆. The above indicates that the observed PL spectrum originates from an exciplex formed by 8mpTP-4mDBtPBfpm-d₁₃ and βNCCP-d₂₆ in the mixed film, which were excited at room temperature.

FIG. 38 described in Example 1 can be referred to for the room-temperature PL spectra of the film of 8mpTP-4mDBtPBfpm, the film of βNCCP, and the mixed film of 8mpTP-4mDBtPBfpm and βNCCP. The observed PL spectrum in Example 1 originates from an exciplex formed by 8mpTP-4mDBtPBfpm and βNCCP in the mixed film, which were excited at room temperature.

FIGS. 35 and 36 described in Example 1 can be referred to for the room-temperature PL spectra of the film of SiTrzCz2, the film of SiTrzCz2-d₁₆, the film of PSiCzCz, the film of PSiCzCz-d₁₅, the mixed film of SiTrzCz2-d₁₆ and PSiCzCz-dis, and the mixed film of SiTrzCz2 and PSiCzCz; these materials were used in the light-emitting devices 2B. The observed PL spectrum in Example 1 originates from an exciplex formed by SiTrzCz2-d₁₆ and PSiCzCz-dis in the mixed film and from an exciplex formed by SiTrzCz2 and PSiCzCz in the mixed film, which were excited at room temperature.

Absorption spectra and PL spectra of emission center substances were measured as described in Example 1. As shown in FIG. 40, the absorption edge on the longer wavelength side of the absorption spectrum of OCPG-006 is at 622 nm. As shown in FIG. 78, the emission edge on the shorter wavelength side of the PL spectrum of the mixed film of 11mDBtBPPnfpr and βNCCP-d₂₆ (the PL spectrum of the exciplex) is at 446 nm. These indicate that the absorption edge on the longer wavelength side of the absorption spectrum of OCPG-006 used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting device 2R_1.

The emission edge of the PL spectrum of OCPG-006 is at 589 nm. This indicates that the emission edge on the shorter wavelength side of the PL spectrum of OCPG-006 used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting device 2R_1.

As shown in FIG. 41, the absorption edge on the longer wavelength side of the absorption spectrum of Ir(5mppy-d₃)₂(mbfpypy-d₃) is at 526 nm. As shown in FIGS. 79 and 38, the emission edge on the shorter wavelength side of the PL spectrum of each of the mixed film of 8mpTP-4mDBtPBfpm-d₁₃ and βNCCP-d₂₆ and the mixed film of 8mpTP-4mDBtPBfpm and βNCCP (the PL spectrum of the exciplex) is at 442 nm. These indicate that the absorption edge on the longer wavelength side of the absorption spectrum of Ir(5mppy-d₃)₂(mbfpypy-d₃) used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting devices 2G.

The emission edge of the PL spectrum of Ir(5mppy-d₃)₂(mbfpypy-d₃) is at 502 nm. This indicates that the emission edge on the shorter wavelength side of the PL spectrum of Ir(5mppy-d₃)₂(mbfpypy-d₃) used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting devices 2G.

As shown in FIG. 39, the absorption edge on the longer wavelength side of the absorption spectrum of Pt(mmtBubOcz35dm4ppy-d₆) is at 463 nm. As shown in FIGS. 35 and 36, the emission edge on the shorter wavelength side of the PL spectrum of each of the mixed film of SiTrzCz2-d₁₆ and PSiCzCz-dis and the mixed film of SiTrzCz2 and PSiCzCz (the PL spectrum of the exciplex) is at 408 nm. These indicate that the absorption edge on the longer wavelength side of the absorption spectrum of Pt(mmtBubOcz35dm4ppy-d₆) used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting devices 2B.

The emission edge of the PL spectrum of Pt(mmtBubOcz35dm4ppy-d₆) is at 445 nm. This indicates that the emission edge on the shorter wavelength side of the PL spectrum of Pt(mmtBubOcz35dm4ppy-d₆) used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting devices 2B.

The HOMO levels and the LUMO levels of the host materials and the light-emitting substances used in the devices were measured as described in Example 1. The HOMO levels of βNCCP-d₂₆ and βNCCP as the hole-transport organic compounds were −5.60 eV and −5.62 eV, respectively, and the HOMO level of 11mDBtBPPnfpr as the electron-transport organic compound was −6.16 eV. The LUMO levels of βNCCP-d₂₆ and βNCCP as the hole-transport organic compounds were −2.19 eV and −2.21 eV, respectively, and the LUMO level of 11mDBtBPPnfpr as the electron-transport organic compound was −3.02 eV. Since the HOMO levels of βNCCP-d₂₆ and βNCCP as the hole-transport organic compounds are higher than or equal to the HOMO level of 11mDBtBPPnfpr as the electron-transport organic compound and the LUMO levels of βNCCP-d₂₆ and βNCCP as the hole-transport organic compounds are higher than or equal to the LUMO level of 11mDBtBPPnfpr as the electron-transport organic compound, the light-emitting devices 2R each include the host materials that can efficiently form an exciplex.

The HOMO levels of βNCCP-d₂₆ and βNCCP as the hole-transport organic compounds were −5.60 eV and −5.62 eV, respectively, and the HOMO level of 8mpTP-4mDBtPBfpm as the electron-transport organic compound was −6.2 eV. Furthermore, the HOMO level of 8mpTP-4mDBtPBfpm-d₁₃ as the electron-transport organic compound has been found to be lower than or equal to −6.0 eV because the oxidation potential was not observed in cyclic voltammetry (CV) measurement. The LUMO levels of βNCCP-d₂₆ and βNCCP as the hole-transport organic compounds were −2.19 eV and −2.21 eV, respectively, and the LUMO levels of 8mpTP-4mDBtPBfpm-d₁₃ and 8mpTP-4mDBtPBfpm as the electron-transport organic compounds were each −3.01 eV. Since the HOMO levels of βNCCP-d₂₆ and βNCCP as the hole-transport organic compounds are higher than or equal to the HOMO levels of 8mpTP-4mDBtPBfpm-d₁₃ and 8mpTP-4mDBtPBfpm as the electron-transport organic compounds and the LUMO levels of βNCCP-d₂₆ and βNCCP as the hole-transport organic compounds are higher than or equal to the LUMO levels of 8mpTP-4mDBtPBfpm-d₁₃ and 8mpTP-4mDBtPBfpm as the electron-transport organic compounds, the light-emitting devices 2G each include the host materials that can efficiently form an exciplex.

The HOMO level and the LUMO level of Ir(5mppy-d₃)₂(mbfpypy-d₃) were −5.32 eV and −2.39 eV, respectively. This indicates that the energy difference between the HOMO level (−5.32 eV) and the LUMO level (−2.39 eV) of Ir(5mppy-d₃)₂(mbfpypy-d₃), which corresponds to the band gap thereof, was 2.93 eV. The energy differences between the HOMO levels and the LUMO levels of the exciplexes formed by the host materials were 2.59 eV and 2.61 eV, which respectively correspond to the energy difference between the HOMO level (−5.60 eV) of βNCCP-d₂₆ as the hole-transport organic compound and the LUMO level (−3.01 eV) of 8mpTP-4mDBtPBfpm-d₁₃ as the electron-transport organic compound and the energy difference between the HOMO level (−5.62 eV) of βNCCP as the hole-transport organic compound and the LUMO level (−3.01 eV) of 8mpTP-4mDBtPBfpm as the electron-transport organic compound. This indicates that the energy difference between the HOMO and LUMO levels of Ir(5mppy-d₃)₂(mbfpypy-d₃) was greater than the energy difference between the HOMO and LUMO levels of the exciplex.

Since the HOMO levels of PSiCzCz-dis and PSiCzCz as the hole-transport organic compounds are higher than or equal to the HOMO levels of SiTrzCz2-d₁₆ and SiTrzCz2 as the electron-transport organic compounds and the LUMO levels of PSiCzCz-dis and PSiCzCz as the hole-transport organic compounds are higher than or equal to the LUMO levels of SiTrzCz2-d₁₆ and SiTrzCz2 as the electron-transport organic compounds, the light-emitting devices 2B each include the host materials that can efficiently form an exciplex.

The HOMO level and the LUMO level of Pt(mmtBubOcz35dm4ppy-d₆) were −5.5 eV and −2.47 eV, respectively. This indicates that the energy difference between the HOMO level (−5.5 eV) and the LUMO level (−2.47 eV) of Pt(mmtBubOcz35dm4ppy-d₆), which corresponds to the band gap thereof, was 3.03 eV. The energy difference between the HOMO and LUMO levels of the exciplex formed by the host materials corresponds to the energy difference between the HOMO level (−5.7 eV) of PSiCzCz-dis or PSiCzCz as the hole-transport organic compound and the LUMO level (−2.98 eV) of SiTrzCz2-d₁₆ or SiTrzCz2 as the electron-transport organic compound. Thus, the energy difference between the HOMO and LUMO levels of each of the exciplex formed by SiTrzCz2-d₁₆ and PSiCzCz-dis and the exciplex formed by SiTrzCz2 and PSiCzCz was 2.72 eV. This indicates that the energy difference between the HOMO and LUMO levels of Pt(mmtBubOcz35dm4ppy-d₆) was greater than the energy difference between the HOMO and LUMO levels of the exciplex.

The T₁ levels of the host materials of the light-emitting layer and the substances used for the first and second hole-transport layers and the first and second electron-transport layers were also calculated as described in Example 1.

According to FIG. 32B, the T₁ level of 8mpTP-4mDBtPBfpm-d₁₃ is 2.55 eV (486 nm).

According to FIG. 33B, the T₁ level of βNCCP-d₂₆ is 2.56 eV (485 nm). The difference between the T₁ level of 8mpTP-4mDBtPBfpm-d₁₃ and the T₁ level of βNCCP-d₂₆ is less than or equal to 0.20 eV, and the efficiency of energy transfer from the triplet excited state is improved by the influence of deuterium; thus, deterioration of the host materials can be inhibited.

According to FIG. 28B, the T₁ level of SiTrzCz2-d₁₆ is 2.93 eV (423 nm). According to FIG. 29B, the T₁ level of PSiCzCz-dis is 2.97 eV (417 nm). The difference between the T₁ level of SiTrzCz2-d₁₆ and the T₁ level of PSiCzCz-dis is less than or equal to 0.20 eV, and the efficiency of energy transfer from the triplet excited state is improved by the influence of deuterium; thus, deterioration of the host materials can be inhibited.

Since each of the emission center substances used in the light-emitting devices 2R, 2G, and 2B is a phosphorescent substance, the T₁ level of each emission center substance can be measured from a PL spectrum as described in Example 1. The T₁ level of OCPG-006 is 2.10 eV (589 nm), the T₁ level of Ir(5mppy-d₃)₂(mbfpypy-d₃) is 2.47 eV (502 nm), and the T₁ level of Pt(mmtBubOcz35dm4ppy-d₆) is 2.79 eV (445 nm).

The T₁ level (2.56 eV) of βNCCP-d₂₆, the T₁ level (2.55 eV) of βNCCP, and the T₁ level (2.20 eV) of 11mDBtBPPnfpr, which are the host materials, have each been found to be higher than the T₁ level (2.10 eV) of OCPG-006 as the emission center substance. This indicates that the light-emitting devices 2R emit light efficiently. Furthermore, the T₁ level (2.56 eV) of βNCCP-d₂₆, the T₁ level (2.55 eV) of βNCCP, the T₁ level (2.55 eV) of 8mpTP-4mDBtPBfpm-d₁₃, and the T₁ level (2.55 eV) of 8mpTP-4mDBtPBfpm, which are the host materials, have each been found to be higher than the T₁ level (2.47 eV) of Ir(5mppy-d₃)₂(mbfpypy-d₃) as the emission center substance. This indicates that the light-emitting devices 2G emit light efficiently. Furthermore, the T₁ level (2.97 eV) of PSiCzCz-dis, the T₁ level (2.97 eV) of PSiCzCz, the T₁ level (2.93 eV) of SiTrzCz2-d₁₆, and the T₁ level (2.95 eV) of SiTrzCz2, which are the host materials, have each been found to be higher than the T₁ level (2.79 eV) of Pt(mmtBubOcz35dm4ppy-d₆) as the emission center substance. This indicates that the light-emitting devices 2B emit light efficiently.

According to FIG. 42, the T₁ level of oFBiSF (2) as the hole-transport organic compound is 2.52 eV (492 nm). According to FIG. 43, the T₁ level of mPCCzPTzn-02 as the electron-transport organic compound is 2.59 eV (478 nm). According to FIG. 44, the T₁ level of mFBPTzn as the electron-transport organic compound is 2.54 eV (488 nm).

Furthermore, the T₁ level (2.52 eV) of oFBiSF (2) used for the first hole-transport layer and the second hole-transport layer has been found to be higher than the T₁ level (2.10 eV) of OCPG-006 as the emission center substance. This indicates that the light-emitting devices 2R emit light efficiently. Furthermore, the T₁ level (2.52 eV) of oFBiSF (2) used for the first hole-transport layer and the second hole-transport layer has been found to be higher than the T₁ level (2.47 eV) of Ir(5mppy-d₃)₂(mbfpypy-d₃) as the emission center substance. This indicates that the light-emitting devices 2G emit light efficiently. Furthermore, the T₁ level (2.97 eV) of PSiCzCz used for the first hole-transport layer and the second hole-transport layer has been found to be higher than the T₁ level (2.79 eV) of Pt(mmtBubOcz35dm4ppy-d₆) as the emission center substance. This indicates that the light-emitting devices 2B emit light efficiently.

The T₁ level (2.59 eV) of mPCCzPTzn-02 used for the first electron-transport layer and the T₁ level (2.54 eV) of mFBPTzn used for the second electron-transport layer have each been found to be higher than the T₁ level (2.10 eV) of OCPG-006 as the emission center substance. This indicates that the light-emitting devices 2R emit light efficiently. Furthermore, the T₁ level (2.59 eV) of mPCCzPTzn-02 used for the first electron-transport layer and the T₁ level (2.54 eV) of mFBPTzn used for the second electron-transport layer have each been found to be higher than the T₁ level (2.47 eV) of Ir(5mppy-d₃)₂(mbfpypy-d₃) as the emission center substance. This indicates that the light-emitting devices 2G emit light efficiently. The T₁ level (2.59 eV) of mPCCzPTzn-02 used for the first electron-transport layer and the T₁ level (2.54 eV) of mFBPTzn used for the second electron-transport layer have each been found to be lower than the T₁ level (2.79 eV) of Pt(mmtBubOcz35dm4ppy-d₆) as the emission center substance. This indicates that the light-emitting devices 2B have high stability.

### <Measurement Results of Phosphorescence Lifetimes of Host Materials Used in Light-Emitting Devices 2R and 2G>

Here, the phosphorescence lifetimes of βNCCP-d₂₆, βNCCP, 8mpTP-4mDBtPBfpm, and 8mpTP-4mDBtPBfpm-d₁₃, which were the host materials used in the light-emitting devices 2R and 2G, were measured. Note that the measurement was performed as described in <Measurement results of phosphorescence lifetimes of host materials used in light-emitting devices 1B> in Example 1.

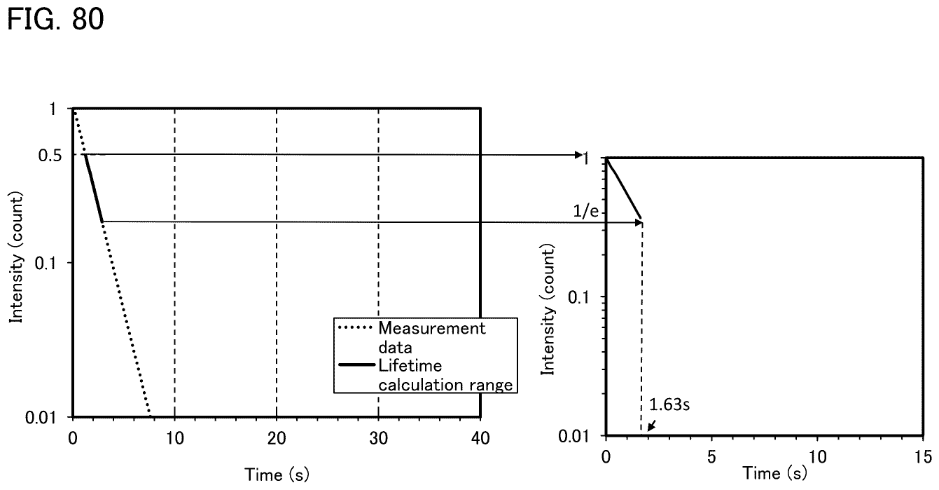

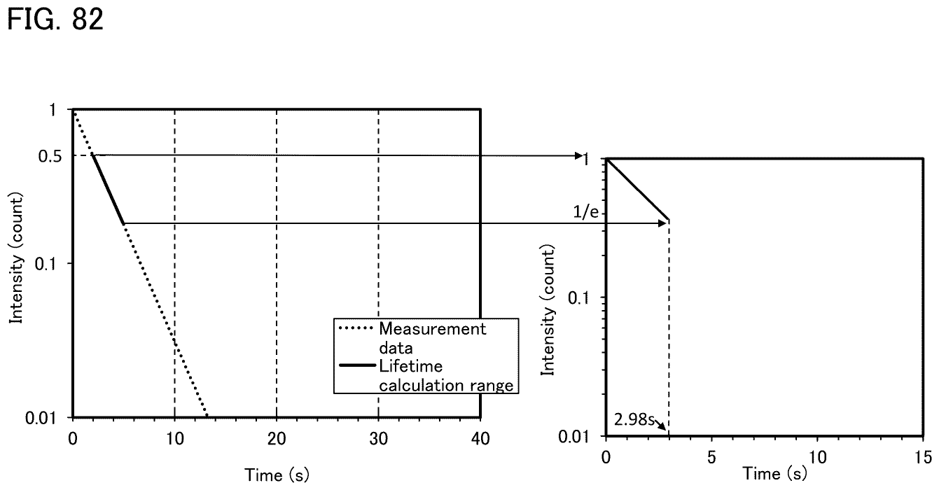

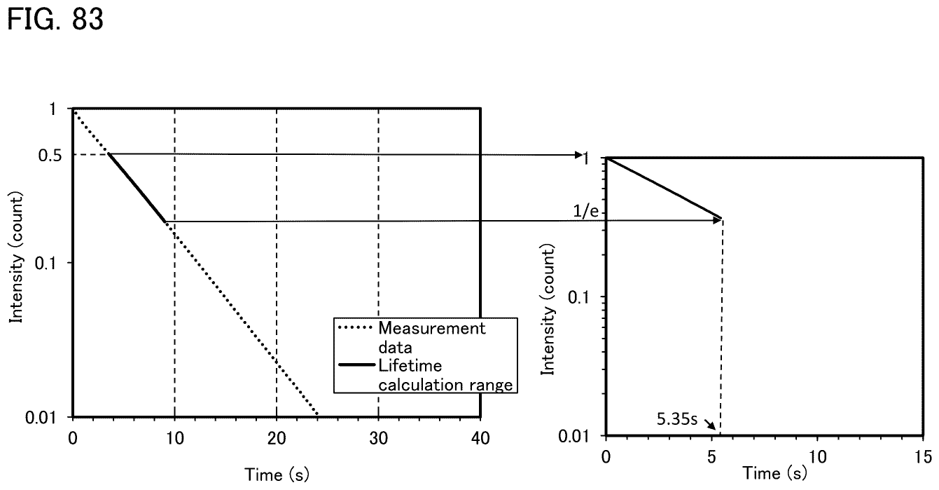

FIG. 80 shows measurement data of βNCCP, and FIG. 81 shows measurement data of βNCCP-d₂₆. FIG. 82 shows measurement data of 8mpTP-4mDBtPBfpm, and FIG. 83 shows measurement data of 8mpTP-4mDBtPBfpm-d₁₃. The phosphorescence lifetime was defined as follows: the time at which the light amount becomes 50% of that at the start of the measurement in the measured data was set as 1=0, and the time taken for the light amount to attenuate to 1/e of that at 1=0 was regarded as the phosphorescence lifetime. In the graphs in FIGS. 80 to 83, the time at which the intensity reaches 50% of that at the start of the measurement is set as time 0 s, the light amount at 0 s is regarded as 1, and the time taken for the light amount to become 1/e is the phosphorescence lifetime.

FIGS. 80 and 81 show that the phosphorescence lifetime of βNCCP is 1.63 seconds and the phosphorescence lifetime of βNCCP-d₂₆ is 5.19 seconds. FIGS. 82 and 83 show that the phosphorescence lifetime of 8mpTP-4mDBtPBfpm is 2.98 seconds and the phosphorescence lifetime of 8mpTP-4mDBtPBfpm-d₁₃ is 5.35 seconds. The phosphorescence lifetime of βNCCP-d₂₆ is 3.18 times the phosphorescence lifetime of βNCCP, and the phosphorescence lifetime of 8mpTP-4mDBtPBfpm-d₁₃ is 1.80 times the phosphorescence lifetime of 8mpTP-4mDBtPBfpm. The product of these multipliers is 5.72, which confirms that the phosphorescence lifetime is increased (extended) by deuteration. A light-emitting device including a deuterated organic compound as an energy donor has less deterioration of the organic compound than a light-emitting device including a non-deuterated organic compound as an energy donor, and thus can have high reliability.

### <Characteristics of Light-Emitting Devices>

The light-emitting devices were sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting devices were measured.

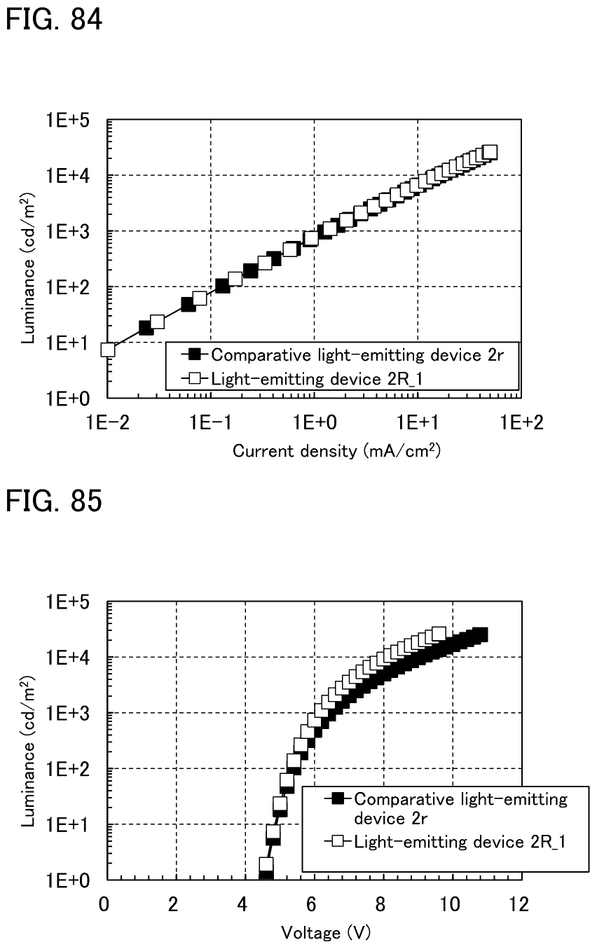

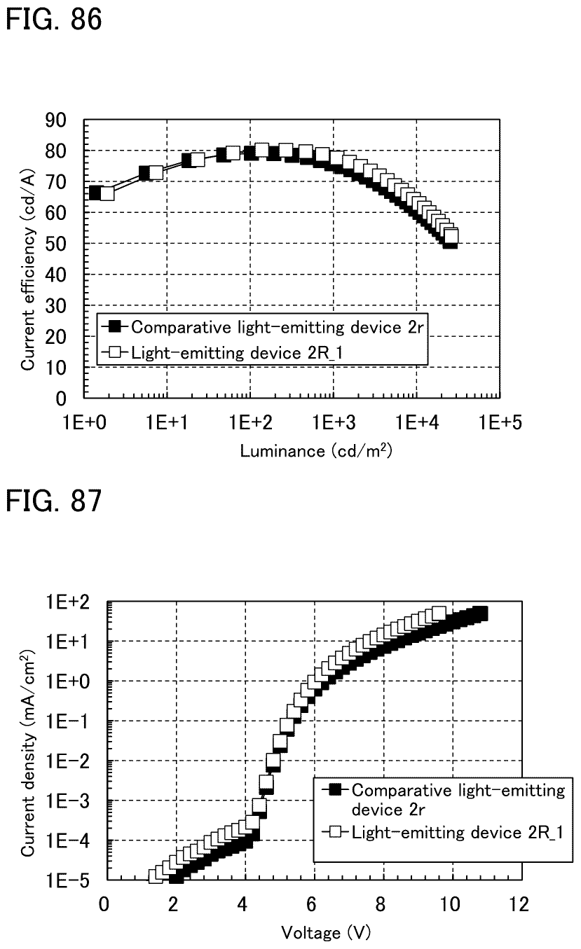

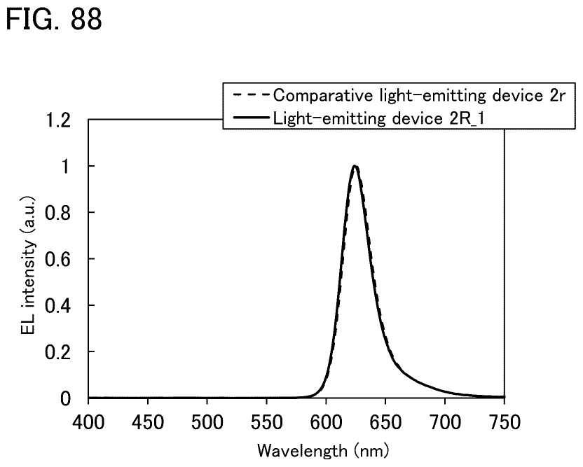

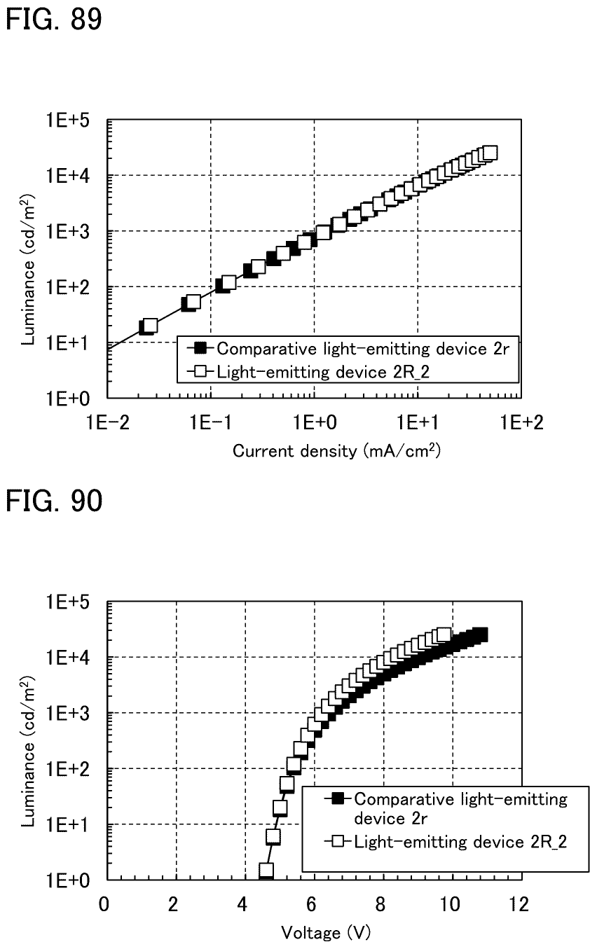

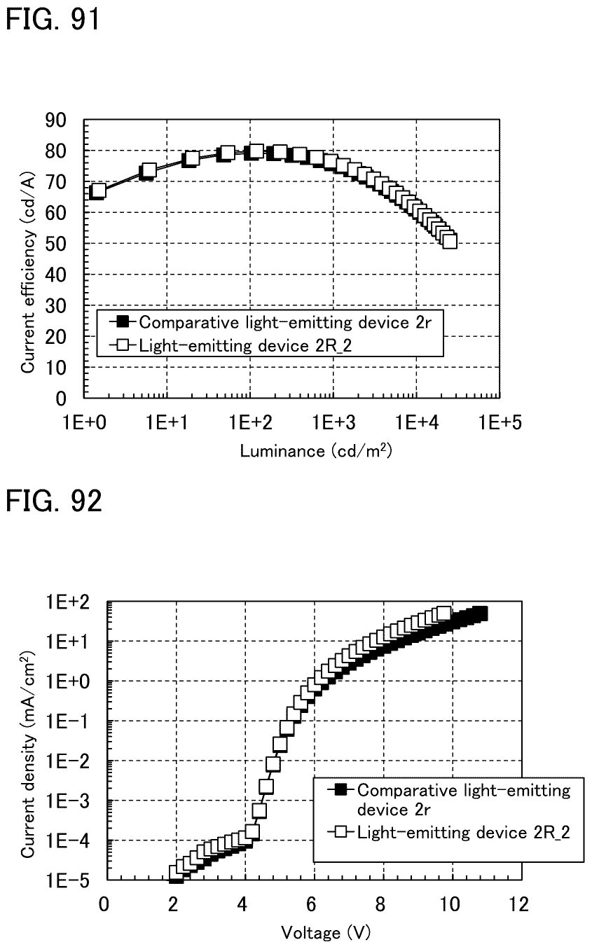

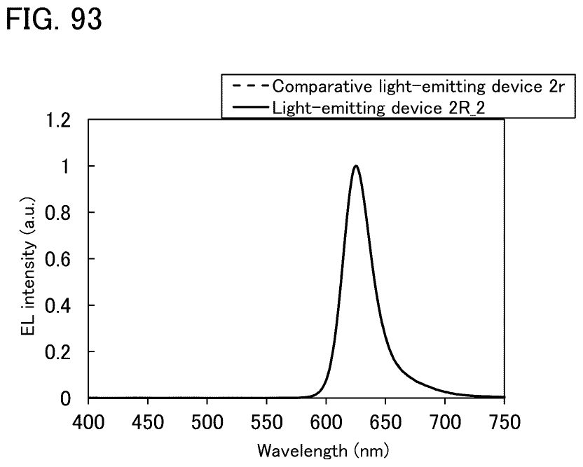

FIG. 84 shows the luminance-current density characteristics of the light-emitting device 2R_1 and the comparative light-emitting device 2r, FIG. 85 shows the luminance-voltage characteristics thereof, FIG. 86 shows the current efficiency-luminance characteristics thereof, FIG. 87 shows the current density-voltage characteristics thereof, and FIG. 88 shows the electroluminescence spectra thereof. FIG. 89 shows the luminance-current density characteristics of the light-emitting device 2R_2 and the comparative light-emitting device 2r, FIG. 90 shows the luminance-voltage characteristics thereof, FIG. 91 shows the current efficiency-luminance characteristics thereof, FIG. 92 shows the current density-voltage characteristics thereof, and FIG. 93 shows the electroluminescence spectra thereof.

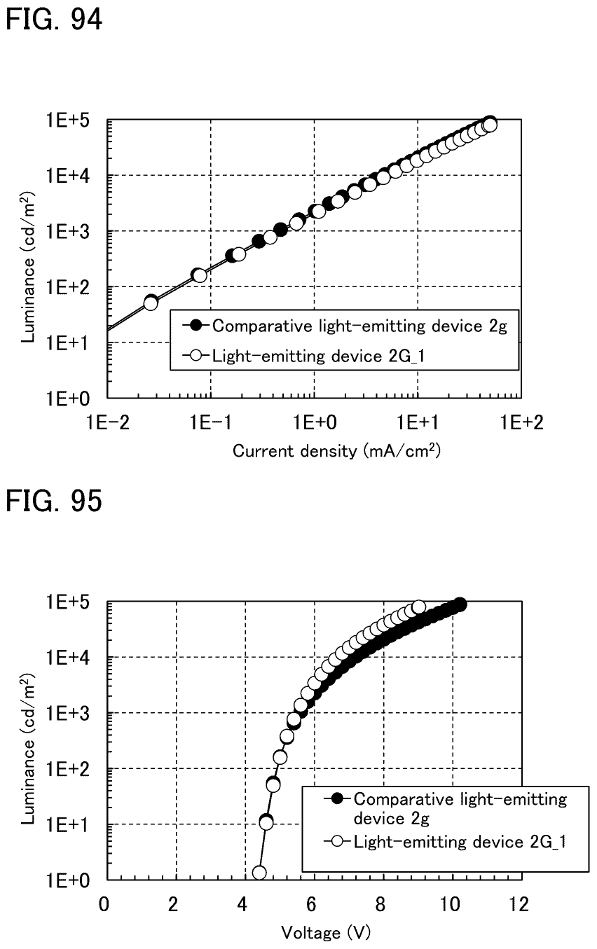

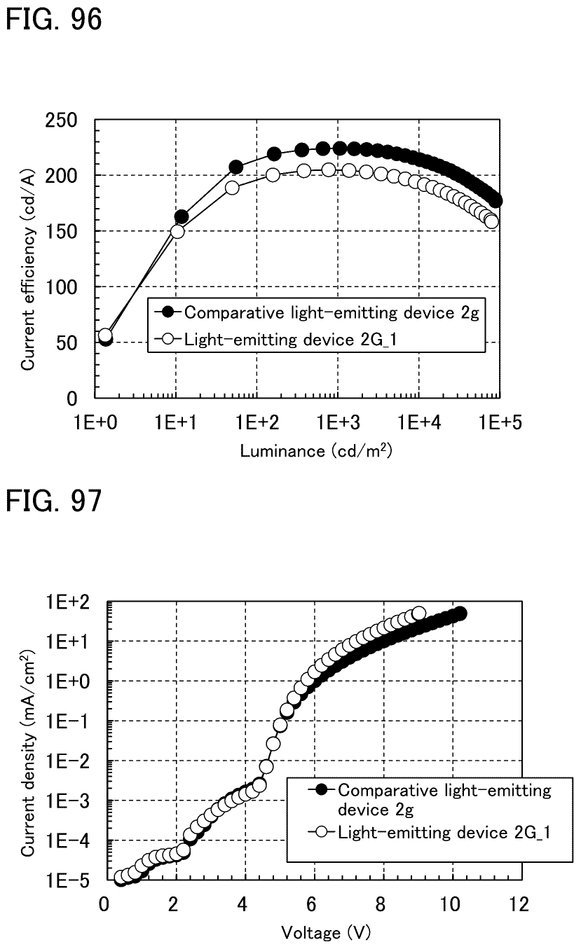

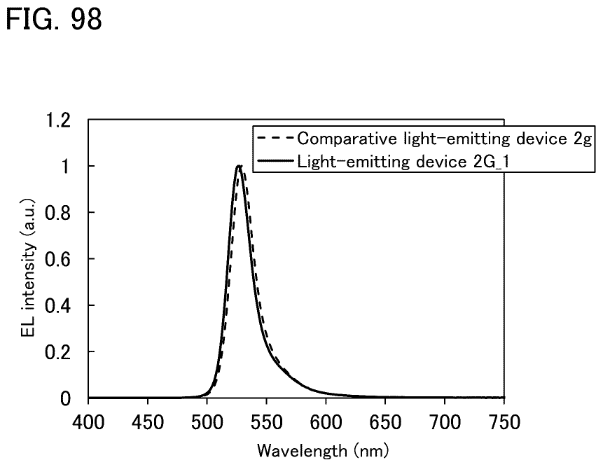

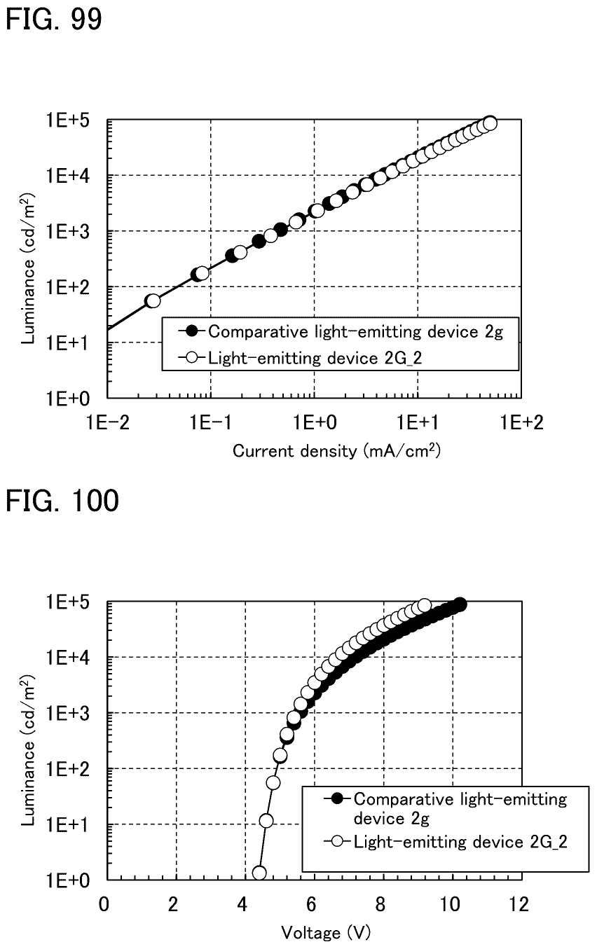

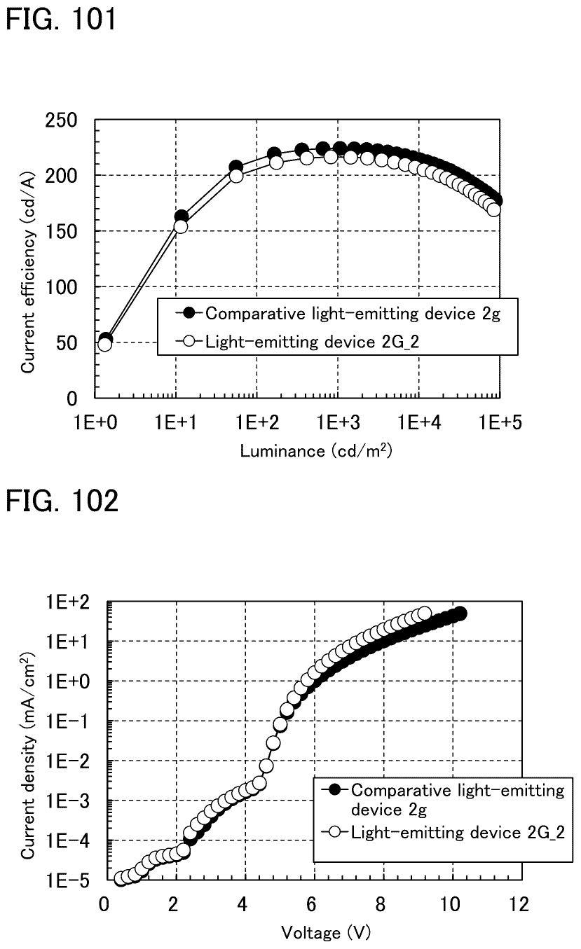

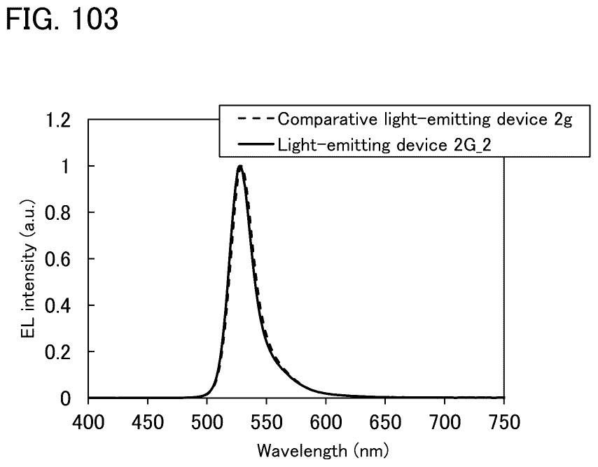

FIG. 94 shows the luminance-current density characteristics of the light-emitting device 2G_1 and the comparative light-emitting device 2g, FIG. 95 shows the luminance-voltage characteristics thereof, FIG. 96 shows the current efficiency-luminance characteristics thereof, FIG. 97 shows the current density-voltage characteristics thereof, and FIG. 98 shows the electroluminescence spectra thereof. FIG. 99 shows the luminance-current density characteristics of the light-emitting device 2G_2 and the comparative light-emitting device 2g, FIG. 100 shows the luminance-voltage characteristics thereof, FIG. 101 shows the current efficiency-luminance characteristics thereof, FIG. 102 shows the current density-voltage characteristics thereof, and FIG. 103 shows the electroluminescence spectra thereof.

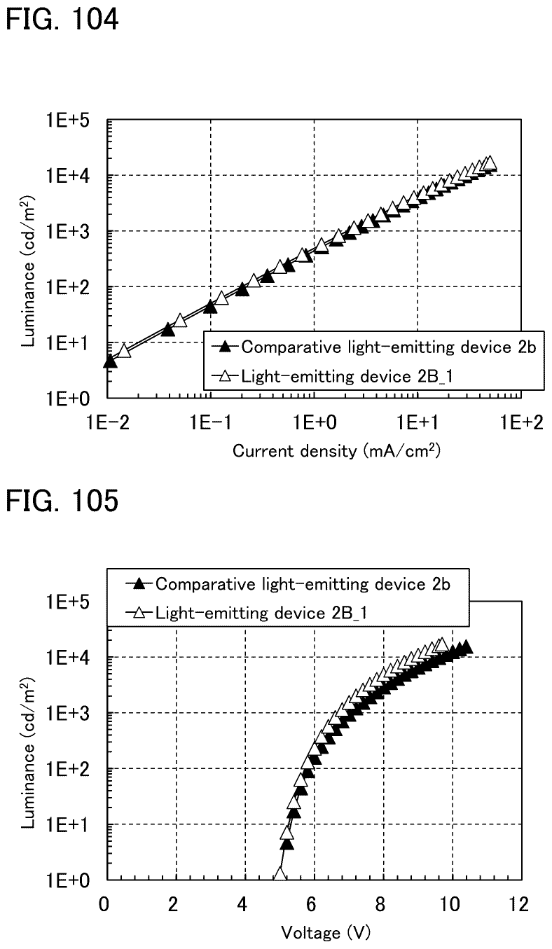

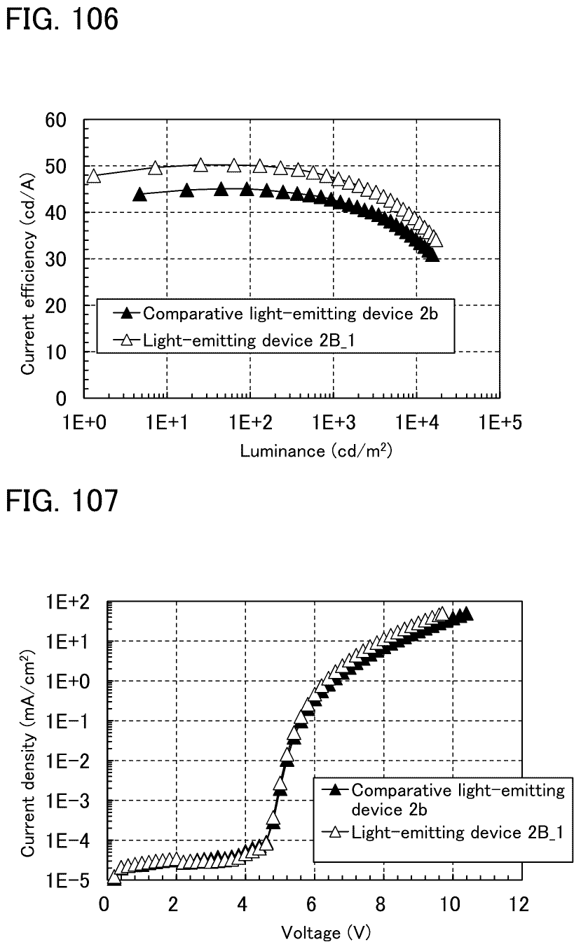

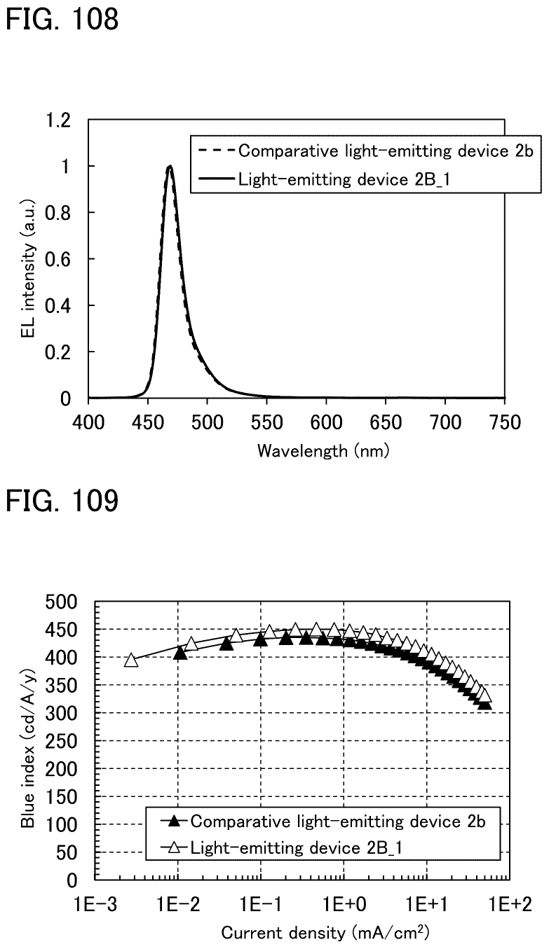

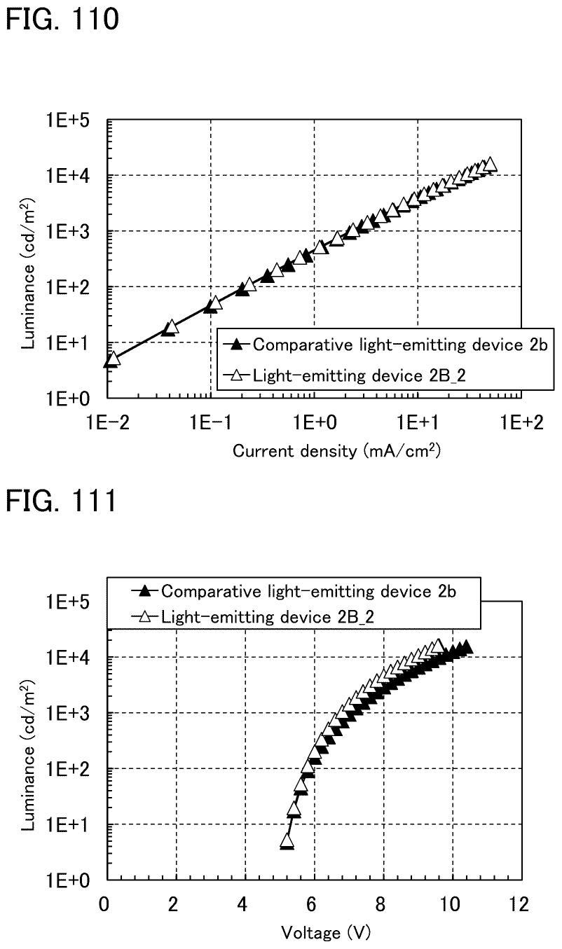

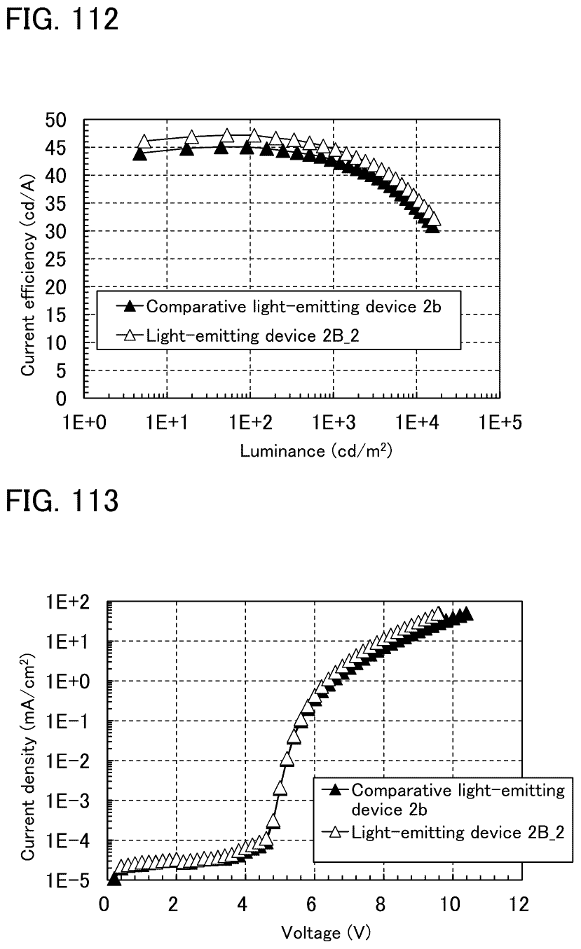

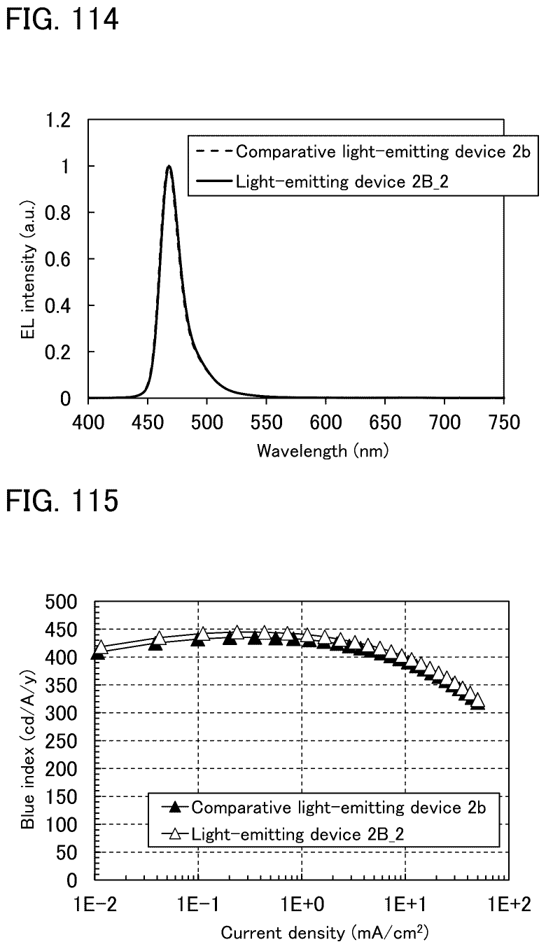

FIG. 104 shows the luminance-current density characteristics of the light-emitting device 2B_1 and the comparative light-emitting device 2b, FIG. 105 shows the luminance-voltage characteristics thereof, FIG. 106 shows the current efficiency-luminance characteristics thereof, FIG. 107 shows the current density-voltage characteristics thereof, FIG. 108 shows the electroluminescence spectra thereof, and FIG. 109 shows the blue index-current density characteristics thereof. FIG. 110 shows the luminance-current density characteristics of the light-emitting device 2B_2 and the comparative light-emitting device 2b, FIG. 111 shows the luminance-voltage characteristics thereof, FIG. 112 shows the current efficiency-luminance characteristics thereof, FIG. 113 shows the current density-voltage characteristics thereof, FIG. 114 shows the electroluminescence spectra thereof, and FIG. 115 shows the blue index-current density characteristics thereof.

Table 17 shows the main characteristics of the light-emitting devices 2 and the comparative light-emitting devices 2 at a luminance of approximately 1000 cd/m². The luminance, CIE chromaticity, and electroluminescence spectra were measured at normal temperature with a spectroradiometer (SR-ULIR, produced by TOPCON TECHNOHOUSE CORPORATION).

TABLE 17

| | | | Current | | | | Current | BI |
|---|---|---|---|---|---|---|---|---|
| | Voltage | Current | density | Chroma- | Chroma- | Luminance | efficiency | value |
| | (V) | (mA) | (mA/cm²) | ticity x | ticity y | (cd/m²) | (cd/A) | (cd/A/y) |
| Light-emitting | 6.20 | 0.0568 | 1.42 | 0.690 | 0.309 | 1101 | 77.6 | — |
| device 2R_1 | | | | | | | | |
| Light-emitting | 6.20 | 0.0486 | 1.22 | 0.692 | 0.308 | 931 | 76.5 | — |
| device 2R_2 | | | | | | | | |
| Comparative | 6.40 | 0.0505 | 1.26 | 0.692 | 0.308 | 955 | 75.7 | — |
| light-emitting | | | | | | | | |
| device 2r | | | | | | | | |
| Light-emitting | 5.40 | 0.0150 | 0.376 | 0.220 | 0.734 | 770 | 205 | — |
| device 2G_1 | | | | | | | | |
| Light-emitting | 5.40 | 0.0152 | 0.379 | 0.224 | 0.733 | 821 | 216 | — |
| device 2G_2 | | | | | | | | |
| Comparative | 5.60 | 0.0189 | 0.473 | 0.231 | 0.730 | 1060 | 224 | — |
| light-emitting | | | | | | | | |
| device 2g | | | | | | | | |
| Light-emitting | 6.80 | 0.0971 | 2.43 | 0.123 | 0.107 | 1147 | 47.2 | 440 |
| device 2B_1 | | | | | | | | |
| Light-emitting | 6.80 | 0.0948 | 2.37 | 0.124 | 0.103 | 1057 | 44.6 | 432 |
| device 2B_2 | | | | | | | | |
| Comparative | 7.00 | 0.0876 | 2.19 | 0.126 | 0.101 | 937 | 42.8 | 424 |
| light-emitting | | | | | | | | |
| device 2b | | | | | | | | |

According to FIGS. 84 to 93 and the above table, the light-emitting devices 2R and the comparative light-emitting device 2r exhibited red light emission originating from OCPG-006. It has also been found that the light-emitting devices 2R have a lower driving voltage than the comparative light-emitting device 2r. It has also been found that the light-emitting device 2R_1 has a particularly favorable current efficiency.

According to FIGS. 94 to 103 and the above table, the light-emitting devices 2G and the comparative light-emitting device 2g exhibited green light emission originating from Ir(5mppy-d₃)₂(mbfpypy-d₃). It has also been found that the light-emitting devices 2G have a lower driving voltage than the comparative light-emitting device 2g.

According to FIGS. 104 to 115 and the above table, the light-emitting devices 2B and the comparative light-emitting device 2b emitted phosphorescent light originating from Pt(mmtBubOcz35dm4tBuppy-d₆). It has also been found that the light-emitting devices 2B have favorable emission characteristics and higher BI values than the comparative light-emitting device 2b, revealing their favorable efficiency as blue-light-emitting devices. It has also been found that the light-emitting devices 2B have higher current efficiencies than the comparative light-emitting device 2b. It has also been found that the light-emitting device 2B_1 has a particularly favorable current efficiency.

Thus, the light-emitting device 2R_1, the light-emitting device 2G_1, and the light-emitting device 2B_1 have higher electron-injection properties, higher efficiencies as light-emitting devices, and lower driving voltages than the comparative light-emitting device 2r, the comparative light-emitting device 2g, and the comparative light-emitting device 2b, respectively, owing to the use of the organic compound (TznP2N) having a triazine skeleton in the second electron-transport layer 918_2.

### <Reliability Test Result>

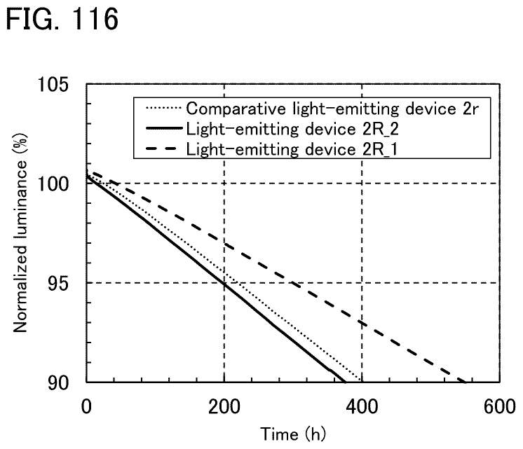

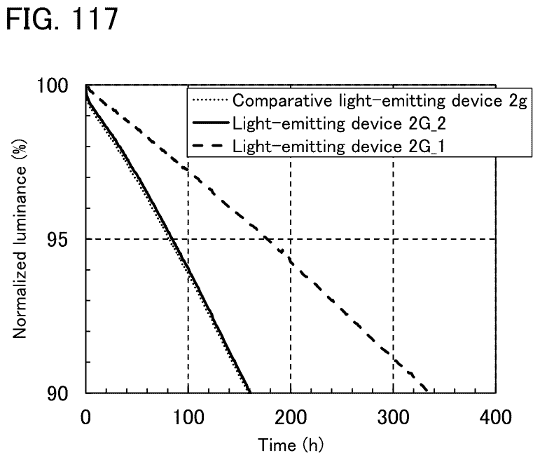

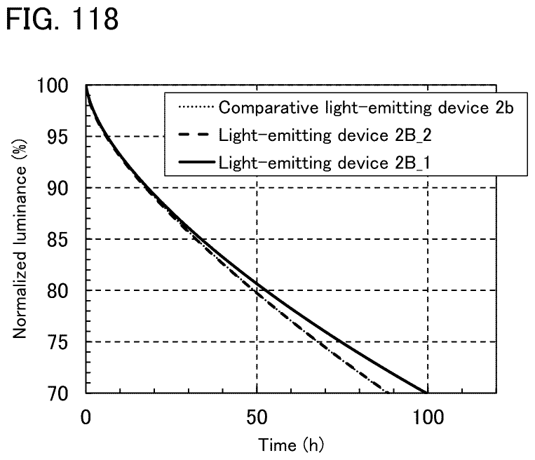

Furthermore, a reliability test was performed on the light-emitting devices 2R, 2G, and 2B and the comparative light-emitting devices 2. FIG. 116 shows time-dependent changes in normalized luminance at the time of constant current density driving (75 [mA/cm²]) of the light-emitting devices 2R. FIG. 117 shows time-dependent changes in normalized luminance at the time of constant current density driving (50 [mA/cm²]) of the light-emitting devices 2G. FIG. 118 shows time-dependent changes in normalized luminance at the time of constant current density driving (10 [mA/cm²]) of the light-emitting devices 2B. In FIGS. 116 to 118, the vertical axis represents the luminance (%) normalized with the luminance at the time of the start of light emission as 100%, and the horizontal axis represent the time (h).

As shown in FIG. 116, the LT90 (h), which is the time that has elapsed until the measured luminance decreases to 90% of the initial luminance, of the light-emitting device 2R_1 is 550 hours. The LT90 (h) of the light-emitting device 2R_2 is 376 hours. The LT90 (h) of the comparative light-emitting device 2r is 403 hours.

As shown in FIG. 117, the LT90 (h) of the light-emitting device 2G_1 is 336 hours. The LT90 (h) of the light-emitting device 2G_2 is 161 hours. The LT90 (h) of the comparative light-emitting device 2g is 159 hours.

As shown in FIG. 118, the LT70 (h) of the light-emitting device 2B_1 is 100 hours. The LT70 (h) of the light-emitting device 2B_2 is 88 hours. The LT70 (h) of the comparative light-emitting device 2b is 88 hours.

The above findings show that the reliability of a light-emitting device can be improved by deuteration of a host material.

### <Panel Characteristics>

Next, display devices 2 each including one of the light-emitting devices 2R, one of the light-emitting devices 2G, and one of the light-emitting devices 2B respectively in red, green, and blue subpixels (a display device 2_1 to a display device 2_4) and a comparative display device 2 including the comparative light-emitting device 2r, the comparative light-emitting device 2g, and the comparative light-emitting device 2b respectively in red, green, and blue subpixels were assumed, and the power consumption of their display portions (except for the power consumption of a driving transistor, a driving circuit, and the like) was tentatively calculated. Note that each of the light-emitting devices assumed to be used in each display device is a tandem light-emitting device, and the same emission center substance is used in the plurality of light-emitting layers in each of the light-emitting devices. Thus, the use of a side-by-side patterning method was assumed for each display device.

Table 18 lists the structures of the light-emitting devices fabricated in this example.

TABLE 18

| | Red | Green | Blue |
|---|---|---|---|
| Display device 2_1 | Light-emitting device 2R_1 | Light-emitting device 2G_1 | Light-emitting device 2B_1 |
| | ▴ | ● | ● |
| Display device 2_2 | Light-emitting device 2R_1 | Light-emitting device 2G_2 | Light-emitting device 2B_2 |
| | ▴ | X | X |
| Display device 2_3 | Light-emitting device 2R_2 | Light-emitting device 2G_1 | Light-emitting device 2B_2 |
| | X | ● | X |
| Display device 2_4 | Light-emitting device 2R_2 | Light-emitting device 2G_2 | Light-emitting device 2B_1 |
| | X | X | ● |
| Comparative display device 2 | Comparative light-emitting device 2r | Comparative light-emitting device 2g | Comparative light-emitting device 2b |
| | X | X | X |

●: Both the first host material and the second host material include deuterium.
▴: Either the first host material or the second host material includes deuterium.
X: Neither the first host material nor the second host material is deuterated.

The conditions of the display devices assumed for the tentative calculation are as follows, which are similar to those in Example 1. Thus, the corresponding description in Example 1 can be referred to.

TABLE 19

| | |
|---|---|
| Panel size | 5 inches (16:9) |
| Panel area | 68.9 cm² |

| | | |
|---|---|---|
| Aperture ratio | 30% | Red 10% |
| | | Green 10% |
| | | Blue 10% |

| | |
|---|---|
| Effective luminance | 1000 cd/m² in displaying white |
| | on the entire screen |
| Circular polarizing plate | Not used |

Table 20 shows the results of calculating the power consumption of the display device 2_1 assumed to include the light-emitting devices 2R_1, 2G_1, and 2B_1.

TABLE 20
Display device 2_1

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.690 | 0.309 | 273.6 | 2736 | 73.5 | 3.72 | 25.7 | 6.79 | 174 |
| Green | 0.219 | 0.735 | 580.5 | 5805 | 198 | 2.93 | 20.2 | 6.30 | 127 |
| Blue | 0.123 | 0.107 | 145.9 | 1459 | 46.6 | 3.13 | 21.6 | 6.96 | 150 |
| Full white | 0.313 | 0.329 | 1000 | — | 102 | — | 67.5 | — | 452 |

Table 21 shows the results of calculating the power consumption of the display device 2_2 assumed to include the light-emitting devices 2R_1, 2G_2, and 2B_2.

TABLE 21
Display device 2_2

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.690 | 0.309 | 270.4 | 2704 | 73.5 | 3.68 | 25.3 | 6.78 | 172 |
| Green | 0.223 | 0.734 | 589.4 | 5894 | 211 | 2.80 | 19.3 | 6.30 | 122 |
| Blue | 0.124 | 0.103 | 140.2 | 1402 | 43.9 | 3.19 | 22.0 | 6.98 | 154 |
| Full white | 0.313 | 0.329 | 1000.0 | — | 103 | — | 66.6 | — | 447 |

Table 22 shows the results of calculating the power consumption of the display device 2_3 assumed to include the light-emitting devices 2R_2, 2G_1, and 2B_2.

TABLE 22
Display device 2_3

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.692 | 0.308 | 269.8 | 2698 | 71.6 | 3.77 | 26.0 | 6.90 | 179 |
| Green | 0.219 | 0.735 | 590.3 | 5903 | 198 | 2.98 | 20.6 | 6.31 | 130 |
| Blue | 0.124 | 0.103 | 139.9 | 1399 | 43.9 | 3.18 | 21.9 | 6.98 | 153 |
| Full white | 0.313 | 0.329 | 1000 | — | 101 | — | 68.5 | — | 462 |

Table 23 shows the results of calculating the power consumption of the display device 2_4 assumed to include the light-emitting devices 2R_2, 2G_2, and 2B_1.

TABLE 23
Display device 2_4

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.692 | 0.308 | 269.0 | 2690 | 71.6 | 3.76 | 25.9 | 6.90 | 179 |
| Green | 0.223 | 0.734 | 584.7 | 5847 | 211 | 2.77 | 19.1 | 6.30 | 120 |
| Blue | 0.123 | 0.107 | 146.3 | 1463 | 46.6 | 3.14 | 21.6 | 6.96 | 151 |
| Full white | 0.313 | 0.329 | 1000 | — | 103 | — | 66.7 | — | 450 |

Table 24 shows the results of calculating the power consumption of the comparative display device 2 assumed to include the comparative light-emitting devices 2r, 2g, and 2b.

TABLE 24
Comparative display device 2

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.692 | 0.308 | 263.0 | 2630 | 71.1 | 3.70 | 25.5 | 7.25 | 185 |
| Green | 0.230 | 0.731 | 599.8 | 5998 | 218 | 2.74 | 18.9 | 6.69 | 127 |
| Blue | 0.126 | 0.101 | 137.2 | 1372 | 42.0 | 3.27 | 22.5 | 7.30 | 164 |
| Full white | 0.313 | 0.329 | 1000 | — | 103 | — | 66.9 | — | 476 |

The above tables show that the display devices 2_1, 2_2, 2_3, and 2_4 each assumed to include the light-emitting devices including the organic compound having a triazine skeleton have higher current efficiencies and lower driving voltages in white light emission than the comparative display device 2. It has also been found that the display devices 2_1, 2_2, 2_3, and 2_4 each assumed to include the light-emitting devices including the deuterated host material can be driven at low voltages. It has also been found that the power consumptions of the display devices 2 are lower than that of the comparative display device 2.

The above results show that the light-emitting devices 2 of embodiments of the present invention have favorable characteristics, and the light-emitting devices 2N_1 each have a particularly low driving voltage and a particularly high emission efficiency.

### Example 3

In this example, light-emitting devices 3R (a light-emitting device 3R_1 and a light-emitting device 3R_2) were fabricated, and their characteristics were evaluated. In addition, a comparative light-emitting device 3r was fabricated, and the characteristics thereof were evaluated.

The light-emitting device 3R_1 is a light-emitting device of one embodiment of the present invention, where the first light-emitting layer 912 and the second light-emitting layer 917 each include a phosphorescent substance as an emission center substance and include host materials at least one of which includes deuterium. Furthermore, the second electron-transport layer 918_2 includes an organic compound having a triazine skeleton.

The light-emitting device 3R_2 is a light-emitting device in which the first light-emitting layer 912 and the second light-emitting layer 917 each include a phosphorescent substance. Note that the first light-emitting layer 912 and the second light-emitting layer 917 each include host materials which are not deuterated. Furthermore, the second electron-transport layer 918_2 includes an organic compound having a triazine skeleton.

The comparative light-emitting device 3r is a light-emitting device in which the first light-emitting layer 912 and the second light-emitting layer 917 each include a phosphorescent substance and host materials neither or none of which is deuterated. Furthermore, the second electron-transport layer 918_2 does not include an organic compound having a triazine skeleton.

The light-emitting devices 3R and the comparative light-emitting device 3r were each fabricated by a continuous vacuum process. Structural formulae of the organic compounds used for the light-emitting devices 3R and the comparative light-emitting device 3r are shown below.

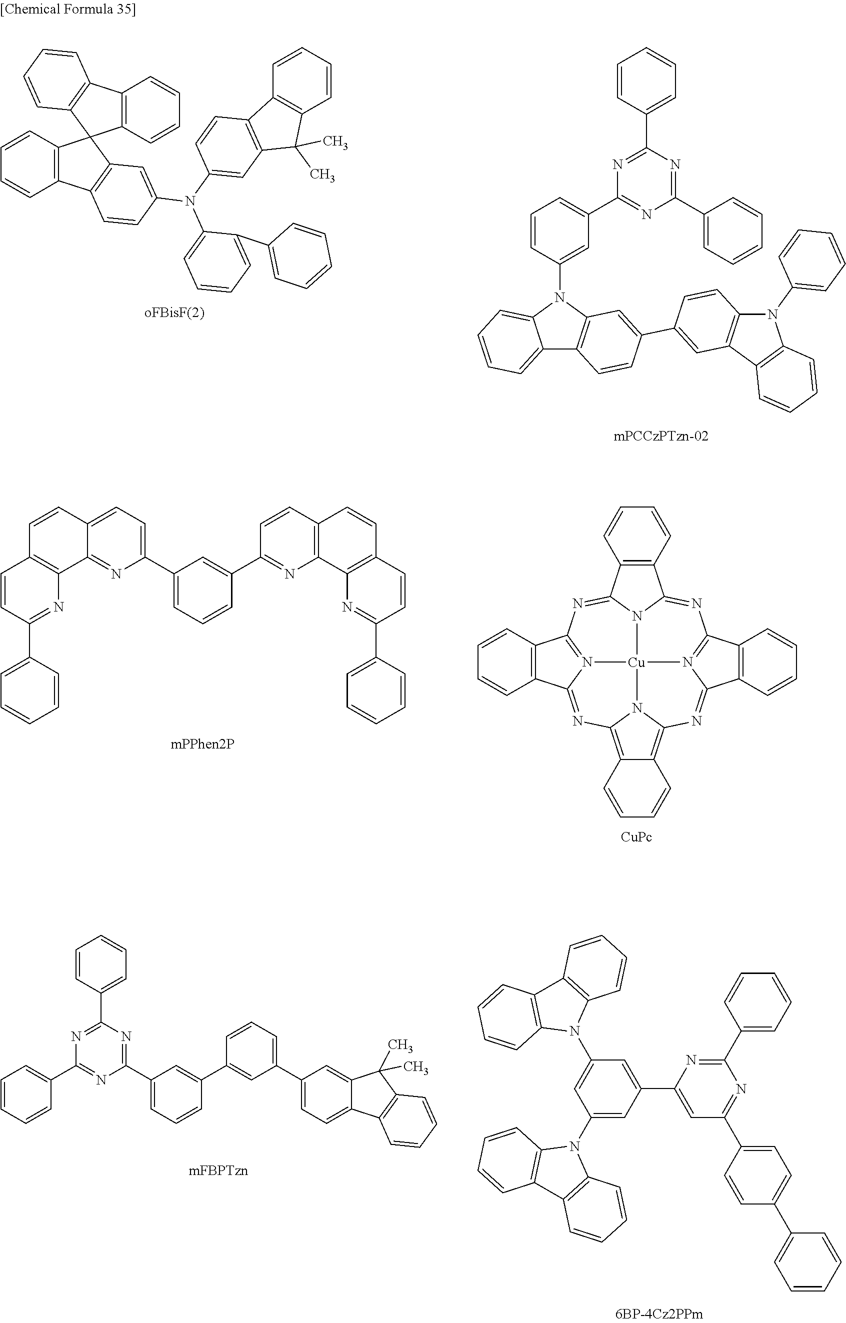

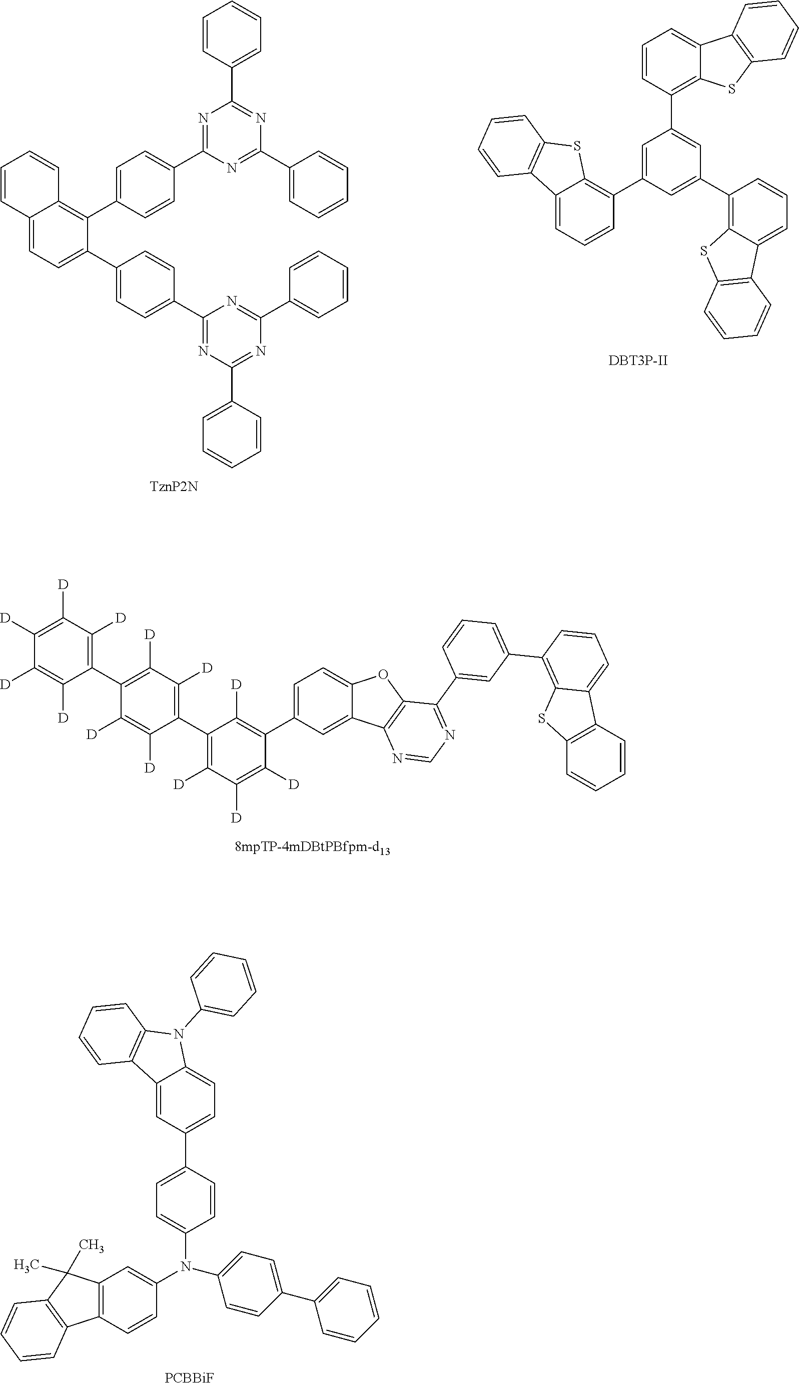

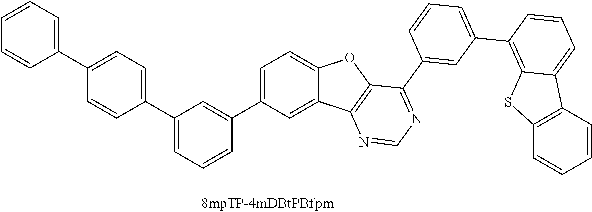 [SMILES: c1ccc(-c2ccc(-c3cccc(-c4ccc5oc6c(-c7cccc(-c8cccc9c8sc8ccccc89)c7)ncnc6c5c4)c3)cc2)cc1]

FIG. 27 illustrates the structures of the light-emitting devices 3R and the comparative light-emitting device 3r. The light-emitting devices 3R and the comparative light-emitting device 3r each have a tandem structure in which the first EL layer 903, the intermediate layer 905, the second EL layer 904, and the second electrode 902 are stacked over the first electrode 901 formed over the substrate 900 that is a glass substrate. Furthermore, the cap layer 909 is provided over the second electrode.

As illustrated in FIG. 27, the first EL layer 903 of each of the light-emitting devices 3R (the light-emitting devices 3R_1 and 3R_2) and the comparative light-emitting device 3r has a structure in which the hole-injection layer 910, the first hole-transport layer 911_1, the first light-emitting layer 912, and the first electron-transport layer 913 are stacked in this order. The second EL layer 904 thereof has a structure in which the second hole-transport layer 916_1, the second light-emitting layer 917, the second electron-transport layer 918 (the second electron-transport layers 918_1 and 918_2), and the electron-injection layer 919 are stacked in this order.

In each of the light-emitting devices 3R and the comparative light-emitting device 3r, the intermediate layer 905 includes the electron-injection buffer region 914 and the layer 915 including the electron-relay region and the charge-generation region.

### <Fabrication Method of Light-Emitting Device 3R_1>

First, as a reflective electrode, silver (Ag) was deposited over a glass substrate to a thickness of 100 nm by a sputtering method, and then, as a transparent electrode, indium tin oxide containing silicon oxide (ITSO) was deposited to a thickness of 85 nm by a sputtering method, so that the first electrode was formed. Note that the transparent electrode serves as an anode, and the transparent electrode and the reflective electrode can be collectively regarded as the first electrode. The first electrode was 2 mm×2 mm.

Next, in pretreatment for fabricating the light-emitting device over the substrate, the surface of the substrate was washed with water, and baking was performed at 200° C. for one hour. After that, the substrate was transferred into a vacuum evaporation apparatus where the pressure was reduced to approximately 1× 10-4 Pa, and was subjected to heat treatment at 170° C. for 30 minutes in a heating chamber of the vacuum evaporation apparatus, and then the substrate was cooled down for approximately 30 minutes.

Next, the substrate provided with the first electrode 901 was fixed to a holder provided in the vacuum evaporation apparatus such that the surface on which the first electrode 901 was formed faced downward. Then, the hole-injection layer 910 was formed on the first electrode 901 by co-evaporation of N-(biphenyl-2-yl)-N-(9,9-dimethylfluoren-2-yl)-9,9′-spirobi[9H-fluoren]-2-amine (abbreviation: oFBiSF (2)) and a fluorine-containing material having an electron-acceptor property with a molecular weight of 672 (OCHD-003) at a weight ratio of 1:0.03 to a thickness of 10 nm by an evaporation method using resistance heating.

Subsequently, the first hole-transport layer 911 (the first hole-transport layer 911_1) was formed over the hole-injection layer 910. By an evaporation method using resistance heating, the first hole-transport layer 911_1 was formed by evaporation of oFBiSF (2) to a thickness of 140 nm.

Next, the first light-emitting layer 912 was formed over the first hole-transport layer 911. By an evaporation method using resistance heating, the first light-emitting layer 912 was formed by co-evaporation of 8-(1,1′:4′,1″-terphenyl-3-yl-2,4,5,6,2′,3′,5′,6′,2″,3″,4″,5″,6″-d₁₃)-4-[3-(dibenzothiophen-4-yl)phenyl]-[1]benzofuro[3,2-d]pyrimidine (abbreviation: 8mpTP-4mDBtPBfpm-d₁₃), N-(biphenyl-4-yl)-N-[4-(9-phenyl-9H-carbazol-3-yl)phenyl]-9,9-dimethyl-9H-fluoren-2-amine (abbreviation: PCBBiF), and OCPG-006 as a material that emits red phosphorescent light at a weight ratio of 0.7:0.3:0.05 to a thickness of 40 nm.

Next, the first electron-transport layer 913 was formed over the first light-emitting layer 912 by evaporation of 9-[3-(4,6-diphenyl-1,3,5-triazin-2-yl)phenyl]-9′-phenyl-2,3′-bi-9H-carbazole (abbreviation: mPCCzPTzn-02) to a thickness of 10 nm.

Next, the intermediate layer 905 was provided. First, by an evaporation method using resistance heating, a layer to be the electron-injection buffer region 914 was formed over the first electron-transport layer 913 by co-evaporation of 2,2′-(1,3-phenylene)bis(9-phenyl-1,10-phenanthroline) (abbreviation: mPPhen2P) and Li₂O at a volume ratio of 1:0.02 to a thickness of 5 nm.

Then, as the electron-relay region, copper phthalocyanine (abbreviation: CuPc) was deposited to a thickness of 2 nm. Next, as the charge-generation region, oFBiSF (2) and a fluorine-containing material having an electron-acceptor property with a molecular weight of 672 (OCHD-003) were deposited by co-evaporation at a weight ratio of 1:0.15 to a thickness of 10 nm by an evaporation method using resistance heating. Thus, the layer 915 including the electron-relay region and the charge-generation region was formed.

Next, the second EL layer 904 was provided over the intermediate layer 905.

First, the second hole-transport layer 916 (the second hole-transport layer 916_1) was formed. Specifically, oFBiSF (2) was deposited to a thickness of 75 nm by an evaporation method using resistance heating.

Next, the second light-emitting layer 917 was formed over the second hole-transport layer 916 by co-evaporation of 8mpTP-4mDBtPBfpm-d₁₃, PCBBiF, and OCPG-006 at a weight ratio of 0.7:0.3:0.05 to a thickness of 40 nm by an evaporation method using resistance heating.

Next, the second electron-transport layer 918 (the second electron-transport layers 918_1 and 918_2) was formed over the second light-emitting layer 917. By an evaporation method using resistance heating, the second electron-transport layer 918_1 was formed by evaporation of 2-[3′-(9,9-dimethyl-9H-fluoren-2-yl)biphenyl-3-yl]-4,6-diphenyl-1,3,5-triazine (abbreviation: mFBPTzn) to a thickness of 10 nm, and then the second electron-transport layer 918_2 was deposited by co-evaporation of 2,2′-(1,2-naphthalenediyldi-4,1-phenylene)bis[4,6-diphenyl-1,3,5-triazine](abbreviation: TznP2N) and 8-quinolinolato-lithium (abbreviation: Liq) at a volume ratio of 1:1 to a thickness of 25 nm.

Next, the electron-injection layer 919 was formed over the second electron-transport layer 918 by evaporation of Liq to a thickness of 1 nm.

Next, the second electrode 902 was formed over the electron-injection layer 919 by co-evaporation of Ag and Mg at a volume ratio of 1:0.1 to a thickness of 15 nm. Note that the second electrode 902 is a transflective electrode having functions of transmitting light and reflecting light.

Then, as the cap layer 909, 4,4′,4″-(benzene-1,3,5-triyl)tri(dibenzothiophene) (abbreviation: DBT3P-II) was deposited to a thickness of 70 nm by evaporation, which leads to an improved light extraction efficiency.

Through the above process, the light-emitting device 3R_1 was fabricated.

### <Fabrication Method of Light-Emitting Device 3R_2>

The light-emitting device 3R_2 is different from the light-emitting device 3R_1 in the structures of the first light-emitting layer 912 and the second light-emitting layer 917. Other components were fabricated in a manner similar to that for the light-emitting device 3R_1.

Specifically, the first light-emitting layer 912 of the light-emitting device 3R_2 was formed by co-evaporation of 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), PCBBiF, and OCPG-006 at a weight ratio of 0.7:0.3:0.05 to a thickness of 40 nm by an evaporation method using resistance heating.

Like the first light-emitting layer 912, the second light-emitting layer 917 was formed over the second hole-transport layer 916 by co-evaporation of 8mpTP-4mDBtPBfpm, PCBBiF, and OCPG-006 at a weight ratio of 0.7:0.3:0.05 to a thickness of 40 nm by an evaporation method using resistance heating.

<Fabrication Method of Comparative Light-Emitting Device 3r>

The comparative light-emitting device 3r is different from the light-emitting device 3R_2 in the structure of the second electron-transport layer 918_2. Other components were fabricated in a manner similar to that for the light-emitting device 3R_2.

Specifically, the second electron-transport layer 918_2 was formed by co-evaporation of 4-[3,5-bis(9H-carbazol-9-yl)phenyl]-2-phenyl-6-(biphenyl-4-yl)pyrimidine (abbreviation: 6BP-4Cz2PPm) and Liq at a volume ratio of 1:1 to a thickness of 25 nm by an evaporation method using resistance heating.

Table 25 lists the structures of the light-emitting devices 3R and the comparative light-emitting device 3r. Note that Condition 3R in Table 25 is shown in Table 26.

TABLE 25

| | | | |
|---|---|---|---|
| Thickness | Light-emitting | Light-emitting | Comparative light- |
| [nm] | device 3R_1 | device 3R_2 | emitting device 3r |

| Cap layer | 70 | DBT3P-II | |
|---|---|---|---|
| Second electrode 902 | 15 | Ag:Mg (1:0.1) | |
| Electron-injection layer 919 | 1 | Liq | |
| Second electron-transport layer 918_2 | 25 | TznP2N:Liq | 6BP-4Cz2PPm:Liq |
| | | (1:1) | (1:1) |

| | | |
|---|---|---|
| Second electron-transport layer 918_1 | 10 | mFBPTzn |
| Second light-emitting layer 917 | 40 | Condition 3R |
| Second hole-transport layer 916_1 | 75 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Li₂O (1:0.02) |
| First electron-transport layer 913 | 10 | mPCCzPTzn-02 |
| First light-emitting layer 912 | 40 | Condition 3R |
| First hole-transport layer 911_1 | 140 | oFBiSF(2) |
| Hole-injection layer 910 | 10 | oFBiSF(2):OCHD-003 (1:0.03) |
| First electrode 902 | 85 | ITSO |
| | 100 | Ag |

TABLE 26

| | Condition 3R |
|---|---|
| Light-emitting device 3R_1 | 8mpTP-4mDBtPBfpm-d₁₃:PCBBiF:OCPG-006 |
| | (0.7:0.3:0.05) |
| Light-emitting device 3R_2 | 8mpTP-4mDBtPBfpm:PCBBiF:OCPG-006 |
| Comparative light-emitting device 3r | (0.7:0.3:0.05) |

### <Measurement Results of PL Spectra of Host Materials Used in Light-Emitting Device>

PL spectra of host materials used in the light-emitting device fabricated in this example were measured at room temperature. Specifically, a PL spectrum of a mixed film of 8mpTP-4mDBtPBfpm-d₁₃ and PCBBiF used in the light-emitting device 3R_1 was measured.

The above PL spectrum was measured using a 50-nm-thick thin film deposited over a quartz substrate. The mixed film was deposited by co-evaporation of the organic compounds at a weight ratio of 1:1. A spectrofluorometer FP-8600DS produced by JASCO Corporation was used for the measurement of the PL spectrum.

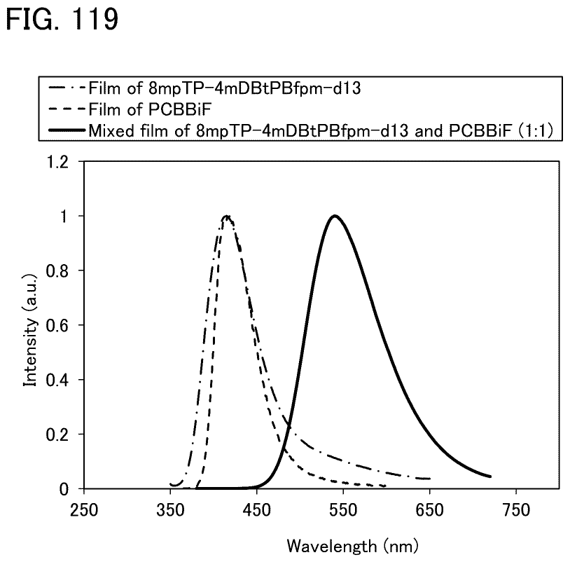

FIG. 119 shows the PL spectra of the film of 8mpTP-4mDBtPBfpm-d₁₃, the film of PCBBiF, and the mixed film of 8mpTP-4mDBtPBfpm-d₁₃ and PCBBiF; these materials were used in the light-emitting device 3R_1. Peak wavelengths of the PL spectra of the film of 8mpTP-4mDBtPBfpm-d₁₃, the film of PCBBiF, and the mixed film of 8mpTP-4mDBtPBfpm-d₁₃ and PCBBiF are 415 nm, 419 nm, and 540 nm, respectively, revealing that the peak wavelength of the PL spectrum of the mixed film of 8mpTP-4mDBtPBfpm-d₁₃ and PCBBiF is longer than that of the PL spectrum of each of the film of 8mpTP-4mDBtPBfpm-d₁₃ and the film of PCBBiF. It has also been found that the PL spectrum of the mixed film of 8mpTP-4mDBtPBfpm-d₁₃ and PCBBiF is different from the spectrum obtained by superimposing the spectra of the films of 8mpTP-4mDBtPBfpm-d₁₃ and PCBBiF, and shifted to a longer wavelength than each of the PL spectra of the films of 8mpTP-4mDBtPBfpm-d₁₃ and PCBBiF. The above indicates that the observed PL spectrum originates from an exciplex formed by 8mpTP-4mDBtPBfpm-d₁₃ and PCBBiF in the mixed film, which were excited at room temperature.

The observed PL spectrum originates also from an exciplex formed by 8mpTP-4mDBtPBfpm and PCBBiF in the mixed film, which were excited at room temperature.

An absorption spectrum and a PL spectrum of the emission center substance were measured as described in Example 1. As shown in FIG. 40, the absorption edge on the longer wavelength side of the absorption spectrum of OCPG-006 is at 622 nm. As shown in FIG. 119, the emission edge on the shorter wavelength side of the PL spectrum of the mixed film of 8mpTP-4mDBtPBfpm-d₁₃ and PCBBiF (the PL spectrum of the exciplex) is at 477 nm. These indicate that the absorption edge on the longer wavelength side of the absorption spectrum of OCPG-006 used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting device 3R_1.

The emission edge of the PL spectrum of OCPG-006 is at 589 nm. This indicates that the emission edge on the shorter wavelength side of the PL spectrum of OCPG-006 used as the emission center substance is at a longer wavelength than the emission edge on the shorter wavelength side of the PL spectrum of the exciplex formed by the hosts. This demonstrates that energy from the exciplex can be efficiently transferred to the emission center substance in the light-emitting device 3R_1.

The HOMO levels and the LUMO levels of the host materials and the light-emitting substance used in the devices were measured as described in Example 1. The HOMO level of PCBBiF as the hole-transport organic compound was −5.36 eV, and the HOMO level of 8mpTP-4mDBtPBfpm as the electron-transport organic compound was −6.2 eV. Furthermore, the HOMO level of 8mpTP-4mDBtPBfpm-d₁₃ as the electron-transport organic compound has been found to be lower than or equal to −6.0 eV because the oxidation potential was not observed in cyclic voltammetry (CV) measurement. The LUMO level of PCBBiF as the hole-transport organic compound was −2.00 eV, and the LUMO levels of 8mpTP-4mDBtPBfpm-d₁₃ and 8mpTP-4mDBtPBfpm as the electron-transport organic compounds were each −3.01 eV. Since the HOMO level of PCBBiF as the hole-transport organic compound is higher than or equal to the HOMO levels of 8mpTP-4mDBtPBfpm-d₁₃ and 8mpTP-4mDBtPBfpm as the electron-transport organic compounds and the LUMO level of PCBBiF as the hole-transport organic compound is higher than or equal to the LUMO levels of 8mpTP-4mDBtPBfpm-d₁₃ and 8mpTP-4mDBtPBfpm as the electron-transport organic compounds, the light-emitting devices 3R each include the host materials that can efficiently form an exciplex.

The HOMO level and the LUMO level of OCPG-006 were −5.26 eV and −2.69 eV, respectively. This indicates that the energy difference between the HOMO level (−5.26 eV) and the LUMO level (−2.69 eV) of OCPG-006, which corresponds to the band gap thereof, was 2.57 eV. The energy difference between the HOMO level and the LUMO level of the exciplex formed by the host materials was 2.35 eV, which corresponds to the energy difference between the HOMO level (−5.36 eV) of PCBBiF as the hole-transport organic compound and the LUMO level (−3.01 eV) of 8mpTP-4mDBtPBfpm-d₁₃ or 8mpTP-4mDBtPBfpm as the electron-transport organic compound. These indicate that the energy difference between the HOMO and LUMO levels of OCPG-006 was greater than the energy difference between the HOMO and LUMO levels of the exciplex.

The T₁ levels of the host materials of the light-emitting layer and the substances used for the first and second hole-transport layers and the first and second electron-transport layers were also calculated as described in Example 1.

According to FIG. 32B, the T₁ level of 8mpTP-4mDBtPBfpm-d₁₃ is 2.55 eV (486 nm). According to FIG. 31, the T₁ level of PCBBIF is 2.49 eV (498 nm). The difference between the T₁ level of 8mpTP-4mDBtPBfpm-d₁₃ and the T₁ level of PCBBiF is less than or equal to 0.20 eV, and the efficiency of energy transfer from the triplet excited state is improved by the influence of deuterium; thus, deterioration of the host materials can be inhibited.

Since the emission center substance used in each of the light-emitting devices 3R is a phosphorescent substance, the T₁ level of the emission center substance can be measured from a PL spectrum as described in Example 1. The T₁ level of OCPG-006 is 2.10 eV (589 nm).

The T₁ level (2.49 eV) of PCBBiF, the T₁ level (2.55 eV) of 8mpTP-4mDBtPBfpm-d₁₃, and the T₁ level (2.55 eV) of 8mpTP-4mDBtPBfpm, which are the host materials, have each been found to be higher than the T₁ level (2.10 eV) of OCPG-006 as the emission center substance. This indicates that the light-emitting devices 3R emit light efficiently.

According to FIG. 42, the T₁ level of oFBiSF (2) as the hole-transport organic compound is 2.52 eV (492 nm). The T₁ level (2.52 eV) of oFBiSF (2) used for the first hole-transport layer and the second hole-transport layer has been found to be higher than the T₁ level (2.10 eV) of OCPG-006 as the emission center substance. This indicates that the light-emitting devices 3R emit light efficiently.

According to FIG. 43, the T₁ level of mPCCzPTzn-02 as the electron-transport organic compound is 2.59 eV (478 nm). According to FIG. 44, the T₁ level of mFBPTzn as the electron-transport organic compound is 2.54 eV (488 nm). The T₁ level (2.59 eV) of mPCCzPTzn-02 used for the first electron-transport layer and the T₁ level (2.54 eV) of mFBPTzn used for the second electron-transport layer have each been found to be higher than the T₁ level (2.10 eV) of OCPG-006 as the emission center substance. This indicates that the light-emitting devices 3R emit light efficiently.

### <Measurement Results of Phosphorescence Lifetimes of Host Materials Used in Light-Emitting Devices 3R>

The phosphorescent lifetimes of 8mpTP-4mDBtPBfpm and 8mpTP-4mDBtPBfpm-d₁₃, which were the host materials used in the light-emitting devices 3R, were measured as described in Example 2. The phosphorescence lifetime of 8mpTP-4mDBtPBfpm is 2.98 seconds, and the phosphorescence lifetime of 8mpTP-4mDBtPBfpm-d₁₃ is 5.35 seconds. The phosphorescence lifetime of 8mpTP-4mDBtPBfpm-d₁₃ is 1.80 times the phosphorescence lifetime of 8mpTP-4mDBtPBfpm. This confirms that the phosphorescence lifetime is increased (extended) by deuteration. A light-emitting device including a deuterated organic compound as an energy donor has less deterioration of the organic compound than a light-emitting device including a non-deuterated organic compound as an energy donor, and thus can have high reliability.

### <Characteristics of Light-Emitting Devices>

The light-emitting devices were sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting devices were measured.

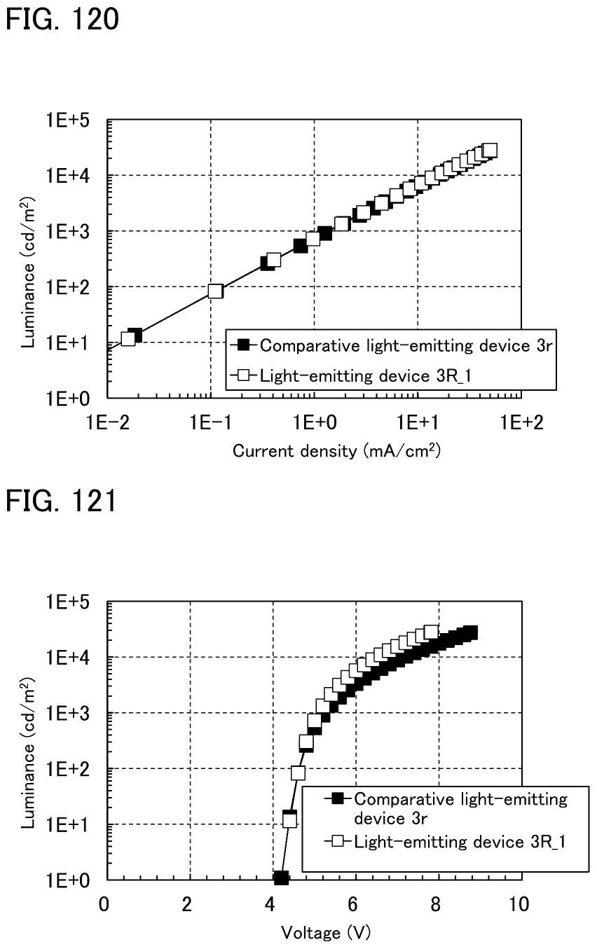

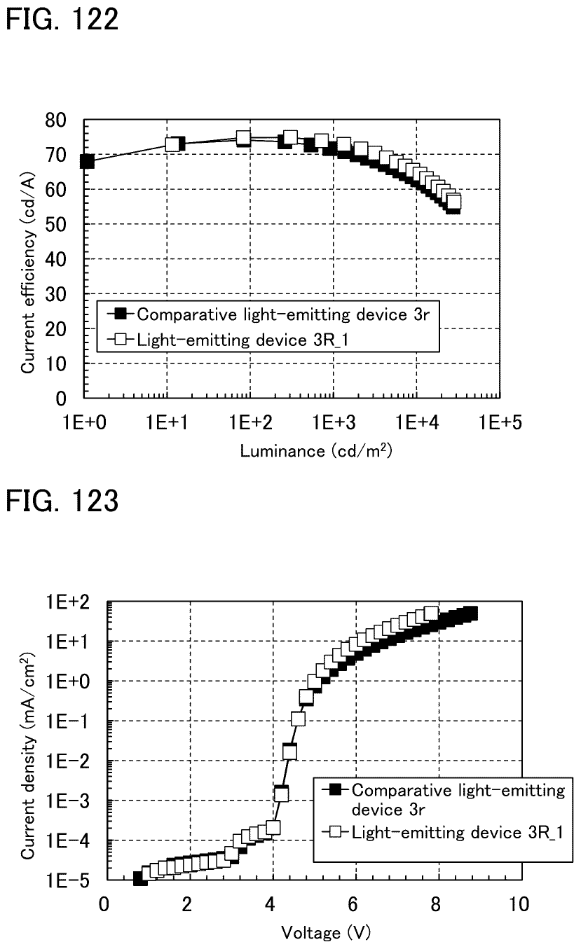

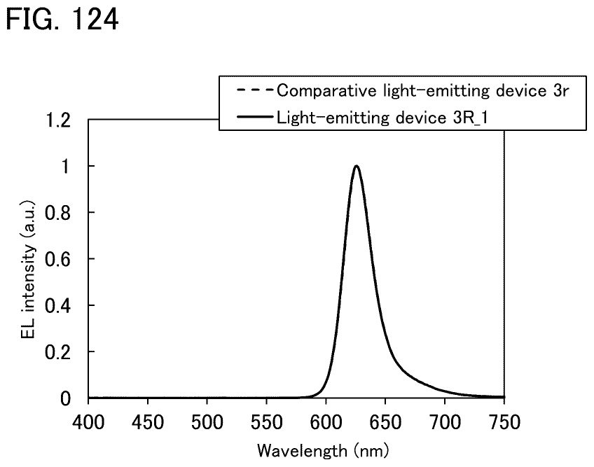

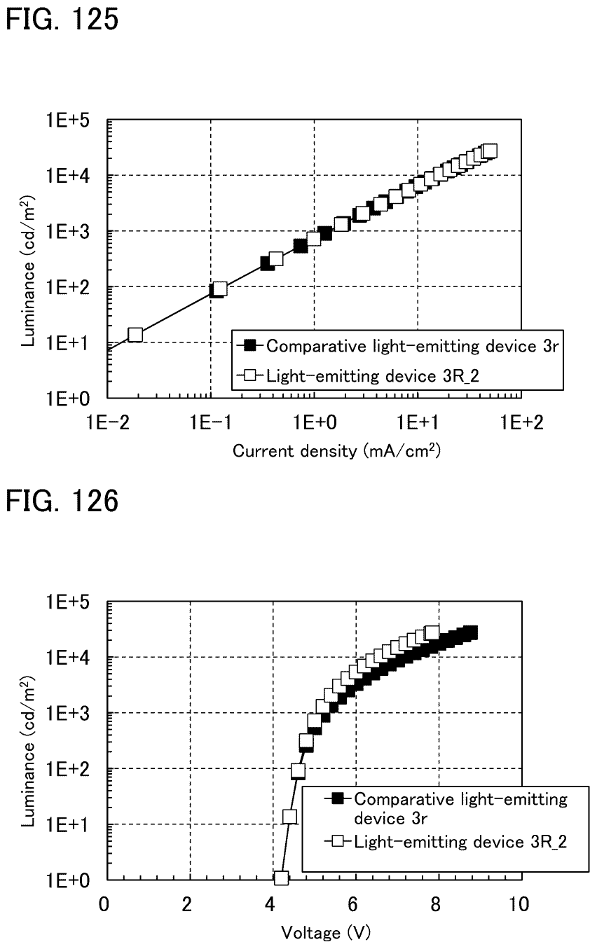

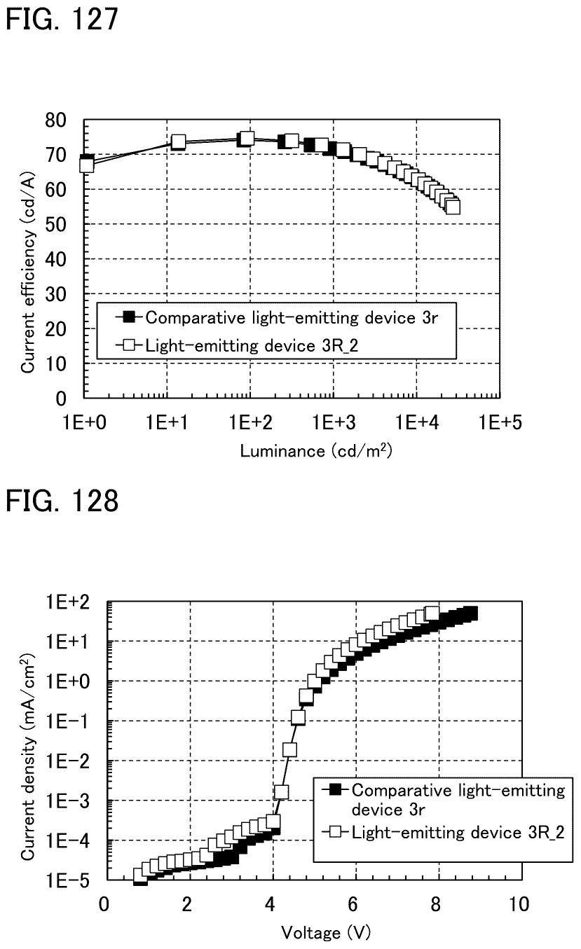

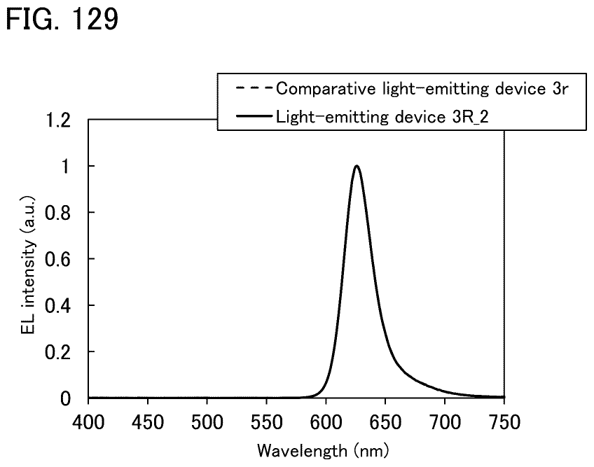

FIG. 120 shows the luminance-current density characteristics of the light-emitting device 3R_1 and the comparative light-emitting device 3r, FIG. 121 shows the luminance-voltage characteristics thereof, FIG. 122 shows the current efficiency-luminance characteristics thereof, FIG. 123 shows the current density-voltage characteristics thereof, and FIG. 124 shows the electroluminescence spectra thereof. FIG. 125 shows the luminance-current density characteristics of the light-emitting device 3R_2 and the comparative light-emitting device 3r, FIG. 126 shows the luminance-voltage characteristics thereof, FIG. 127 shows the current efficiency-luminance characteristics thereof, FIG. 128 shows the current density-voltage characteristics thereof, and FIG. 129 shows the electroluminescence spectra thereof.

Table 27 shows the main characteristics of the light-emitting devices 3R and the comparative light-emitting device 3r at a luminance of approximately 1000 cd/m². The luminance, CIE chromaticity, and electroluminescence spectra were measured at normal temperature with a spectroradiometer (SR-ULIR, produced by TOPCON TECHNOHOUSE CORPORATION).

TABLE 27

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-emitting device 3R_1 | 5.00 | 0.0389 | 0.972 | 0.693 | 0.307 | 719 | 73.9 |
| Light-emitting device 3R_2 | 5.00 | 0.0395 | 0.987 | 0.693 | 0.306 | 717 | 72.7 |
| Comparative light-emitting device 3r | 5.20 | 0.0505 | 1.26 | 0.693 | 0.306 | 904 | 71.6 |

According to FIGS. 120 to 129 and the above table, the light-emitting devices 3R and the comparative light-emitting device 3r exhibited red light emission originating from OCPG-006. It has also been found that the light-emitting devices 3R have a lower driving voltage than the comparative light-emitting device 3r. It has also been found that the light-emitting device 3R_1 has a particularly favorable current efficiency.

Thus, the light-emitting device 3R_1 has a higher electron-injection property, a higher efficiency as a light-emitting device, and a lower driving voltage than the comparative light-emitting device 3r owing to the use of the organic compound (TznP2N) having a triazine skeleton in the second electron-transport layer 918_2.

### <Panel Characteristics>

Next, display devices 3 each including one of the light-emitting devices 3R, one of the light-emitting devices 2G fabricated in Example 2, and one of the light-emitting devices 2B fabricated in Example 2 respectively in red, green, and blue subpixels (a display device 3_1 to a display device 3_4) and a comparative display device 3 including the comparative light-emitting device 3r, the comparative light-emitting device 2g fabricated in Example 2, and the comparative light-emitting device 2b fabricated in Example 2 respectively in red, green, and blue subpixels were assumed, and the power consumption of their display portions (except for the power consumption of a driving transistor, a driving circuit, and the like) was tentatively calculated. Note that each of the light-emitting devices assumed to be used in each display device is a tandem light-emitting device, and the same emission center substance is used in the plurality of light-emitting layers in each of the light-emitting devices. Thus, the use of a side-by-side patterning method was assumed for each display device.

Table 28 lists the structures of the light-emitting devices fabricated in this and previous examples.

TABLE 28

| | Red | Green | Blue |
|---|---|---|---|
| Display device 3_1 | Light-emitting device 3R_1 | Light-emitting device 2G_1 | Light-emitting device 2B_1 |
| | ▴ | ● | ● |
| Display device 3_2 | Light-emitting device 3R_1 | Light-emitting device 2G_2 | Light-emitting device 2B_2 |
| | ▴ | X | X |
| Display device 3_3 | Light-emitting device 3R_2 | Light-emitting device 2G_1 | Light-emitting device 2B_2 |
| | X | ● | X |
| Display device 3_4 | Light-emitting device 3R_2 | Light-emitting device 2G_2 | Light-emitting device 2B_1 |
| | X | X | ● |
| Comparative display device 3 | Comparative light-emitting device 3r | Comparative light-emitting device 2g | Comparative light-emitting device 2b |
| | X | X | X |

●: Both the first host material and the second host material include deuterium.
▴: Either the first host material or the second host material includes deuterium.
X: Neither the first host material nor the second host material is deuterated.

The conditions of the display devices assumed for the tentative calculation are as follows, which are similar to those in Example 1. Thus, the corresponding description in Example 1 can be referred to.

TABLE 29

| | |
|---|---|
| Panel size | 5 inches (16:9) |
| Panel area | 68.9 cm² |

| | | |
|---|---|---|
| Aperture ratio | 30% | Red 10% |
| | | Green 10% |
| | | Blue 10% |

| | |
|---|---|
| Effective luminance | 1000 cd/m² in displaying white |
| | on the entire screen |
| Circular polarizing plate | Not used |

Table 30 shows the results of calculating the power consumption of the display device 3_1 assumed to include the light-emitting devices 3R_1, 2G_1, and 2B_1.

TABLE 30
Display device 3_1

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.693 | 0.307 | 269.6 | 2696 | 70.9 | 3.8 | 26.2 | 5.51 | 145 |
| Green | 0.219 | 0.735 | 584.5 | 5845 | 198 | 3.0 | 20.4 | 6.30 | 128 |
| Blue | 0.123 | 0.107 | 145.9 | 1459 | 46.6 | 3.1 | 21.6 | 6.96 | 150 |
| Full white | 0.313 | 0.329 | 1000 | — | 101 | — | 68.1 | — | 423 |

Table 31 shows the results of calculating the power consumption of the display device 3_2 assumed to include the light-emitting devices 3R_1, 2G_2, and 2B_2.

TABLE 31
Display device 3_2

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.693 | 0.307 | 266.5 | 2665 | 70.9 | 3.8 | 25.9 | 5.51 | 143 |
| Green | 0.223 | 0.734 | 593.3 | 5933 | 211 | 2.8 | 19.4 | 6.31 | 122 |
| Blue | 0.124 | 0.103 | 140.2 | 1402 | 43.9 | 3.2 | 22.0 | 6.98 | 154 |
| Full white | 0.313 | 0.329 | 1000 | — | 102 | — | 67.3 | — | 419 |

Table 32 shows the results of calculating the power consumption of the display device 3_3 assumed to include the light-emitting devices 3R_2, 2G_1, and 2B_2.

TABLE 32
Display device 3_3

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.693 | 0.306 | 267.8 | 2678 | 69.1 | 3.9 | 26.7 | 5.53 | 148 |
| Green | 0.219 | 0.735 | 592.4 | 5924 | 198 | 3.0 | 20.6 | 6.31 | 130 |
| Blue | 0.124 | 0.103 | 139.9 | 1399 | 43.9 | 3.2 | 21.9 | 6.98 | 153 |
| Full white | 0.313 | 0.329 | 1000 | — | 99 | — | 69.3 | — | 431 |

Table 33 shows the results of calculating the power consumption of the display device 3_4 assumed to include the light-emitting devices 3R_2, 2G_2, and 2B_1.

TABLE 33
Display device 3_4

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.693 | 0.306 | 266.9 | 2669 | 69.1 | 3.9 | 26.6 | 5.53 | 147 |
| Green | 0.223 | 0.734 | 586.8 | 5868 | 211 | 2.8 | 19.2 | 6.30 | 121 |
| Blue | 0.123 | 0.107 | 146.3 | 1463 | 46.6 | 3.1 | 21.6 | 6.96 | 151 |
| Full white | 0.313 | 0.329 | 1000 | — | 102 | — | 67.4 | — | 419 |

Table 34 shows the results of calculating the power consumption of the comparative display device 3 assumed to include the comparative light-emitting devices 3r, 2g, and 2b.

TABLE 34
Comparative display device 3

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.693 | 0.306 | 260.8 | 2608 | 68.8 | 3.8 | 26.1 | 5.81 | 152 |
| Green | 0.230 | 0.731 | 602.0 | 6020 | 218 | 2.8 | 19.0 | 6.70 | 127 |
| Blue | 0.126 | 0.101 | 137.2 | 1372 | 42.0 | 3.3 | 22.5 | 7.30 | 164 |
| Full white | 0.313 | 0.329 | 1000 | — | 102 | — | 67.6 | — | 443 |

The above tables show that the display devices 3_1, 3_2, 3_3, and 3_4 each assumed to include the light-emitting devices including the organic compound having a triazine skeleton have higher current efficiencies and lower driving voltages in white light emission than the comparative display device 3. It has also been found that the display devices 3_1, 3_2, 3_3, and 3_4 each assumed to include the light-emitting devices including the deuterated host material can be driven at low voltages. It has also been found that the power consumptions of the display devices 3 are lower than that of the comparative display device 3.

The above results show that the light-emitting devices 3R of embodiments of the present invention have favorable characteristics, and the light-emitting device 3R_1 has a particularly low driving voltage and a particularly high emission efficiency.

### Example 4

In this example, light-emitting devices 4 (a light-emitting device 4B, a light-emitting device 4R, and a light-emitting device 4G) were fabricated, and the characteristics thereof were evaluated.

The light-emitting device 4B is a light-emitting device in which the first light-emitting layer 912 and the second light-emitting layer 917 each include a phosphorescent substance of one embodiment of the present invention. Furthermore, the second electron-transport layer 918_2 includes an organic compound having a triazine skeleton.

The light-emitting devices 4R and 4G are each a light-emitting device in which the second electron-transport layer 918_2 includes an organic compound having a triazine skeleton.

The light-emitting devices 4 were each fabricated by a continuous vacuum process. Structural formulae of the organic compounds used for the light-emitting devices 4 are shown below.

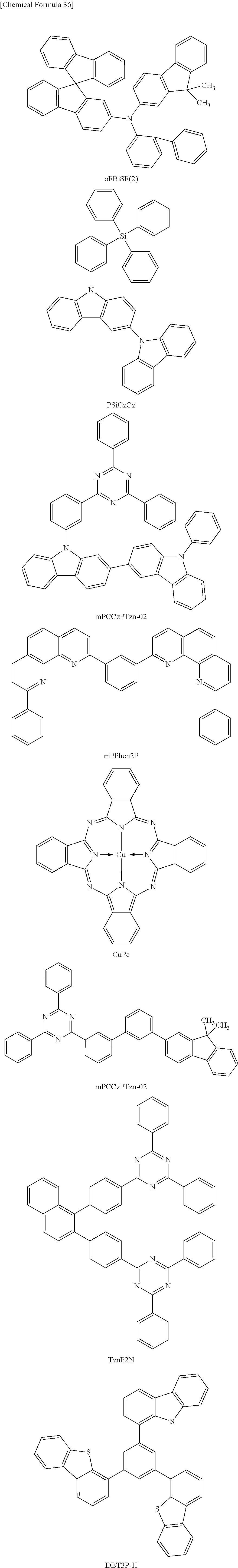

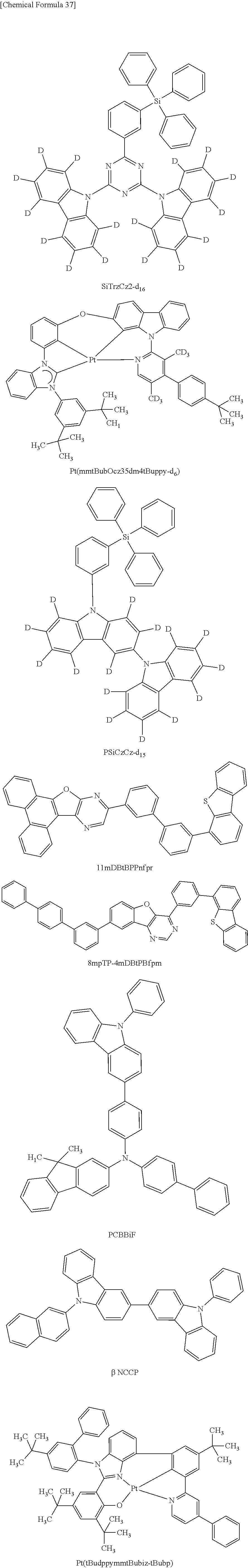

FIG. 26 illustrates the structure of the light-emitting device 4B. FIG. 27 illustrates the structures of the light-emitting devices 4R and 4G. The light-emitting devices 4 each have a tandem structure in which the first EL layer 903, the intermediate layer 905, the second EL layer 904, and the second electrode 902 are stacked over the first electrode 901 formed over the substrate 900 that is a glass substrate. Furthermore, the cap layer 909 is provided over the second electrode.

As illustrated in FIG. 26, the first EL layer 903 of the light-emitting device 4B has a structure in which the hole-injection layer 910, the first hole-transport layer 911 (the first hole-transport layer 911_1 and the first hole-transport layer 911_2), the first light-emitting layer 912, and the first electron-transport layer 913 are stacked in this order. The second EL layer 904 of the light-emitting device 4B has a structure in which the second hole-transport layer 916 (the second hole-transport layer 916_1 and the second hole-transport layer 916_2), the second light-emitting layer 917, the second electron-transport layer 918 (the second electron-transport layer 918_1 and the second electron-transport layer 918_2), and the electron-injection layer 919 are stacked in this order.

Meanwhile, as illustrated in FIG. 27, the first EL layer 903 of each of the light-emitting devices 4R and 4G has a structure in which the hole-injection layer 910, the first hole-transport layer 911_1, the first light-emitting layer 912, and the first electron-transport layer 913 are stacked in this order. The second EL layer 904 thereof has a structure in which the second hole-transport layer 916_1, the second light-emitting layer 917, the second electron-transport layer 918 (the second electron-transport layers 918_1 and 918_2), and the electron-injection layer 919 are stacked in this order.

In each of the light-emitting devices 4, the intermediate layer 905 includes the electron-injection buffer region 914 and the layer 915 including the electron-relay region and the charge-generation region.

### <Fabrication Method of Light-Emitting Device 4B>

First, as a reflective electrode, silver (Ag) was deposited over a glass substrate to a thickness of 100 nm by a sputtering method, and then, as a transparent electrode, indium tin oxide containing silicon oxide (ITSO) was deposited to a thickness of 85 nm by a sputtering method, so that the first electrode was formed. Note that the transparent electrode serves as an anode, and the transparent electrode and the reflective electrode can be collectively regarded as the first electrode. The first electrode was 2 mm×2 mm.

Next, in pretreatment for fabricating the light-emitting device over the substrate, the surface of the substrate was washed with water, and baking was performed at 200° C. for one hour.

After that, the substrate was transferred into a vacuum evaporation apparatus where the pressure was reduced to approximately 1× 10-4 Pa, and was subjected to heat treatment at 170° C. for 30 minutes in a heating chamber of the vacuum evaporation apparatus, and then the substrate was cooled down for approximately 30 minutes.

Next, the substrate provided with the first electrode 901 was fixed to a holder provided in the vacuum evaporation apparatus such that the surface on which the first electrode 901 was formed faced downward. Then, the hole-injection layer 910 was formed on the first electrode 901 by co-evaporation of N-(biphenyl-2-yl)-N-(9,9-dimethylfluoren-2-yl)-9,9′-spirobi[9H-fluoren]-2-amine (abbreviation: oFBiSF (2)) and a fluorine-containing material having an electron-acceptor property with a molecular weight of 672 (OCHD-003) at a weight ratio of 1:0.03 to a thickness of 10 nm by an evaporation method using resistance heating.

Subsequently, the first hole-transport layer 911 (the first hole-transport layers 911_1 and 911_2) was formed over the hole-injection layer 910. By an evaporation method using resistance heating, the first hole-transport layer 911_1 was formed by evaporation of oFBiSF (2) to a thickness of 50 nm, and then the first hole-transport layer 911_2 was formed over the first hole-transport layer 911_1 by evaporation of 9-[3-(triphenylsilyl)phenyl]-3,9′-bi-9H-carbazole (abbreviation: PSiCzCz) to a thickness of 5 nm.

Next, the first light-emitting layer 912 was formed over the first hole-transport layer 911. By an evaporation method using resistance heating, the first light-emitting layer 912 was formed by co-evaporation of 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d₁₆) (abbreviation: SiTrzCz2-d₁₆), 9-[3-(triphenylsilyl)phenyl]-3,9′-(bi-9H-carbazole-d₁₅) (abbreviation: PSiCzCz-d₁₅), and (2-{3-[3-(3,5-di-tert-butylphenyl)benzimidazol-1-yl-2-ylidene-κC²]phenoxy-κC²}-9-[4-tert-butylphenyl-3,5-di(methyl-3)-2-pyridinyl-κN]carbazole-2,1-diyl-κC)platinum(II) (abbreviation: Pt(mmtBubOcz35dm4tBuppy-d₆)) at a weight ratio of 0.45:0.45:0.10 to a thickness of 25 nm.

Next, the first electron-transport layer 913 was formed over the first light-emitting layer 912 by evaporation of 9-[3-(4,6-diphenyl-1,3,5-triazin-2-yl)phenyl]-9′-phenyl-2,3′-bi-9H-carbazole (abbreviation: mPCCzPTzn-02) to a thickness of 10 nm.

Next, the intermediate layer 905 was provided. First, by an evaporation method using resistance heating, a layer to be the electron-injection buffer region 914 was formed over the first electron-transport layer 913 by co-evaporation of 2,2′-(1,3-phenylene)bis(9-phenyl-1,10-phenanthroline) (abbreviation: mPPhen2P) and ytterbium (Yb) at a volume ratio of 1:0.02 to a thickness of 5 nm.

Then, as the electron-relay region, copper phthalocyanine (abbreviation: CuPc) was deposited to a thickness of 2 nm. Next, as the charge-generation region, oFBiSF (2) and a fluorine-containing material having an electron-acceptor property with a molecular weight of 672 (OCHD-003) were deposited by co-evaporation at a weight ratio of 1:0.15 to a thickness of 10 nm by an evaporation method using resistance heating. Thus, the layer 915 including the electron-relay region and the charge-generation region was formed.

Next, the second EL layer 904 was provided over the intermediate layer 905.

First, the second hole-transport layer 916 (the second hole-transport layers 916_1 and 916_2) was formed. After the second hole-transport layer 916_1 was formed by evaporation of OFBiSF (2) to a thickness of 45 nm, the second hole-transport layer 916_2 was formed over the second hole-transport layer 916_1 by evaporation of PSiCzCz to a thickness of 5 nm.

Next, the second light-emitting layer 917 was formed over the second hole-transport layer 916 by co-evaporation of SiTrzCz2-d₁₆, PSiCzCz-dis, and Pt(mmtBubOcz35dm4tBuppy-d₆) at a weight ratio of 0.45:0.45:0.10 to a thickness of 25 nm by an evaporation method using resistance heating.

Next, the second electron-transport layer 918 (the second electron-transport layers 918_1 and 918_2) was formed over the second light-emitting layer 917. By an evaporation method using resistance heating, the second electron-transport layer 918_1 was formed by evaporation of 2-[3′-(9,9-dimethyl-9H-fluoren-2-yl)biphenyl-3-yl]-4,6-diphenyl-1,3,5-triazine (abbreviation: mFBPTzn) to a thickness of 10 nm, and then the second electron-transport layer 918_2 was formed by co-evaporation of 2,2′-(1,2-naphthalenediyldi-4,1-phenylene)bis[4,6-diphenyl-1,3,5-triazine](abbreviation: TznP2N) and 8-quinolinolato-lithium (abbreviation: Liq) at a volume ratio of 1:1 to a thickness of 25 nm.

Next, the electron-injection layer 919 was formed over the second electron-transport layer 918 by co-evaporation of lithium fluoride (LiF) and ytterbium (Yb) at a volume ratio of 2:1 to a thickness of 1.5 nm.

Next, the second electrode 902 was formed over the electron-injection layer 919 by co-evaporation of Ag and Mg at a volume ratio of 1:0.1 to a thickness of 15 nm. Note that the second electrode 902 is a transflective electrode having functions of transmitting light and reflecting light.

Then, as the cap layer 909, 4,4′,4″-(benzene-1,3,5-triyl)tri(dibenzothiophene) (abbreviation: DBT3P-II) was deposited to a thickness of 70 nm by evaporation, which leads to an improved light extraction efficiency.

Through the above process, the light-emitting device 4B was fabricated. Table 35 lists the structure of the light-emitting device 4B.

TABLE 35

| | Thickness | |
|---|---|---|
| | [nm] | Light-emitting device 4B |
| Cap layer | 70 | DBT3P-II |
| Second electrode 902 | 15 | Ag:Mg (1:0.1) |
| Electron-injection layer 919 | 1.5 | LiF:Yb (2:1) |
| Second electron-transport layer 918_2 | 25 | TznP2N:Liq (1:1) |
| Second electron-transport layer 918_1 | 10 | mFBPTzn |
| Second light-emitting layer 917 | 25 | SiTrzCz2-d₁₆:PSiCzCz-d₁₅:Pt(mmtBubOcz35dm4tBuppy-d₆) |
| | | (0.45:0.45:0.10) |
| Second hole-transport layer 916_2 | 5 | PSiCzCz |
| Second hole-transport layer 916_1 | 45 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Yb (1:0.02) |
| First electron-transport layer 913 | 10 | mPCCzPTzn-02 |
| First light-emitting layer 912 | 25 | SiTrzCz2-d₁₆:PSiCzCz-d₁₅:Pt(mmtBubOcz35dm4tBuppy-d₆) |
| | | (0.45:0.45:0.10) |
| First hole-transport layer 911_2 | 5 | PSiCzCz |
| First hole-transport layer 911_1 | 50 | oFBiSF(2) |
| Hole-injection layer 910 | 10 | oFBiSF(2):OCHD-003 (1:0.03) |
| First electrode 901 | 85 | ITSO |
| | 100 | Ag |

### <Fabrication Method of Light-Emitting Device 4R>

The light-emitting device 4R is different from the light-emitting device 4B in the structures and thicknesses of the first and second light-emitting layers 912 and 917 and the first and second hole-transport layers 911 and 916. Other components were fabricated in a manner similar to that for the light-emitting device 4B.

Specifically, each of the first and second light-emitting layers 912 and 917 in the light-emitting device 4R was formed by co-evaporation of 11-[3′-(dibenzothiophen-4-yl)biphenyl-3-yl]phenanthro[9′,10′:4,5]furo[2,3-b]pyrazine (abbreviation: 11mDBtBPPnfpr), N-(biphenyl-4-yl)-N-[4-(9-phenyl-9H-carbazol-3-yl)phenyl]-9,9-dimethyl-9H-fluoren-2-amine (abbreviation: PCBBiF), and OCPG-006 as a material that emits red phosphorescent light at a weight ratio of 0.7:0.3:0.05 to a thickness of 40 nm.

In the light-emitting device 4R, the first and second hole-transport layers 911_2 and 916_2 of the light-emitting device 4B were not provided. Stated differently, the first hole-transport layer 911 (the first hole-transport layer 911_1) was formed by evaporation of oFBiSF (2) to a thickness of 160 nm by an evaporation method using resistance heating. In addition, the second hole-transport layer 916 (the second hole-transport layer 916_1) was formed by evaporation of oFBiSF (2) to a thickness of 75 nm by an evaporation method using resistance heating.

Table 36 lists the structure of the light-emitting device 4R.

TABLE 36

| | Thickness | |
|---|---|---|
| | [nm] | Light-emitting device 4R |
| Cap layer | 70 | DBT3P-II |
| Second electrode 902 | 15 | Ag:Mg (1:0.1) |
| Electron-injection layer 919 | 1.5 | LiF:Yb (2:1) |
| Second electron-transport layer 918_2 | 25 | TznP2N:Liq (1:1) |
| Second electron-transport layer 918_1 | 10 | mFBPTzn |
| Second light-emitting layer 917 | 40 | 11mDBtBPPnfpr:PCBBiF:OCPG-006 |
| | | (0.7:0.3:0.05) |
| Second hole-transport layer 916_1 | 75 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Yb (1:0.02) |
| First electron-transport layer 913 | 10 | mPCCzPTzn-02 |
| First light-emitting layer 912 | 40 | 11mDBtBPPnfpr:PCBBiF:OCPG-006 |
| | | (0.7:0.3:0.05) |
| First hole-transport layer 911_1 | 160 | oFBiSF(2) |
| Hole-injection layer 910 | 10 | oFBiSF(2):OCHD-003 (1:0.03) |
| First electrode 902 | 85 | ITSO |
| | 100 | Ag |

### <Fabrication Method of Light-Emitting Device 4G>

The light-emitting device 4G is different from the light-emitting device 4R in the thicknesses of the first and second hole-transport layers 911 and 916 and the structures of the first and second light-emitting layers 912 and 917. Other components were fabricated in a manner similar to that for the light-emitting device 4R.

Specifically, the first light-emitting layer 912 and the second light-emitting layer 917 in the light-emitting device 4G were each formed by co-evaporation of 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), 9-(2-naphthyl)-9′-phenyl-3,3′-bi-9H-carbazole (abbreviation: βNCCP), and (2-{1-(5-tert-butylbiphenyl-2-yl)-4-[3-tert-butyl-5-(4-phenyl-2-pyridinyl-κN)phenyl-κC⁶]-2-benzimidazolyl-κN3}-4,6-di-tert-butylphenolato-κO)platinum(II) (abbreviation: Pt(tBudppymmtBubiz-tBubp)) at a weight ratio of 0.5:0.5:0.1 to a thickness of 40 nm by an evaporation method using resistance heating.

In the light-emitting device 4G, the thickness of the first hole-transport layer 911 was set to 90 nm, and the thickness of the second hole-transport layer 916 was set to 65 nm. Table 37 lists the structure of the light-emitting device 4G.

TABLE 37

| | Thickness | |
|---|---|---|
| | [nm] | Light-emitting device 4G |
| Cap layer | 70 | DBT3P-II |
| Second electrode 902 | 15 | Ag:Mg (1:0.1) |
| Electron-injection layer 919 | 1.5 | LiF:Yb (2:1) |
| Second electron-transport layer 918_2 | 25 | TznP2N:Liq (1:1) |
| Second electron-transport layer 918_1 | 10 | mFBPTzn |
| Second light-emitting layer 917 | 40 | 8mpTP-4mDBtPBfpm:βNCCP:Pt(tBudppymmtBubiz- |
| | | tBubp) |
| Second hole-transport layer 916_1 | 65 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Yb (1:0.02) |
| First electron-transport layer 913 | 10 | mPCCzPTzn-02 |
| First light-emitting layer 912 | 40 | 8mpTP-4mDBtPBfpm:βNCCP:Pt(tBudppymmtBubiz- |
| | | tBubp) |
| First hole-transport layer 911_1 | 90 | oFBiSF(2) |
| Hole-injection layer 910 | 10 | oFBiSF(2):OCHD-003 (1:0.03) |
| First electrode 902 | 85 | ITSO |
| | 100 | Ag |

### <Measurement Results of PL Spectra of Host Materials Used in Devices>

Here, Examples 1 and 2 can be referred to for the PL spectra (at room temperature) of the host materials used in the devices, the HOMO levels and the LUMO levels of the host materials and the light-emitting substances used in the devices, and the T₁ levels of the host materials in the light-emitting layers and the substances in the first hole-transport layer, the second hole-transport layer, the first electron-transport layer, and the second electron-transport layer.

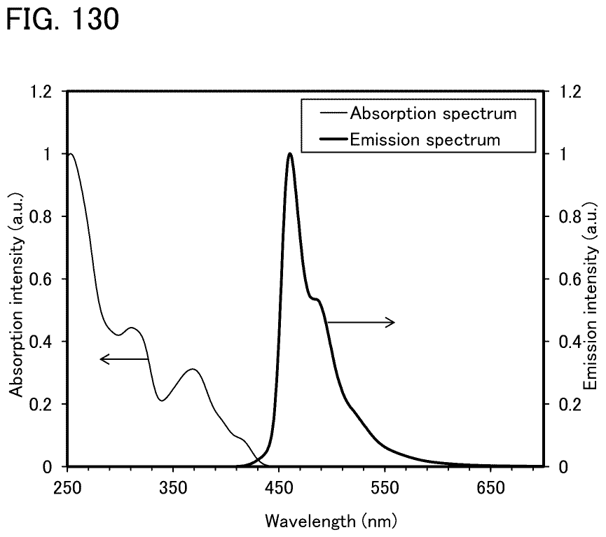

As shown in FIG. 130, the absorption edge on the longer wavelength side of the absorption spectrum of Pt(mmtBubOcz35dm4tBuppy-d₆) is at 461 nm. As shown in FIG. 35, the emission edge on the shorter wavelength side of the PL spectrum of the mixed film of PSiCzCz-dis and SiTrzCz2-d₁₆ (the PL spectrum of the exciplex) is at 408 nm. These indicate that the absorption edge on the longer wavelength side of the absorption spectrum of Pt(mmtBubOcz35dm4tBuppy-d₆) used as the emission center substance is at a longer wavelength than the emission edge on the shorter wavelength side of the PL spectrum of the exciplex formed by the hosts. This demonstrates that energy from the exciplex can be efficiently transferred to the emission center substance.

The emission edge of the PL spectrum of Pt(mmtBubOcz35dm4tBuppy-d₆) is at 445 nm. This indicates that the emission edge on the shorter wavelength side of the PL spectrum of Pt(mmtBubOcz35dm4tBuppy-d₆) used as the emission center substance is at a longer wavelength than the emission edge on the shorter wavelength side of the PL spectrum of the exciplex formed by the hosts. This demonstrates that energy from the exciplex can be efficiently transferred to the emission center substance.

The HOMO level and the LUMO level of Pt(mmtBubOcz35dm4tBuppy-d₆) were −5.4 eV and −2.45 eV, respectively. This indicates that the energy difference between the HOMO level (−5.4 eV) and the LUMO level (−2.45 eV) of Pt(mmtBubOcz35dm4tBuppy-d₆), which corresponds to the band gap thereof, was 2.95 eV. The energy difference between the HOMO level and the LUMO level of the exciplex formed by the host materials was 2.72 eV, which corresponds to the energy difference between the HOMO level (−5.7 eV) of PSiCzCz-dis as the hole-transport organic compound and the LUMO level (−2.98 eV) of SiTrzCz2-d₁₆ as the electron-transport organic compound. This indicates that the energy difference between the HOMO and LUMO levels of Pt(mmtBubOcz35dm4tBuppy-d₆) was greater than the energy difference between the HOMO and LUMO levels of the exciplex.

The T₁ level of Pt(mmtBubOcz35dm4tBuppy-d₆) calculated from the emission edge on the shorter wavelength side of the PL spectrum is 2.79 eV (445 nm).

The T₁ level (2.97 eV) of PSiCzCz-dis and the T₁ level (2.93 eV) of SiTrzCz2-d₁₆, which are the host materials, have each been found to be higher than the T₁ level (2.79 eV) of Pt(mmtBubOcz35dm4tBuppy-d₆) as the emission center substance. This indicates that the light-emitting device 4B emits light efficiently.

Furthermore, the T₁ level (2.97 eV) of PSiCzCz used for the first hole-transport layer and the second hole-transport layer has been found to be higher than the T₁ level (2.79 eV) of Pt(mmtBubOcz35dm4tBuppy-d₆) as the emission center substance. This indicates that the light-emitting device 4B emits light efficiently.

The T₁ level (2.59 eV) of mPCCzPTzn-02 used for the first electron-transport layer and the T₁ level (2.54 eV) of mFBPTzn used for the second electron-transport layer have each been found to be lower than the T₁ level (2.79 eV) of Pt(mmtBubOcz35dm4tBuppy-d₆) as the emission center substance. This indicates that the light-emitting device 4B has high stability.

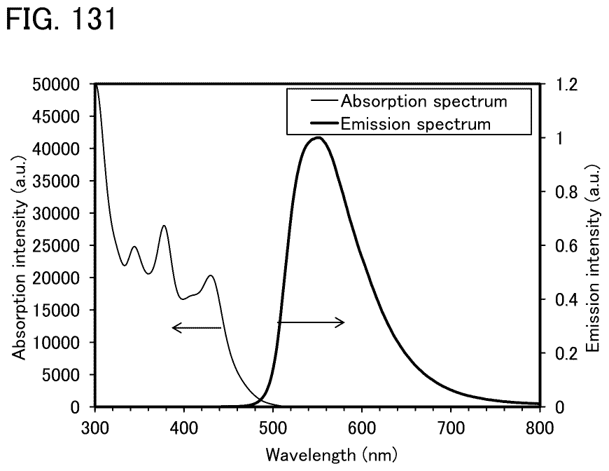

As shown in FIG. 131, the absorption edge on the longer wavelength side of the absorption spectrum of Pt(tBudppymmtBubiz-tBubp) is at 512 nm. As shown in FIG. 38, the emission edge on the shorter wavelength side of the PL spectrum of the mixed film of βNCCP and 8mpTP-4mDBtPBfpm (the PL spectrum of the exciplex) is at 442 nm. These indicate that the absorption edge on the longer wavelength side of the absorption spectrum of Pt(tBudppymmtBubiz-tBubp) used as the emission center substance is at a longer wavelength than the emission edge on the shorter wavelength side of the PL spectrum of the exciplex formed by the hosts. This demonstrates that energy from the exciplex can be efficiently transferred to the emission center substance.

The emission edge of the PL spectrum of Pt(tBudppymmtBubiz-tBubp) is at 498 nm. This indicates that the emission edge on the shorter wavelength side of the PL spectrum of Pt(tBudppymmtBubiz-tBubp) used as the emission center substance is at a longer wavelength than the emission edge on the shorter wavelength side of the PL spectrum of the exciplex formed by the hosts. This demonstrates that energy from the exciplex can be efficiently transferred to the emission center substance.

The HOMO level and the LUMO level of Pt(tBudppymmtBubiz-tBubp) were −5.4 eV and −2.78 eV, respectively. This indicates that the energy difference between the HOMO level (−5.4 eV) and the LUMO level (−2.78 eV) of Pt(tBudppymmtBubiz-tBubp), which corresponds to the band gap thereof, was 2.62 eV. The energy difference between the HOMO level and the LUMO level of the exciplex formed by the host materials was 2.61 eV, which corresponds to the energy difference between the HOMO level (−5.62 eV) of βNCCP as the hole-transport organic compound and the LUMO level (−3.01 eV) of 8mpTP-4mDBtPBfpm as the electron-transport organic compound. This indicates that the energy difference between the HOMO and LUMO levels of Pt(tBudppymmtBubiz-tBubp) was greater than the energy difference between the HOMO and LUMO levels of the exciplex.

The T₁ level of Pt(tBudppymmtBubiz-tBubp) calculated from the emission edge on the shorter wavelength side of the PL spectrum was 2.49 eV (498 nm).

The T₁ level (2.55 eV) of βNCCP and the T₁ level (2.55 eV) of 8mpTP-4mDBtPBfpm, which are the host materials, have each been found to be higher than the T₁ level (2.49 eV) of Pt(tBudppymmtBubiz-tBubp) as the emission center substance. This indicates that the light-emitting device 4G emits light efficiently.

Furthermore, the T₁ level (2.52 eV) of oFBiSF (2) used for the first hole-transport layer and the second hole-transport layer has been found to be higher than the T₁ level (2.49 eV) of Pt(tBudppymmtBubiz-tBubp) as the emission center substance. This indicates that the light-emitting device 4G emits light efficiently.

The T₁ level (2.59 eV) of mPCCzPTzn-02 used for the first electron-transport layer and the T₁ level (2.54 eV) of mFBPTzn used for the second electron-transport layer have been found to be higher than the T₁ level (2.49 eV) of Pt(tBudppymmtBubiz-tBubp) as the emission center substance. This indicates that the light-emitting device 4G emits light efficiently.

### <Device Characteristics>

The light-emitting devices 4 were sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting devices 4 were measured.

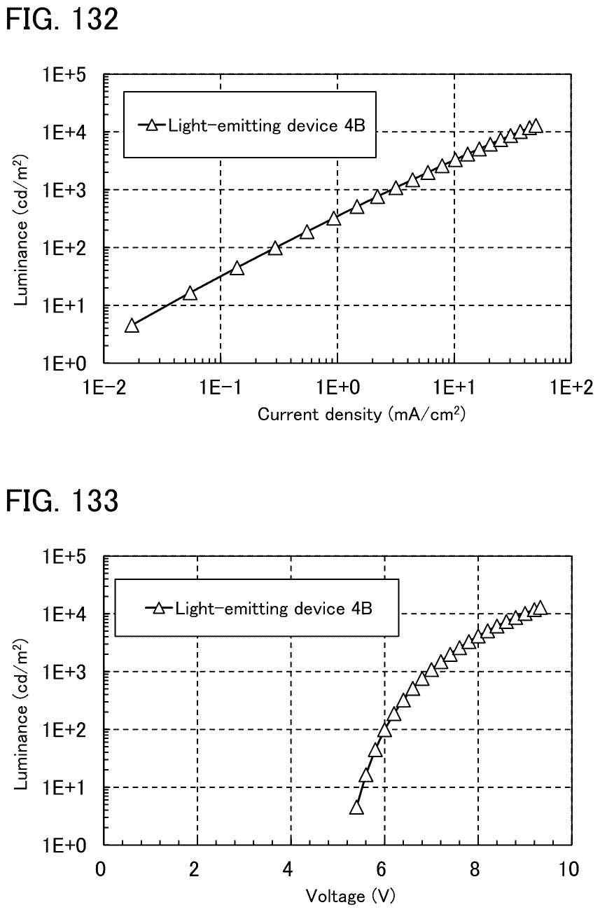

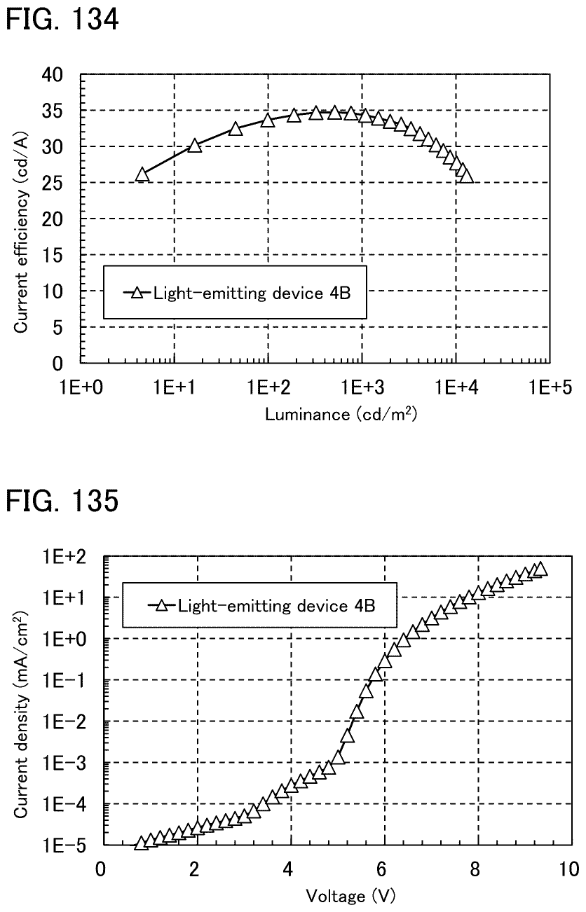

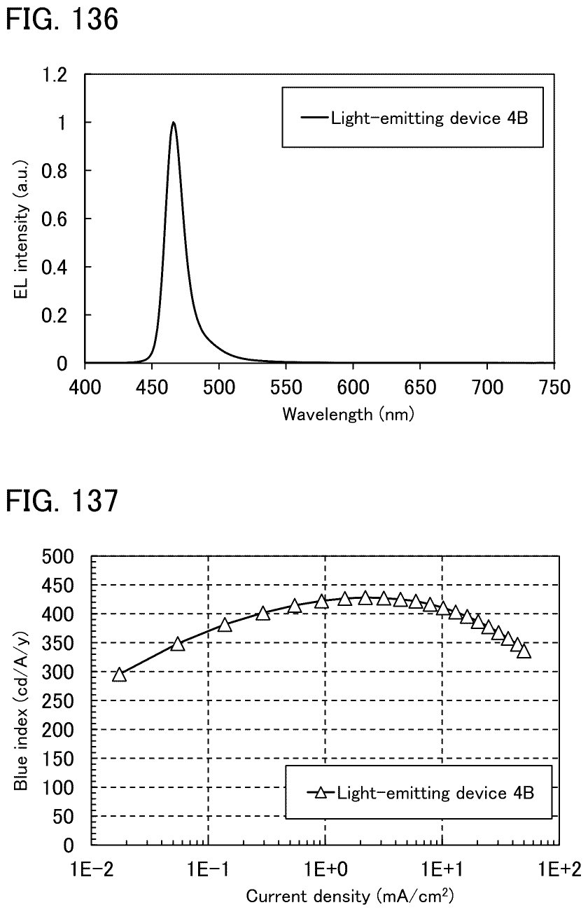

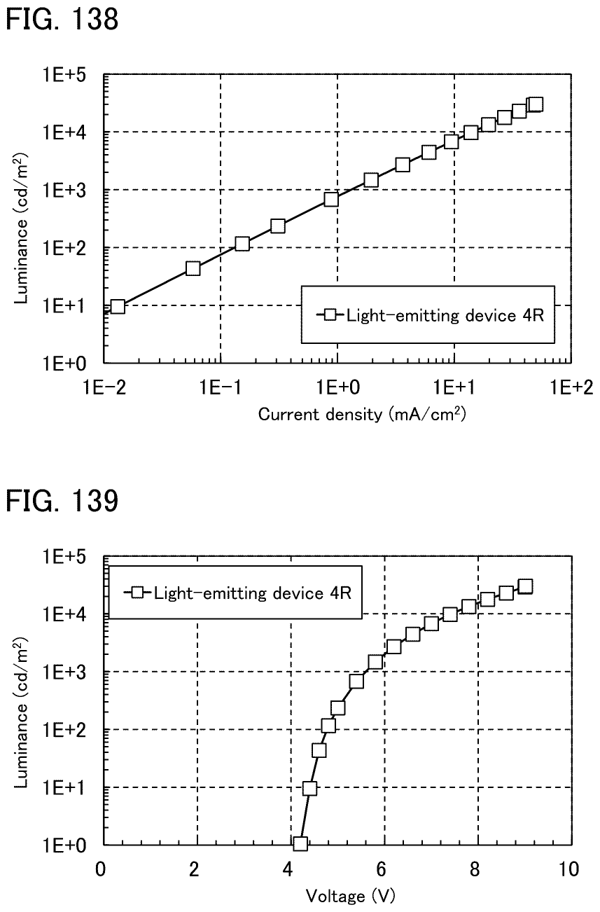

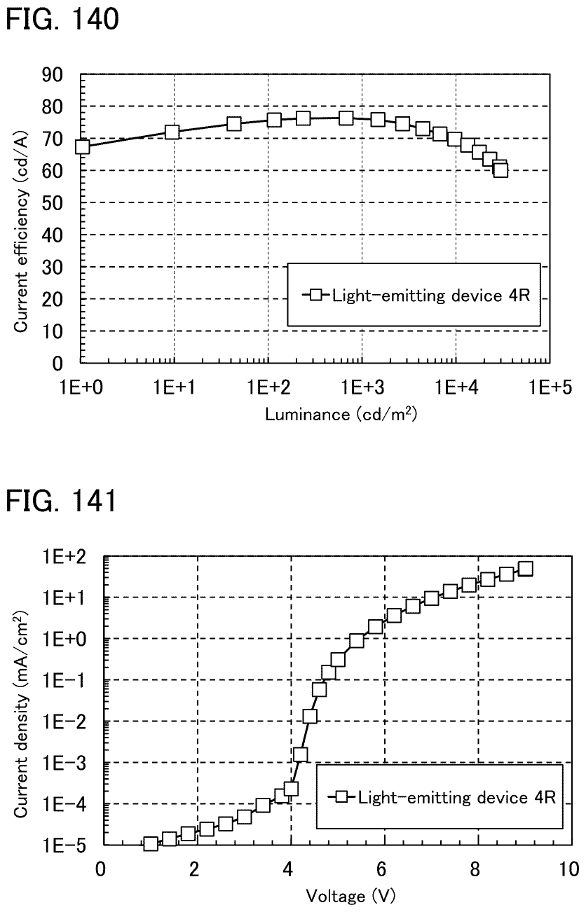

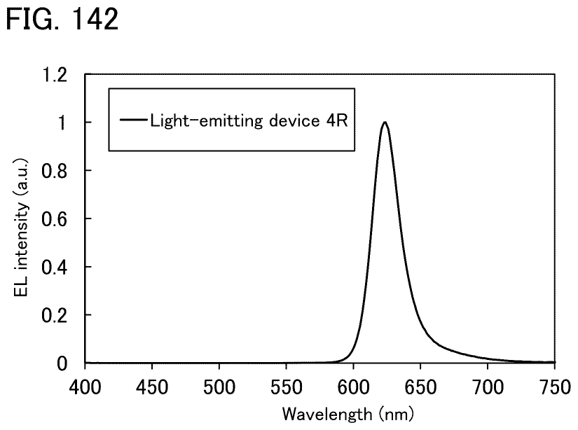

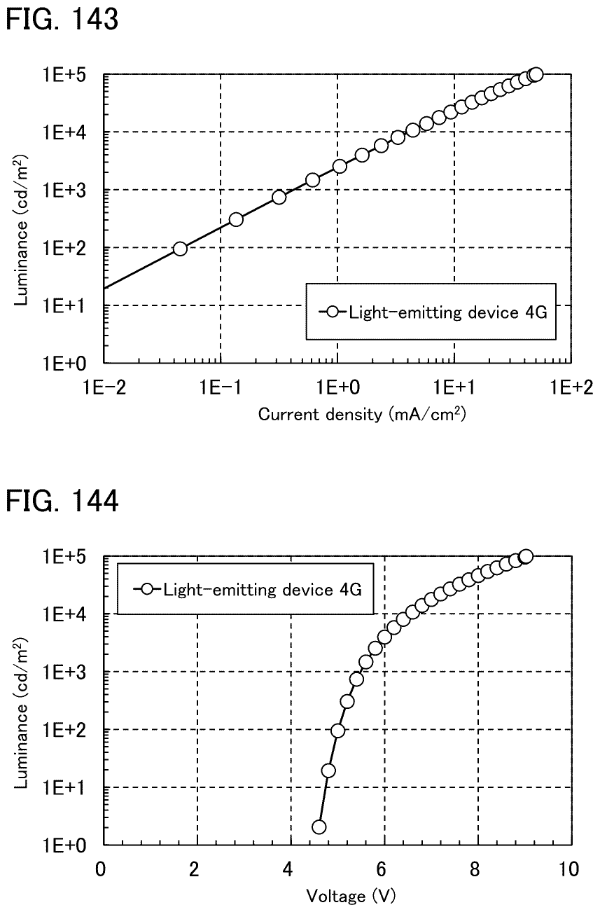

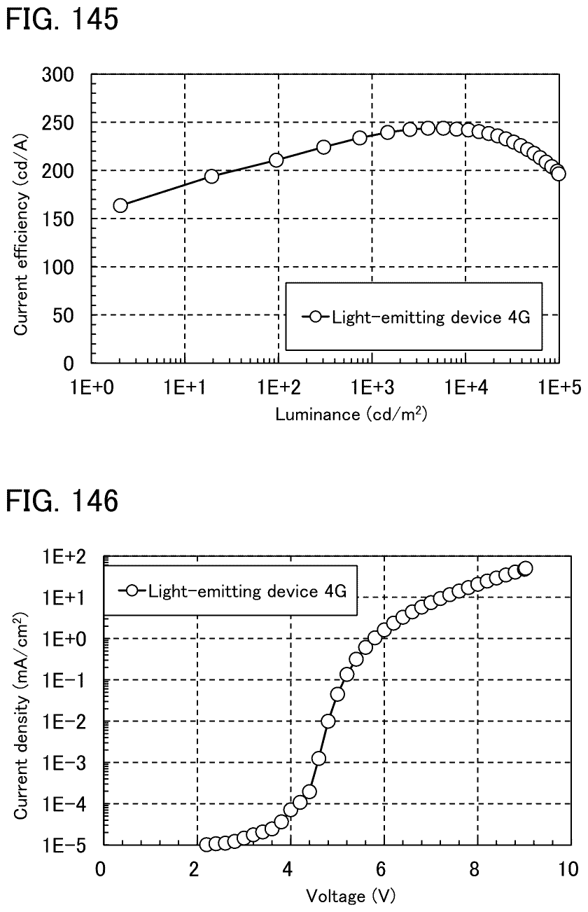

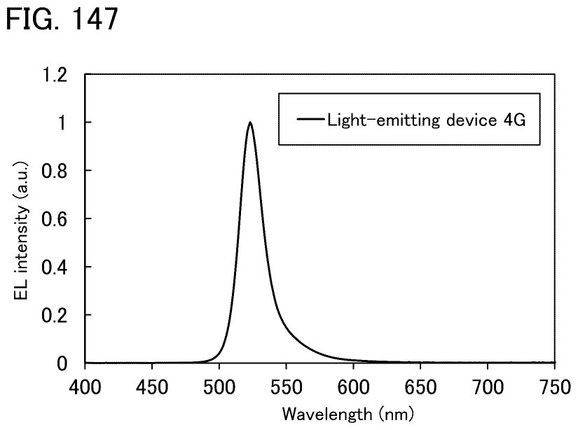

FIG. 132 shows the luminance-current density characteristics of the light-emitting device 4B, FIG. 133 shows the luminance-voltage characteristics thereof, FIG. 134 shows the current efficiency-luminance characteristics thereof, FIG. 135 shows the current density-voltage characteristics thereof, FIG. 136 shows the electroluminescence spectrum thereof, and FIG. 137 shows the blue index-current density characteristics thereof. FIG. 138 shows the luminance-current density characteristics of the light-emitting device 4R, FIG. 139 shows the luminance-voltage characteristics thereof, FIG. 140 shows the current efficiency-luminance characteristics thereof, FIG. 141 shows the current density-voltage characteristics thereof, and FIG. 142 shows the electroluminescence spectrum thereof. FIG. 143 shows the luminance-current density characteristics of the light-emitting device 4G, FIG. 144 shows the luminance-voltage characteristics thereof, FIG. 145 shows the current efficiency-luminance characteristics thereof, FIG. 146 shows the current density-voltage characteristics thereof, and FIG. 147 shows the electroluminescence spectrum thereof.

Table 38 shows the main characteristics of the light-emitting devices 4 at a luminance of approximately 1000 cd/m². The luminance, CIE chromaticity, and electroluminescence spectra were measured at normal temperature with a spectroradiometer (SR-ULIR, produced by TOPCON TECHNOHOUSE CORPORATION).

TABLE 38

| | | | Current | | | | Current | |
|---|---|---|---|---|---|---|---|---|
| | Voltage | Current | density | Chromaticity | Chromaticity | Luminance | efficiency | BI value |
| | (V) | (mA) | (mA/cm²) | x | y | (cd/m²) | (cd/A) | (cd/A/y) |
| Light-emitting device 4B | 7.00 | 0.127 | 3.16 | 0.130 | 0.0803 | 1085 | 34.3 | 427 |
| Light-emitting device 4R | 5.40 | 0.0354 | 0.886 | 0.691 | 0.309 | 676 | 76.3 | — |
| Light-emitting device 4G | 5.40 | 0.0126 | 0.316 | 0.183 | 0.754 | 739 | 234 | — |

According to FIGS. 132 to 137 and the above table, the light-emitting device 4B emitted phosphorescent light originating from Pt(mmtBubOcz35dm4ppy-d₆). It has also been found that the light-emitting device 4B has favorable emission characteristics and is highly efficient as a blue-light-emitting device.

According to FIGS. 138 to 142 and the above table, the light-emitting device 4R exhibited red light emission originating from OCPG-006. It has also been found that the light-emitting device 4R has favorable emission characteristics.

According to FIGS. 143 to 147 and the above table, the light-emitting device 4G exhibited green light emission originating from Pt(tBudppymmtBubiz-tBubp). It has also been found that the light-emitting device 4G has favorable emission characteristics.

### <Panel Characteristics>

Next, a light-emitting apparatus 4 including the light-emitting device 4B, the light-emitting device 4R, and the light-emitting device 4G respectively in blue, red, and green subpixels was assumed, and the power consumption of its display portion (except for the power consumption of a driving transistor, a driving circuit, and the like) was tentatively calculated. Note that each of the light-emitting devices assumed to be used in the light-emitting apparatus 4 is a tandem light-emitting device, and the same emission center substance is used in the plurality of light-emitting layers in each of the light-emitting devices. Thus, a side-by-side patterning method was employed for the light-emitting apparatus 4.

Since the conditions of the light-emitting apparatus 4 assumed for the tentative calculation are the same as those of the display device 1 described in Example 1, Example 1 can be referred to for the conditions. Table 39 shows the results of calculating the power consumption of the light-emitting apparatus 4 assumed to include the light-emitting devices 4R, 4G, and 4B.

TABLE 39
Light-emitting apparatus 4

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.691 | 0.309 | 283.0 | 2830 | 74.4 | 3.80 | 26.2 | 6.23 | 163 |
| Green | 0.183 | 0.754 | 611.7 | 6117 | 244 | 2.51 | 17.3 | 6.23 | 108 |
| Blue | 0.130 | 0.080 | 105.3 | 1053 | 34.3 | 3.07 | 21.1 | 6.98 | 148 |
| Full white | 0.313 | 0.329 | 1000 | — | 107 | — | 64.7 | — | 419 |

The above table shows that the light-emitting apparatus 4 assumed to include the light-emitting devices 4 has high current efficiency and low driving voltage in white light emission.

The above results show that the light-emitting devices 4 of embodiments of the present invention have favorable characteristics, and the light-emitting device 4B has a particularly low driving voltage and a particularly high emission efficiency.

### Example 5

In this example, light-emitting devices 5 (a light-emitting device 5B, a light-emitting device 5R, and a light-emitting device 5G) were fabricated, and the characteristics thereof were evaluated.

The light-emitting device 5B is a light-emitting device in which the first light-emitting layer 912 and the second light-emitting layer 917 each include a phosphorescent substance of one embodiment of the present invention. Furthermore, the second electron-transport layer 918_2 includes an organic compound having a triazine skeleton.

The light-emitting devices 5R and 5G are each a light-emitting device in which the second electron-transport layer 918_2 includes an organic compound having a triazine skeleton.

The light-emitting devices 5 were each fabricated by a continuous vacuum process.

Structural formulae of the organic compounds used for the light-emitting devices 5 are shown below.

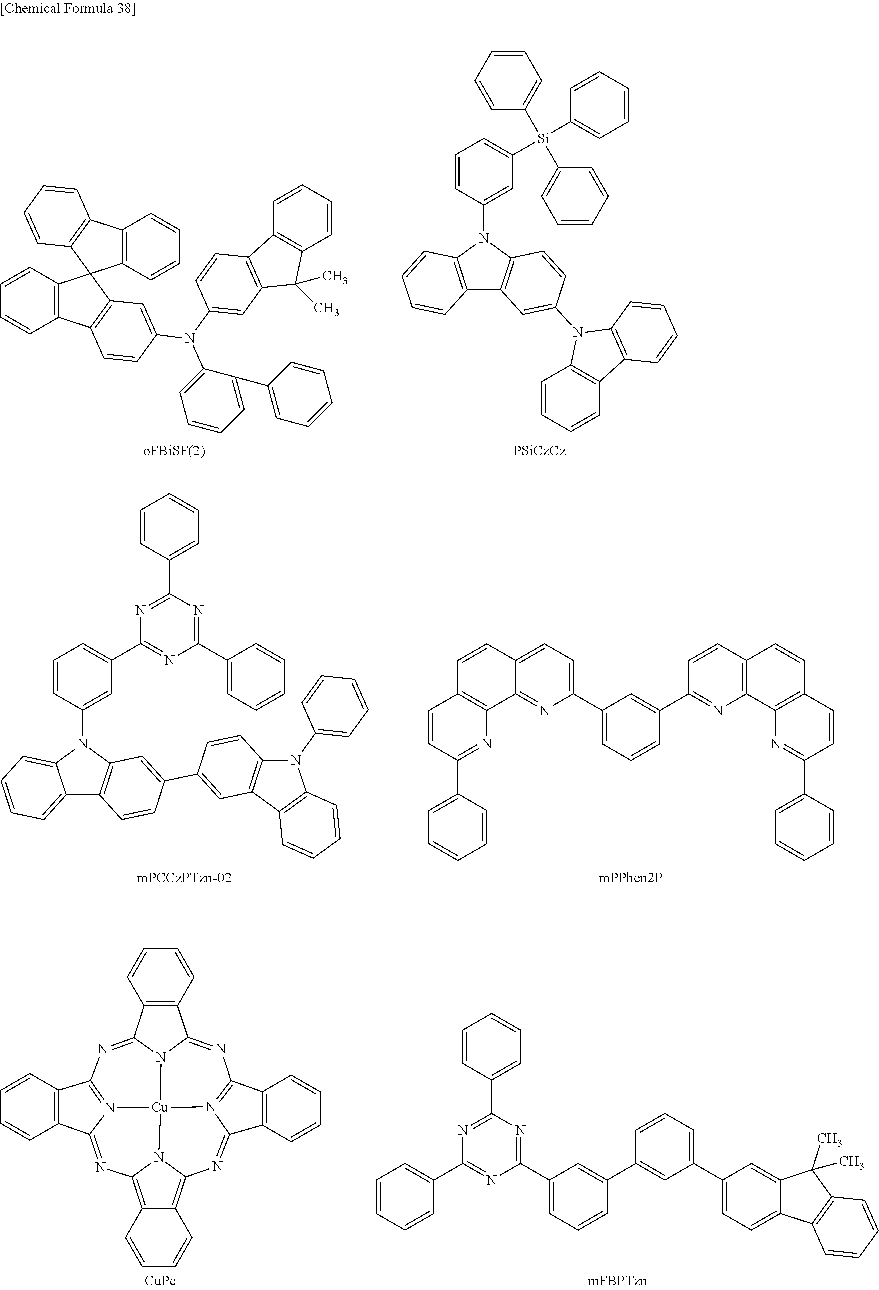

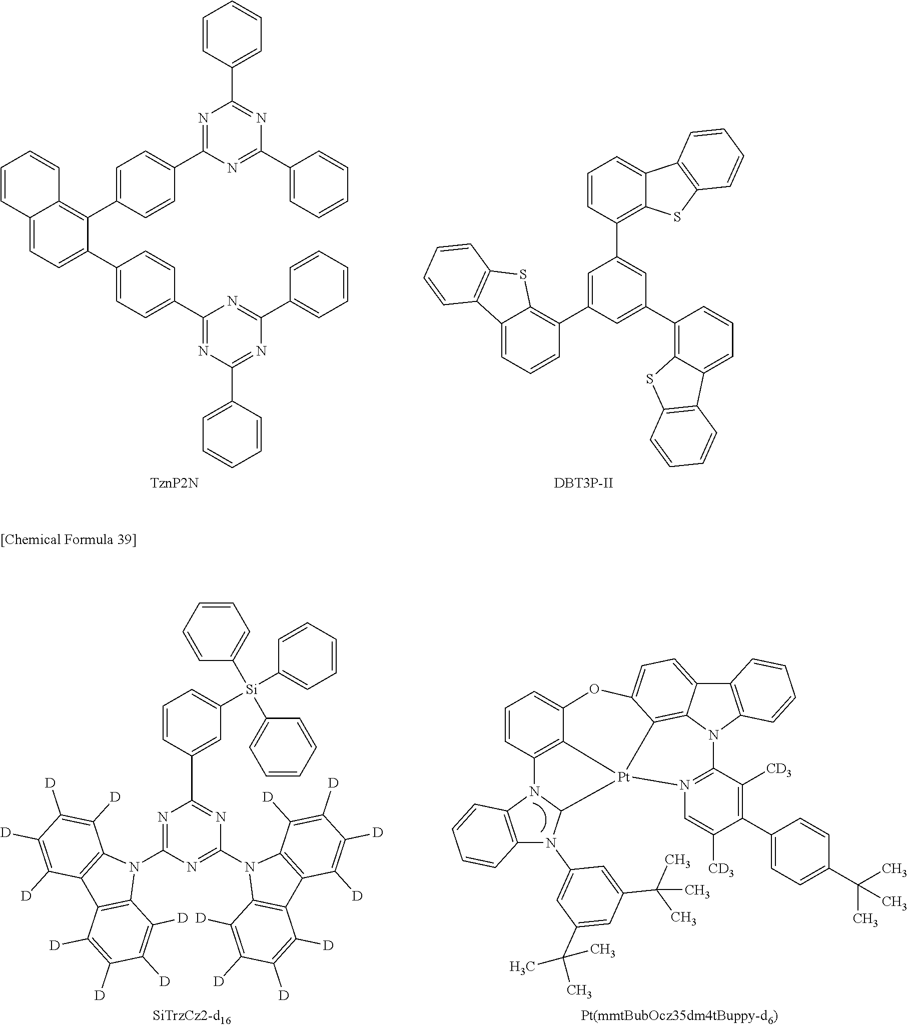

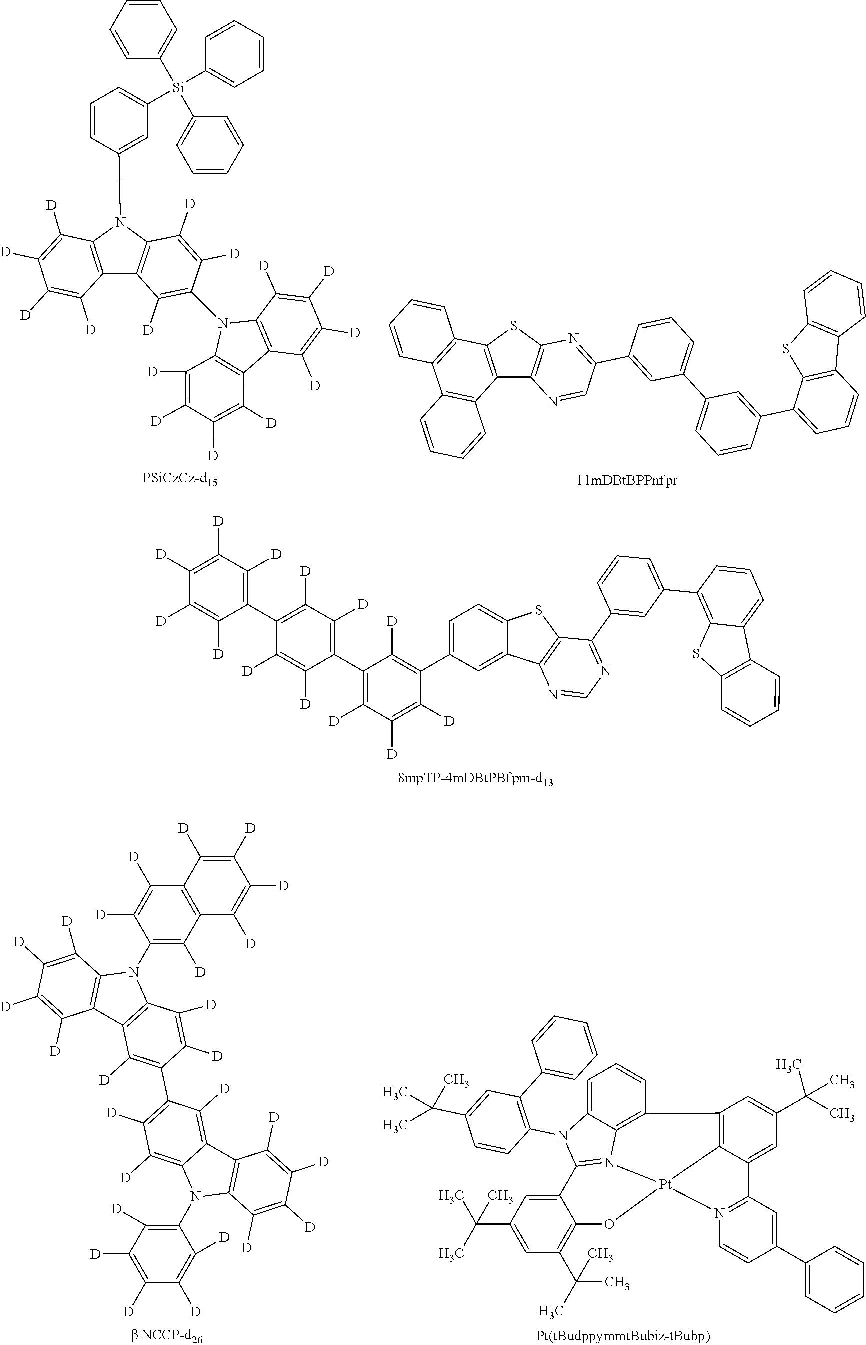

FIG. 26 illustrates the structure of the light-emitting device 5B. FIG. 27 illustrates the structures of the light-emitting devices 5R and 5G. The light-emitting devices 5 each have a tandem structure in which the first EL layer 903, the intermediate layer 905, the second EL layer 904, and the second electrode 902 are stacked over the first electrode 901 formed over the substrate 900 that is a glass substrate. Furthermore, the cap layer 909 is provided over the second electrode.

As illustrated in FIG. 26, the first EL layer 903 of the light-emitting device 5B has a structure in which the hole-injection layer 910, the first hole-transport layer 911 (the first hole-transport layer 911_1 and the first hole-transport layer 911_2), the first light-emitting layer 912, and the first electron-transport layer 913 are stacked in this order. The second EL layer 904 of the light-emitting device 5B has a structure in which the second hole-transport layer 916 (the second hole-transport layer 916_1 and the second hole-transport layer 916_2), the second light-emitting layer 917, the second electron-transport layer 918 (the second electron-transport layer 918_1 and the second electron-transport layer 918_2), and the electron-injection layer 919 are stacked in this order.

Meanwhile, as illustrated in FIG. 27, the first EL layer 903 of each of the light-emitting devices 5R and 5G has a structure in which the hole-injection layer 910, the first hole-transport layer 911_1, the first light-emitting layer 912, and the first electron-transport layer 913 are stacked in this order. The second EL layer 904 thereof has a structure in which the second hole-transport layer 916_1, the second light-emitting layer 917, the second electron-transport layer 918 (the second electron-transport layers 918_1 and 918_2), and the electron-injection layer 919 are stacked in this order.

In each of the light-emitting devices 5, the intermediate layer 905 includes the electron-injection buffer region 914 and the layer 915 including the electron-relay region and the charge-generation region.

### <Fabrication Method of Light-Emitting Device 5B>

First, as a reflective electrode, silver (Ag) was deposited over a glass substrate to a thickness of 100 nm by a sputtering method, and then, as a transparent electrode, indium tin oxide containing silicon oxide (ITSO) was deposited to a thickness of 85 nm by a sputtering method, so that the first electrode was formed. Note that the transparent electrode serves as an anode, and the transparent electrode and the reflective electrode can be collectively regarded as the first electrode. The first electrode was 2 mm×2 mm.

Next, in pretreatment for fabricating the light-emitting device over the substrate, the surface of the substrate was washed with water, and baking was performed at 200° C. for one hour.

After that, the substrate was transferred into a vacuum evaporation apparatus where the pressure was reduced to approximately 1×10⁻⁴ Pa, and was subjected to heat treatment at 170° C. for 30 minutes in a heating chamber of the vacuum evaporation apparatus, and then the substrate was cooled down for approximately 30 minutes.

Next, the substrate provided with the first electrode 901 was fixed to a holder provided in the vacuum evaporation apparatus such that the surface on which the first electrode 901 was formed faced downward. Then, the hole-injection layer 910 was formed on the first electrode 901 by co-evaporation of N-(biphenyl-2-yl)-N-(9,9-dimethylfluoren-2-yl)-9,9′-spirobi[9H-fluoren]-2-amine (abbreviation: oFBiSF (2)) and a fluorine-containing material having an electron-acceptor property with a molecular weight of 672 (OCHD-003) at a weight ratio of 1:0.03 to a thickness of 10 nm by an evaporation method using resistance heating.

Subsequently, the first hole-transport layer 911 (the first hole-transport layers 911_1 and 911_2) was formed over the hole-injection layer 910. By an evaporation method using resistance heating, the first hole-transport layer 911_1 was formed by evaporation of oFBiSF (2) to a thickness of 50 nm, and then the first hole-transport layer 911_2 was formed over the first hole-transport layer 911_1 by evaporation of 9-[3-(triphenylsilyl)phenyl]-3,9′-bi-9H-carbazole (abbreviation: PSiCzCz) to a thickness of 5 nm.

Next, the first light-emitting layer 912 was formed over the first hole-transport layer 911. By an evaporation method using resistance heating, the first light-emitting layer 912 was formed by co-evaporation of 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d₁₆) (abbreviation: SiTrzCz2-d₁₆), 9-[3-(triphenylsilyl)phenyl]-3,9′-(bi-9H-carbazole-d₁₅) (abbreviation: PSiCzCz-d₁₅), and (2-{3-[3-(3,5-di-tert-butylphenyl)benzimidazol-1-yl-2-ylidene-κC²]phenoxy-κC²}-9-[4-tert-butylphenyl-3,5-di(methyl-3)-2-pyridinyl-κN]carbazole-2,1-diyl-κC)platinum(II) (abbreviation: Pt(mmtBubOcz35dm4tBuppy-d₆)) at a weight ratio of 0.45:0.45:0.10 to a thickness of 25 nm.

Next, the first electron-transport layer 913 was formed over the first light-emitting layer 912 by evaporation of 9-[3-(4,6-diphenyl-1,3,5-triazin-2-yl)phenyl]-9′-phenyl-2,3′-bi-9H-carbazole (abbreviation: mPCCzPTzn-02) to a thickness of 10 nm.

Next, the intermediate layer 905 was provided. First, by an evaporation method using resistance heating, a layer to be the electron-injection buffer region 914 was formed over the first electron-transport layer 913 by co-evaporation of 2,2′-(1,3-phenylene)bis(9-phenyl-1,10-phenanthroline) (abbreviation: mPPhen2P) and ytterbium (Yb) at a volume ratio of 1:0.02 to a thickness of 5 nm.

Then, as the electron-relay region, copper phthalocyanine (abbreviation: CuPc) was deposited to a thickness of 2 nm. Next, as the charge-generation region, oFBiSF (2) and a fluorine-containing material having an electron-acceptor property with a molecular weight of 672 (OCHD-003) were deposited by co-evaporation at a weight ratio of 1:0.15 to a thickness of 10 nm by an evaporation method using resistance heating. Thus, the layer 915 including the electron-relay region and the charge-generation region was formed.

Next, the second EL layer 904 was provided over the intermediate layer 905.

First, the second hole-transport layer 916 (the second hole-transport layers 916_1 and 916_2) was formed. After the second hole-transport layer 916_1 was formed by evaporation of OFBiSF (2) to a thickness of 45 nm, the second hole-transport layer 916_2 was formed over the second hole-transport layer 916_1 by evaporation of PSiCzCz to a thickness of 5 nm.

Next, the second light-emitting layer 917 was formed over the second hole-transport layer 916 by co-evaporation of SiTrzCz2-d₁₆, PSiCzCz-d₁₅, and Pt(mmtBubOcz35dm4tBuppy-d₆) at a weight ratio of 0.45:0.45:0.10 to a thickness of 25 nm by an evaporation method using resistance heating.

Next, the second electron-transport layer 918 (the second electron-transport layers 918_1 and 918_2) was formed over the second light-emitting layer 917. By an evaporation method using resistance heating, the second electron-transport layer 918_1 was formed by evaporation of 2-[3′-(9,9-dimethyl-9H-fluoren-2-yl)biphenyl-3-yl]-4,6-diphenyl-1,3,5-triazine (abbreviation: mFBPTzn) to a thickness of 10 nm, and then the second electron-transport layer 918_2 was formed by co-evaporation of 2,2′-(1,2-naphthalenediyldi-4,1-phenylene)bis[4,6-diphenyl-1,3,5-triazine](abbreviation: TznP2N) and 8-quinolinolato-lithium (abbreviation: Liq) at a volume ratio of 1:1 to a thickness of 25 nm.

Next, the electron-injection layer 919 was formed over the second electron-transport layer 918 by co-evaporation of lithium fluoride (LiF) and ytterbium (Yb) at a volume ratio of 2:1 to a thickness of 1.5 nm.

Next, the second electrode 902 was formed over the electron-injection layer 919 by co-evaporation of Ag and Mg at a volume ratio of 1:0.1 to a thickness of 15 nm. Note that the second electrode 902 is a transflective electrode having functions of transmitting light and reflecting light.

Then, as the cap layer 909, 4,4′,4″-(benzene-1,3,5-triyl)tri(dibenzothiophene) (abbreviation: DBT3P-II) was deposited to a thickness of 70 nm by evaporation, which leads to an improved light extraction efficiency.

Through the above process, the light-emitting device 5B was fabricated. Table 40 lists the structure of the light-emitting device 5B.

TABLE 40

| | Thickness | |
|---|---|---|
| | [nm] | Light-emitting device 5B |
| Cap layer | 70 | DBT3P-II |
| Second electrode 902 | 15 | Ag:Mg (1:0.1) |
| Electron-injection layer 919 | 1.5 | LiF:Yb (2:1) |
| Second electron-transport layer 918_2 | 25 | TznP2N:Liq (1:1) |
| Second electron-transport layer 918_1 | 10 | mFBPTzn |
| Second light-emitting layer 917 | 25 | SiTrzCz2-d₁₆:PSiCzCz-d₁₅:Pt(mmtBubOcz35dm4tBuppy-d₆) |
| | | (0.45:0.45:0.10) |
| Second hole-transport layer 916_2 | 5 | PSiCzCz |
| Second hole-transport layer 916_1 | 45 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Yb (1:0.02) |
| First electron-transport layer 913 | 10 | mPCCzPTzn-02 |
| First light-emitting layer 912 | 25 | SiTrzCz2-d₁₆:PSiCzCz-d₁₅:Pt(mmtBubOcz35dm4tBuppy-d₆) |
| | | (0.45:0.45:0.10) |
| First hole-transport layer 911_2 | 5 | PSiCzCz |
| First hole-transport layer 911_1 | 50 | oFBiSF(2) |
| Hole-injection layer 910 | 10 | oFBiSF(2):OCHD-003 (1:0.03) |
| First electrode 901 | 85 | ITSO |
| | 100 | Ag |

### <Fabrication Method of Light-Emitting Device 5R>

The light-emitting device 5R is different from the light-emitting device 5B in the structures and thicknesses of the first and second light-emitting layers 912 and 917 and the first and second hole-transport layers 911 and 916. Other components were fabricated in a manner similar to that for the light-emitting device 5B.

Specifically, each of the first and second light-emitting layers 912 and 917 in the light-emitting device 5R was formed by co-evaporation of 11-[3′-(dibenzothiophen-4-yl)biphenyl-3-yl]phenanthro[9′,10′:4,5]furo[2,3-b]pyrazine (abbreviation: 11mDBtBPPnfpr), 9-(2-naphthyl-1,3,4,5,6,7,8-d₇)-9′-(phenyl-2,3,4,5,6-d₅)-3,3′-bi-9H-carbazole-1,1′,2,2′,4,4′,5,5′,6,6′,7,7′,8,8′-d₁₄ (abbreviation: βNCCP-d₂₆), and OCPG-006 as a material that emits red phosphorescent light at a weight ratio of 0.6:0.4:0.05 to a thickness of 40 nm.

In the light-emitting device 5R, the first hole-transport layer 911_2 and the second hole-transport layer 916_2 of the light-emitting device 5B were not provided. Stated differently, the first hole-transport layer 911 (the first hole-transport layer 911_1) was formed by evaporation of oFBiSF (2) to a thickness of 160 nm by an evaporation method using resistance heating. In addition, the second hole-transport layer 916 (the second hole-transport layer 916_1) was formed by evaporation of oFBiSF (2) to a thickness of 75 nm by an evaporation method using resistance heating.

Table 41 lists the structure of the light-emitting device 5R.

TABLE 41

| | Thickness | |
|---|---|---|
| | [nm] | Light-emitting device 5R |
| Cap layer | 70 | DBT3P-II |
| Second electrode 902 | 15 | Ag:Mg (1:0.1) |
| Electron-injection layer 919 | 1.5 | LiF:Yb (2:1) |
| Second electron-transport layer 918_2 | 25 | TznP2N:Liq (1:1) |
| Second electron-transport layer 918_1 | 10 | mFBPTzn |
| Second light-emitting layer 917 | 40 | 11mDBtBPPnfpr:βNCCP-d₂₆:OCPG-006 |
| | | (0.6:0.4:0.05) |
| Second hole-transport layer 916_1 | 75 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Yb (1:0.02) |
| First electron-transport layer 913 | 10 | mPCCzPTzn-02 |
| First light-emitting layer 912 | 40 | 11mDBtBPPnfpr:βNCCP-d₂₆:OCPG-006 |
| | | (0.6:0.4:0.05) |
| First hole-transport layer 911_1 | 160 | oFBiSF(2) |
| Hole-injection layer 910 | 10 | oFBiSF(2):OCHD-003 (1:0.03) |
| First electrode 902 | 85 | ITSO |
| | 100 | Ag |

### <Fabrication Method of Light-Emitting Device 5G>

The light-emitting device 5G is different from the light-emitting device 5R in the thicknesses of the first and second hole-transport layers 911 and 916 and the structures of the first and second light-emitting layers 912 and 917. Other components were fabricated in a manner similar to that for the light-emitting device 5R.

Specifically, the first light-emitting layer 912 and the second light-emitting layer 917 in the light-emitting device 5G were each formed by co-evaporation of 8-(1,1′:4′,1″-terphenyl-3-yl-2,4,5,6,2′,3′,5′,6′,2″,3″,4″,5″,6″-d₁₃)-4-[3-(dibenzothiophen-4-yl)phenyl]-[1]benzofuro[3,2-d]pyrimidine (abbreviation: 8mpTP-4mDBtPBfpm-d₁₃), βNCCP-d₂₆, and (2-{1-(5-tert-butylbiphenyl-2-yl)-4-[3-tert-butyl-5-(4-phenyl-2-pyridinyl-κN)phenyl-κC6]-2-benzimidazolyl-κN}-4,6-di-tert-butylphenolato-κO)platinum(II) (abbreviation: Pt(tBudppymmtBubiz-tBubp)) at a weight ratio of 0.5:0.5:0.1 to a thickness of 40 nm.

In the light-emitting device 5G, the thickness of the first hole-transport layer 911 was set to 90 nm, and the thickness of the second hole-transport layer 916 was set to 65 nm.

Table 42 lists the structure of the light-emitting device 5G.

TABLE 42

| | Thickness | |
|---|---|---|
| | [nm] | Light-emitting device 5G |
| Cap layer | 70 | DBT3P-II |
| Second electrode 902 | 15 | Ag:Mg (1:0.1) |
| Electron-injection layer 919 | 1.5 | LiF:Yb (2:1) |
| Second electron-transport layer 918_2 | 25 | TznP2N:Liq (1:1) |
| Second electron-transport layer 918_1 | 10 | mFBPTzn |
| Second light-emitting layer 917 | 40 | 8mpTP-4mDBtPBfpm-d₁₃:βNCCP-d₂₆:Pt(tBudppymmtBubiz-tBubp) |
| | | (0.5:0.5:0.1) |
| Second hole-transport layer 916_1 | 65 | oFBiSF(2) |
| Charge-generation region | 10 | oFBiSF(2):OCHD-003 (1:0.15) |
| Electron-relay region | 2 | CuPc |
| Electron-injection buffer region 914 | 5 | mPPhen2P:Yb (1:0.02) |
| First electron-transport layer 913 | 10 | mPCCzPTzn-02 |
| First light-emitting layer 912 | 40 | 8mpTP-4mDBtPBfpm-d₁₃:βNCCP-d₂₆:Pt(tBudppymmtBubiz-tBubp) |
| | | (0.5:0.5:0.1) |
| First hole-transport layer 911_1 | 90 | oFBiSF(2) |
| Hole-injection layer 910 | 10 | oFBiSF(2):OCHD-003 (1:0.03) |
| First electrode 902 | 85 | ITSO |
| | 100 | Ag |

### <Measurement Results of PL Spectra of Host Materials Used in Devices>

Here, Examples 1 to 3 can be referred to for the PL spectra (at room temperature) of the host materials used in the devices, the HOMO levels and the LUMO levels of the host materials and the light-emitting substances used in the devices, and the T₁ levels of the host materials in the light-emitting layers and the substances in the first hole-transport layer, the second hole-transport layer, the first electron-transport layer, and the second electron-transport layer.

As shown in FIG. 131, the absorption edge on the longer wavelength side of the absorption spectrum of Pt(tBudppymmtBubiz-tBubp) is at 512 nm. As shown in FIG. 79, the emission edge on the shorter wavelength side of the PL spectrum of the mixed film of βNCCP-d₂₆ and 8mpTP-4mDBtPBfpm-d₁₃ (the PL spectrum of the exciplex) is at 442 nm. These indicate that the absorption edge on the longer wavelength side of the absorption spectrum of Pt(tBudppymmtBubiz-tBubp) used as the emission center substance is at a longer wavelength than the emission edge on the shorter wavelength side of the PL spectrum of the exciplex formed by the hosts. This demonstrates that energy from the exciplex can be efficiently transferred to the emission center substance.

The emission edge of the PL spectrum of Pt(tBudppymmtBubiz-tBubp) is at 498 nm. This indicates that the emission edge on the shorter wavelength side of the PL spectrum of Pt(tBudppymmtBubiz-tBubp) used as the emission center substance is at a longer wavelength than the emission edge on the shorter wavelength side of the PL spectrum of the exciplex formed by the hosts. This demonstrates that energy from the exciplex can be efficiently transferred to the emission center substance.

The HOMO level and the LUMO level of Pt(tBudppymmtBubiz-tBubp) were −5.4 eV and −2.78 eV, respectively. This indicates that the energy difference between the HOMO level (−5.4 eV) and the LUMO level (−2.78 eV) of Pt(tBudppymmtBubiz-tBubp), which corresponds to the band gap thereof, was 2.62 eV. The energy difference between the HOMO level and the LUMO level of the exciplex formed by the host materials was 2.61 eV, which corresponds to the energy difference between the HOMO level (−5.62 eV) of βNCCP-d₂₆ as the hole-transport organic compound and the LUMO level (−3.01 eV) of 8mpTP-4mDBtPBfpm-d₁₃ as the electron-transport organic compound. This indicates that the energy difference between the HOMO and LUMO levels of Pt(tBudppymmtBubiz-tBubp) was greater than the energy difference between the HOMO and LUMO levels of the exciplex.

The T₁ level of Pt(tBudppymmtBubiz-tBubp) calculated from the emission edge on the shorter wavelength side of the PL spectrum was 2.49 eV (498 nm).

The T₁ level (2.55 eV) of βNCCP-d₂₆ and the T₁ level (2.55 eV) of 8mpTP-4mDBtPBfpm-d₁₃, which are the host materials, have each been found to be higher than the T₁ level (2.49 eV) of Pt(tBudppymmtBubiz-tBubp) as the emission center substance. This indicates that the light-emitting device 5G emits light efficiently.

Furthermore, the T₁ level (2.52 eV) of oFBiSF (2) used for the first hole-transport layer and the second hole-transport layer has been found to be higher than the T₁ level (2.49 eV) of Pt(tBudppymmtBubiz-tBubp) as the emission center substance. This indicates that the light-emitting device 5G emits light efficiently.

The T₁ level (2.59 eV) of mPCCzPTzn-02 used for the first electron-transport layer and the T₁ level (2.54 eV) of mFBPTzn used for the second electron-transport layer have been found to be higher than the T₁ level (2.49 eV) of Pt(tBudppymmtBubiz-tBubp) as the emission center substance. This indicates that the light-emitting device 5G emits light efficiently.

### <Device Characteristics>

The light-emitting devices 5 were sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting devices 5 were measured.

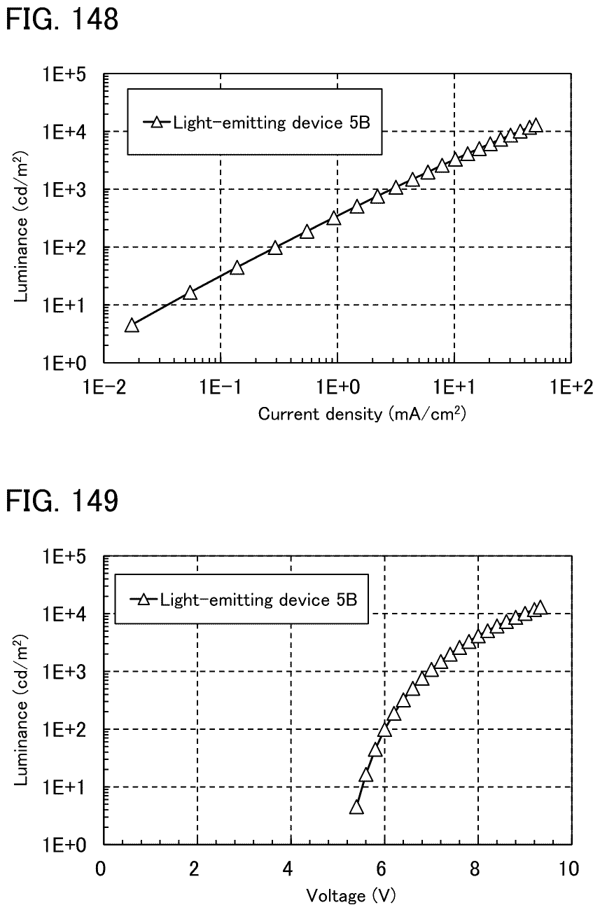

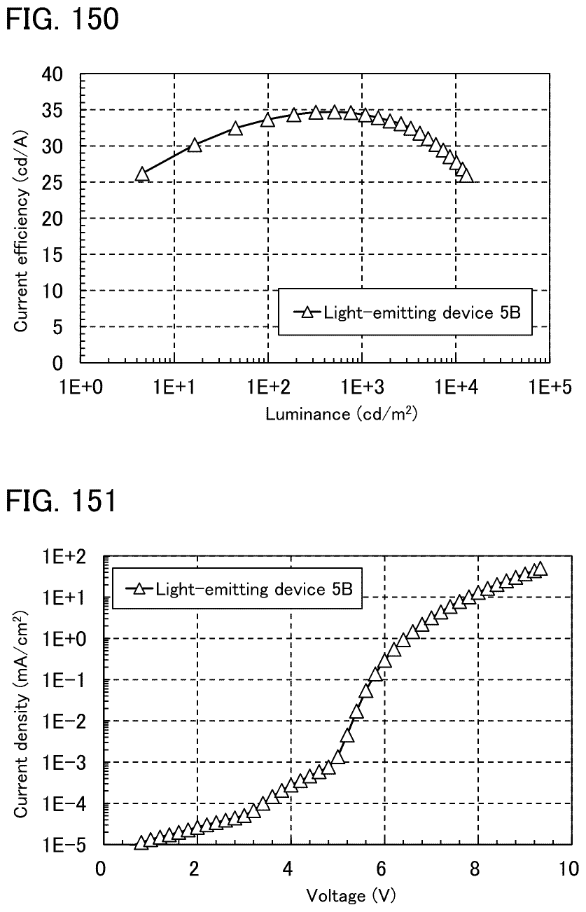

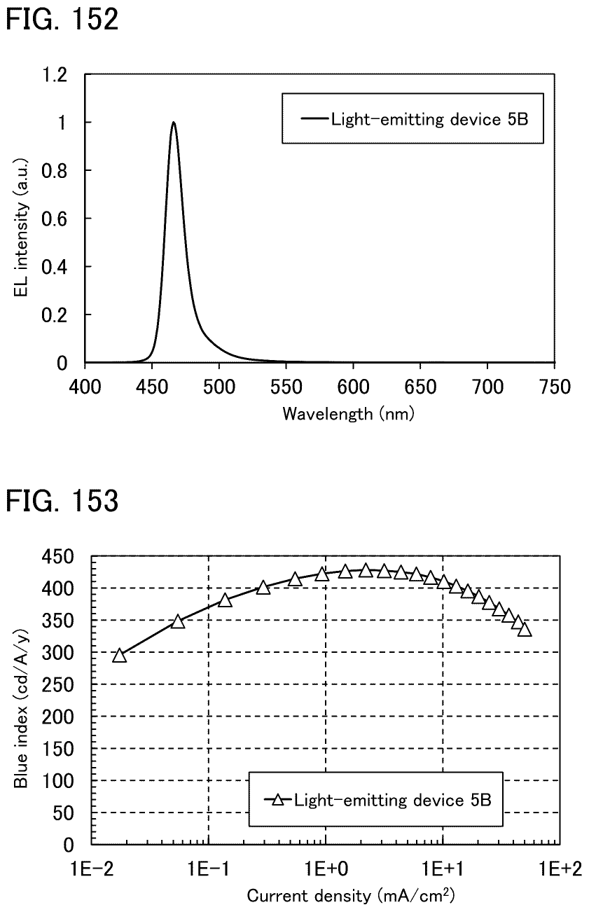

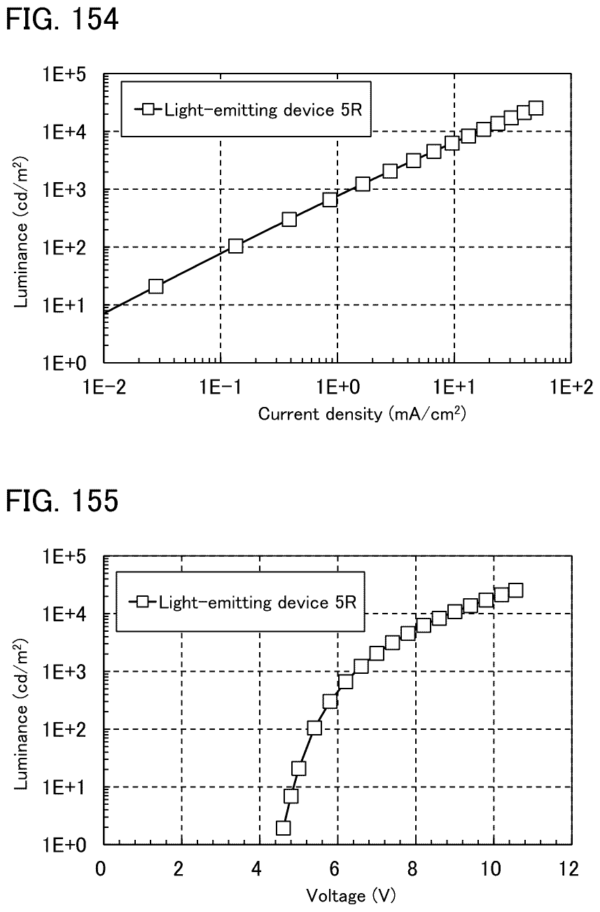

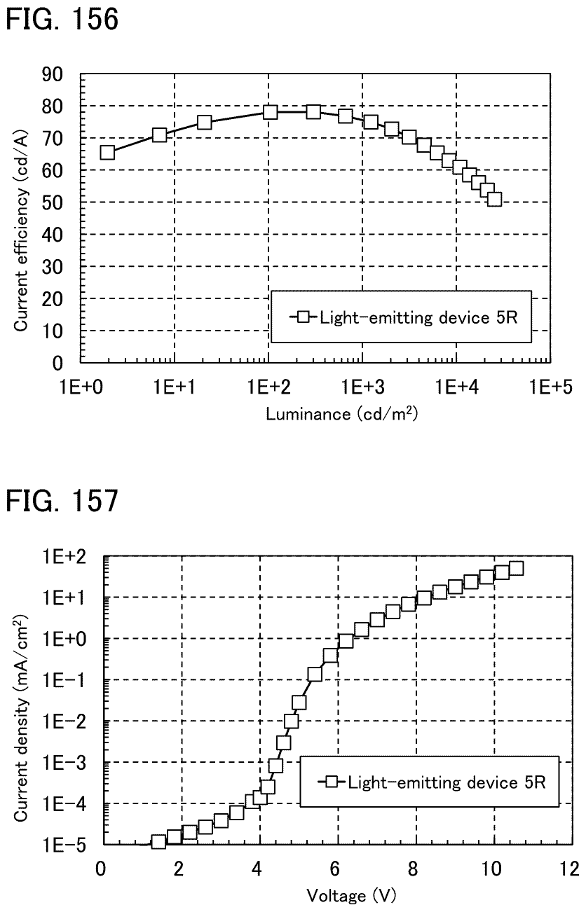

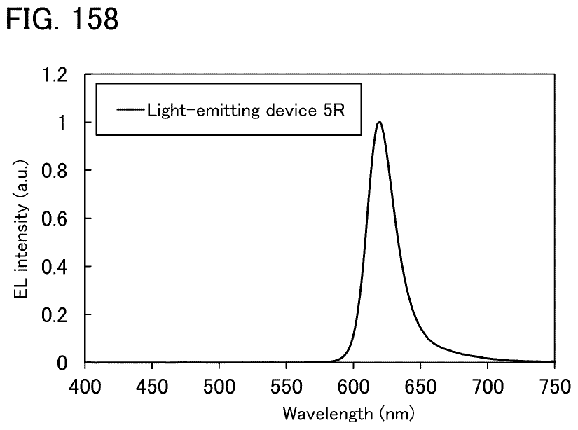

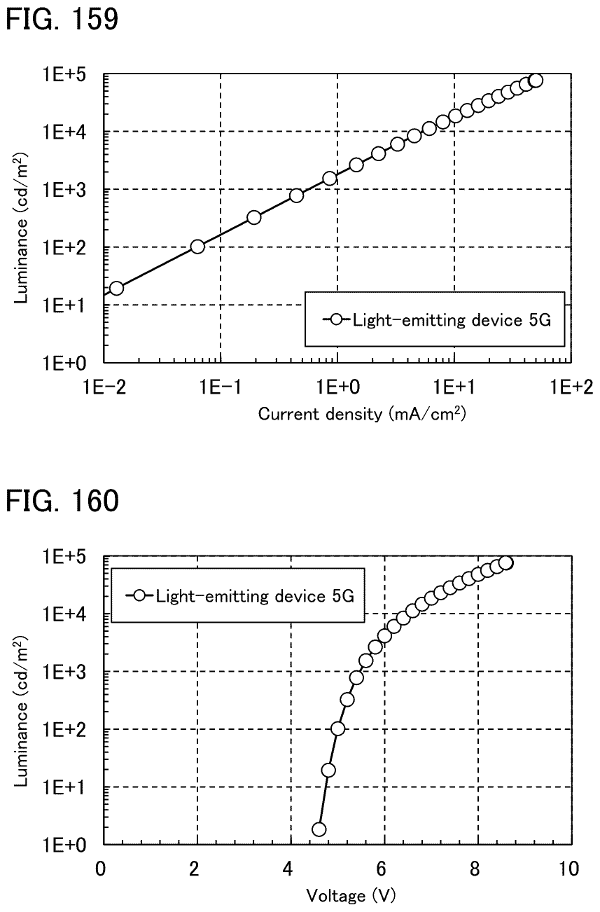

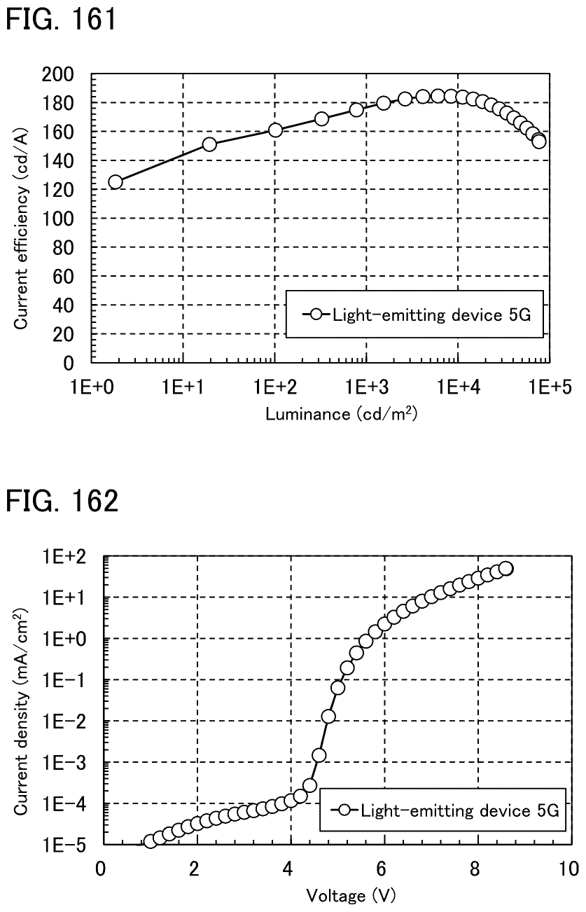

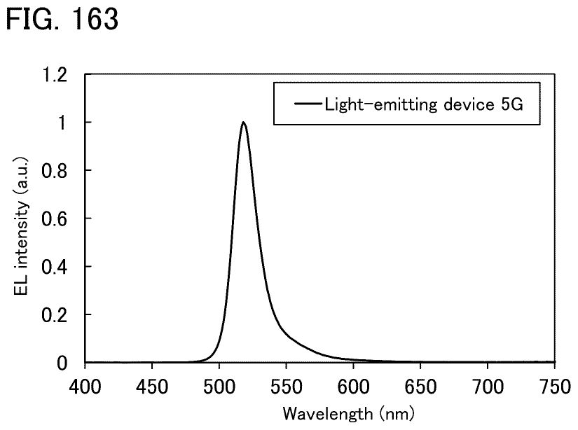

FIG. 148 shows the luminance-current density characteristics of the light-emitting device 5B, FIG. 149 shows the luminance-voltage characteristics thereof, FIG. 150 shows the current efficiency-luminance characteristics thereof, FIG. 151 shows the current density-voltage characteristics thereof, FIG. 152 shows the electroluminescence spectrum thereof, and FIG. 153 shows the blue index-current density characteristics thereof. FIG. 154 shows the luminance-current density characteristics of the light-emitting device 5R, FIG. 155 shows the luminance-voltage characteristics thereof, FIG. 156 shows the current efficiency-luminance characteristics thereof, FIG. 157 shows the current density-voltage characteristics thereof, and FIG. 158 shows the electroluminescence spectrum thereof. FIG. 159 shows the luminance-current density characteristics of the light-emitting device 5G, FIG. 160 shows the luminance-voltage characteristics thereof, FIG. 161 shows the current efficiency-luminance characteristics thereof, FIG. 162 shows the current density-voltage characteristics thereof, and FIG. 163 shows the electroluminescence spectrum thereof.

Table 43 shows the main characteristics of the light-emitting devices 5 at a luminance of approximately 1000 cd/m². The luminance, CIE chromaticity, and electroluminescence spectra were measured at normal temperature with a spectroradiometer (SR-ULIR, produced by TOPCON TECHNOHOUSE CORPORATION).

TABLE 43

| | | | Current | | | | Current | |
|---|---|---|---|---|---|---|---|---|
| | Voltage | Current | density | Chromaticity | Chromaticity | Luminance | efficiency | BI value |
| | (V) | (mA) | (mA/cm²) | x | y | (cd/m²) | (cd/A) | (cd/A/y) |
| Light-emitting device 5B | 7.00 | 0.127 | 3.16 | 0.130 | 0.0803 | 1085 | 34.3 | 427 |
| Light-emitting device 5R | 6.60 | 0.0658 | 1.64 | 0.684 | 0.315 | 1232 | 74.9 | — |
| Light-emitting device 5G | 5.40 | 0.0178 | 0.446 | 0.163 | 0.749 | 780 | 175 | — |

According to FIGS. 148 to 153 and the above table, the light-emitting device 5B emitted phosphorescent light originating from Pt(mmtBubOcz35dm4ppy-d₆). It has also been found that the light-emitting device 5B has favorable emission characteristics and is highly efficient as a blue-light-emitting device.

According to FIGS. 154 to 158 and the above table, the light-emitting device 5R exhibited red light emission originating from OCPG-006. It has also been found that the light-emitting device 5R has favorable emission characteristics.

According to FIGS. 159 to 163 and the above table, the light-emitting device 5G exhibited green light emission originating from Pt(tBudppymmtBubiz-tBubp). It has also been found that the light-emitting device 5G has favorable emission characteristics.

### <Panel Characteristics>

Next, a light-emitting apparatus 5 including the light-emitting device 5B, the light-emitting device 5R, and the light-emitting device 5G respectively in blue, red, and green subpixels was assumed, and the power consumption of its display portion (except for the power consumption of a driving transistor, a driving circuit, and the like) was tentatively calculated. Note that each of the light-emitting devices assumed to be used in the light-emitting apparatus 5 is a tandem light-emitting device, and the same emission center substance is used in the plurality of light-emitting layers in each of the light-emitting devices. Thus, a side-by-side patterning method was employed for the light-emitting apparatus 5.

Since the conditions of the light-emitting apparatus 5 assumed for the tentative calculation are the same as those of the display device 1 described in Example 1, Example 1 can be referred to for the conditions. Table 44 shows the results of calculating the power consumption of the light-emitting apparatus 5 assumed to include the light-emitting devices 5R, 5G, and 5B.

TABLE 44
Light-emitting apparatus 5

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.684 | 0.315 | 301.7 | 3017 | 70.6 | 4.27 | 29.5 | 7.35 | 217 |
| Green | 0.163 | 0.749 | 594.9 | 5949 | 185 | 3.22 | 22.2 | 6.19 | 138 |
| Blue | 0.130 | 0.080 | 103.4 | 1034 | 34.3 | 3.01 | 20.8 | 6.97 | 145 |
| Full white | 0.313 | 0.329 | 1000 | — | 95.1 | — | 72.4 | — | 499 |

The above table shows that the light-emitting apparatus 5 assumed to include the light-emitting devices 5 has high current efficiency and low driving voltage in white light emission.

The above results show that the light-emitting devices 5 of embodiments of the present invention have favorable characteristics, and the light-emitting device 5B has a particularly low driving voltage and a particularly high emission efficiency.

This application is based on Japanese Patent Application Serial No. 2024-096254 filed with Japan Patent Office on Jun. 13, 2024, the entire contents of which are hereby incorporated by reference.

What is claimed is:

1. A light-emitting device comprising:
a first electrode;
a second electrode;
an intermediate layer;
a first light-emitting layer; and
a second light-emitting layer,
wherein the intermediate layer is between the first electrode and the second electrode,
wherein the first light-emitting layer is between the first electrode and the intermediate layer,
wherein the second light-emitting layer is between the intermediate layer and the second electrode,
wherein the first light-emitting layer comprises a first emission center substance and a first organic compound,
wherein the first organic compound comprises deuterium,
wherein the second light-emitting layer comprises a second emission center substance,
wherein the first emission center substance is a phosphorescent substance having an emission peak at a wavelength longer than or equal to 440 nm and shorter than or equal to 500 nm,
wherein a difference between a maximum peak wavelength of a PL spectrum of the first emission center substance and a maximum peak wavelength of a PL spectrum of the second emission center substance is less than or equal to 30 nm, and
wherein the first light-emitting layer and the second light-emitting layer each emit light with a color gamut different from a color gamut of light emitted by a light-emitting layer included in at least one of a plurality of adjacent light-emitting devices.

2. A light-emitting device comprising:
a first electrode;
a second electrode;
an intermediate layer;
a first light-emitting layer; and
a second light-emitting layer,
wherein the intermediate layer is between the first electrode and the second electrode,
wherein the first light-emitting layer is between the first electrode and the intermediate layer,
wherein the second light-emitting layer is between the intermediate layer and the second electrode,
wherein the first light-emitting layer comprises a first emission center substance, a first organic compound, and a second organic compound,
wherein at least one of the first organic compound and the second organic compound comprises deuterium,
wherein the second light-emitting layer comprises a second emission center substance,
wherein the first emission center substance is a phosphorescent substance having an emission peak at a wavelength longer than or equal to 440 nm and shorter than or equal to 500 nm,
wherein a difference between a maximum peak wavelength of a PL spectrum of the first emission center substance and a maximum peak wavelength of a PL spectrum of the second emission center substance is less than or equal to 30 nm, and
wherein the first light-emitting layer and the second light-emitting layer each emit light with a color gamut different from a color gamut of light emitted by a light-emitting layer included in at least one of a plurality of adjacent light-emitting devices.

3. The light-emitting device according to claim 2,
wherein the first organic compound comprises a π-electron deficient heteroaromatic ring, and
wherein the second organic compound comprises at least one of a π-electron rich heteroaromatic ring and an aromatic amine skeleton.

4. The light-emitting device according to claim 3,
wherein the second light-emitting layer comprises the second emission center substance, a third organic compound, and a fourth organic compound,
wherein the third organic compound comprises a π-electron deficient heteroaromatic ring,
wherein the fourth organic compound comprises at least one of a-electron rich heteroaromatic ring and an aromatic amine skeleton,
wherein at least one of the third organic compound and the fourth organic compound comprises deuterium,
wherein a combination of the first organic compound and the second organic compound forms a first exciplex,
wherein a combination of the third organic compound and the fourth organic compound forms a second exciplex,
wherein an emission edge on a shorter wavelength side of a PL spectrum of the first exciplex is positioned at a shorter wavelength than an absorption edge on a longer wavelength side of an absorption spectrum of the first emission center substance, and
wherein an emission edge on a shorter wavelength side of a PL spectrum of the second exciplex is positioned at a shorter wavelength than an absorption edge on a longer wavelength side of an absorption spectrum of the second emission center substance.

5. The light-emitting device according to claim 4,
wherein a difference between a lowest triplet excitation energy level of the first organic compound and a lowest triplet excitation energy level of the second organic compound is less than or equal to 0.20 eV, and
wherein a difference between a lowest triplet excitation energy level of the third organic compound and a lowest triplet excitation energy level of the fourth organic compound is less than or equal to 0.20 eV.

6. The light-emitting device according to claim 4,
wherein a phosphorescence lifetime or a delayed fluorescence lifetime at 77 K of the first organic compound is 1.20 times or more a phosphorescence lifetime or a delayed fluorescence lifetime at 77 K of a fifth organic compound that is a non-deuterated substance of the first organic compound, and
wherein a phosphorescence lifetime or a delayed fluorescence lifetime at 77 K of the second organic compound is 1.05 times or more a phosphorescence lifetime or a delayed fluorescence lifetime at 77 K of a sixth organic compound that is a non-deuterated substance of the second organic compound.

7. The light-emitting device according to claim 4, wherein a product of X and Y is greater than or equal to 1.26 when a phosphorescence lifetime or a delayed fluorescence lifetime at 77 K of the first organic compound is X times a phosphorescence lifetime or a delayed fluorescence lifetime at 77 K of a fifth organic compound that is a non-deuterated substance of the first organic compound and a phosphorescence lifetime or a delayed fluorescence lifetime at 77 K of the second organic compound is Y times a phosphorescence lifetime or a delayed fluorescence lifetime at 77 K of a sixth organic compound that is a non-deuterated substance of the second organic compound.

8. The light-emitting device according to claim 1, wherein the first emission center substance is the same substance as the second emission center substance.

9. The light-emitting device according to claim 1, wherein the first emission center substance is a platinum complex.

10. The light-emitting device according to claim 1, further comprising:
a first hole-transport layer between the first electrode and the first light-emitting layer; and
a second hole-transport layer between the intermediate layer and the second light-emitting layer,
wherein the first hole-transport layer or the second hole-transport layer has a stacked-layer structure comprising at least a first layer comprising a seventh organic compound and a second layer comprising an eighth organic compound,
wherein the second layer is in contact with the first light-emitting layer or the second light-emitting layer,
wherein the seventh organic compound comprises an amine skeleton and a polycyclic hydrocarbon, and
wherein the eighth organic compound comprises a π-electron rich polycyclic heteroaromatic ring.

11. The light-emitting device according to claim 1, further comprising:
a first electron-transport layer between the second light-emitting layer and the second electrode,
wherein the first electron-transport layer comprises a layer comprising a ninth organic compound comprising a triazine skeleton, and
wherein the intermediate layer comprises a first mixed layer of lithium or a lithium compound and a tenth organic compound comprising a phenanthroline skeleton.

12. The light-emitting device according to claim 11,
wherein the first electron-transport layer further comprises a second mixed layer of lithium or a lithium compound and an eleventh organic compound comprising a triazine skeleton, and
wherein the second mixed layer is between the second electrode and the layer comprising the ninth organic compound.

13. A display device comprising:
a first light-emitting device; and
a second light-emitting device whose emission color is different from an emission color of the first light-emitting device,
wherein the first light-emitting device comprises a first electrode, a second electrode, a first intermediate layer, a first light-emitting layer, and a second light-emitting layer,
wherein the first intermediate layer is between the first electrode and the second electrode,
wherein the first light-emitting layer is between the first electrode and the first intermediate layer,
wherein the second light-emitting layer is between the first intermediate layer and the second electrode,
wherein the first light-emitting layer comprises a first emission center substance, a first organic compound, and a second organic compound,
wherein at least one of the first organic compound and the second organic compound comprises deuterium,
wherein the second light-emitting layer comprises a second emission center substance,
wherein the first emission center substance and the second emission center substance are phosphorescent substances each having an emission peak at a wavelength longer than or equal to 440 nm and shorter than or equal to 500 nm,
wherein a difference between a maximum peak wavelength of a PL spectrum of the first emission center substance and a maximum peak wavelength of a PL spectrum of the second emission center substance is less than or equal to 30 nm,
wherein the second light-emitting device comprises a third electrode, a fourth electrode, a second intermediate layer, a third light-emitting layer, and a fourth light-emitting layer,
wherein the second intermediate layer is between the third electrode and the fourth electrode,
wherein the third light-emitting layer is between the third electrode and the second intermediate layer,
wherein the fourth light-emitting layer is between the second intermediate layer and the fourth electrode,
wherein the third light-emitting layer comprises a third emission center substance,
wherein the fourth light-emitting layer comprises a fourth emission center substance,
wherein a difference between a maximum peak wavelength of a PL spectrum of the third emission center substance and a maximum peak wavelength of a PL spectrum of the fourth emission center substance is less than or equal to 30 nm, and
wherein each of the first light-emitting layer and the second light-emitting layer emits light with a color gamut different from a color gamut of light emitted by each of the third light-emitting layer and the fourth light-emitting layer.

14. The display device according to claim 13,
wherein the third light-emitting layer comprises a third organic compound, and
wherein the third organic compound comprises deuterium.

15. A display device comprising:
a first light-emitting device;
a second light-emitting device whose emission color is different from an emission color of the first light-emitting device; and
a third light-emitting device whose emission color is different from the emission color of the first light-emitting device and the emission color of the second light-emitting device,
wherein the first light-emitting device comprises a first electrode, a second electrode, a first intermediate layer, a first light-emitting layer, and a second light-emitting layer,
wherein the first intermediate layer is between the first electrode and the second electrode,
wherein the first light-emitting layer is between the first electrode and the first intermediate layer,
wherein the second light-emitting layer is between the first intermediate layer and the second electrode,
wherein the first light-emitting layer comprises a first emission center substance, a first organic compound, and a second organic compound,
wherein at least one of the first organic compound and the second organic compound comprises deuterium,
wherein the second light-emitting layer comprises a second emission center substance,
wherein the first emission center substance and the second emission center substance are phosphorescent substances,
wherein a difference between a maximum peak wavelength of a PL spectrum of the first emission center substance and a maximum peak wavelength of a PL spectrum of the second emission center substance is less than or equal to 30 nm,
wherein the second light-emitting device comprises a third electrode, a fourth electrode, a second intermediate layer, a third light-emitting layer, and a fourth light-emitting layer,
wherein the second intermediate layer is between the third electrode and the fourth electrode,
wherein the third light-emitting layer is between the third electrode and the second intermediate layer,
wherein the fourth light-emitting layer is between the second intermediate layer and the fourth electrode,
wherein the third light-emitting layer comprises a third emission center substance,
wherein the fourth light-emitting layer comprises a fourth emission center substance,
wherein the third emission center substance and the fourth emission center substance are phosphorescent substances,
wherein a difference between a maximum peak wavelength of a PL spectrum of the third emission center substance and a maximum peak wavelength of a PL spectrum of the fourth emission center substance is less than or equal to 30 nm,
wherein the third light-emitting device comprises a fifth electrode, a sixth electrode, a third intermediate layer, a fifth light-emitting layer, and a sixth light-emitting layer,
wherein the third intermediate layer is between the fifth electrode and the sixth electrode,
wherein the fifth light-emitting layer is between the fifth electrode and the third intermediate layer,
wherein the sixth light-emitting layer is between the third intermediate layer and the sixth electrode,
wherein the fifth light-emitting layer comprises a fifth emission center substance,
wherein the sixth light-emitting layer comprises a sixth emission center substance,
wherein the fifth emission center substance and the sixth emission center substance are phosphorescent substances,
wherein a difference between a maximum peak wavelength of a PL spectrum of the fifth emission center substance and a maximum peak wavelength of a PL spectrum of the sixth emission center substance is less than or equal to 30 nm, and
wherein each of the first light-emitting layer and the second light-emitting layer emits light with a color gamut different from a color gamut of light emitted by each of the third light-emitting layer, the fourth light-emitting layer, the fifth light-emitting layer, and the sixth light-emitting layer.

16. The display device according to claim 15,
wherein the third light-emitting layer comprises a third organic compound,
wherein the third organic compound comprises deuterium,
wherein the fifth light-emitting layer comprises a fifth organic compound, and
wherein the fifth organic compound comprises deuterium.
